(19) United States
(12) Patent Application Publication
(10) Pub. No.: US 2023/0269997 A1
(43) Pub. Date: Aug. 24, 2023

(54) LIGHT EMITTING ELEMENT AND POLYCYCLIC COMPOUND FOR THE SAME

(71) Applicant: Samsung Display Co., Ltd., Yongin-si (KR)

(72) Inventors: SUN YOUNG PAK, Suwon-si (KR); TAEIL KIM, Hwaseong-si (KR); Kyoung SUNWOO, Hwaseong-si (KR); MUN-KI SIM, Seoul (KR); CHANSEOK OH, Seoul (KR); MORAN HA, Asan-si (KR)

(21) Appl. No.: 18/073,368

(22) Filed: Dec. 1, 2022

(30) Foreign Application Priority Data
Feb. 24, 2022 (KR) 10-2022-0024101

(51) Int. Cl. H10K 85/30; C07F 5/02; C09K 11/06

(52) U.S. Cl. CPC H01L 51/008; C07F 5/027; C09K 11/06; H01L 51/5012

(57) ABSTRACT

A light emitting element of an embodiment includes a first electrode, a second electrode, and at least one functional layer disposed between the first electrode and the second electrode, wherein the at least one functional layer includes a first compound represented by Formula 1, and at least one compound selected from among a second compound represented by Formula 2, a third compound represented by Formula 3, and a fourth compound represented by Formula 4, thereby showing high efficiency and long-life characteristics.

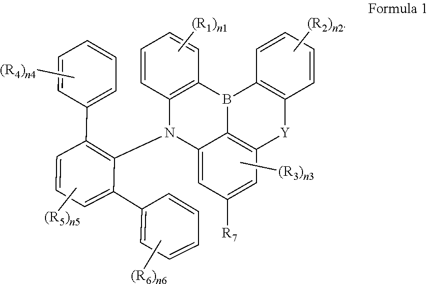

### CROSS-REFERENCE TO RELATED APPLICATIONS

This application claims priority to and the benefit of Korean Patent Application No. 10-2022-0024101, filed on Feb. 24, 2022, in the Korean Intellectual Property Office, the entire content of which is hereby incorporated by reference.

### BACKGROUND

### 1. Field

The present disclosure herein relates to a polycyclic compound and a light emitting element including the same, and particularly, to a light emitting element including a novel polycyclic compound in an emission layer.

### 2. Description of Related Art

Recently, the development of an organic electroluminescence display device, and/or the like as an image display device is being actively conducted. The organic electroluminescence display device, and/or the like is a so-called self-luminescent display in which holes and electrons injected from a first electrode and a second electrode recombine in an emission layer so that a light emitting material in the emission layer emits light to achieve display (e.g., to display an image).

In the application of a light emitting element to a display device, the decrease of a driving voltage and the increase of emission efficiency and life (e.g., lifespan) are required or desired, and development on materials for a light emitting element capable of stably attaining such characteristics is being consistently pursued.

### SUMMARY

Aspects according to embodiments of the present disclosure are directed toward a light emitting element showing long-life characteristics.

Aspects according to embodiments of the present disclosure are directed toward a polycyclic compound which is a material for a light emitting element having long-life characteristics.

Additional aspects will be set forth in part in the description which follows and, in part, will be apparent from the description, or may be learned by practice of the presented embodiments of the disclosure.

According to an embodiment of the present disclosure, a light emitting element includes: a first electrode; a second electrode facing the first electrode; and at least one functional layer between the first electrode and the second electrode, wherein the at least one functional layer includes: a first compound represented by Formula 1; and at least one compound selected from among a second compound represented by Formula 2, a third compound represented by Formula 3, and a fourth compound represented by Formula 4.

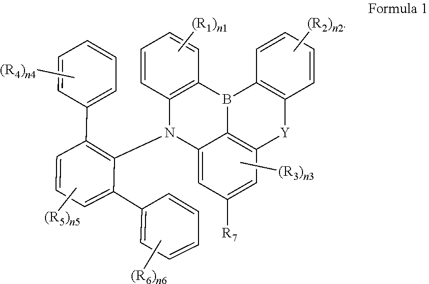

In Formula 1, Y may be S, Se, or Te, R₁ to R₇ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, n1 and n2 may each independently be an integer of 0 to 4, n3 may be an integer of 0 to 2, n4 may be an integer of 0 to 5, n5 may be an integer of 0 to 3, and n6 may be an integer of 0 to 5.

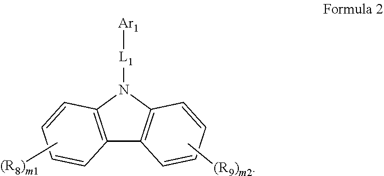

In Formula 2, L₁ may be a direct linkage, a substituted or unsubstituted arylene group of 6 to 30 ring-forming carbon atoms, or a substituted or unsubstituted heteroarylene group of 2 to 30 ring-forming carbon atoms, Ar₁ may be a substituted or unsubstituted aryl group of 6 to 30 ring-forming carbon atoms, or a substituted or unsubstituted heteroaryl group of 2 to 30 ring-forming carbon atoms, R₈ and R₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and m1 and m2 may each independently be an integer of 0 to 4.

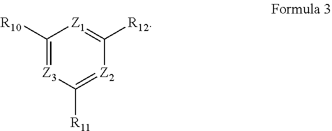

In Formula 3, Z₁, Z₂ and Z₃ may each independently be N or CR₁₃, and at least one thereof is N, and R₁₀ to R₁₃ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

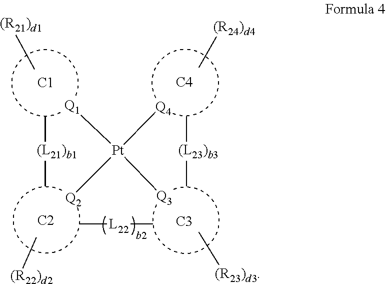

In Formula 4, Q₁ to Q₄ may each independently be C or N, C1 to C4 may each independently be a substituted or unsubstituted hydrocarbon ring of 5 to 30 ring-forming carbon atoms, or a substituted or unsubstituted heterocycle of 2 to 30 ring-forming carbon atoms, L₂₁ to L₂₃ may each independently be a direct linkage,

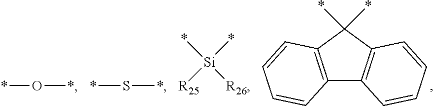

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, b1 to b3 may each independently be 0 or 1, R₂₁ to R₂₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and d1 to d4 may each independently be an integer of 0 to 4.

In an embodiment, the at least one functional layer may include an emission layer, a hole transport region between the first electrode and the emission layer, and an electron transport region between the emission layer and the second electrode, and the emission layer may include: the first compound; and at least one compound selected from among the second compound, the third compound, and the fourth compound.

In an embodiment, the emission layer may be to emit delayed fluorescence.

In an embodiment, the emission layer may be to emit light having a central (e.g., peak) wavelength of about 430 nm to about 490 nm.

In an embodiment, the at least one functional layer may include the first compound, the second compound, and the third compound.

In an embodiment, the at least one functional layer may include the first compound, the second compound, the third compound, and the fourth compound.

In an embodiment, the first compound represented by Formula 1 may be represented by any one selected from among Formula 1-1a to Formula 1-1h.

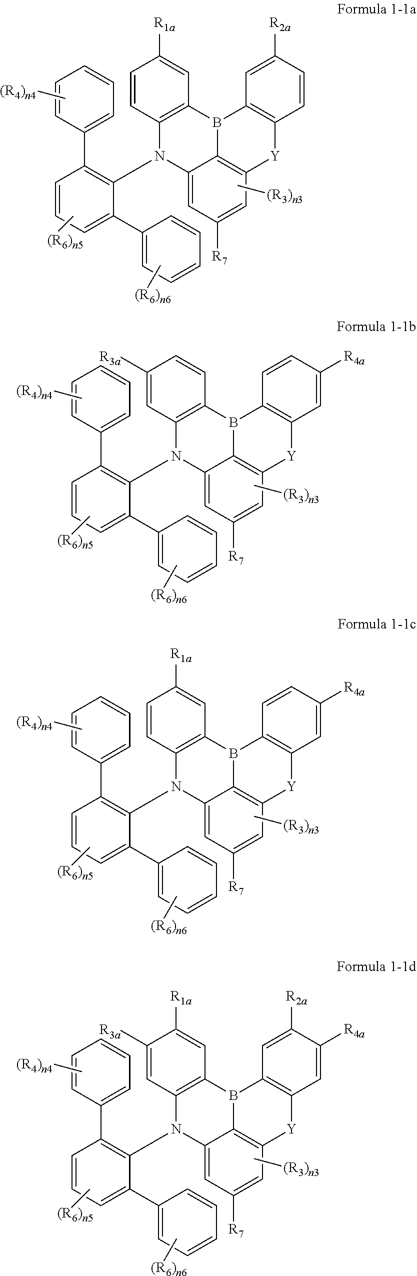

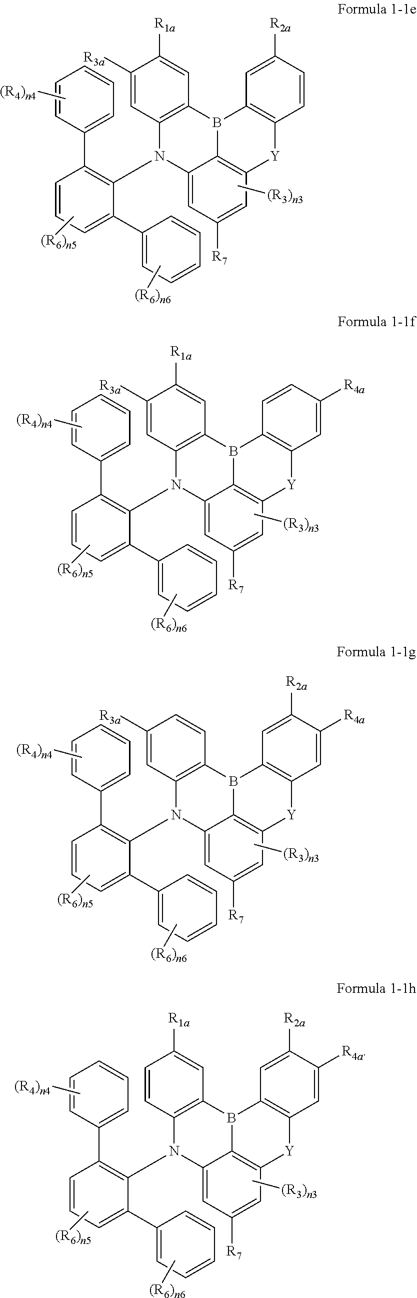

In Formula 1-1a to Formula 1-1h, R₁ₐ to R₄ₐ may each independently be a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and R₃ to R₇, Y, and n3 to n6 may each independently be the same as respectively defined in Formula 1.

In an embodiment, R₁ₐ to R₄ₐ may each independently be a substituted or unsubstituted t-butyl group, a substituted or unsubstituted phenyl group, a substituted or unsubstituted biphenyl group, a substituted or unsubstituted naphthyl group, a substituted or unsubstituted terphenyl group, a substituted or unsubstituted pyridine group, or a substituted or unsubstituted carbazole group, and/or combined with an adjacent group to form a ring.

In an embodiment, R₁ and R₂ may each independently be a hydrogen atom, a substituted or unsubstituted t-butyl group, a substituted or unsubstituted phenyl group, a substituted or unsubstituted biphenyl group, a substituted or unsubstituted naphthyl group, a substituted or unsubstituted terphenyl group, a substituted or unsubstituted pyridine group, or a substituted or unsubstituted carbazole group, and/or combined with an adjacent group to form a ring.

In an embodiment, R₃ may be a hydrogen atom.

In an embodiment, R₄ and R₆ may each independently be a hydrogen atom, a deuterium atom, a halogen atom, a cyano group, a substituted or unsubstituted silyl group, a substituted or unsubstituted alkoxy group, a substituted or unsubstituted methyl group, a substituted or unsubstituted t-butyl group, a substituted or unsubstituted cyclohexyl group, a substituted or unsubstituted phenyl group, or a substituted or unsubstituted carbazole group, and/or combined with an adjacent group to form a ring.

In an embodiment, R₅ may be a hydrogen atom or a substituted or unsubstituted t-butyl group.

In an embodiment, R₇ may be a hydrogen atom, a substituted or unsubstituted methyl group, a substituted or unsubstituted t-butyl group, a substituted or unsubstituted cyclohexyl group, a substituted or unsubstituted silyl group, a substituted or unsubstituted amine group, a substituted or unsubstituted phenyl group, a substituted or unsubstituted pyridine group, a substituted or unsubstituted carbazole group, a substituted or unsubstituted dibenzofuran group, or a substituted or unsubstituted dibenzothiophene group.

In an embodiment, R₇ may be a substituent represented in Substituent Group S1.

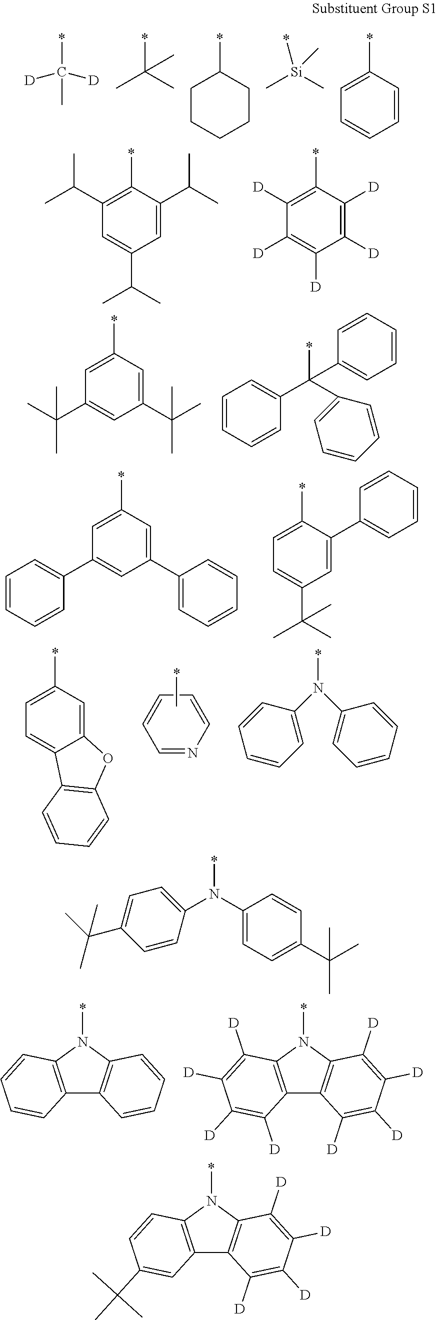

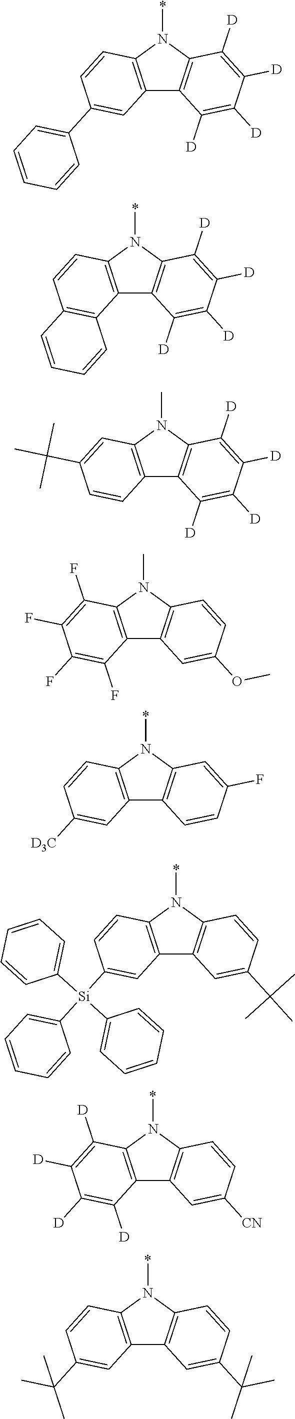

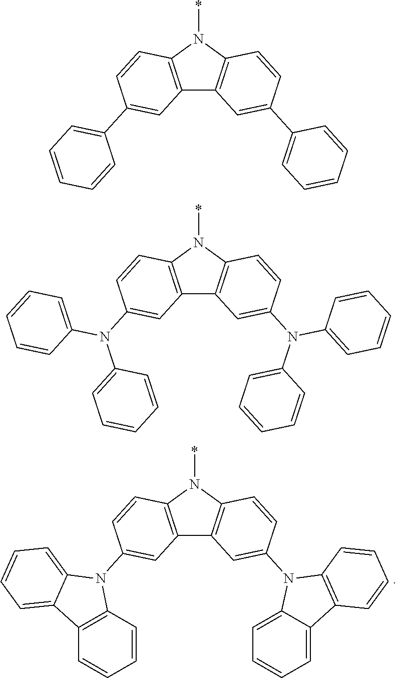 [SMILES: *n1c2ccc(-c3ccccc3)cc2c2cc(-c3ccccc3)ccc21 ; *n1c2ccc(N(c3ccccc3)c3ccccc3)cc2c2cc(N(c3ccccc3)c3ccccc3)ccc21 ; *n1c2ccc(-n3c4ccccc4c4ccccc43)cc2c2cc(-n3c4ccccc4c4ccccc43)ccc21]

In Substituent Group S1, D is a deuterium atom, and “ [symbol] ” refers to a position where R₇ is connected with Formula 1.

According to an embodiment of the present disclosure, a light emitting element includes: a first electrode; a second electrode facing the first electrode; and an emission layer between the first electrode and the second electrode, and including a polycyclic compound represented by Formula 1.

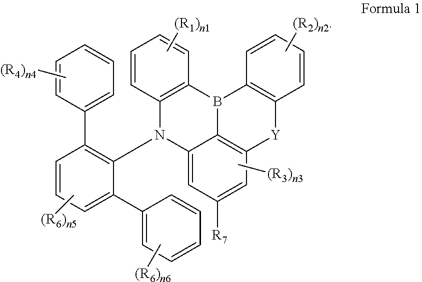

In Formula 1, Y may be S, Se, or Te, R₁ to R₇ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, n1 and n2 may each independently be an integer of 0 to 4, n3 may be an integer of 0 to 2, n4 may be an integer of 0 to 5, n5 may be an integer of 0 to 3, and n6 may be an integer of 0 to 5.

According to another embodiment of the present disclosure, a polycyclic compound is represented by Formula 1.

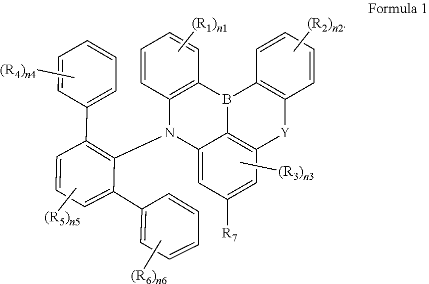

In Formula 1, Y may be S, Se, or Te, R₁ to R₇ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, n1 and n2 may each independently be an integer of 0 to 4, n3 may be an integer of 0 to 2, n4 may be an integer of 0 to 5, n5 may be an integer of 0 to 3, and n6 may be an integer of 0 to 5.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a plan view showing a display apparatus according to an embodiment;

FIG. 2 is a cross-sectional view of a display apparatus according to an embodiment;

FIG. 3 is a cross-sectional view schematically showing a light emitting element according to an embodiment;

FIG. 4 is a cross-sectional view schematically showing a light emitting element according to an embodiment;

FIG. 5 is a cross-sectional view schematically showing a light emitting element according to an embodiment;

FIG. 6 is a cross-sectional view schematically showing a light emitting element according to an embodiment;

FIG. 7 is a cross-sectional view of a display apparatus according to an embodiment;

FIG. 8 is a cross-sectional view of a display apparatus according to an embodiment;

FIG. 9 is a cross-sectional view showing a display apparatus according to an embodiment; and

FIG. 10 is a cross-sectional view showing a display apparatus according to an embodiment.

### DETAILED DESCRIPTION

The subject matter of the present disclosure may have one or more suitable modifications and may be embodied in different forms, and example embodiments will be explained in more detail with reference to the accompany drawings. The subject matter of the present disclosure may, however, be embodied in different forms and should not be construed as limited to the embodiments set forth herein. Rather, all modifications, equivalents, and substituents are included in the spirit and technical scope of the present disclosure.

Like reference numerals refer to like elements throughout, and duplicative descriptions thereof may not be provided. In the drawings, the dimensions of structures may be exaggerated for clarity of illustration. It will be understood that, although the terms first, second, etc. may be used herein to describe one or more suitable elements, these elements should not be limited by these terms. These terms are only used to distinguish one element from another element. Thus, a first element could be termed a second element without departing from the teachings of the present disclosure. Similarly, a second element could be termed a first element. As used herein, the singular forms are intended to include the plural forms as well, unless the context clearly indicates otherwise.

In the description, it will be further understood that the terms “comprises” and/or “comprising,” when used in this specification, specify the presence of stated features, numerals, steps (e.g., acts or tasks), operations, elements, parts, or the combination thereof, but do not preclude the presence or addition of one or more other features, numerals, steps, operations, elements, parts, or the combination thereof. As used herein, the singular forms “a”, “an” and “the” are intended to include the plural forms as well, unless the context clearly indicates otherwise.

In the description, when a layer, a film, a region, a plate, etc. is referred to as being “on” or “above” another part, it can be “directly on” the other part, or one or more intervening layers may also be present. In contrast, when a layer, a film, a region, a plate, etc. is referred to as being “under” or “below” another part, it can be “directly under” the other part, or intervening layers may also be present. Also, when an element is referred to as being disposed “on” another element, it can be disposed on or under the other element.

In the description, the term “substituted or unsubstituted” corresponds to a functional group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the exemplified substituents may be substituted or unsubstituted. For example, a biphenyl group may be interpreted as an aryl group or a phenyl group substituted with a phenyl group.

In the description, the term “forming a ring via the combination with an adjacent group” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocycles or polycycles. In addition, the ring formed via the combination with an adjacent group may be combined with another ring to form a spiro structure.

In the description, the term “adjacent group” may refer to a substituent substituted for an atom which is directly combined with an atom substituted with a corresponding substituent, another substituent substituted for an atom which is substituted with a corresponding substituent, or a substituent sterically positioned at the nearest position to a corresponding substituent. For example, in 1,2-dimethylbenzene, the two methyl groups may be interpreted as “adjacent groups” to each other, and in 1,1-diethylcyclopentene, the two ethyl groups may be interpreted as “adjacent groups” to each other. In addition, in 4,5-dimethylphenanthrene, the two methyl groups may be interpreted as “adjacent groups” to each other.

In the description, a halogen atom may be a fluorine atom, a chlorine atom, a bromine atom or an iodine atom.

In the description, an alkyl group may be a linear, branched, or cyclic t alkyl group. The carbon number of the alkyl group may be 1 to 50, 1 to 30, 1 to 20, 1 to 10, or 1 to 6. Non-limiting examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc.

In the description, an alkenyl group refers to a hydrocarbon group including one or more carbon-carbon double bonds in the middle and/or at the terminal end of an alkyl group having a carbon number of 2 or more. The alkenyl group may be a linear chain or a branched chain. The carbon number is not specifically limited, but may be 2 to 30, 2 to 20, or 2 to 10. Non-limiting examples of the alkenyl group may include a vinyl group, a 1-butenyl group, a 1-pentenyl group, a 1,3-butadienyl aryl group, a styrenyl group, a styrylvinyl group, etc.

In the description, an alkynyl group refers to a hydrocarbon group including one or more carbon-carbon triple bonds in the middle and/or at the terminal end of an alkyl group having a carbon number of 2 or more. The alkynyl group may be a linear chain or a branched chain. The carbon number is not specifically limited, but may be 2 to 30, 2 to 20, or 2 to 10. Non-limiting examples of the alkynyl group may include an ethynyl group, a propynyl group, etc.

In the description, a hydrocarbon ring group refers to an optional functional group or substituent derived from an aliphatic hydrocarbon ring. The hydrocarbon ring group may be a saturated hydrocarbon ring group of 5 to 20 ring-forming carbon atoms.

In the description, an aryl group refers to an optional functional group or substituent derived from an aromatic hydrocarbon ring. The aryl group may be a monocyclic aryl group or a polycyclic aryl group. The carbon number for forming rings in the aryl group may be 6 to 30, 6 to 20, or 6 to 15. Non-limiting examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc.

In the description, a fluorenyl group may be substituted, and two substituents may be combined with each other to form a spiro structure. Examples of a substituted fluorenyl group are as follows, but an embodiment of the present disclosure is not limited thereto.

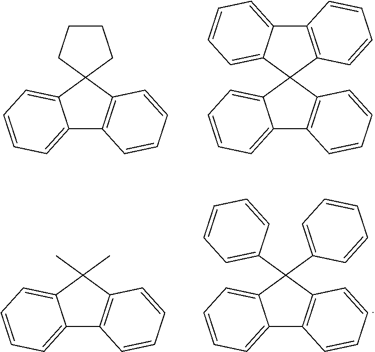

In the description, a heterocyclic group refers to an optional functional group or substituent derived from a ring including one or more selected from among B, O, N, P, Si, S, Se and Te as heteroatoms. The heterocyclic group includes an aliphatic heterocyclic group and an aromatic heterocyclic group. The aromatic heterocyclic group may be a heteroaryl group. The aliphatic heterocyclic group and the aromatic heterocyclic group may be a monocycle or a polycycle.

When the heterocyclic group includes two or more heteroatoms, the two or more heteroatoms may be the same or different. In the description, the heterocyclic group may be a monocyclic heterocyclic group or a polycyclic heterocyclic group, and may include a heteroaryl group. The carbon number for forming rings of the heterocyclic group may be 2 to 30, 2 to 20, and 2 to 10.

In the description, an aliphatic heterocyclic group may include one or more selected from among B, O, N, P, Si, S, Se and Te as heteroatoms. The number of ring-forming carbon atoms of the aliphatic heterocyclic group may be 2 to 30, 2 to 20, or 2 to 10. Non-limiting examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc.

In the description, a heteroaryl group may include one or more selected from among B, O, N, P, Si, S, Se and Te as heteroatoms. When the heteroaryl group includes two or more heteroatoms, the two or more heteroatoms may be the same or different. The heteroaryl group may be a monocyclic heterocyclic group or polycyclic heterocyclic group. The carbon number for forming rings of the heteroaryl group may be 2 to 30, 2 to 20, or 2 to 10. Non-limiting examples of the heteroaryl group may include a thiophene group, a furan group, a pyrrole group, an imidazole group, a triazole group, a pyridine group, a bipyridine group, a pyrimidine group, a triazine group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isooxazole group, an oxazole group, an oxadiazole group, a thiadiazole group, a phenothiazine group, a dibenzosilole group, a dibenzofuran group, etc.

In the description, the same explanation on the above-described aryl group may be applied to an arylene group except that the arylene group is a divalent group. The same explanation on the above-described heteroaryl group may be applied to a heteroarylene group except that the heteroarylene group is a divalent group.

In the description, a boron (e.g., boryl) group may include an alkyl boron group and an aryl boron group. Non-limiting examples of the boron group may include a dimethylboron group, a diethylboron group, a t-butylmethylboron group, a diphenylboron group, a phenylboron group, etc. For example, the alkyl groups in the alkyl boron group may be the same as the above-described examples, and the aryl groups in the aryl boron group may be the same as the above-described examples.

In the description, a silyl group includes an alkyl silyl group and an aryl silyl group. Non-limiting examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc.

In the description, the carbon number of a carbonyl group is not specifically limited, but the carbon number may be 1 to 40, 1 to 30, or 1 to 20. For example, the carbonyl group may have the structures below, but is not limited thereto.

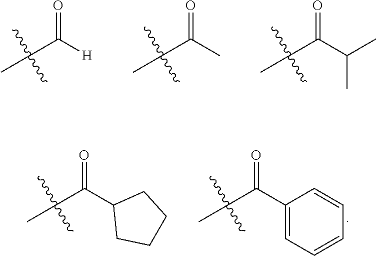

In the description, the carbon number of a sulfinyl group and sulfonyl group is not specifically limited, but may be 1 to 30. The sulfinyl group may include an alkyl sulfinyl group and an aryl sulfinyl group. The sulfonyl group may include an alkyl sulfonyl group and an aryl sulfonyl group.

In the description, a thio group may include an alkyl thio group and an aryl thio group. The thio group may refer to the above-defined alkyl group or aryl group combined with a sulfur atom. Non-limiting examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc.

In the description, an oxy group may refer to the above-defined alkyl group or aryl group which is combined with an oxygen atom. The oxy group may include an alkoxy group and an aryl oxy group. The alkoxy group may be a linear, branched or cyclic chain. The carbon number of the alkoxy group is not specifically limited but may be, for example, 1 to 20 or 1 to 10. Examples of the oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc. However, an embodiment of the present disclosure is not limited thereto.

In the description, the carbon number of an amine group is not specifically limited, but may be 1 to 30. The amine group may include an alkyl amine group and an aryl amine group. Non-limiting examples of the amine group may include a methylamine group, a dimethylamine group, a phenylamine group, a diphenylamine group, a naphthylamine group, a 9-methyl-anthracenylamine group, etc.

In the description, the alkyl group in the alkylthio group, the alkylsulfoxy group, the alkylaryl group, the alkylamino group, the alkylboron group, the alkyl silyl group, and the alkyl amine group may be the same as the examples of the above-described alkyl group.

In the description, the aryl group in the aryloxy group, the arylthio group, the arylsulfoxy group, the aryl amino group, the arylboron group, and the aryl silyl group may be the same as the examples of the above-described aryl group.

In the description, a direct linkage may refer to a single bond.

In the description, “ [symbol] ”, and “ [symbol] ” each refer to positions to be connected.

Hereinafter, embodiments of the present disclosure will be explained by referring to the drawings.

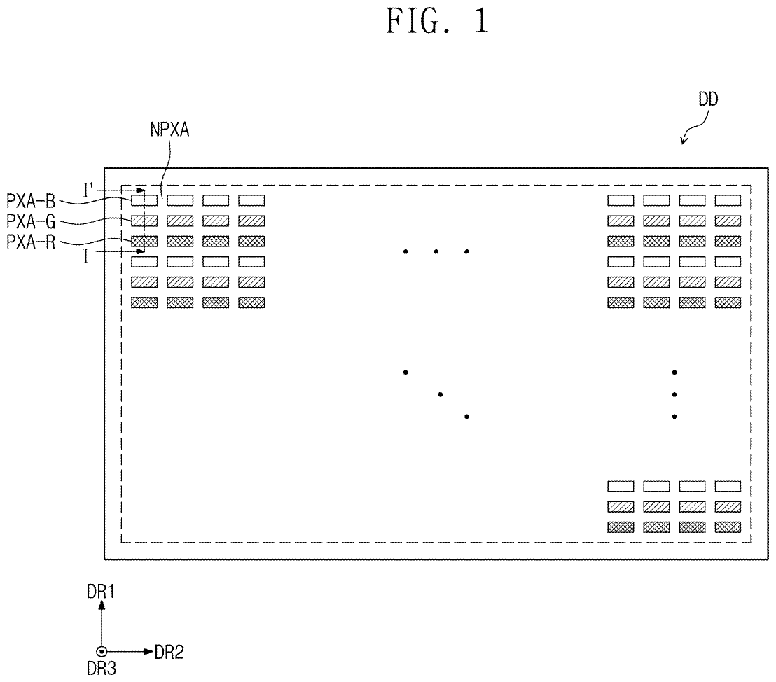

FIG. 1 is a plan view showing an embodiment of a display apparatus DD.

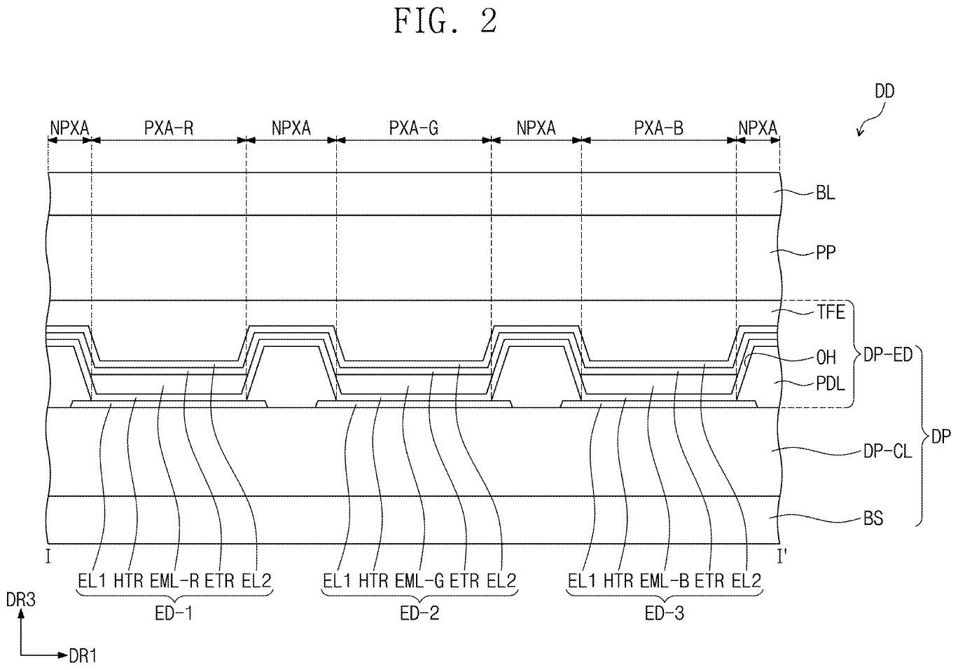

FIG. 2 is a cross-sectional view of a display apparatus DD of an embodiment. FIG. 2 is a cross-sectional view showing a part corresponding to the line I-I′ of FIG. 1.

The display apparatus DD may include a display panel DP and an optical layer PP disposed on the display panel DP. The display panel DP includes light emitting elements ED-1, ED-2 and ED-3. The display apparatus DD may include multiple light emitting elements ED-1, ED-2 and ED-3. The optical layer PP may be disposed on the display panel DP and control reflection of external light at the display panel DP. The optical layer PP may include, for example, a polarization layer and/or a color filter layer. In some embodiments, different from the drawings, the optical layer PP may not be provided in the display apparatus DD of an embodiment.

On the optical layer PP, a base substrate BL may be disposed. The base substrate BL may be a member providing a base surface on which the optical layer PP is disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, different from the drawings, the base substrate BL may not be provided in an embodiment.

The display apparatus DD according to an embodiment may further include a plugging layer (e.g., filling layer). The plugging layer may be disposed between a display device layer DP-ED and a base substrate BL. The plugging layer may be an organic layer. The plugging layer may include at least one selected from among an acrylic resin, a silicon-based resin and an epoxy-based resin.

The display panel DP may include a base layer BS, a circuit layer DP-CL provided on the base layer BS and a display device layer DP-ED. The display device layer DP-ED may include a pixel definition layer PDL, light emitting elements ED-1, ED-2 and ED-3 disposed in the pixel definition layer PDL, and an encapsulating layer TFE disposed on the light emitting elements ED-1, ED-2 and ED-3.

The base layer BS may be a member providing a base surface where the display device layer DP-ED is disposed. The base layer BS may be a glass substrate, a metal substrate, a plastic substrate, etc. However, an embodiment of the present disclosure is not limited thereto, and the base layer BS may be an inorganic layer, an organic layer or a composite material layer.

In an embodiment, the circuit layer DP-CL is disposed on the base layer BS, and the circuit layer DP-CL may include multiple transistors. Each of the transistors may include a control electrode, an input electrode, and an output electrode. For example, the circuit layer DP-CL may include switching transistors and driving transistors for driving the light emitting elements ED-1, ED-2 and ED-3 of the display device layer DP-ED.

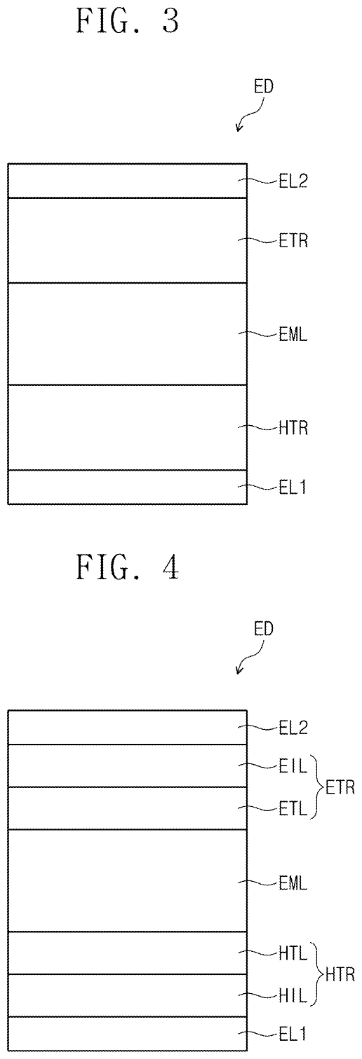

Each of the light emitting elements ED-1, ED-2 and ED-3 may have the structures of light emitting elements ED of embodiments according to FIG. 3 to FIG. 6, which will be explained in more detail later. Each of the light emitting elements ED-1, ED-2 and ED-3 may include a first electrode EL1, a hole transport region HTR, emission layer(s) EML-R, EML-G and EML-B (e.g., a corresponding one of the emission layer EML-R, the emission layer EML-G, or the emission layer EML-B), an electron transport region ETR, and a second electrode EL2.

FIG. 2 shows an embodiment where the emission layers EML-R, EML-G and EML-B of light emitting elements ED-1, ED-2 and ED-3 are disposed in opening portions OH defined in a pixel definition layer PDL, and a hole transport region HTR, an electron transport region ETR and a second electrode EL2 are provided as common layers in all light emitting elements ED-1, ED-2 and ED-3. However, an embodiment of the present disclosure is not limited thereto. Different from FIG. 2, in an embodiment, the hole transport region HTR and the electron transport region ETR may be patterned and provided in the opening portions OH defined in the pixel definition layer PDL. For example, in an embodiment, the hole transport region HTR, the emission layers EML-R, EML-G and EML-B, and the electron transport region ETR of the light emitting elements ED-1, ED-2 and ED-3 may be patterned and provided through an inkjet printing method.

An encapsulating layer TFE may cover the light emitting elements ED-1, ED-2 and ED-3. The encapsulating layer TFE may encapsulate the display device layer DP-ED. The encapsulating layer TFE may be a thin film encapsulating layer. The encapsulating layer TFE may be one layer or a stacked layer of multiple layers. The encapsulating layer TFE includes at least one insulating layer. The encapsulating layer TFE according to an embodiment may include at least one inorganic layer (hereinafter, encapsulating inorganic layer). In some embodiments, the encapsulating layer TFE according to an embodiment may include at least one organic layer (hereinafter, encapsulating organic layer) and at least one encapsulating inorganic layer.

The encapsulating inorganic layer protects the display device layer DP-ED from moisture/oxygen, and the encapsulating organic layer protects the display device layer DP-ED from foreign materials such as dust particles. The encapsulating inorganic layer may include silicon nitride, silicon oxy nitride, silicon oxide, titanium oxide, and/or aluminum oxide, but the present disclosure is not limited thereto. The encapsulating organic layer may include an acrylic compound, an epoxy-based compound, etc. The encapsulating organic layer may include a photopolymerizable organic material, but the present disclosure is not limited thereto.

The encapsulating layer TFE may be disposed on the second electrode EL2 and may be disposed to fill the opening portion OH.

Referring to FIG. 1 and FIG. 2, the display apparatus DD may include a non-luminous (e.g., non-light emitting) area NPXA and luminous (e.g., light emitting) areas PXA-R, PXA-G and PXA-B. The luminous areas PXA-R, PXA-G and PXA-B may be areas emitting light produced from the light emitting elements ED-1, ED-2 and ED-3, respectively. The luminous areas PXA-R, PXA-G and PXA-B may be separated from each other on a plane (e.g., in a plan view).

The luminous areas PXA-R, PXA-G and PXA-B may be areas separated by the pixel definition layer PDL. The non-luminous areas NPXA may be areas between neighboring luminous areas PXA-R, PXA-G and PXA-B and may be areas corresponding to the pixel definition layer PDL. In some embodiments, in the disclosure, each of the luminous areas PXA-R, PXA-G and PXA-B may correspond to a pixel. The pixel definition layer PDL may divide the light emitting elements ED-1, ED-2 and ED-3. The emission layers EML-R, EML-G and EML-B of the light emitting elements ED-1, ED-2 and ED-3 may be disposed and divided in the opening portions OH defined in the pixel definition layer PDL.

The luminous areas PXA-R, PXA-G and PXA-B may be divided into multiple groups according to the color of light produced from the light emitting elements ED-1, ED-2 and ED-3. In the display apparatus DD of an embodiment, shown in FIG. 1 and FIG. 2, three luminous areas PXA-R, PXA-G and PXA-B emitting red light, green light, and blue light, respectively, are illustrated as an embodiment. For example, the display apparatus DD of an embodiment may include a red luminous area PXA-R, a green luminous area PXA-G and a blue luminous area PXA-B, which are separated from each other.

In the display apparatus DD according to an embodiment, multiple light emitting elements ED-1, ED-2 and ED-3 may be to emit light having different wavelength regions. For example, in an embodiment, the display apparatus DD may include a first light emitting element ED-1 emitting red light, a second light emitting element ED-2 emitting green light, and a third light emitting element ED-3 emitting blue light. For example, each of the red luminous area PXA-R, the green luminous area PXA-G, and the blue luminous area PXA-B of the display apparatus DD may correspond to the first light emitting element ED-1, the second light emitting element ED-2, and the third light emitting element ED-3, respectively.

However, an embodiment of the present disclosure is not limited thereto, and the first to third light emitting elements ED-1, ED-2 and ED-3 may be to emit light in substantially the same wavelength region, or at least one thereof may be to emit light in a different wavelength region. For example, the first to third light emitting elements ED-1, ED-2 and ED-3 may all emit blue light.

The luminous areas PXA-R, PXA-G and PXA-B in the display apparatus DD according to an embodiment may be arranged in a stripe shape. Referring to FIG. 1, multiple red luminous areas PXA-R may be arranged with each other along a second directional axis DR2, multiple green luminous areas PXA-G may be arranged with each other along the second directional axis DR2, and multiple blue luminous areas PXA-B may be arranged with each other along the second directional axis DR2. In some embodiments, the red luminous area PXA-R, the green luminous area PXA-G and the blue luminous area PXA-B may be alternately arranged in this stated order along a first directional axis DR1.

In FIG. 1 and FIG. 2, the areas of the luminous areas PXA-R, PXA-G and PXA-B are shown as similar in size, but an embodiment of the present disclosure is not limited thereto. The areas of the luminous areas PXA-R, PXA-G and PXA-B may be different from each other according to the wavelength region of light emitted. In some embodiments, the areas of the luminous areas PXA-R, PXA-G and PXA-B may refer to areas when viewed on a plane defined by the first directional axis DR1 and the second directional axis DR2 (e.g., in a plan view).

In some embodiments, the arrangement of the luminous areas PXA-R, PXA-G and PXA-B is not limited to the configuration shown in FIG. 1, and the arrangement order of the red luminous areas PXA-R, the green luminous areas PXA-G and the blue luminous areas PXA-B may be provided in one or more suitable combinations according to the properties of display quality required or desired for the display apparatus DD. For example, the luminous areas PXA-R, PXA-G and PXA-B may be arranged in a pentile (PENTILE®) arrangement form, or a diamond (Diamond Pixel™) arrangement form. PENTILE® and Diamond Pixel™ are trademarks of Samsung Display Co., Ltd.

In some embodiments, the areas of the luminous areas PXA-R, PXA-G and PXA-B may be different from each other. For example, in an embodiment, the area of the green luminous area PXA-G may be smaller than the area of the blue luminous area PXA-B, but an embodiment of the present disclosure is not limited thereto.

In the display apparatus DD of an embodiment, as shown in FIG. 2, at least one selected from among first to third light emitting elements ED-1, ED-2 and ED-3, may include a polycyclic compound of an embodiment, which will be explained in more detail later.

Hereinafter, FIG. 3 to FIG. 6 are cross-sectional views schematically showing light emitting elements according to embodiments. The light emitting element ED according to an embodiment may include a first electrode EL1, a second electrode EL2 which is oppositely disposed to the first electrode EL1, and at least one functional layer disposed between the first electrode EL1 and the second electrode EL2. The light emitting element ED of an embodiment may include a polycyclic compound of an embodiment, which will be explained in more detail later, in at least one functional layer. In some embodiments, the polycyclic compound of an embodiment may be referred to (e.g., named) as a first compound in the present description.

The light emitting element ED may include a hole transport region HTR, an emission layer EML, an electron transport region ETR, and/or the like, stacked in the stated order, as the at least one functional layer. Referring to FIG. 3, the light emitting element ED of an embodiment may include a first electrode EL1, a hole transport region HTR, an emission layer EML, an electron transport region ETR, and a second electrode EL2, stacked in the stated order. In some embodiments, the light emitting element ED of an embodiment may include a polycyclic compound, which will be explained in more detail later, in the emission layer EML.

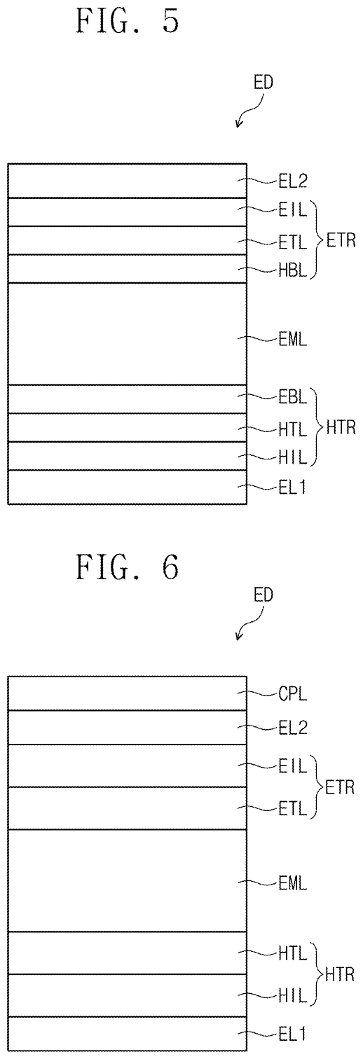

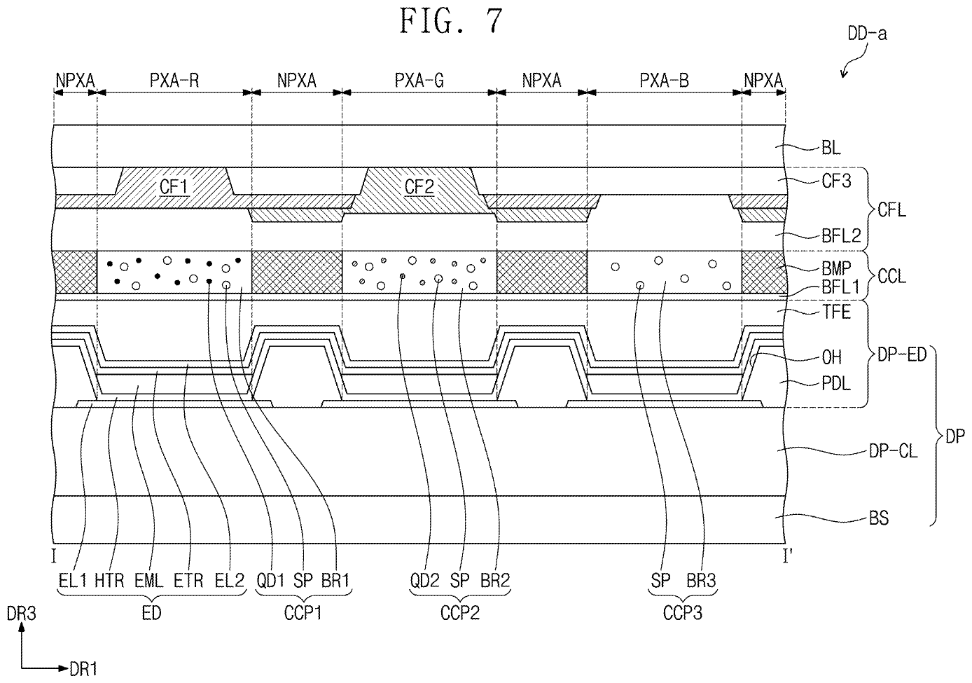

When compared to FIG. 3, FIG. 4 shows the cross-sectional view of a light emitting element ED of an embodiment, wherein a hole transport region HTR includes a hole injection layer HIL and a hole transport layer HTL, and an electron transport region ETR includes an electron injection layer EIL and an electron transport layer ETL. In addition, when compared to FIG. 3, FIG. 5 shows the cross-sectional view of a light emitting element ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared to FIG. 4, FIG. 6 shows the cross-sectional view of a light emitting element ED of an embodiment, further including a capping layer CPL disposed on the second electrode EL2.

In an embodiment, the emission layer EML may include (e.g., a material having) a core part including a boron atom, a nitrogen atom, and a heavy atom as ring-forming atoms, and at least one or more terphenyl groups substituted at the core part. In some embodiments, the emission layer EML may include at least one compound selected from among a second compound, a third compound, and a fourth compound. The second compound may include substituted or unsubstituted carbazole. The third compound may include a six-member ring containing at least one nitrogen atom as a ring-forming atom. The fourth compound may be a compound containing platinum.

In the light emitting element ED according to an embodiment, the first electrode EL1 has conductivity (e.g., is a conductor). The first electrode EL1 may be formed utilizing a metal material, a metal alloy or a conductive compound. The first electrode EL1 may be an anode or a cathode. However, an embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from Ag, Mg, Cu, Al, Pt, Pd, Au, Ni, Nd, Ir, Cr, Li, Ca, LiF, Mo, Ti, W, In, Sn, Zn, compounds of two or more selected therefrom, mixtures of two or more selected therefrom, and/or oxides thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compound(s) thereof, or mixture(s) thereof (for example, a mixture of Ag and Mg).

Also, the first electrode EL1 may have a structure including multiple layers including a reflective layer or a transflective layer formed utilizing the above materials, and a transmissive conductive layer formed utilizing ITO, IZO, ZnO, or ITZO. For example, the first electrode EL1 may have a three-layer structure of ITO/Ag/ITO. However, an embodiment of the present disclosure is not limited thereto. The first electrode EL1 may include one or more of the above-described metal materials, combinations of two or more metal materials selected from the above-described metal materials, and/or one or more of oxides of the above-described metal materials. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may have a single layer formed utilizing a single material, a single layer formed utilizing multiple different materials, or a multilayer structure including multiple layers formed utilizing multiple different materials.

The hole transport region HTR may include at least one of a hole injection layer HIL, a hole transport layer HTL, or an electron blocking layer EBL. In some embodiments, though not shown, the hole transport region HTR may include multiple stacked hole transport layers.

In some embodiments, differently, the hole transport region HTR may have the structure of a single layer of a hole injection layer HIL or a hole transport layer HTL, or may have a structure of a single layer formed utilizing a hole injection material and a hole transport material. In an embodiment, the hole transport region HTR may have a structure of a single layer formed utilizing multiple different materials, or a structure of hole injection layer HIL/hole transport layer HTL, hole injection layer HIL/hole transport layer HTL/buffer layer, hole injection layer HIL/buffer layer, or hole transport layer HTL/buffer layer, stacked in the respective stated order from the first electrode EL1, but the present disclosure is not limited thereto.

The thickness of the hole transport region HTR may be, for example, about 50 Å to about 15,000 Å. The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

In the light emitting element ED of an embodiment, the hole transport region HTR may include a compound represented by Formula H-1.

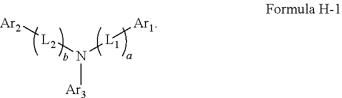

In Formula H-1 above, L₁ and L₂ may each independently be a direct linkage, a substituted or unsubstituted arylene group of 6 to 30 ring-forming carbon atoms, or a substituted or unsubstituted heteroarylene group of 2 to 30 ring-forming carbon atoms. “a” and “b” may each independently be an integer of 0 to 10. In some embodiments, when “a” or “b” is an integer of 2 or more, multiple L₁ and L₂ may each independently be a substituted or unsubstituted arylene group of 6 to 30 ring-forming carbon atoms, or a substituted or unsubstituted heteroarylene group of 2 to 30 ring-forming carbon atoms.

In Formula H-1, Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. In some embodiments, in Formula H-1, Ar₃ may be a substituted or unsubstituted aryl group of 6 to 30 ring-forming carbon atoms.

The compound represented by Formula H-1 may be a monoamine compound (e.g., a compound including a single amine group). In some embodiments, the compound represented by Formula H-1 may be a diamine compound in which at least one selected from among Ar₁ to Ar₃ includes an amine group as a substituent. In some embodiments, the compound represented by Formula H-1 may be a carbazole-based compound in which Ar₁ and/or Ar₂ includes a substituted or unsubstituted carbazole group, or a fluorene-based compound in which Ar₁ and/or Ar₂ includes a substituted or unsubstituted fluorene group.

The compound represented by Formula H-1 may be any one of the compounds in Compound Group H. However, the compounds shown in Compound Group H are only examples, and the compound represented by Formula H-1 is not limited to the compounds represented in Compound Group H.

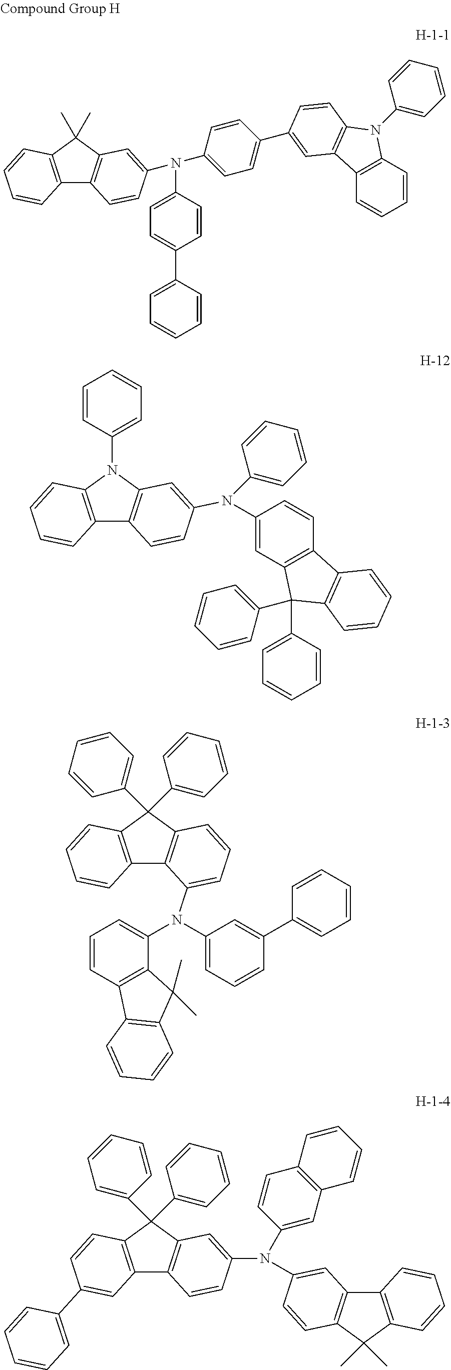 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

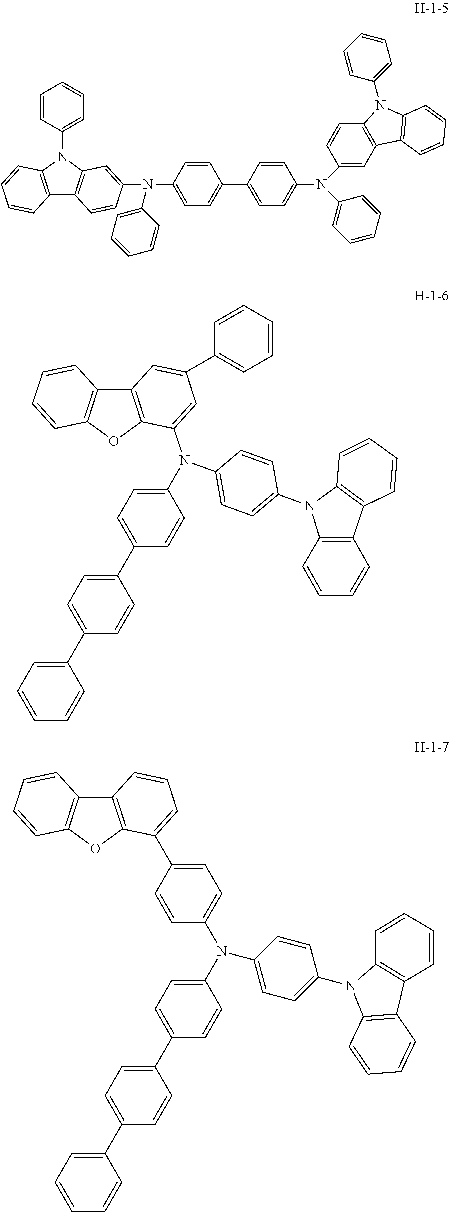 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

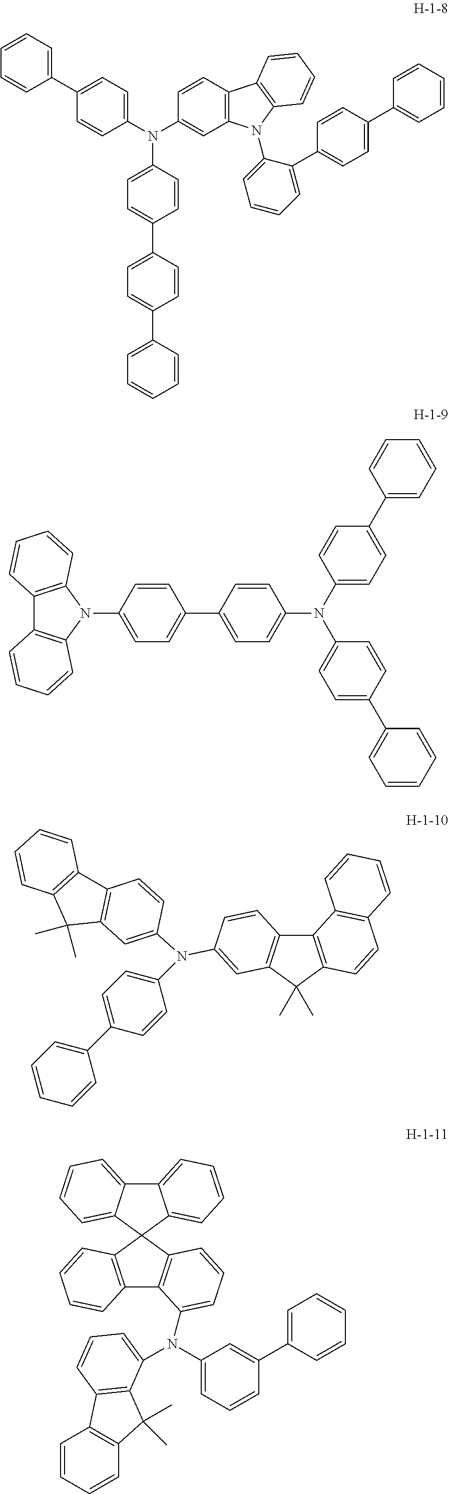 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

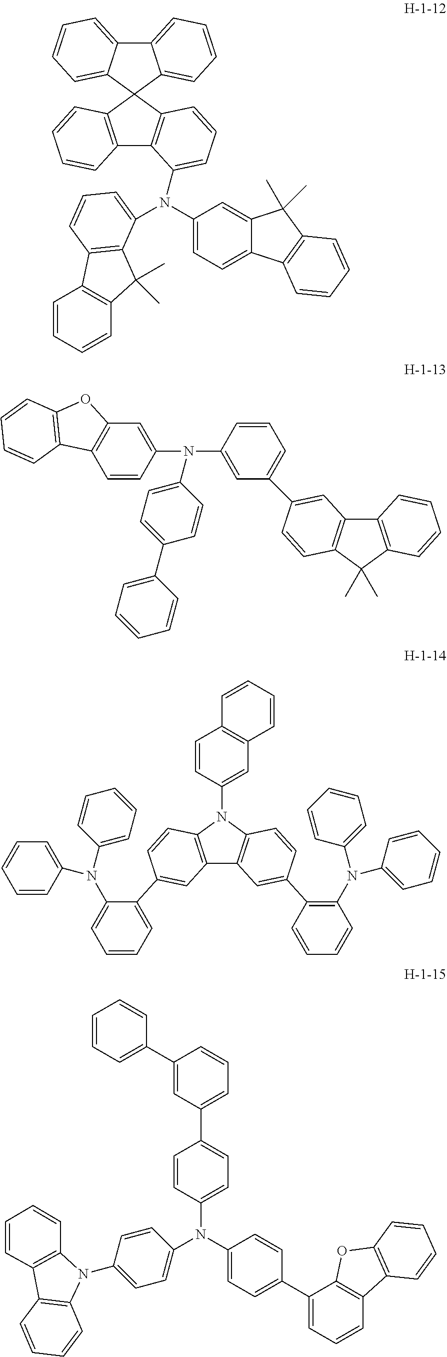 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

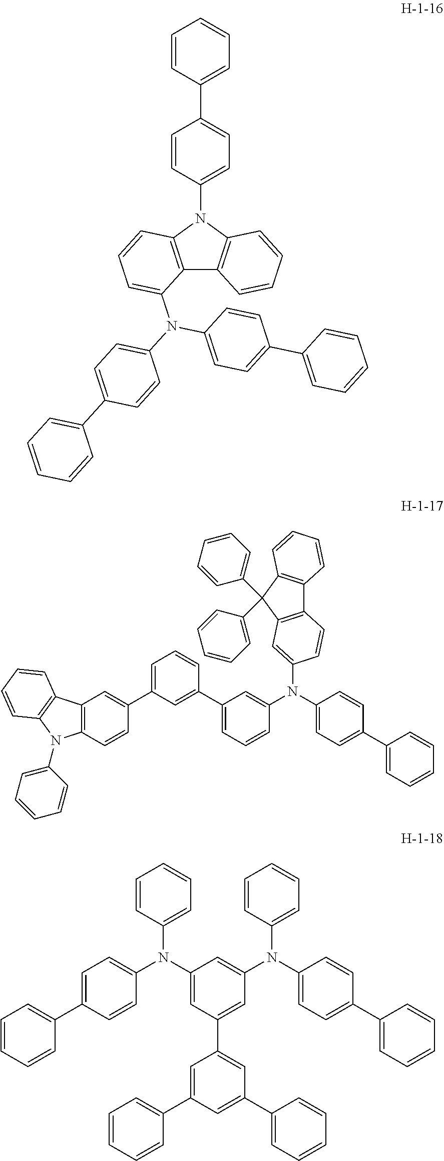 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

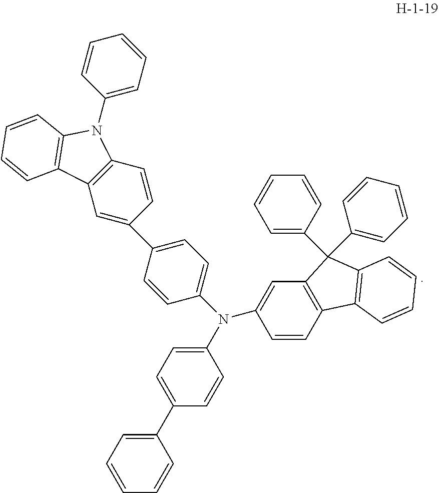 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N4,N4-di-m-tolylbenzene-1,4-diamine) (DNTPD), 4,4′,4″-[tris(3-methyl phenyl) phenylamino]triphenylamine (m-MTDATA), 4,4′,4″-tris(N,N-diphenylamino)triphenylamine (TDATA), 4,4′,4″-tris[N(1-naphthyl)-N-phenylamino]-triphenylamine (1-TNATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-idenbndine (NPB, or NPD, α-NPD), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h] quinoxaline-2,3,6,7,10,11-hexacarbonitrile (HAT-CN).

The hole transport region HTR may include carbazole derivatives such as N-phenyl carbazole and/or polyvinyl carbazole, fluorene-based derivatives, triphenylamine-based derivatives such as 4,4′,4″-tris(N-carbazolyl)triphenylamine (TCTA), N,N′-bis(3-methylphenyl)-N,N′-diphenyl-[1,1′-biphenyl]-4,4′-diamine (TPD), N,N′-di(1-naphthalene-1-yl)-N,N′-diphenyl-benzidine (NPB), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one selected from among the hole injection layer HIL, the hole transport layer HTL, and the electron blocking layer EBL.

The thickness of the hole transport region HTR may be from about 100 Å to about 10,000 Å, for example, from about 100 Å to about 5,000 Å. When the hole transport region HTR includes a hole injection layer HIL, the thickness of the hole injection region HIL may be, for example, from about 30 Å to about 1,000 Å. When the hole transport region HTR includes a hole transport layer HTL, the thickness of the hole transport layer HTL may be from about 30 Å to about 1,000 Å. For example, when the hole transport region HTR includes an electron blocking layer EBL, the thickness of the electron blocking layer EBL may be from about 10 Å to about 1,000 Å. When the thicknesses of the hole transport region HTR, the hole injection layer HIL, the hole transport layer HTL and the electron blocking layer EBL satisfy the above-described ranges, satisfactory hole transport properties may be achieved without substantial increase of a driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include one or more of metal halide compounds, quinone derivatives, metal oxides, and cyano group-containing compounds, but the present disclosure is not limited thereto. For example, the p-dopant may include one or more metal halide compounds such as Cul and/or Rbl, quinone derivatives such as tetracyanoquinodimethane (TCNQ) and/or 2,3,5,6-tetrafluoro-7,7′,8,8-tetracyanoquinodimethane (F4-TCNQ), metal oxides such as tungsten oxide and molybdenum oxide, cyano group-containing compounds such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the present disclosure is not limited thereto.

As described above, the hole transport region HTR may further include a buffer layer and/or an electron blocking layer EBL in addition to the hole injection layer HIL and the hole transport layer HTL. The buffer layer may compensate for a resonance distance according to the wavelength of light emitted from an emission layer EML and may thus increase emission efficiency. As materials included in the buffer layer, materials which may be included in the hole transport region HTR may be utilized. The electron blocking layer EBL is a layer playing the role of blocking the injection of electrons from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed utilizing a single material, a single layer formed utilizing multiple different materials, or a multilayer structure having multiple layers formed utilizing multiple different materials.

In an embodiment, the emission layer EML may include a first compound represented by Formula 1. The first compound corresponds to a polycyclic compound of an embodiment.

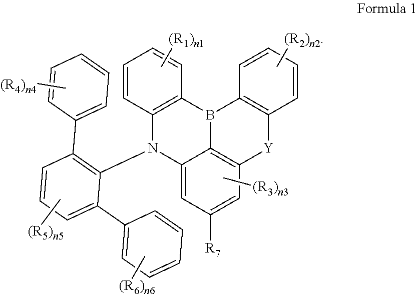

In Formula 1, Y may be S, Se, or Te. That is, Y may be a heavy atom. The polycyclic compound of the present disclosure includes a heavy atom, and an electron spin state in a molecule may be easily changed, and reverse intersystem crossing (RISC) may become active. Accordingly, the polycyclic compound of the present disclosure may have improved material stability as a material for thermally activated delayed fluorescence (TADF), and when applied to an element (e.g., light emitting element), the improvement of element life may be achieved.

R₁ to R₇ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

For example, R₁ and R₂ may each independently be a hydrogen atom, a substituted or unsubstituted 1-butyl group, a substituted or unsubstituted phenyl group, a substituted or unsubstituted biphenyl group, a substituted or unsubstituted naphthyl group, a substituted or unsubstituted terphenyl group, a substituted or unsubstituted pyridine group, or a substituted or unsubstituted carbazole group, and/or combined with an adjacent group to form a ring. For example, when R₁ and R₂ are each independently a substituted phenyl group, R₁ and R₂ may each independently be a phenyl group substituted with deuterium, a phenyl group substituted with a fluorine atom, a phenyl group substituted with a cyano group, a phenyl group substituted with a substituted or unsubstituted trimethylsilyl group, a phenyl group substituted with a substituted or unsubstituted t-butyl group, a phenyl group substituted with a substituted or unsubstituted cyclohexyl group, a phenyl group substituted with a substituted or unsubstituted naphthyl group, or a phenyl group substituted with a substituted or unsubstituted carbazole group. However, an embodiment of the present disclosure is not limited thereto.

For example, when R₁ and R₂ are each independently combined with an adjacent group to form a ring, R₁ and R₂ may each independently be combined with an adjacent group to form a substituted or unsubstituted dibenzofuran group or a substituted or unsubstituted carbazole group.

For example, R₃ may be a hydrogen atom.

For example, R₄ and R₆ may each independently be a hydrogen atom, a deuterium atom, a halogen atom, a cyano group, a substituted or unsubstituted silyl group, a substituted or unsubstituted alkoxy group, a substituted or unsubstituted methyl group, a substituted or unsubstituted t-butyl group, a substituted or unsubstituted cyclohexyl group, a substituted or unsubstituted phenyl group, or a substituted or unsubstituted carbazole group, and/or combined with an adjacent group to form a ring. For example, when R₄ and R₆ are each independently a halogen atom, R₄ and R₆ may each independently be a fluorine atom. For example, when R₄ and R₆ are each independently a substituted or unsubstituted silyl group, R₄ and R₆ may each independently be a substituted or unsubstituted trimethylsilyl group. For example, when R₄ and R₆ are each independently combined with an adjacent group to form a ring, R₄ and R₆ may each independently be combined with an adjacent group to form a substituted or unsubstituted naphthalene group, a substituted or unsubstituted dibenzofuran group, or a substituted or unsubstituted dibenzothiophene group.

For example, R₅ may be a hydrogen atom, or a substituted or unsubstituted t-butyl group.

For example, R₇ may be a hydrogen atom, a substituted or unsubstituted methyl group, a substituted or unsubstituted t-butyl group, a substituted or unsubstituted cyclohexyl group, a substituted or unsubstituted silyl group, a substituted or unsubstituted amine group, a substituted or unsubstituted phenyl group, a substituted or unsubstituted pyridine group, a substituted or unsubstituted carbazole group, a substituted or unsubstituted dibenzofuran group, or a substituted or unsubstituted dibenzothiophene group.

In an embodiment, R₇ may be a substituent of substituents represented in Substituent Group S1. However, R₇ is not limited to the substituents represented in Substituent Group S1. In Substituent Group S1, D is a deuterium atom, and “ [symbol] ” refers to a position where R₇ is connected with Formula 1.

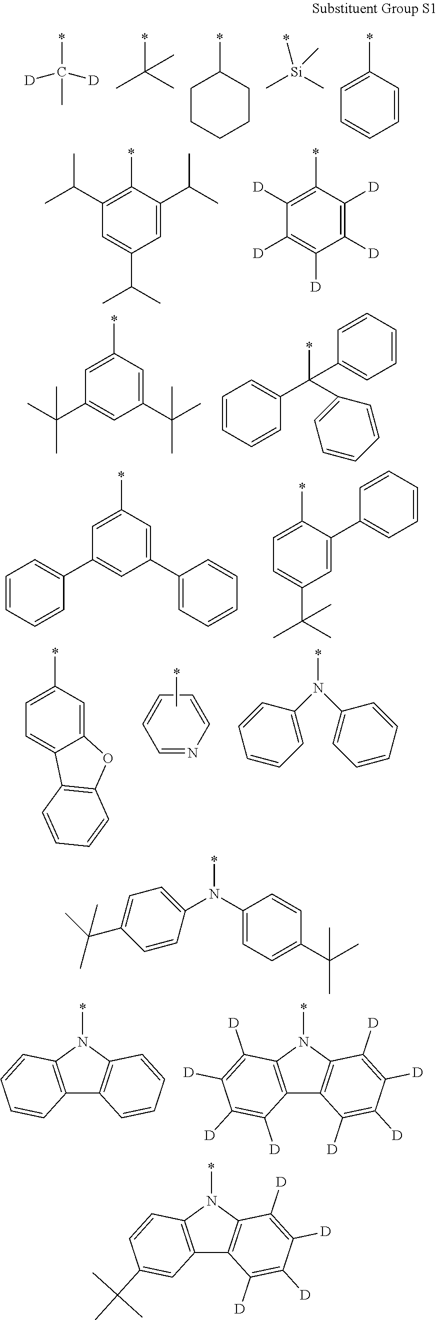

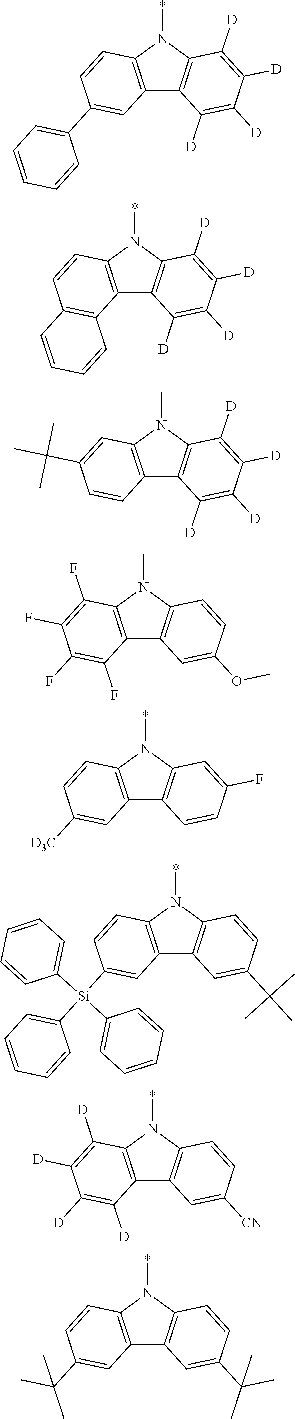

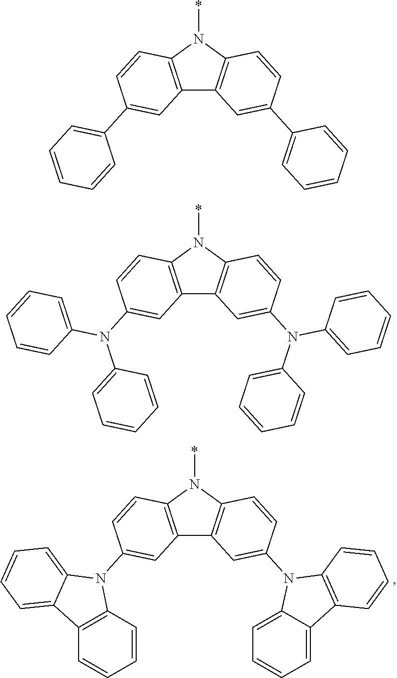 [SMILES: *n1c2ccc(-c3ccccc3)cc2c2cc(-c3ccccc3)ccc21 ; *n1c2ccc(N(c3ccccc3)c3ccccc3)cc2c2cc(N(c3ccccc3)c3ccccc3)ccc21 ; *n1c2ccc(-n3c4ccccc4c4ccccc43)cc2c2cc(-n3c4ccccc4c4ccccc43)ccc21]

n1 and n2 may each independently be an integer of 0 to 4. For example, n1 and n2 may each independently be 0, 1 or 2. A case where n1 is 0 may be the same as a case where n1 is 4, and R₁ is a hydrogen atom. A case where n1 is 0 may be understood as a polycyclic compound represented by Formula 1 at which R₁ is unsubstituted. A case where n2 is 0 may be the same as a case where n2 is 4, and R₂ is a hydrogen atom. A case where n2 is 0 may be understood as a polycyclic compound represented by Formula 1 at which R₂ is unsubstituted.

n3 is an integer of 0 to 2. For example, n3 may be 0. A case where n3 is 0 may be the same as a case where n3 is 2, and R₃ is a hydrogen atom. A case where n3 is 0 may be understood as a polycyclic compound represented by Formula 1 at which R₃ is unsubstituted.

n4 is an integer of 0 to 5. A case where n4 is 0 may be the same as a case where n4 is 5, and R₄ is a hydrogen atom. A case where n4 is 0 may be understood as a polycyclic compound represented by Formula 1 at which R₄ is unsubstituted.

n5 is an integer of 0 to 3. For example, n5 may be 0 or 1. A case where n5 is 0 may be the same as a case where n5 is 3, and R₅ is a hydrogen atom. A case where n5 is 0 may be understood as a polycyclic compound represented by Formula 1 at which R₅ is unsubstituted.

n6 is an integer of 0 to 5. A case where n6 is 0 may be the same as a case where n6 is 5, and R₆ is a hydrogen atom. A case where n6 is 0 may be understood as a polycyclic compound represented by Formula 1 at which R₆ is unsubstituted.

In an embodiment, the first compound represented by Formula 1 may be represented by any one selected from among Formula 1-1a to Formula 1-1h.

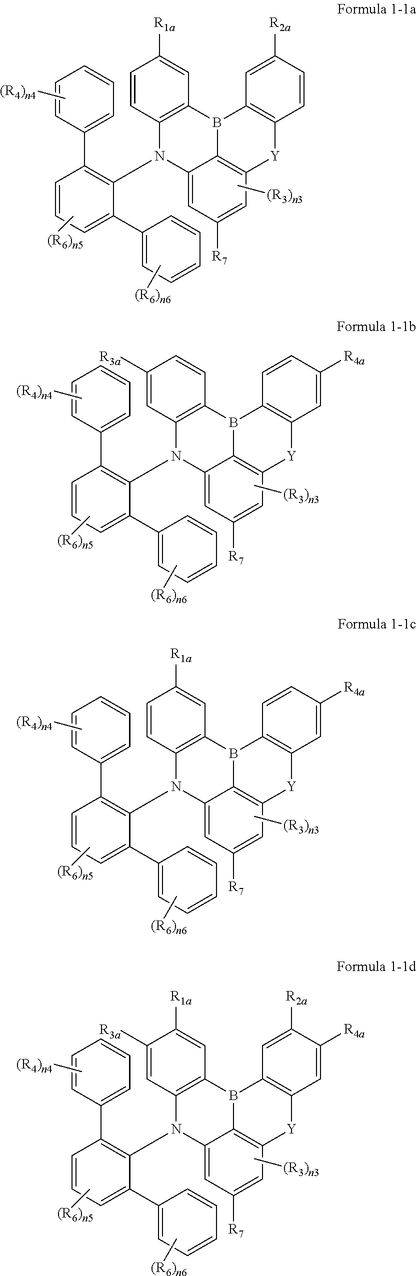

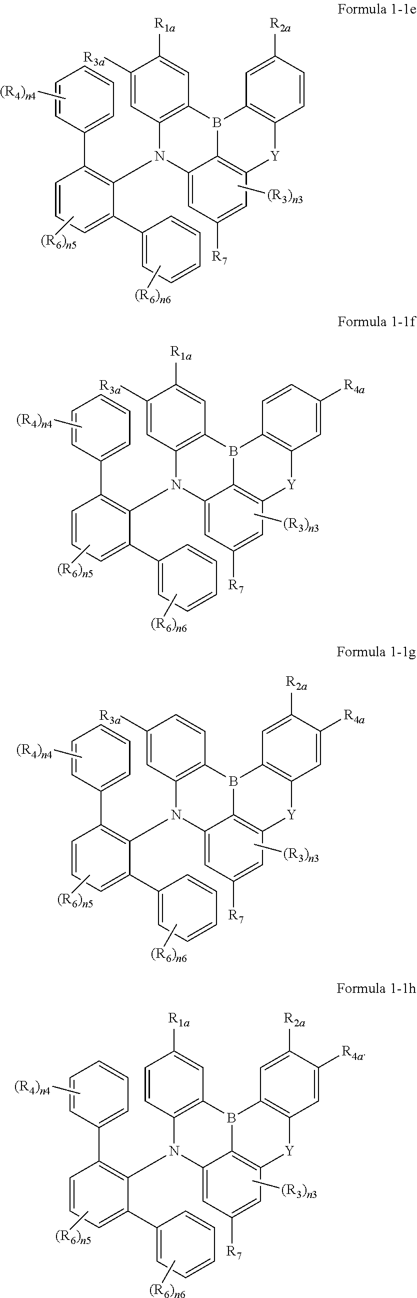

Formula 1-1a to Formula 1-1h correspond to Formula 1 where R₁ is embodied as at least one selected from among R₁ₐ and R₃ₐ, and R₂ is embodied as at least one selected from among R₂ₐ and R₄ₐ.

In Formula 1-1a to Formula 1-1h, R₁ₐ to R₄ₐ may each independently be a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

For example, R₁ₐ to R₄ₐ may each independently be a substituted or unsubstituted t-butyl group, a substituted or unsubstituted phenyl group, a substituted or unsubstituted biphenyl group, a substituted or unsubstituted naphthyl group, a substituted or unsubstituted terphenyl group, a substituted or unsubstituted pyridine group, or a substituted or unsubstituted carbazole group, and/or combined with an adjacent group to form a ring. For example, when R₁ₐ to R₄ₐ are each independently a substituted or unsubstituted phenyl group, R₁ₐ to R₄ₐ may each independently be a phenyl group substituted with a deuterium atom, a phenyl group substituted with a fluorine atom, a phenyl group substituted with a cyano group, a phenyl group substituted with a substituted or unsubstituted trimethylsilyl group, a phenyl group substituted with a substituted or unsubstituted t-butyl group, a phenyl group substituted with a substituted or unsubstituted cyclohexyl group, a phenyl group substituted with a substituted or unsubstituted naphthyl group, or a phenyl group substituted with a substituted or unsubstituted carbazole group. However, an embodiment of the present disclosure is not limited thereto.

In Formula 1-1a to Formula 1-1h, R₃ to R₇, Y, and n3 to n6 may each independently be the same as defined in Formula 1.

In an embodiment, the polycyclic compound represented by Formula 1 may be represented by any one selected from among Formula 1-2a to Formula 1-2c.

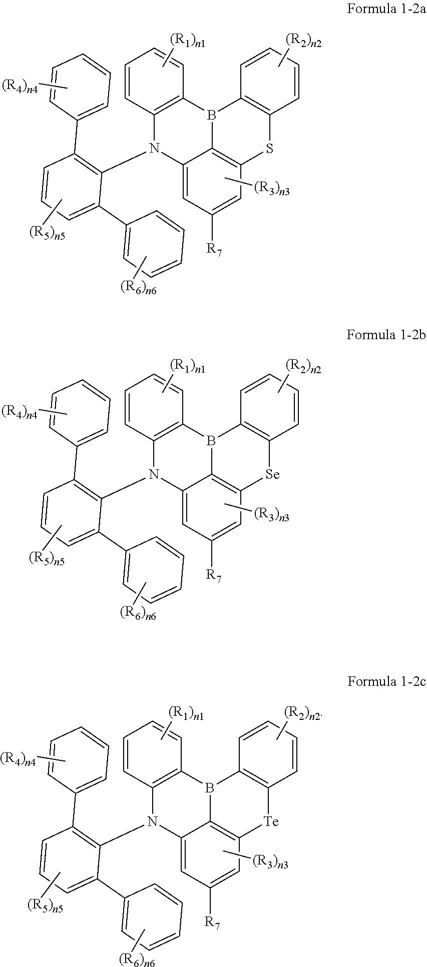

Formula 1-2a to Formula 1-2c correspond to Formula 1 where Y is embodied as S, Se, or Te.

R₁ to R₇, and n1 to n6 may each independently be the same as defined in Formula 1.

The polycyclic compound of the present disclosure, represented by Formula 1, may include a fused ring skeleton including a boron atom, a nitrogen atom, and a heavy atom represented by Y, and an ortho-type or kind terphenyl group connected with the nitrogen atom of the fused ring skeleton. The polycyclic compound of the present disclosure, represented by Formula 1, includes a heavy atom represented by Y and may show improved transition properties in a molecule, for example, improved transition rate of excitons from a triplet to a singlet, thereby reducing the time of reverse intersystem crossing (RISC) and reducing the concentration of triplet excitons having an unstable state. Accordingly, when the polycyclic compound of the present disclosure is utilized as a TADF dopant material, material stability may be improved.

In some embodiments, the ortho-type or kind terphenyl group included in the polycyclic compound protects the p-orbital of the boron atom and may prevent or reduce the deformation of the trigonal bond structure of the boron atom due to the bonding of an external nucleophile with the p-orbital of the boron atom. The deformation of the trigonal bond structure of the boron atom may become the cause of element (e.g., light emitting element) deterioration, but the polycyclic compound of the present disclosure includes the ortho-type or kind terphenyl group, and when applied to an element, defects of the element deterioration may be prevented or reduced, and the improvement of element life may be achieved.

The polycyclic compound of the present disclosure includes an ortho-type or kind terphenyl group, and intermolecular distance is relatively increased when compared to a polycyclic compound not including an ortho-type or kind terphenyl group, and intermolecular interaction such as intermolecular aggregation, excimer formation and/or exciplex formation, which may cause the reduction of emission efficiency, may be relatively reduced. In addition, by preventing or reducing the intermolecular aggregation, the sublimation and purification processes of the polycyclic compound of the present disclosure may be easy, and stability against thermal decomposition during the sublimation and purification processes may be secured.

The polycyclic compound of the present disclosure has the same emission spectrum (e.g., wavelength of emission spectrum) measured in a solution state as the emission spectrum (e.g., wavelength of emission spectrum) measured in a deposited layer state (e.g., solid state), and when applied to an emission layer, high color purity may be shown (e.g., achieved).

The polycyclic compound of an embodiment may be any one selected from among the compounds in Compound Group 1. In Compound Group 1, D is a deuterium atom.

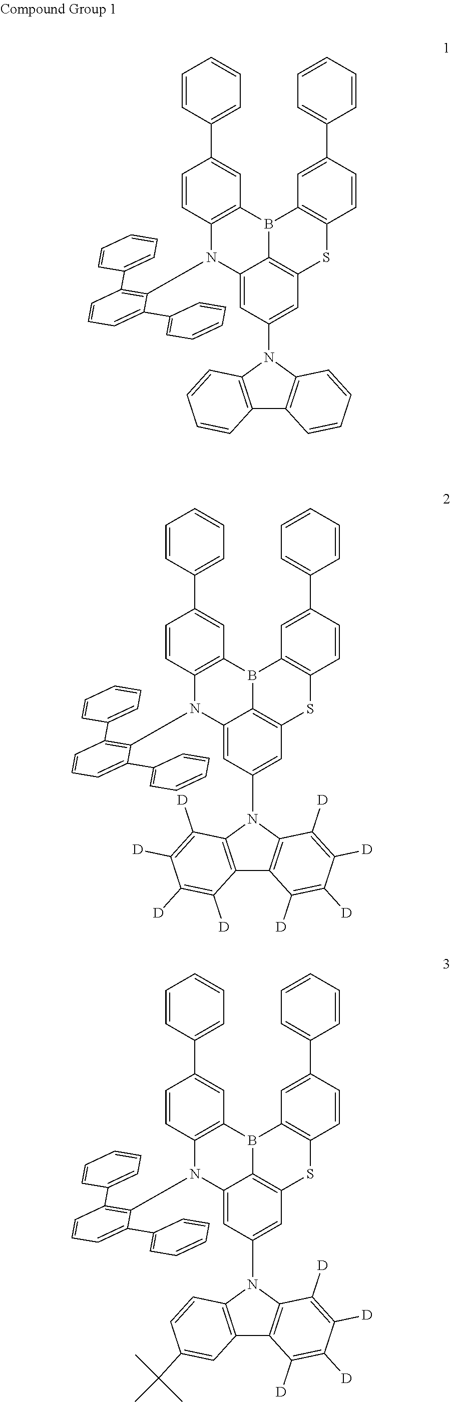 [SMILES: c1ccc(-c2ccc3c(c2)B2c4cc(-c5ccccc5)ccc4N(c4c(-c5ccccc5)cccc4-c4ccccc4)c4cc(-n5c6ccccc6c6ccccc65)cc(c42)S3)cc1 ; [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4ccccc4)cc1B3c1cc(-c3ccccc3)ccc1S2 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4ccccc4)cc1B3c1cc(-c3ccccc3)ccc1S2]

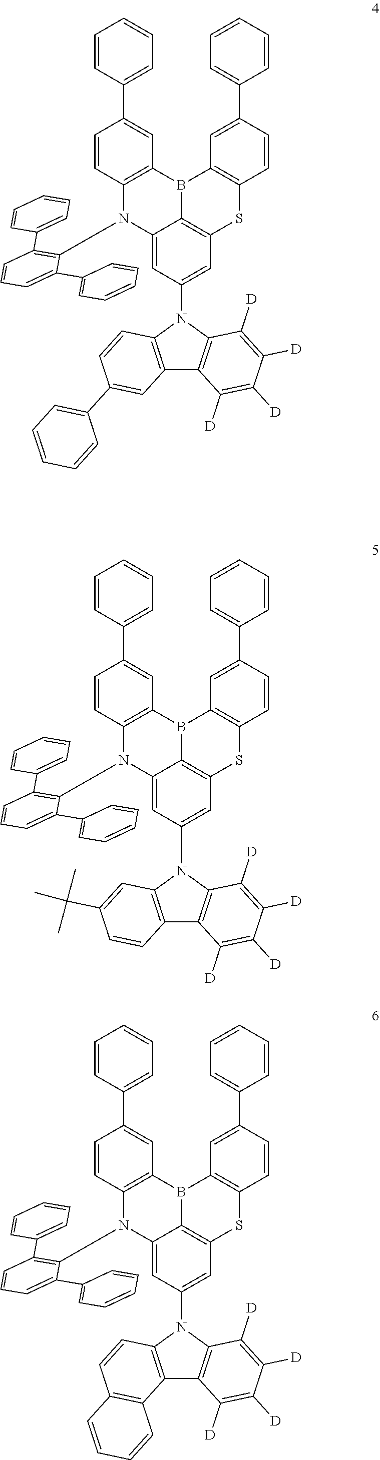 [SMILES: [2H]c1c([2H])c([2H])c2c(c1[2H])c1cc(-c3ccccc3)ccc1n2-c1cc2c3c(c1)N(c1c(-c4ccccc4)cccc1-c1ccccc1)c1ccc(-c4ccccc4)cc1B3c1cc(-c3ccccc3)ccc1S2 ; [2H]c1c([2H])c([2H])c2c(c1[2H])c1ccc(C(C)(C)C)cc1n2-c1cc2c3c(c1)N(c1c(-c4ccccc4)cccc1-c1ccccc1)c1ccc(-c4ccccc4)cc1B3c1cc(-c3ccccc3)ccc1S2 ; [2H]c1c([2H])c([2H])c2c(c1[2H])c1c3ccccc3ccc1n2-c1cc2c3c(c1)N(c1c(-c4ccccc4)cccc1-c1ccccc1)c1ccc(-c4ccccc4)cc1B3c1cc(-c3ccccc3)ccc1S2]

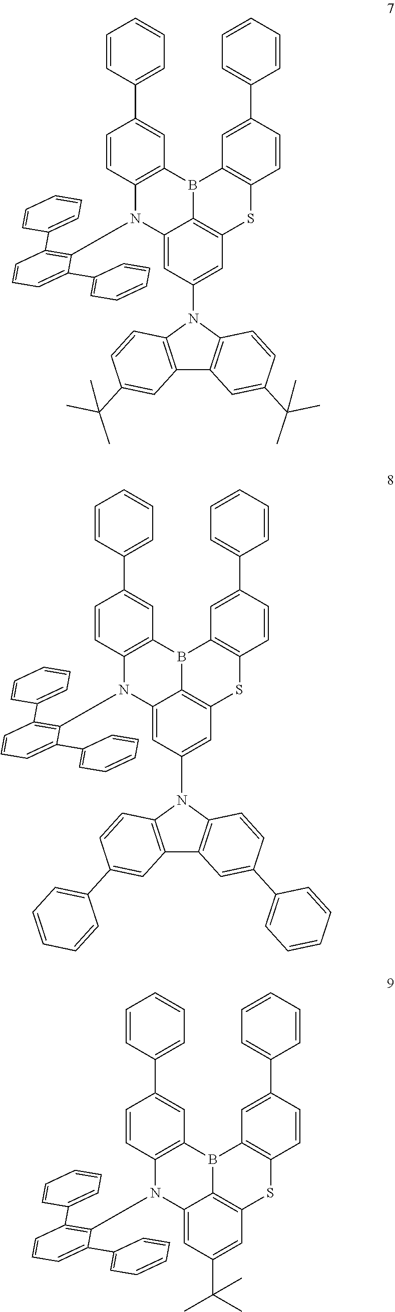

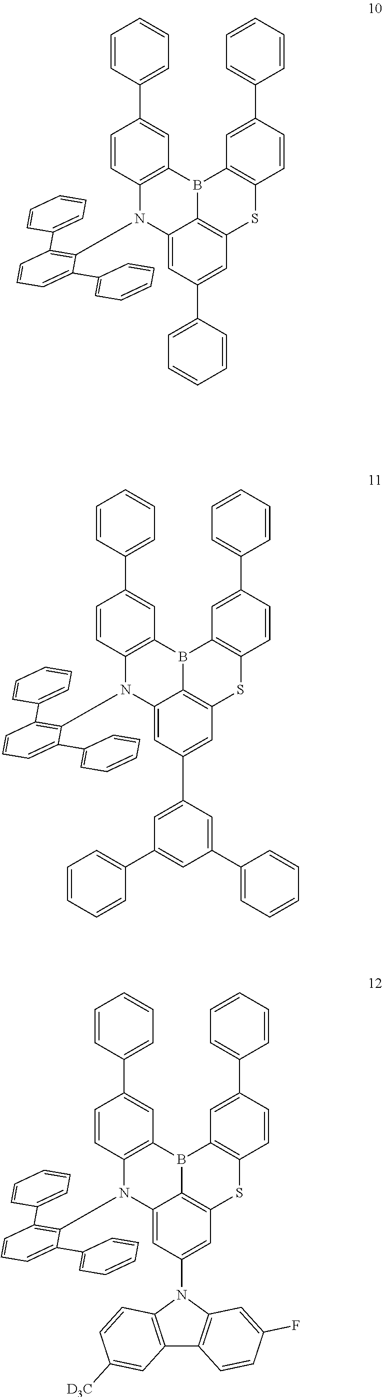 [SMILES: c1ccc(-c2ccc3c(c2)B2c4cc(-c5ccccc5)ccc4N(c4c(-c5ccccc5)cccc4-c4ccccc4)c4cc(-c5ccccc5)cc(c42)S3)cc1 ; c1ccc(-c2cc(-c3ccccc3)cc(-c3cc4c5c(c3)N(c3c(-c6ccccc6)cccc3-c3ccccc3)c3ccc(-c6ccccc6)cc3B5c3cc(-c5ccccc5)ccc3S4)c2)cc1 ; [2H]C([2H])([2H])c1ccc2c(c1)c1ccc(F)cc1n2-c1cc2c3c(c1)N(c1c(-c4ccccc4)cccc1-c1ccccc1)c1ccc(-c4ccccc4)cc1B3c1cc(-c3ccccc3)ccc1S2]

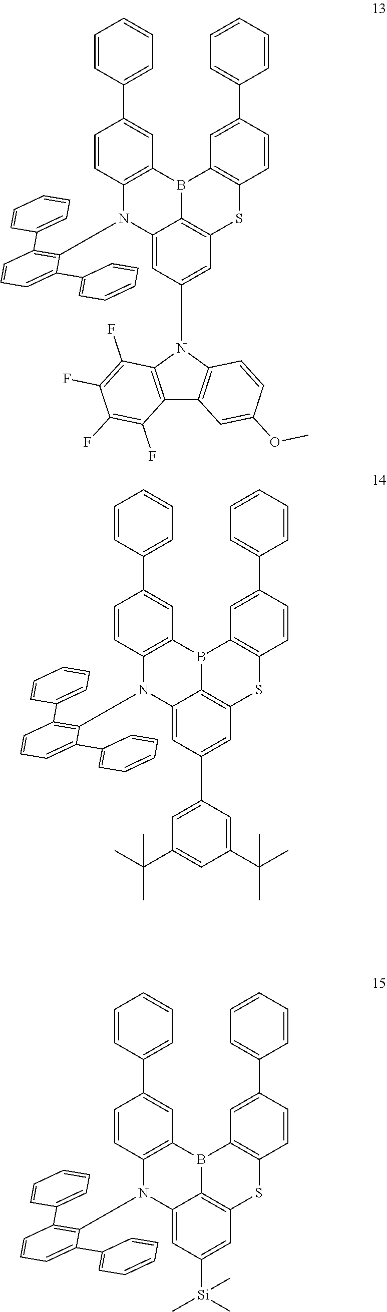

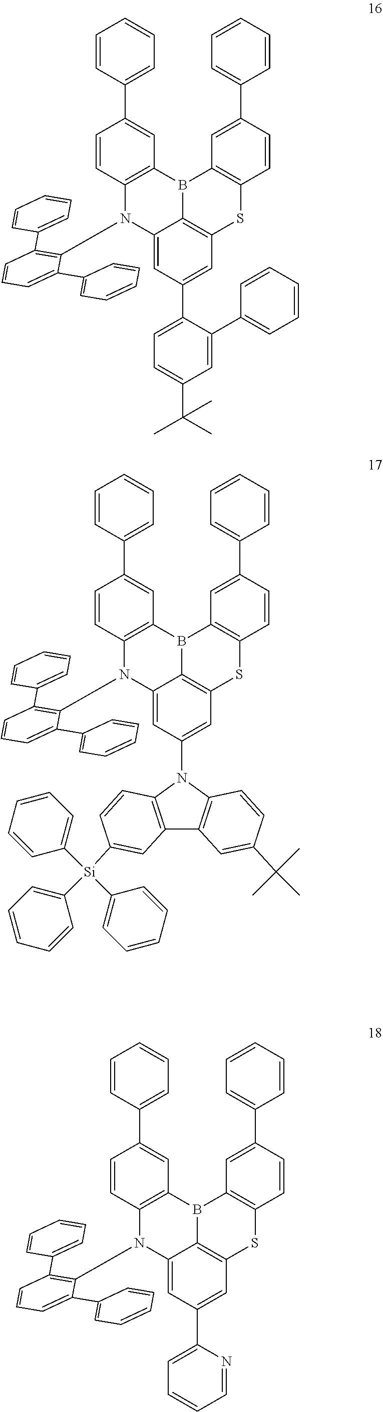 [SMILES: CC(C)(C)c1ccc(-c2cc3c4c(c2)N(c2c(-c5ccccc5)cccc2-c2ccccc2)c2ccc(-c5ccccc5)cc2B4c2cc(-c4ccccc4)ccc2S3)c(-c2ccccc2)c1 ; CC(C)(C)c1ccc2c(c1)c1cc([Si](c3ccccc3)(c3ccccc3)c3ccccc3)ccc1n2-c1cc2c3c(c1)N(c1c(-c4ccccc4)cccc1-c1ccccc1)c1ccc(-c4ccccc4)cc1B3c1cc(-c3ccccc3)ccc1S2 ; c1ccc(-c2ccc3c(c2)B2c4cc(-c5ccccc5)ccc4N(c4c(-c5ccccc5)cccc4-c4ccccc4)c4cc(-c5ccccn5)cc(c42)S3)cc1]

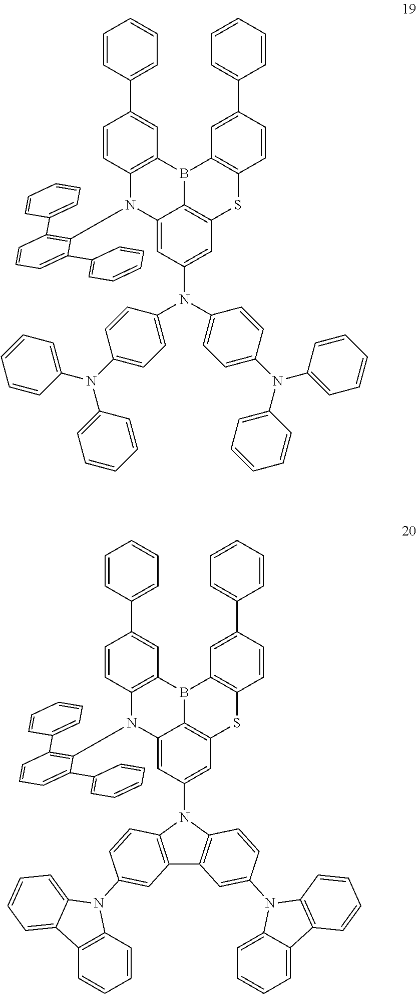 [SMILES: c1ccc(-c2ccc3c(c2)B2c4cc(-c5ccccc5)ccc4N(c4c(-c5ccccc5)cccc4-c4ccccc4)c4cc(N(c5ccc(N(c6ccccc6)c6ccccc6)cc5)c5ccc(N(c6ccccc6)c6ccccc6)cc5)cc(c42)S3)cc1 ; c1ccc(-c2ccc3c(c2)B2c4cc(-c5ccccc5)ccc4N(c4c(-c5ccccc5)cccc4-c4ccccc4)c4cc(-n5c6ccc(-n7c8ccccc8c8ccccc87)cc6c6cc(-n7c8ccccc8c8ccccc87)ccc65)cc(c42)S3)cc1]

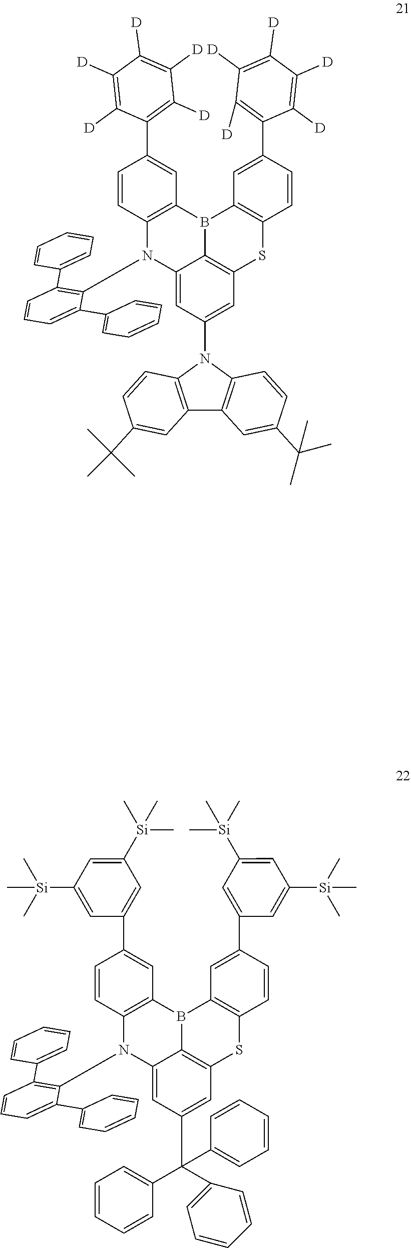 [SMILES: [2H]c1c([2H])c([2H])c(-c2ccc3c(c2)B2c4cc(-c5c([2H])c([2H])c([2H])c([2H])c5[2H])ccc4N(c4c(-c5ccccc5)cccc4-c4ccccc4)c4cc(-n5c6ccc(C(C)(C)C)cc6c6cc(C(C)(C)C)ccc65)cc(c42)S3)c([2H])c1[2H] ; C[Si](C)(C)c1cc(-c2ccc3c(c2)B2c4cc(-c5cc([Si](C)(C)C)cc([Si](C)(C)C)c5)ccc4N(c4c(-c5ccccc5)cccc4-c4ccccc4)c4cc(C(c5ccccc5)(c5ccccc5)c5ccccc5)cc(c42)S3)cc([Si](C)(C)C)c1]

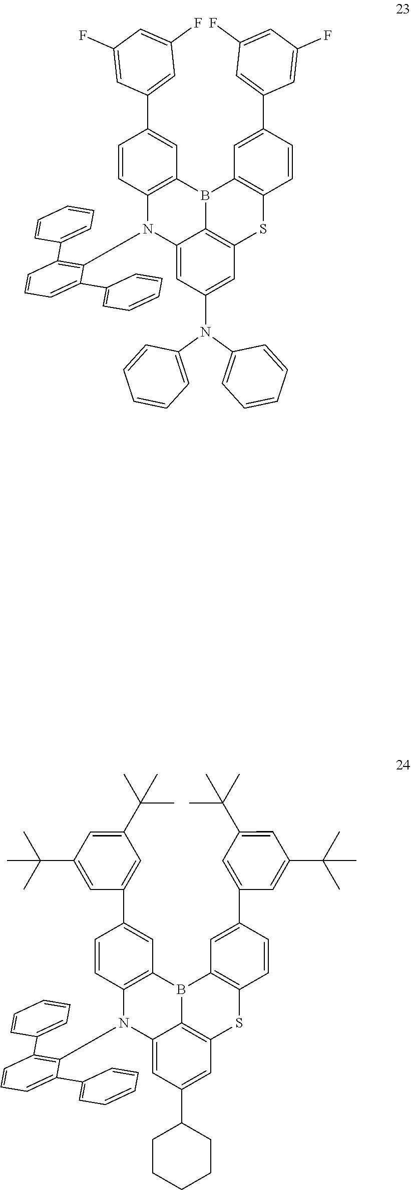 [SMILES: Fc1cc(F)cc(-c2ccc3c(c2)B2c4cc(-c5cc(F)cc(F)c5)ccc4N(c4c(-c5ccccc5)cccc4-c4ccccc4)c4cc(N(c5ccccc5)c5ccccc5)cc(c42)S3)c1 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(C5CCCCC5)cc(c42)S3)cc(C(C)(C)C)c1]

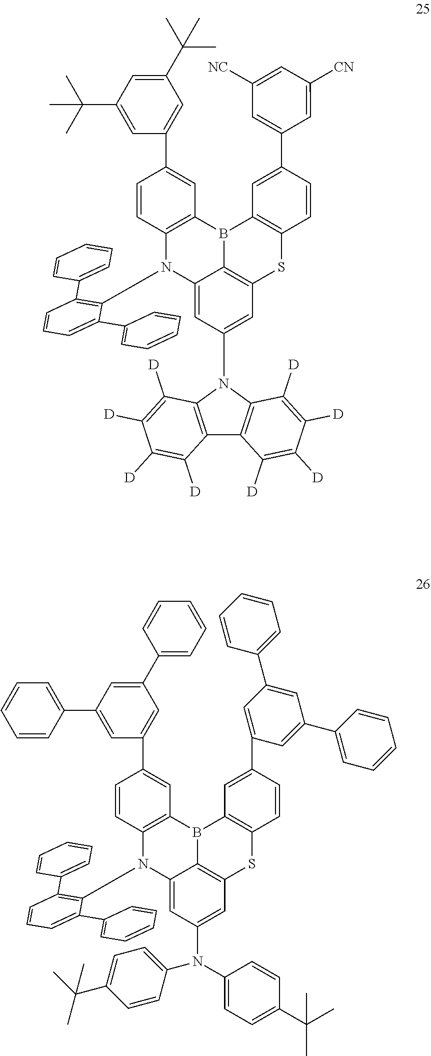 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4cc(C(C)(C)C)cc(C(C)(C)C)c4)cc1B3c1cc(-c3cc(C#N)cc(C#N)c3)ccc1S2 ; CC(C)(C)c1ccc(N(c2ccc(C(C)(C)C)cc2)c2cc3c4c(c2)N(c2c(-c5ccccc5)cccc2-c2ccccc2)c2ccc(-c5cc(-c6ccccc6)cc(-c6ccccc6)c5)cc2B4c2cc(-c4cc(-c5ccccc5)cc(-c5ccccc5)c4)ccc2S3)cc1]

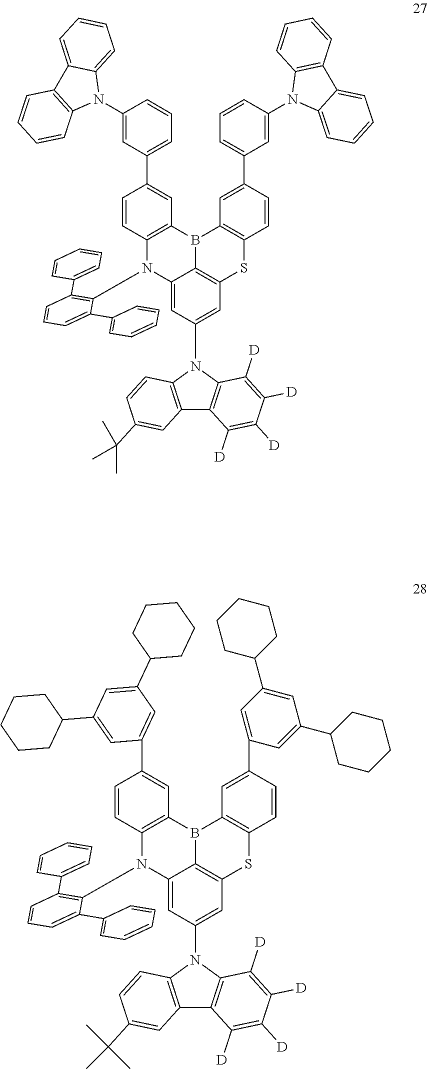 [SMILES: [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cccc(-n5c6ccccc6c6ccccc65)c4)cc1B3c1cc(-c3cccc(-n4c5ccccc5c5ccccc54)c3)ccc1S2 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cc(C5CCCCC5)cc(C5CCCCC5)c4)cc1B3c1cc(-c3cc(C4CCCCC4)cc(C4CCCCC4)c3)ccc1S2]

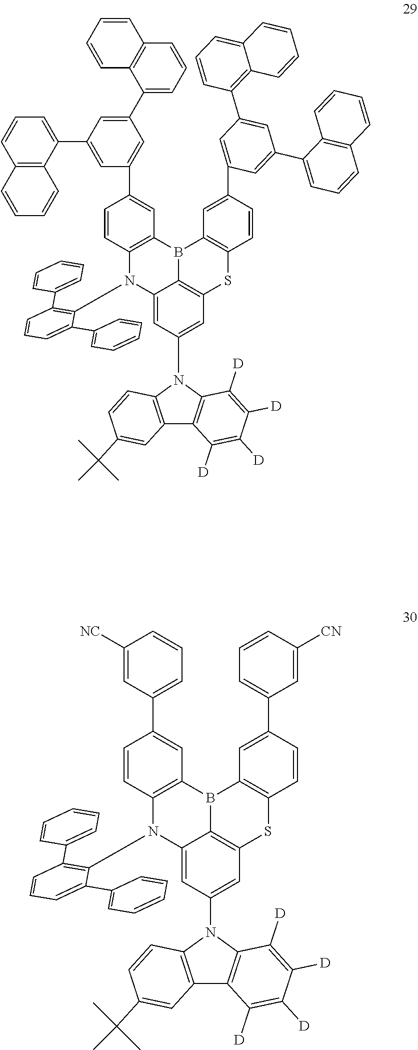 [SMILES: [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cc(-c5cccc6ccccc56)cc(-c5cccc6ccccc56)c4)cc1B3c1cc(-c3cc(-c4cccc5ccccc45)cc(-c4cccc5ccccc45)c3)ccc1S2 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cccc(C#N)c4)cc1B3c1cc(-c3cccc(C#N)c3)ccc1S2]

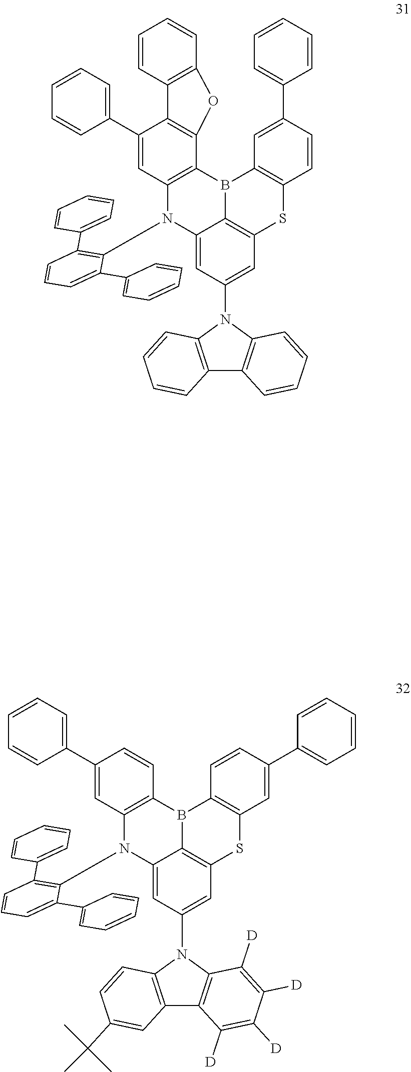 [SMILES: c1ccc(-c2ccc3c(c2)B2c4c(cc(-n5c6ccccc6c6ccccc65)cc4N(c4c(-c5ccccc5)cccc4-c4ccccc4)c4cc(-c5ccccc5)c5c(oc6ccccc65)c42)S3)cc1 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1cc(-c4ccccc4)ccc1B3c1ccc(-c3ccccc3)cc1S2]

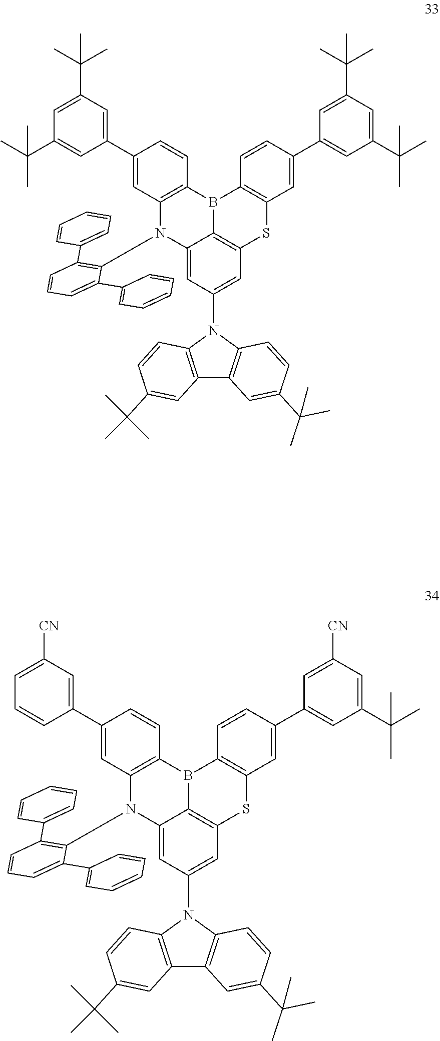 [SMILES: CC(C)(C)c1cc(-c2ccc3c(c2)Sc2cc(-n4c5ccc(C(C)(C)C)cc5c5cc(C(C)(C)C)ccc54)cc4c2B3c2ccc(-c3cc(C(C)(C)C)cc(C(C)(C)C)c3)cc2N4c2c(-c3ccccc3)cccc2-c2ccccc2)cc(C(C)(C)C)c1 ; CC(C)(C)c1cc(C#N)cc(-c2ccc3c(c2)Sc2cc(-n4c5ccc(C(C)(C)C)cc5c5cc(C(C)(C)C)ccc54)cc4c2B3c2ccc(-c3cccc(C#N)c3)cc2N4c2c(-c3ccccc3)cccc2-c2ccccc2)c1]

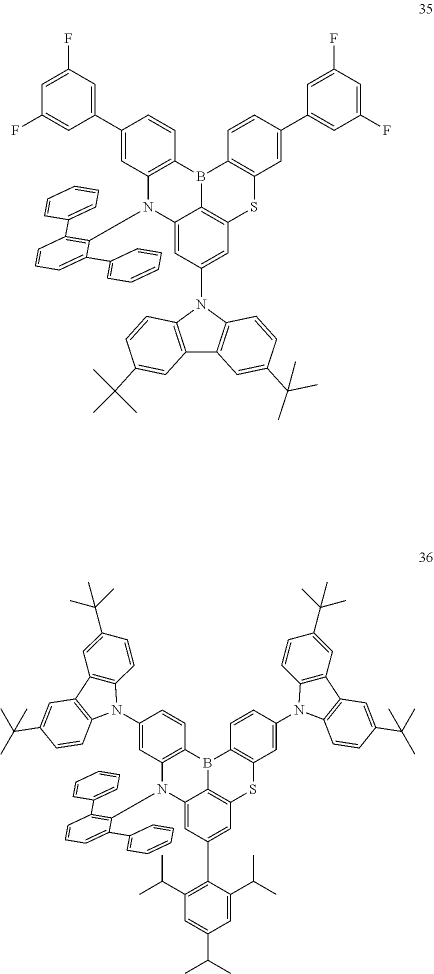 [SMILES: CC(C)(C)c1ccc2c(c1)c1cc(C(C)(C)C)ccc1n2-c1cc2c3c(c1)N(c1c(-c4ccccc4)cccc1-c1ccccc1)c1cc(-c4cc(F)cc(F)c4)ccc1B3c1ccc(-c3cc(F)cc(F)c3)cc1S2 ; CC(C)c1cc(C(C)C)c(-c2cc3c4c(c2)N(c2c(-c5ccccc5)cccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2S3)c(C(C)C)c1]

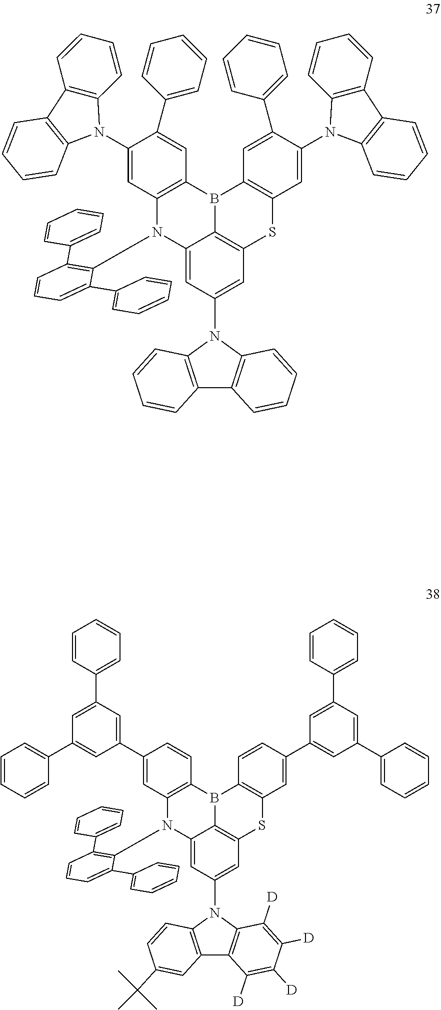 [SMILES: c1ccc(-c2cc3c(cc2-n2c4ccccc4c4ccccc42)Sc2cc(-n4c5ccccc5c5ccccc54)cc4c2B3c2cc(-c3ccccc3)c(-n3c5ccccc5c5ccccc53)cc2N4c2c(-c3ccccc3)cccc2-c2ccccc2)cc1 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1cc(-c4cc(-c5ccccc5)cc(-c5ccccc5)c4)ccc1B3c1ccc(-c3cc(-c4ccccc4)cc(-c4ccccc4)c3)cc1S2]

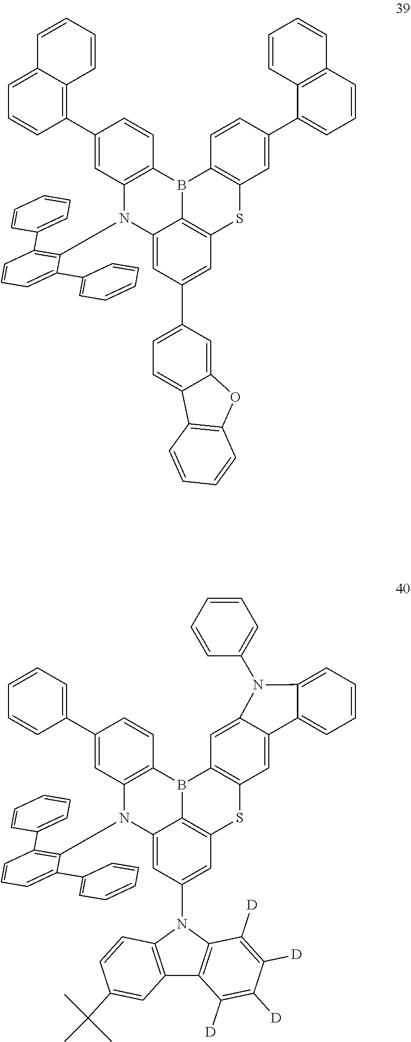 [SMILES: c1ccc(-c2cccc(-c3ccccc3)c2N2c3cc(-c4cccc5ccccc45)ccc3B3c4ccc(-c5cccc6ccccc56)cc4Sc4cc(-c5ccc6c(c5)oc5ccccc56)cc2c43)cc1 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1cc(-c4ccccc4)ccc1B3c1cc3c(cc1S2)c1ccccc1n3-c1ccccc1]

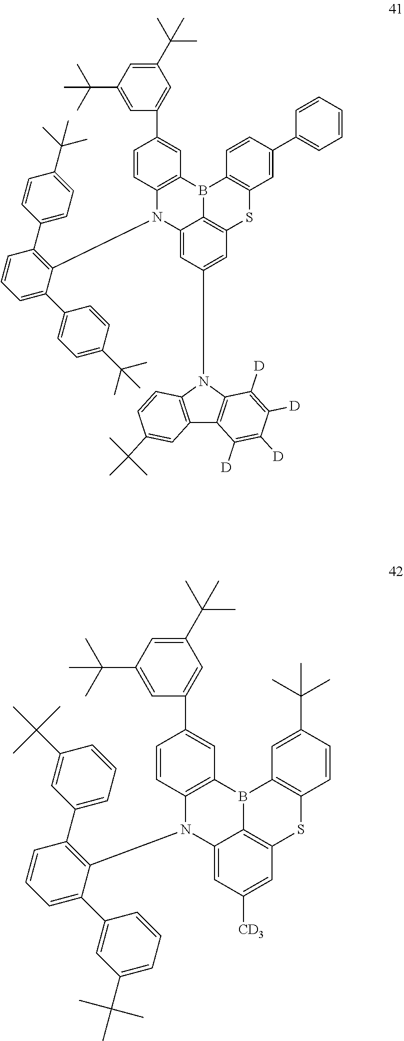 [SMILES: [2H]c1c([2H])c([2H])c2c(c1[2H])c1cc(C(C)(C)C)ccc1n2-c1cc2c3c(c1)N(c1c(-c4ccc(C(C)(C)C)cc4)cccc1-c1ccc(C(C)(C)C)cc1)c1ccc(-c4cc(C(C)(C)C)cc(C(C)(C)C)c4)cc1B3c1ccc(-c3ccccc3)cc1S2 ; [2H]C([2H])([2H])c1cc2c3c(c1)N(c1c(-c4cccc(C(C)(C)C)c4)cccc1-c1cccc(C(C)(C)C)c1)c1ccc(-c4cc(C(C)(C)C)cc(C(C)(C)C)c4)cc1B3c1cc(C(C)(C)C)ccc1S2]

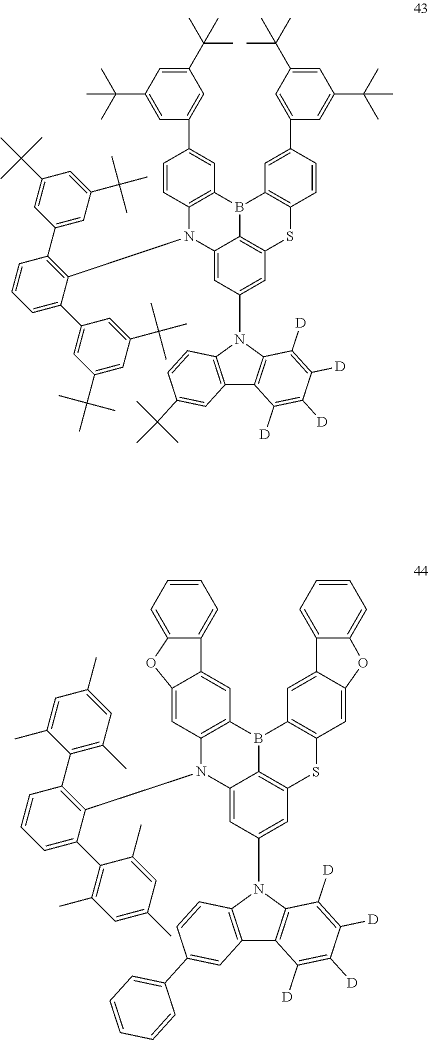

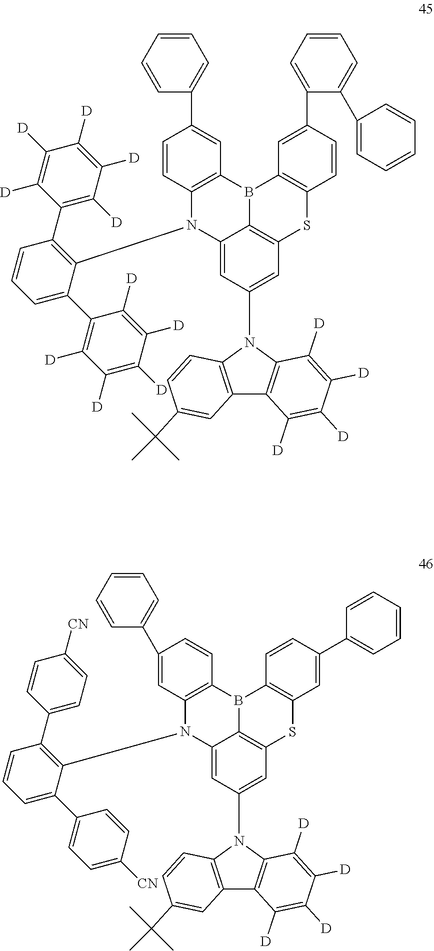 [SMILES: [2H]c1c([2H])c([2H])c(-c2cccc(-c3c([2H])c([2H])c([2H])c([2H])c3[2H])c2N2c3ccc(-c4ccccc4)cc3B3c4cc(-c5ccccc5-c5ccccc5)ccc4Sc4cc(-n5c6ccc(C(C)(C)C)cc6c6c([2H])c([2H])c([2H])c([2H])c65)cc2c43)c([2H])c1[2H] ; [2H]c1c([2H])c([2H])c2c(c1[2H])c1cc(C(C)(C)C)ccc1n2-c1cc2c3c(c1)N(c1c(-c4ccc(C#N)cc4)cccc1-c1ccc(C#N)cc1)c1cc(-c4ccccc4)ccc1B3c1ccc(-c3ccccc3)cc1S2]

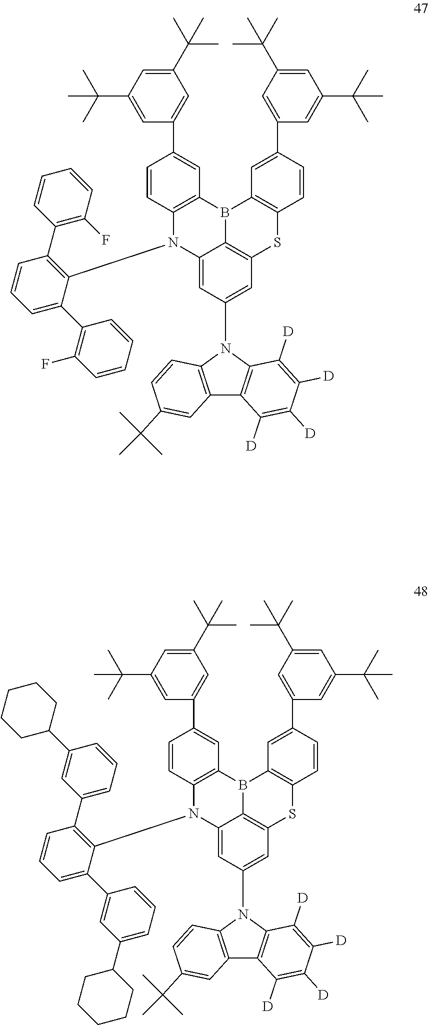 [SMILES: [2H]c1c([2H])c([2H])c2c(c1[2H])c1cc(C(C)(C)C)ccc1n2-c1cc2c3c(c1)N(c1c(-c4ccccc4F)cccc1-c1ccccc1F)c1ccc(-c4cc(C(C)(C)C)cc(C(C)(C)C)c4)cc1B3c1cc(-c3cc(C(C)(C)C)cc(C(C)(C)C)c3)ccc1S2 ; [2H]c1c([2H])c([2H])c2c(c1[2H])c1cc(C(C)(C)C)ccc1n2-c1cc2c3c(c1)N(c1c(-c4cccc(C5CCCCC5)c4)cccc1-c1cccc(C4CCCCC4)c1)c1ccc(-c4cc(C(C)(C)C)cc(C(C)(C)C)c4)cc1B3c1cc(-c3cc(C(C)(C)C)cc(C(C)(C)C)c3)ccc1S2]

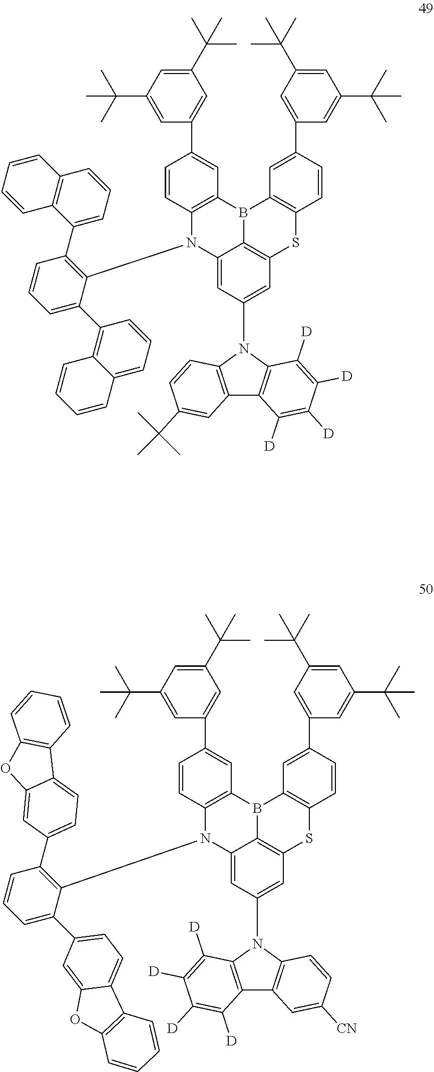 [SMILES: [2H]c1c([2H])c([2H])c2c(c1[2H])c1cc(C(C)(C)C)ccc1n2-c1cc2c3c(c1)N(c1c(-c4cccc5ccccc45)cccc1-c1cccc4ccccc14)c1ccc(-c4cc(C(C)(C)C)cc(C(C)(C)C)c4)cc1B3c1cc(-c3cc(C(C)(C)C)cc(C(C)(C)C)c3)ccc1S2 ; [2H]c1c([2H])c([2H])c2c(c1[2H])c1cc(C#N)ccc1n2-c1cc2c3c(c1)N(c1c(-c4ccc5c(c4)oc4ccccc45)cccc1-c1ccc4c(c1)oc1ccccc14)c1ccc(-c4cc(C(C)(C)C)cc(C(C)(C)C)c4)cc1B3c1cc(-c3cc(C(C)(C)C)cc(C(C)(C)C)c3)ccc1S2]

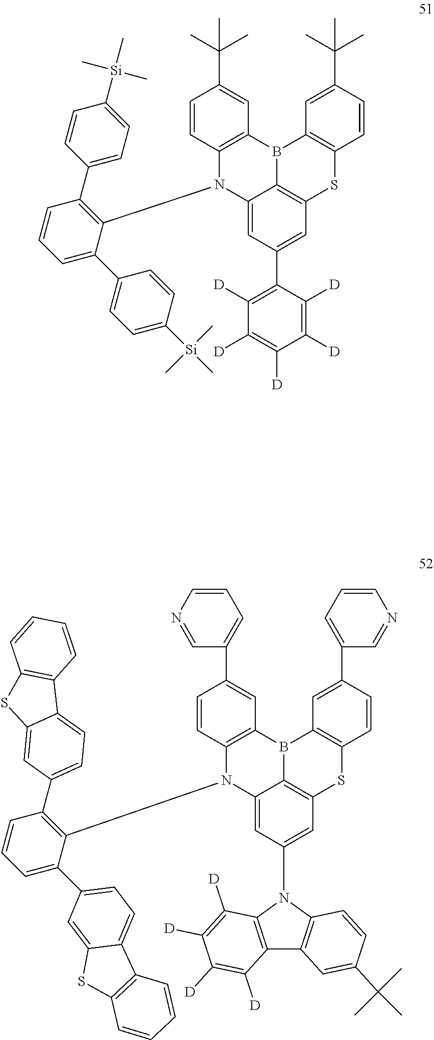 [SMILES: [2H]c1c([2H])c([2H])c(-c2cc3c4c(c2)N(c2c(-c5ccc([Si](C)(C)C)cc5)cccc2-c2ccc([Si](C)(C)C)cc2)c2ccc(C(C)(C)C)cc2B4c2cc(C(C)(C)C)ccc2S3)c([2H])c1[2H] ; [2H]c1c([2H])c([2H])c2c(c1[2H])c1cc(C(C)(C)C)ccc1n2-c1cc2c3c(c1)N(c1c(-c4ccc5c(c4)sc4ccccc45)cccc1-c1ccc4c(c1)sc1ccccc14)c1ccc(-c4cccnc4)cc1B3c1cc(-c3cccnc3)ccc1S2]

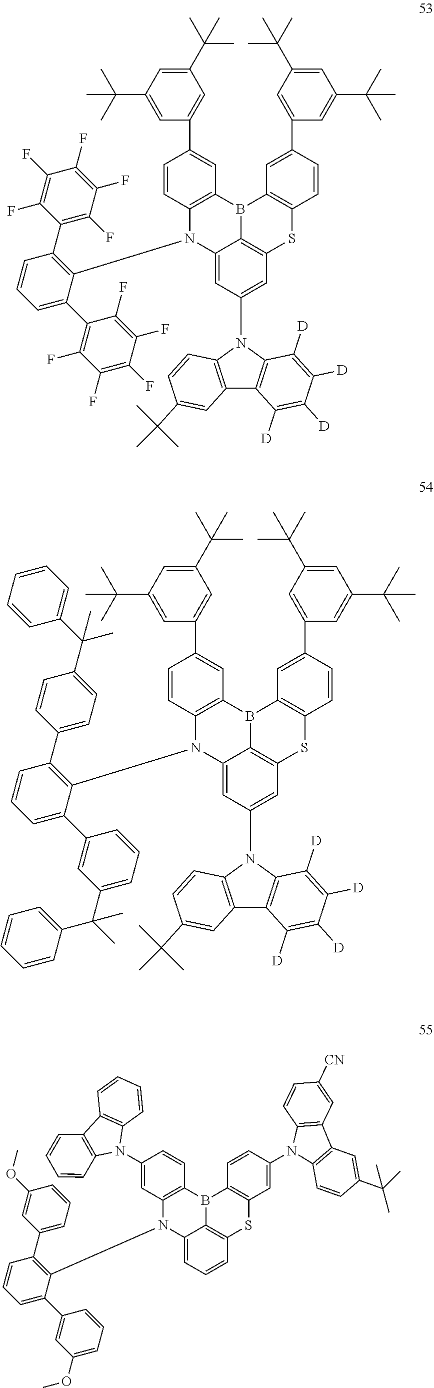

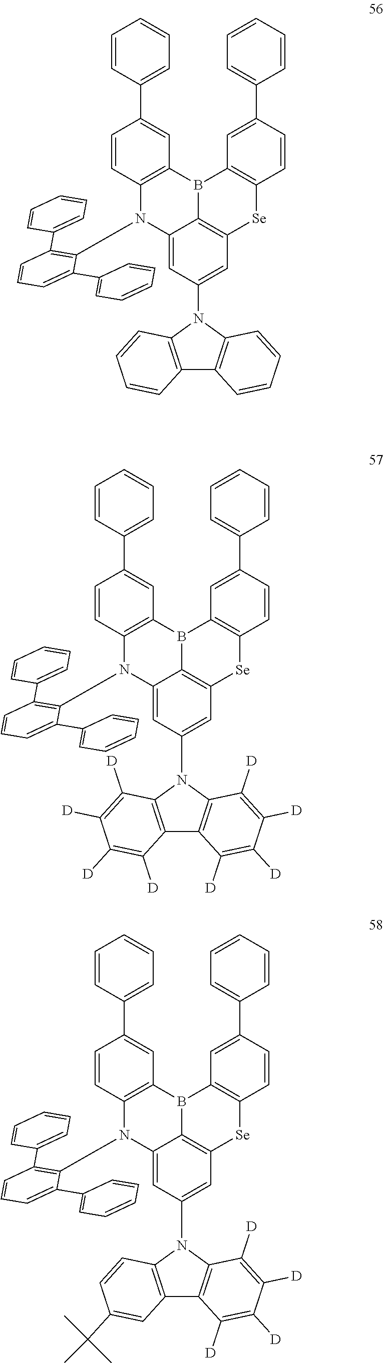 [SMILES: c1ccc(-c2ccc3c(c2)B2c4cc(-c5ccccc5)ccc4N(c4c(-c5ccccc5)cccc4-c4ccccc4)c4cc(-n5c6ccccc6c6ccccc65)cc(c42)[Se]3)cc1 ; [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4ccccc4)cc1B3c1cc(-c3ccccc3)ccc1[Se]2 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4ccccc4)cc1B3c1cc(-c3ccccc3)ccc1[Se]2]

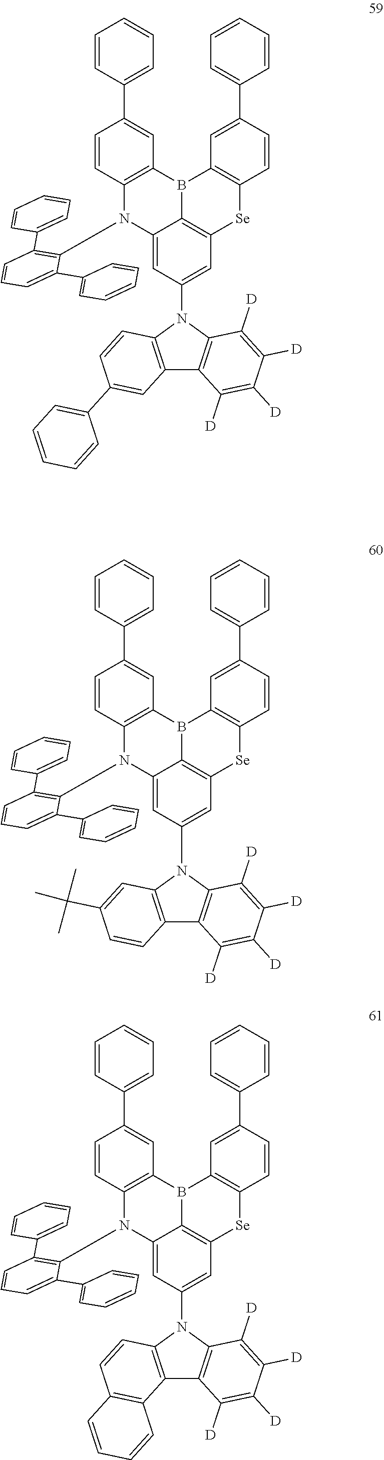 [SMILES: [2H]c1c([2H])c([2H])c2c(c1[2H])c1cc(-c3ccccc3)ccc1n2-c1cc2c3c(c1)N(c1c(-c4ccccc4)cccc1-c1ccccc1)c1ccc(-c4ccccc4)cc1B3c1cc(-c3ccccc3)ccc1[Se]2 ; [2H]c1c([2H])c([2H])c2c(c1[2H])c1ccc(C(C)(C)C)cc1n2-c1cc2c3c(c1)N(c1c(-c4ccccc4)cccc1-c1ccccc1)c1ccc(-c4ccccc4)cc1B3c1cc(-c3ccccc3)ccc1[Se]2 ; [2H]c1c([2H])c([2H])c2c(c1[2H])c1c3ccccc3ccc1n2-c1cc2c3c(c1)N(c1c(-c4ccccc4)cccc1-c1ccccc1)c1ccc(-c4ccccc4)cc1B3c1cc(-c3ccccc3)ccc1[Se]2]

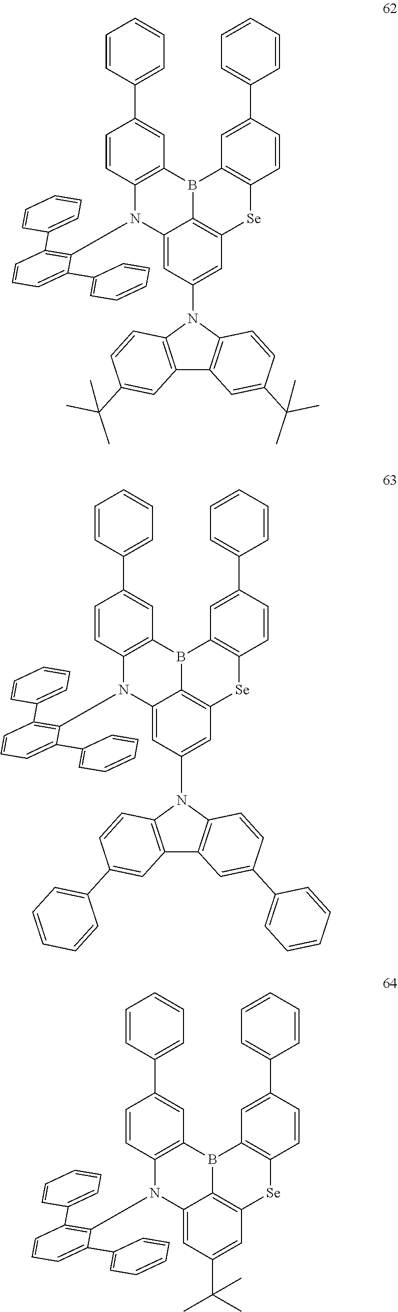

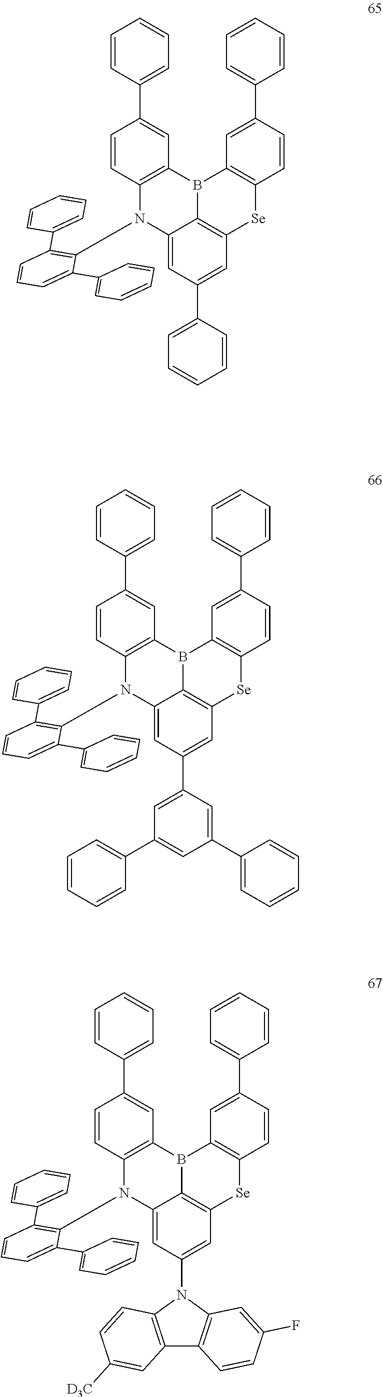 [SMILES: c1ccc(-c2ccc3c(c2)B2c4cc(-c5ccccc5)ccc4N(c4c(-c5ccccc5)cccc4-c4ccccc4)c4cc(-c5ccccc5)cc(c42)[Se]3)cc1 ; c1ccc(-c2cc(-c3ccccc3)cc(-c3cc4c5c(c3)N(c3c(-c6ccccc6)cccc3-c3ccccc3)c3ccc(-c6ccccc6)cc3B5c3cc(-c5ccccc5)ccc3[Se]4)c2)cc1 ; [2H]C([2H])([2H])c1ccc2c(c1)c1ccc(F)cc1n2-c1cc2c3c(c1)N(c1c(-c4ccccc4)cccc1-c1ccccc1)c1ccc(-c4ccccc4)cc1B3c1cc(-c3ccccc3)ccc1[Se]2]

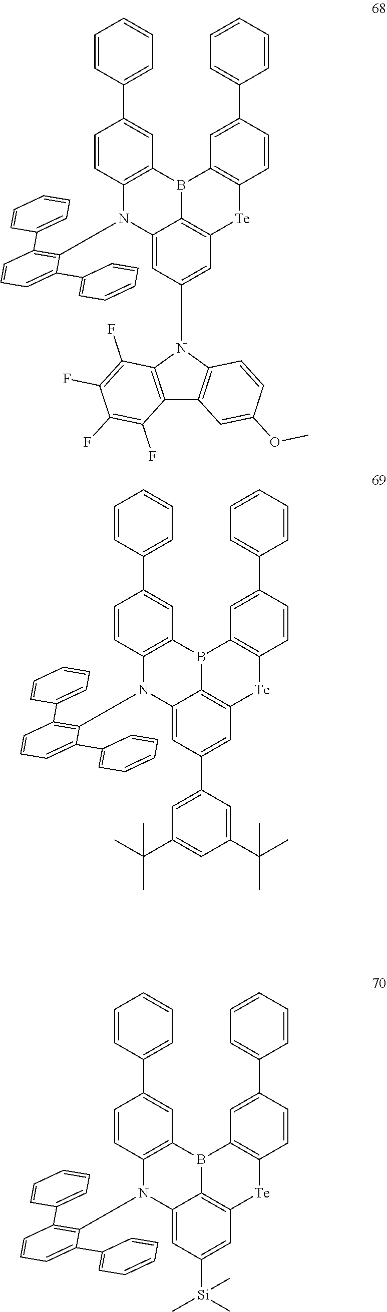

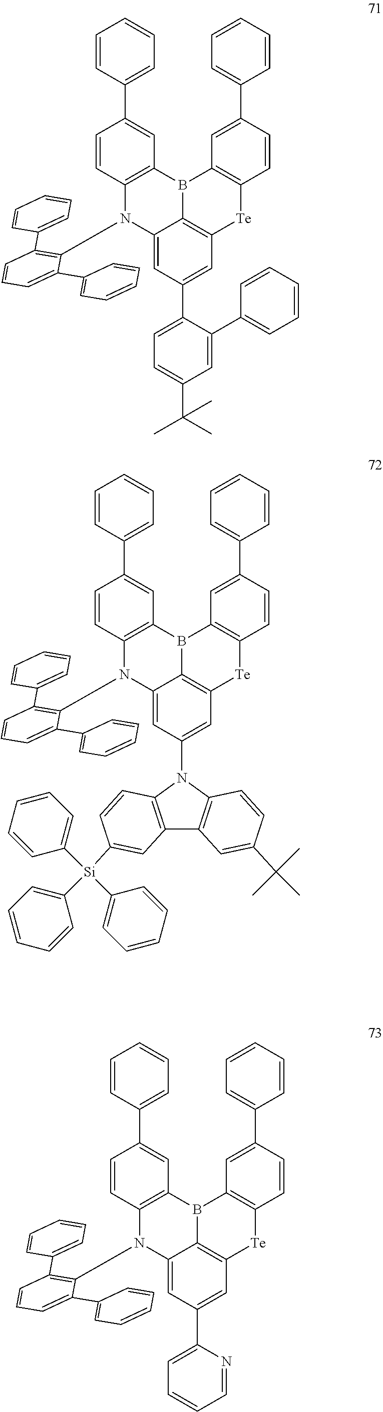

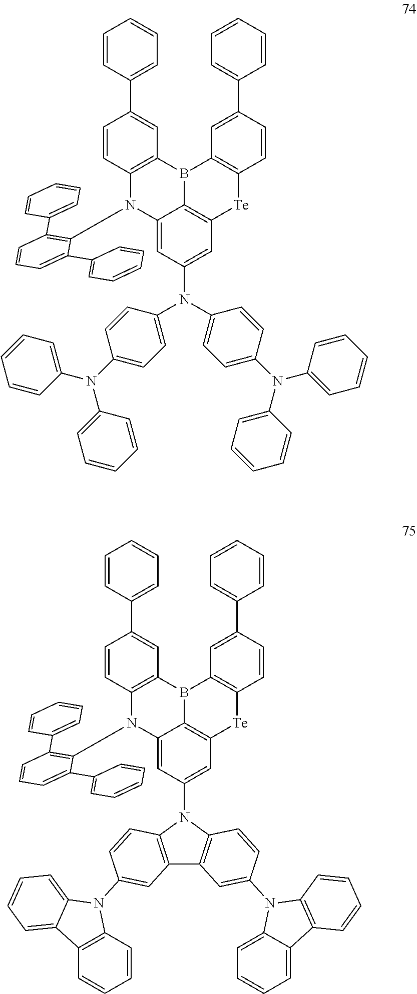

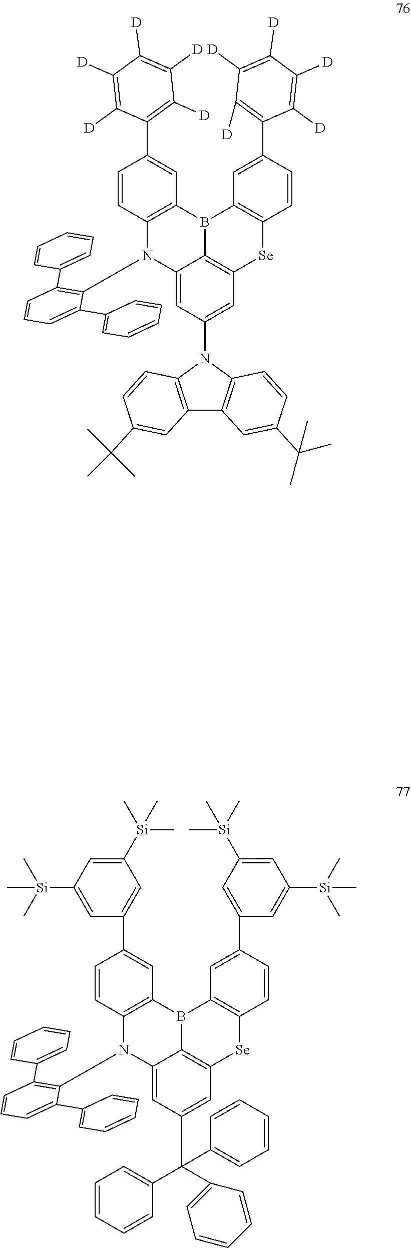 [SMILES: [2H]c1c([2H])c([2H])c(-c2ccc3c(c2)B2c4cc(-c5c([2H])c([2H])c([2H])c([2H])c5[2H])ccc4N(c4c(-c5ccccc5)cccc4-c4ccccc4)c4cc(-n5c6ccc(C(C)(C)C)cc6c6cc(C(C)(C)C)ccc65)cc(c42)[Se]3)c([2H])c1[2H] ; C[Si](C)(C)c1cc(-c2ccc3c(c2)B2c4cc(-c5cc([Si](C)(C)C)cc([Si](C)(C)C)c5)ccc4N(c4c(-c5ccccc5)cccc4-c4ccccc4)c4cc(C(c5ccccc5)(c5ccccc5)c5ccccc5)cc(c42)[Se]3)cc([Si](C)(C)C)c1]

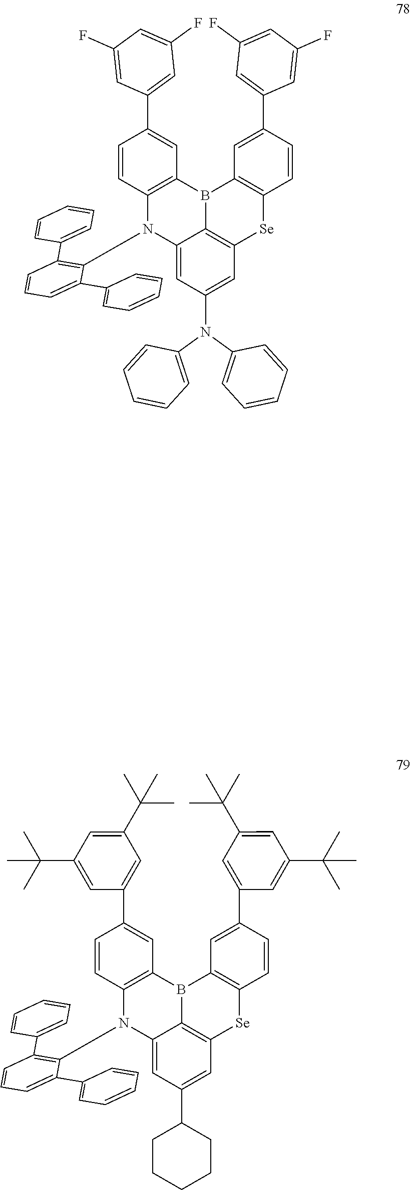 [SMILES: Fc1cc(F)cc(-c2ccc3c(c2)B2c4cc(-c5cc(F)cc(F)c5)ccc4N(c4c(-c5ccccc5)cccc4-c4ccccc4)c4cc(N(c5ccccc5)c5ccccc5)cc(c42)[Se]3)c1 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(C5CCCCC5)cc(c42)[Se]3)cc(C(C)(C)C)c1]

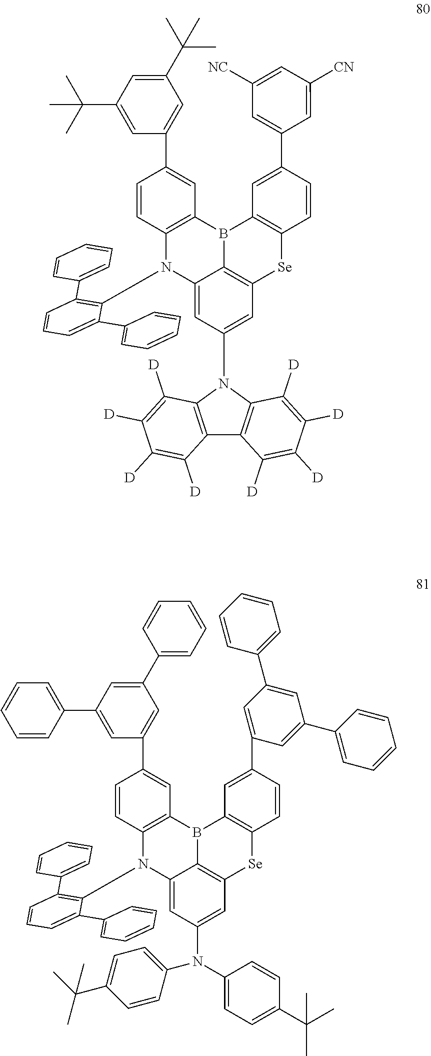 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4cc(C(C)(C)C)cc(C(C)(C)C)c4)cc1B3c1cc(-c3cc(C#N)cc(C#N)c3)ccc1[Se]2 ; CC(C)(C)c1ccc(N(c2ccc(C(C)(C)C)cc2)c2cc3c4c(c2)N(c2c(-c5ccccc5)cccc2-c2ccccc2)c2ccc(-c5cc(-c6ccccc6)cc(-c6ccccc6)c5)cc2B4c2cc(-c4cc(-c5ccccc5)cc(-c5ccccc5)c4)ccc2[Se]3)cc1]

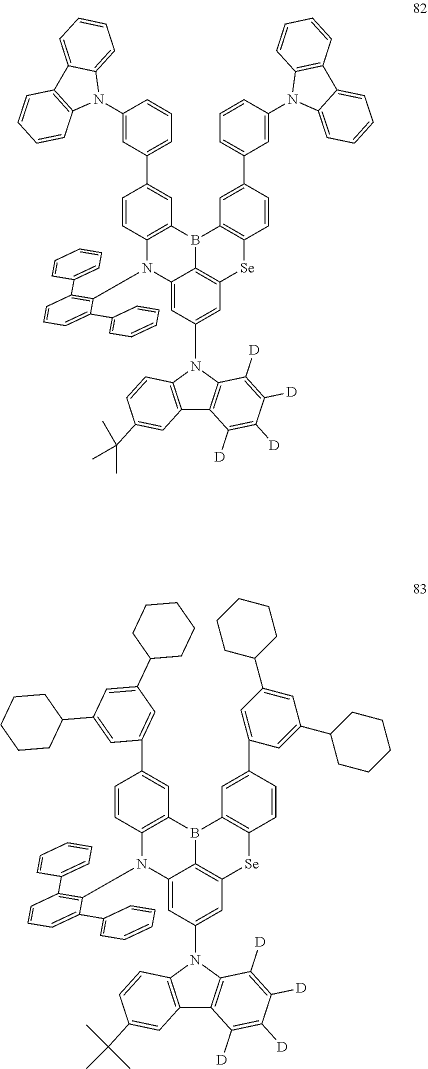 [SMILES: [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cccc(-n5c6ccccc6c6ccccc65)c4)cc1B3c1cc(-c3cccc(-n4c5ccccc5c5ccccc54)c3)ccc1[Se]2 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cc(C5CCCCC5)cc(C5CCCCC5)c4)cc1B3c1cc(-c3cc(C4CCCCC4)cc(C4CCCCC4)c3)ccc1[Se]2]

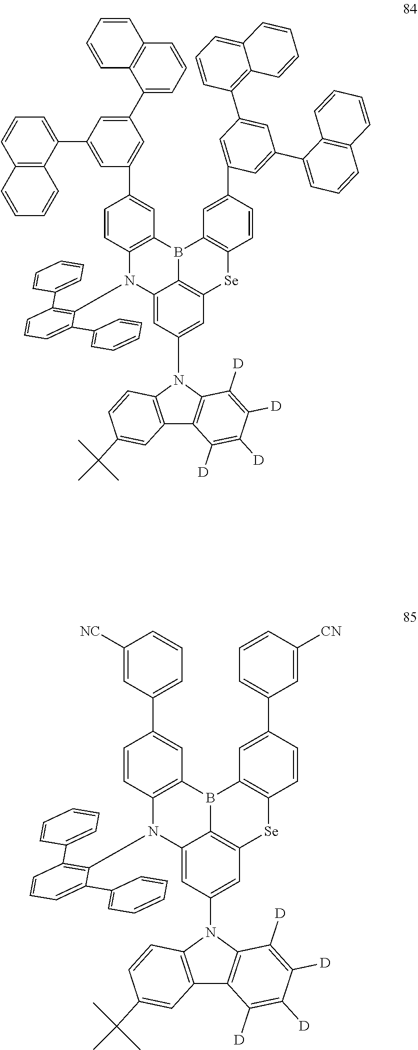 [SMILES: [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cc(-c5cccc6ccccc56)cc(-c5cccc6ccccc56)c4)cc1B3c1cc(-c3cc(-c4cccc5ccccc45)cc(-c4cccc5ccccc45)c3)ccc1[Se]2 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccc(-c4cccc(C#N)c4)cc1B3c1cc(-c3cccc(C#N)c3)ccc1[Se]2]

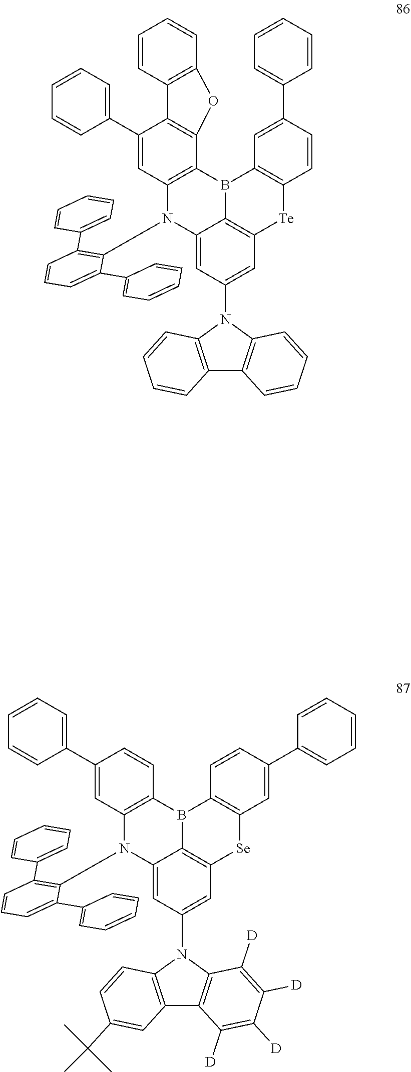

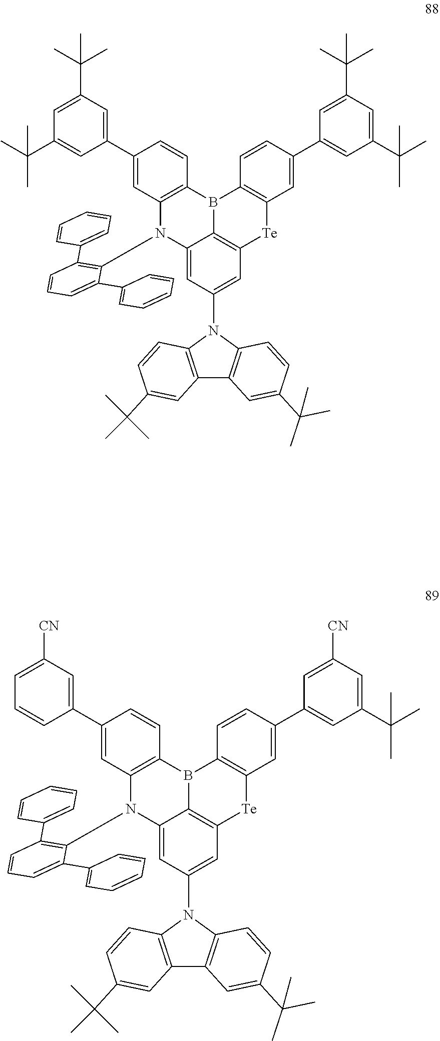

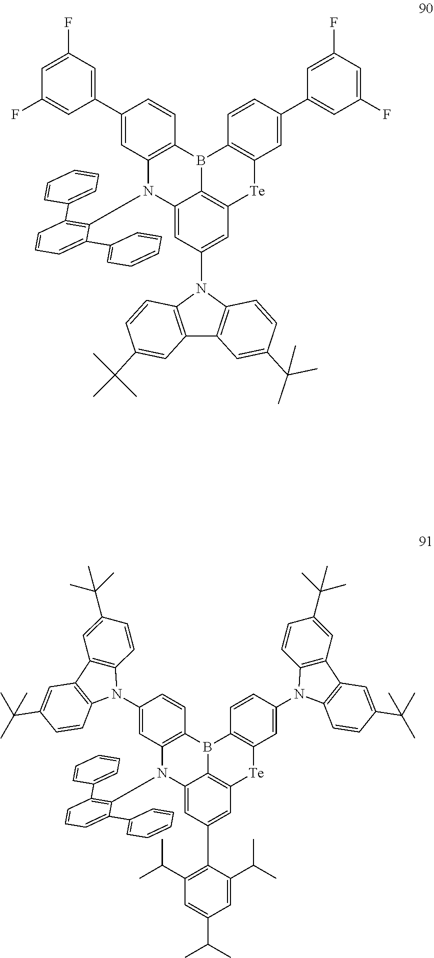

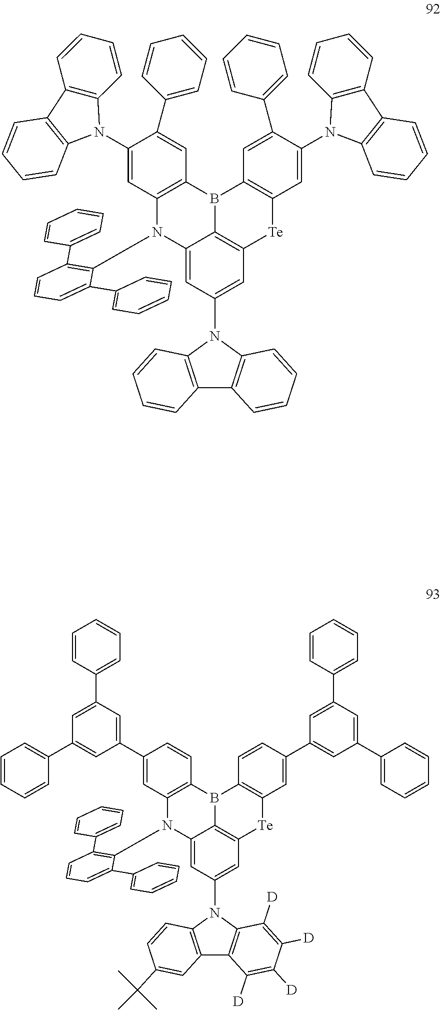

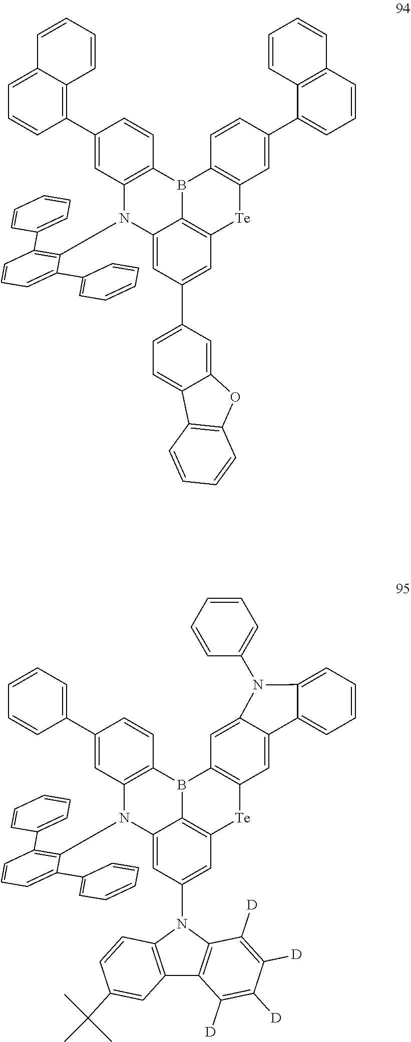

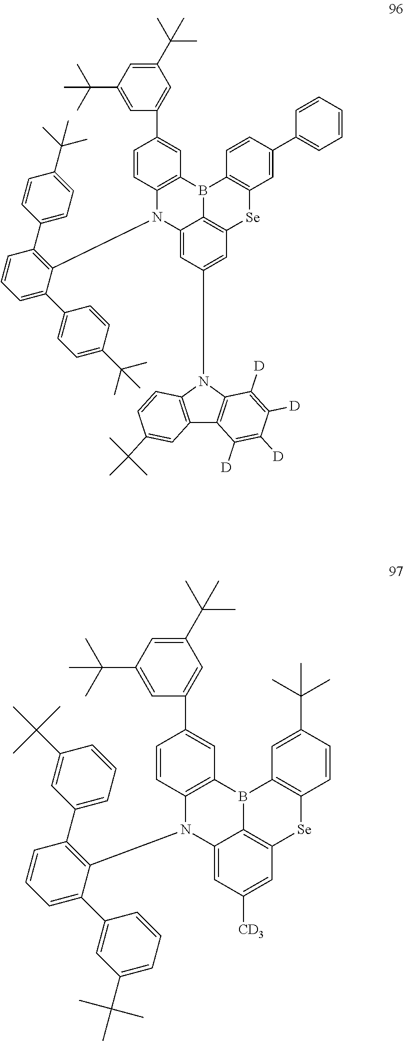 [SMILES: [2H]c1c([2H])c([2H])c2c(c1[2H])c1cc(C(C)(C)C)ccc1n2-c1cc2c3c(c1)N(c1c(-c4ccc(C(C)(C)C)cc4)cccc1-c1ccc(C(C)(C)C)cc1)c1ccc(-c4cc(C(C)(C)C)cc(C(C)(C)C)c4)cc1B3c1ccc(-c3ccccc3)cc1[Se]2 ; [2H]C([2H])([2H])c1cc2c3c(c1)N(c1c(-c4cccc(C(C)(C)C)c4)cccc1-c1cccc(C(C)(C)C)c1)c1ccc(-c4cc(C(C)(C)C)cc(C(C)(C)C)c4)cc1B3c1cc(C(C)(C)C)ccc1[Se]2]

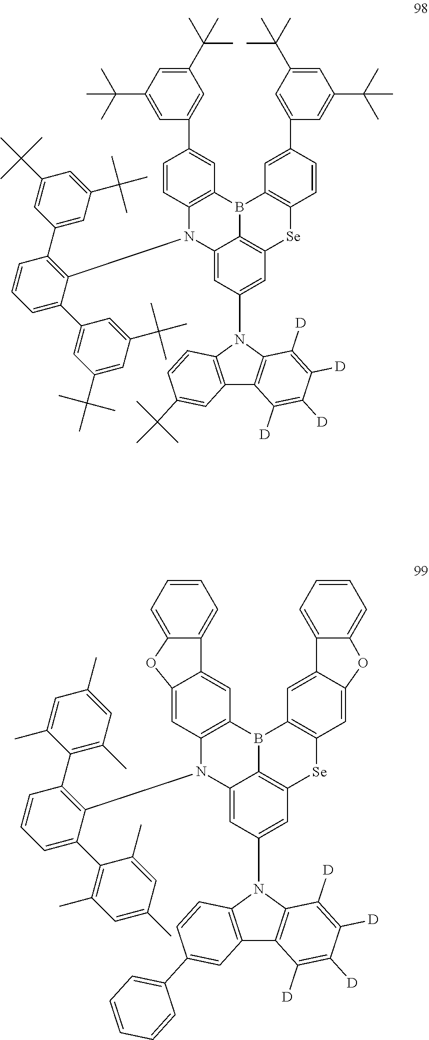

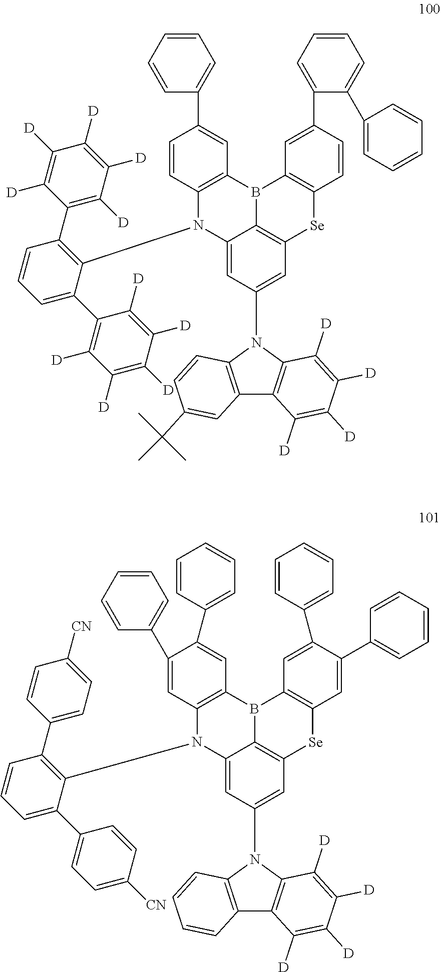 [SMILES: [2H]c1c([2H])c([2H])c(-c2cccc(-c3c([2H])c([2H])c([2H])c([2H])c3[2H])c2N2c3ccc(-c4ccccc4)cc3B3c4cc(-c5ccccc5-c5ccccc5)ccc4[Se]c4cc(-n5c6ccc(C(C)(C)C)cc6c6c([2H])c([2H])c([2H])c([2H])c65)cc2c43)c([2H])c1[2H] ; [2H]c1c([2H])c([2H])c2c(c1[2H])c1ccccc1n2-c1cc2c3c(c1)N(c1c(-c4ccc(C#N)cc4)cccc1-c1ccc(C#N)cc1)c1cc(-c4ccccc4)c(-c4ccccc4)cc1B3c1cc(-c3ccccc3)c(-c3ccccc3)cc1[Se]2]

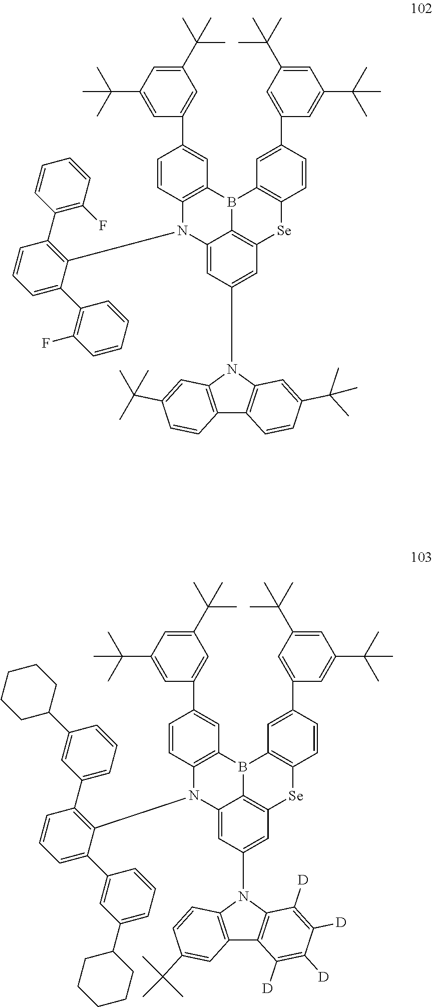 [SMILES: CC(C)(C)c1cc(-c2ccc3c(c2)B2c4cc(-c5cc(C(C)(C)C)cc(C(C)(C)C)c5)ccc4N(c4c(-c5ccccc5F)cccc4-c4ccccc4F)c4cc(-n5c6cc(C(C)(C)C)ccc6c6ccc(C(C)(C)C)cc65)cc(c42)[Se]3)cc(C(C)(C)C)c1 ; [2H]c1c([2H])c([2H])c2c(c1[2H])c1cc(C(C)(C)C)ccc1n2-c1cc2c3c(c1)N(c1c(-c4cccc(C5CCCCC5)c4)cccc1-c1cccc(C4CCCCC4)c1)c1ccc(-c4cc(C(C)(C)C)cc(C(C)(C)C)c4)cc1B3c1cc(-c3cc(C(C)(C)C)cc(C(C)(C)C)c3)ccc1[Se]2]

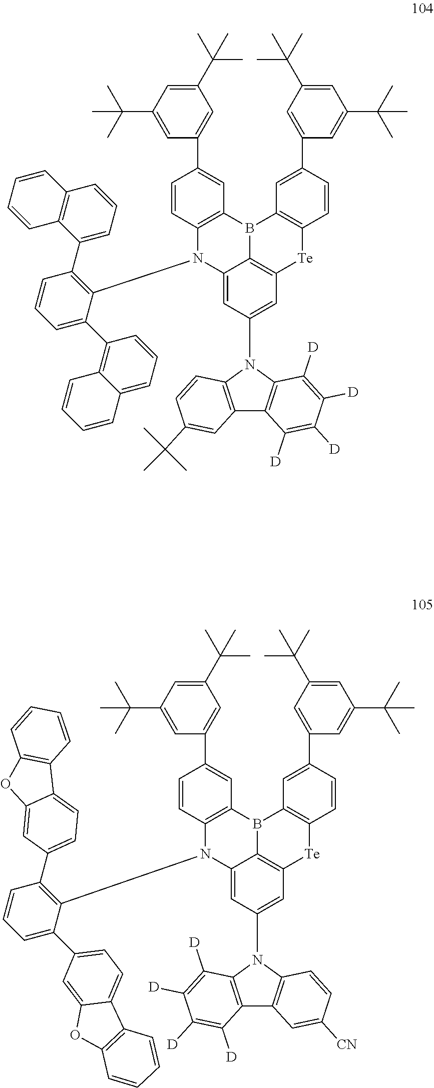

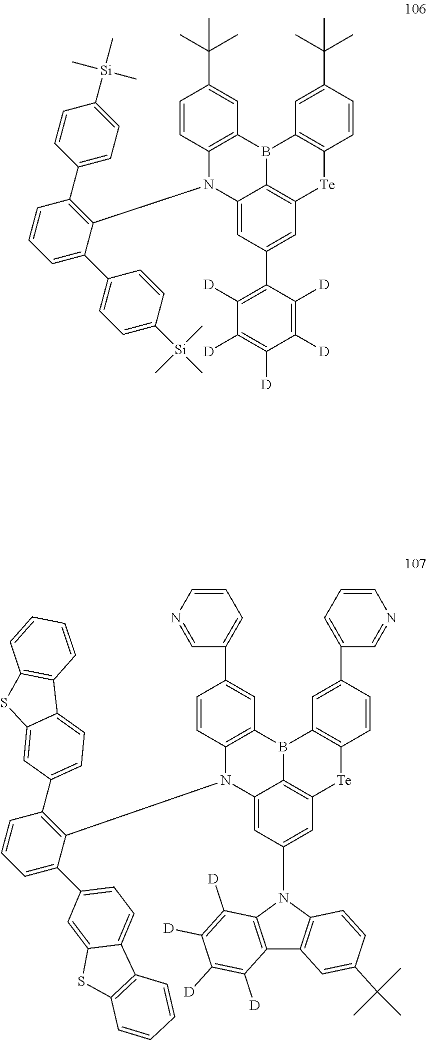

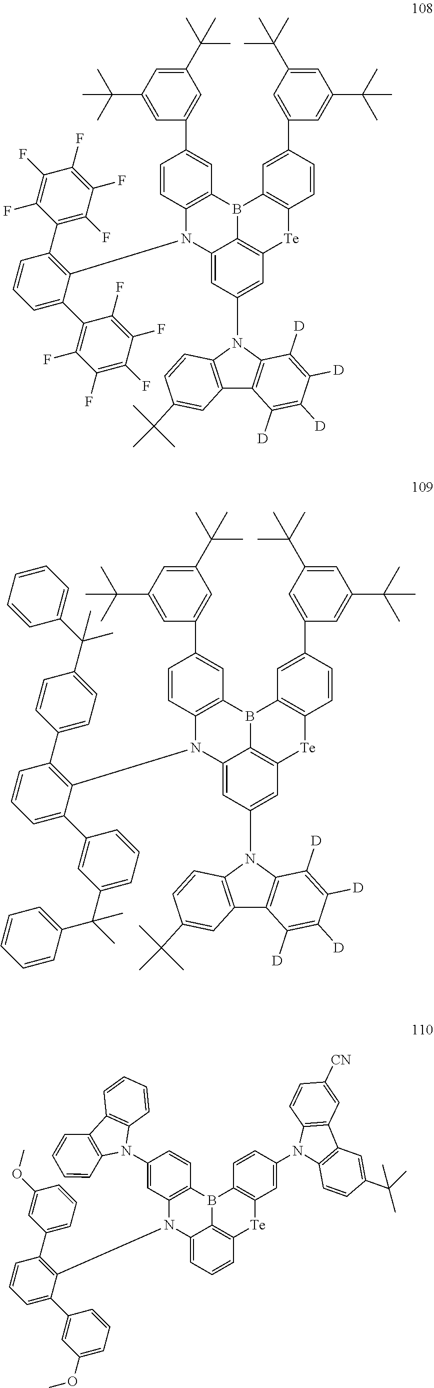

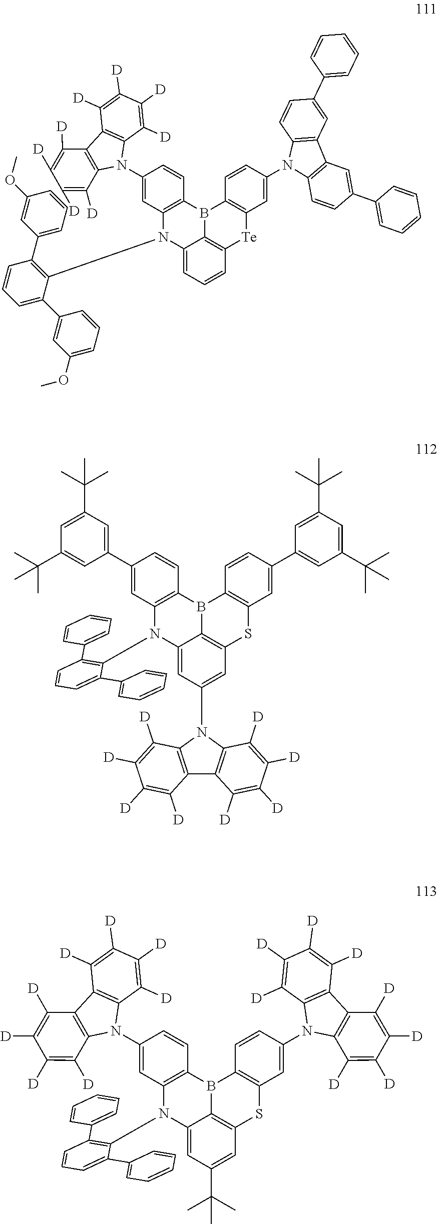

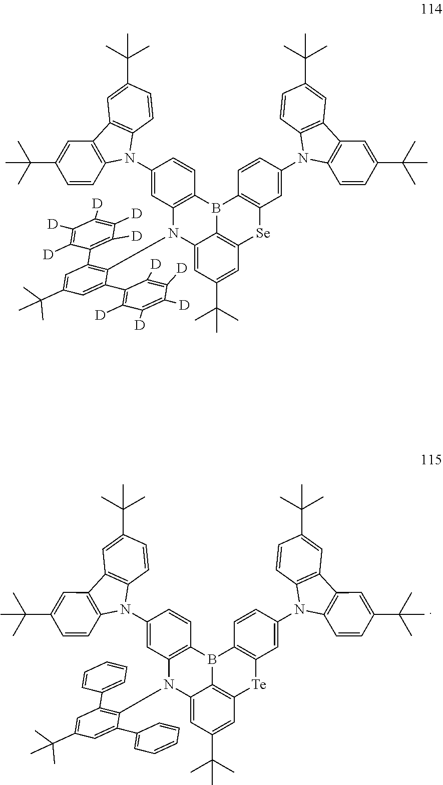

The polycyclic compound of an embodiment includes a fused ring skeleton containing a boron atom, a nitrogen atom, and a heavy atom as ring-forming atoms, an ortho-type or kind terphenyl group connected with the nitrogen atom, and has steric shielding effects to show stable compound properties. In addition, by utilizing the polycyclic compound of an embodiment as the material of a light emitting element, the life-characteristics (lifespan) of the light emitting element may be improved.

In some embodiments, the polycyclic compound of an embodiment may be included in an emission layer EML. The polycyclic compound of an embodiment may be included as a dopant material in an emission layer EML. The polycyclic compound of an embodiment may be a material emitting thermally activated delayed fluorescence. The polycyclic compound of an embodiment may be utilized as a thermally activated delayed fluorescence dopant. For example, in the light emitting element ED of an embodiment, the emission layer EML may include at least one selected from among the polycyclic compounds represented in Compound Group 1 as a thermally activated delayed fluorescence dopant. However, the usage of the polycyclic compound of an embodiment is not limited thereto.

The polycyclic compound of an embodiment may emit blue light and may have the maximum emission wavelength around about 460 nm. The polycyclic compound of an embodiment may emit pure blue having the maximum emission wavelength of around 460 nm.

In an embodiment, the emission layer EML may include a first compound represented by Formula 1, and at least one compound selected from among a second compound represented by Formula 2, a third compound represented by Formula 3 and a fourth compound represented by Formula 4.

For example, in an embodiment, the second compound may be utilized as a hole transport host material in an emission layer EML.

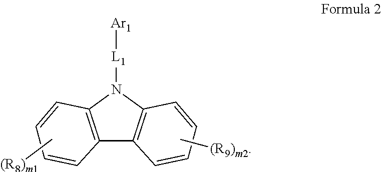

In Formula 2, L₁ may be a direct linkage, a substituted or unsubstituted arylene group of 6 to 30 ring-forming carbon atoms, or a substituted or unsubstituted heteroarylene group of 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, and/or the like, but an embodiment of the present disclosure is not limited thereto.

Ar₁ may be a substituted or unsubstituted aryl group of 6 to 30 ring-forming carbon atoms, or a substituted or unsubstituted heteroaryl group of 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group and/or the like, but an embodiment of the present disclosure is not limited thereto.

R₈ and R₉ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring. For example, R₈ and R₉ may each independently be a hydrogen atom, or a deuterium atom.

m1 and m2 may be integers of 0 to 4. In Formula 2, m1 and m2 may each independently be an integer of 0 to 4. When m1 and m2 are 0, the second compound of an embodiment may be unsubstituted with R₈ and R₉, respectively. In Formula 2, a case where m1 and m2 are each 4, and R₈ and R₉ are each hydrogen atoms, may be the same as a case where m1 and m2 are each 0. When m1 and m2 are each integers of 2 or more, each of multiple R₈ and R₉ may all be the same, or at least one selected from among multiple R₈ and R₉ may be different from the remainder thereof.

In an embodiment, the emission layer EML may include a third compound represented by Formula 3. For example, the third compound may be utilized as the electron transport host material of the emission layer EML.

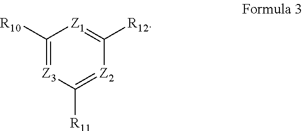

In Formula 3, Z₁, Z₂ and Z₃ may each independently be N or CR₁₃, and at least one thereof may be N. For example, the third compound represented by Formula 3 may include a pyridine moiety, a pyrimidine moiety, or a triazine moiety.

R₁₀ to R₁₃ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring. For example, R₁₀ to R₁₃ may each independently be a substituted or unsubstituted phenyl group, a substituted or unsubstituted carbazole group, and/or the like, but an embodiment of the present disclosure is not limited thereto.

For example, the emission layer may include the second compound and the third compound, and the second compound and the third compound may form exciplexes. In the emission layer EML, exciplexes may be formed by a hole transport host and an electron transport host. In this case, the triplet energy of the exciplexes formed by the hole transport host and the electron transport host may correspond to a difference between the energy level of the lowest unoccupied molecular orbital (LUMO) of the electron transport host and the energy level of the highest occupied molecular orbital (HOMO) of the hole transport host.

For example, the absolute value of the triplet energy level (T1) of the exciplexes formed by the hole transport host and the electron transport host may be about 2.4 eV to about 3.0 eV. In some embodiments, the triplet energy of the exciplexes may be a smaller value than the energy gap of the host materials. The exciplexes may have a triplet energy of about 3.0 eV or less, which is the energy gap of the hole transport host and the electron transport host.

In an embodiment, the emission layer EML may include a fourth compound in addition to the first compound to the third compound. The fourth compound may be utilized as a phosphorescence sensitizer of an emission layer EML. Energy may be transferred from the fourth compound to the first compound to emit light.

For example, the emission layer EML may include an organometallic complex including platinum (Pt) as a central metal atom and ligands bonded to the central metal atom, as the fourth compound. In the light emitting element ED of an embodiment, the emission layer EML may include a compound represented by Formula 4 as the fourth compound.

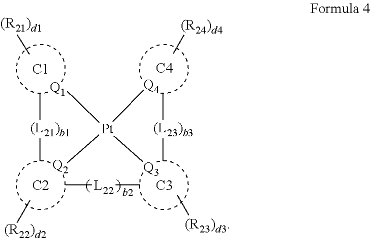

In Formula 4, Q₁ to 04 may each independently be C or N.

C1 to 04 may each independently be a substituted or unsubstituted hydrocarbon ring of 5 to 30 ring-forming carbon atoms, or a substituted or unsubstituted heterocyclic group of 2 to 30 ring-forming carbon atoms.

L₂₁ to L₂₃ may each independently be a direct linkage,

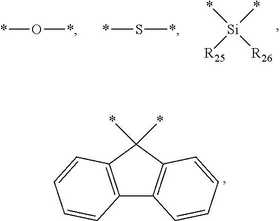

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₂₁ to L₂₃, “ [symbol] ” may be a connected part with C1 to C4.

b1 to b3 may each independently be 0 or 1. When b1 is 0, C1 and C2 may not be connected with each other. When b2 is 0, C2 and C3 may not be connected with each other. When b3 is 0, C3 and C4 may not be connected with each other.

R₂₁ to R₂₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring. For example, R₂₁ to R₂₆ may each independently be a substituted or unsubstituted methyl group or a substituted or unsubstituted t-butyl group.

d1 to d4 may each independently be an integer of 0 to 4. In some embodiments, when d1 to d4 are integers of 2 or more, multiple R₂₁ to R₂₄ may all be the same, or at least one may be different from a remainder thereof.

In some embodiments, C1 to C4 may each independently be a substituted or unsubstituted hydrocarbon ring or a substituted or unsubstituted heterocycle, represented by any one selected from among C-1 to C-3.

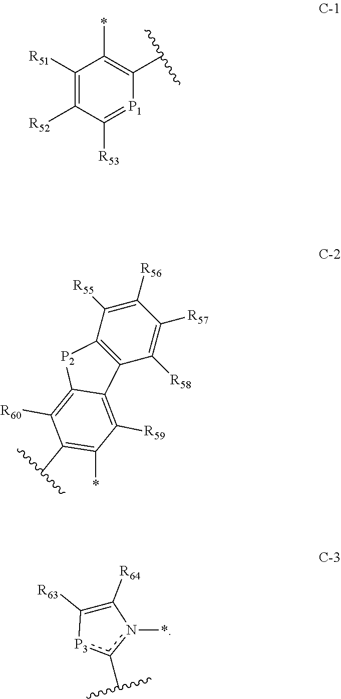

In C-1 to C-3, P₁ may be “ [symbol] ” or CR₅₄, P₂ may be “ [symbol] ” or NR₆₁, and P₃ may be “ [symbol] ” or NR₆₂.

R₅₁ to R₆₄ may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 6 to 30 ring-forming carbon atoms, and/or combined with an adjacent group to form a ring.

In some embodiments, in C-1 to C-3,

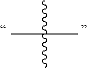

is a part connected with the Pt central metal atom, and “ [symbol] ” is a part connected with neighboring ring groups (C1 to [symbol] C4) or linkers (L₂₁ to L₂₄).

The emission layer EML of an embodiment may include the first compound which is a polycyclic compound, and at least one selected from among the second to fourth compounds. For example, the emission layer EML may include the first compound, the second compound and the third compound. In the emission layer EML, the second compound and the third compound may form exciplexes, and energy transfer from the exciplexes to the first compound may occur to emit light.

In some embodiments, the emission layer EML may include the first compound, the second compound, the third compound and the fourth compound. In the emission layer EML, the second compound and the third compound may form exciplexes, and energy transfer from the exciplexes to the fourth compound and the first compound may occur to emit light. In an embodiment, the fourth compound may be a sensitizer. In the light emitting element ED of an embodiment, the fourth compound included in the emission layer EML may play the role of a sensitizer and transferring energy from the host to the first compound which is a light emitting dopant.

For example, the fourth compound which plays the role of an auxiliary dopant may accelerate the energy transfer to the first compound which is a light emitting dopant to increase the light emitting ratio of the first compound. Accordingly, the emission efficiency of the emission layer EML of an embodiment may be improved. In some embodiments, when the energy transfer to the first compound increases, excitons formed in the emission layer EML may not be accumulated in the emission layer EML but may emit light rapidly, thereby reducing the element deterioration. Accordingly, the lifetime of the light emitting element ED of an embodiment may increase.

The light emitting element ED of an embodiment includes all of the first compound, the second compound, the third compound, and the fourth compound, and the emission layer EML may include a combination of two host materials and two dopant materials. In the light emitting element ED of an embodiment, the emission layer EML may include two different hosts, a first compound emitting delayed fluorescence, and a fourth compound including an organometallic complex, concurrently (e.g., simultaneously), and excellent or suitable emission efficiency properties may be shown.

In an embodiment, the second compound represented by Formula 2 may be any compound represented in Compound Group 2. The emission layer EML may include at least one of the compounds represented in Compound Group 2 as a hole transport host material.

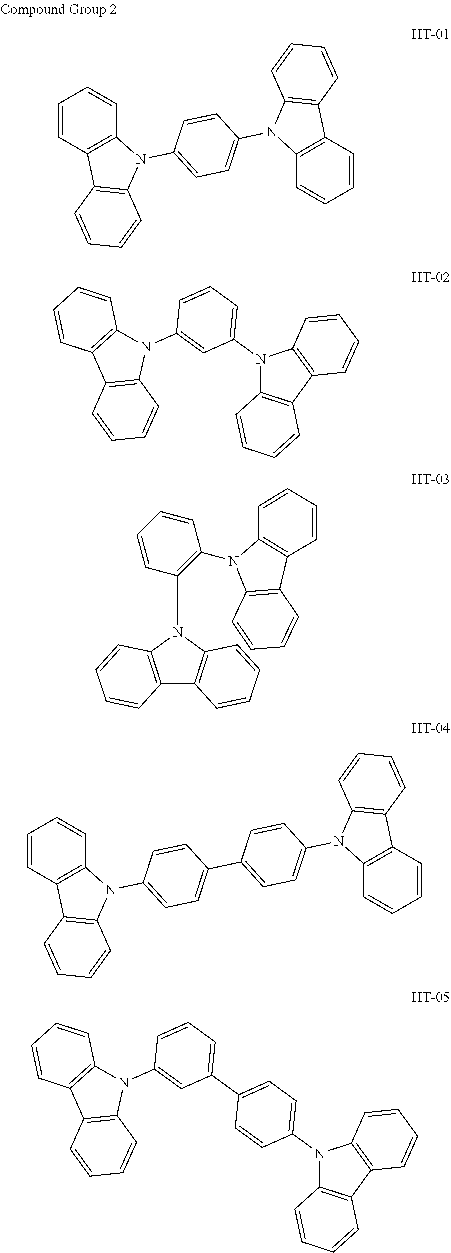

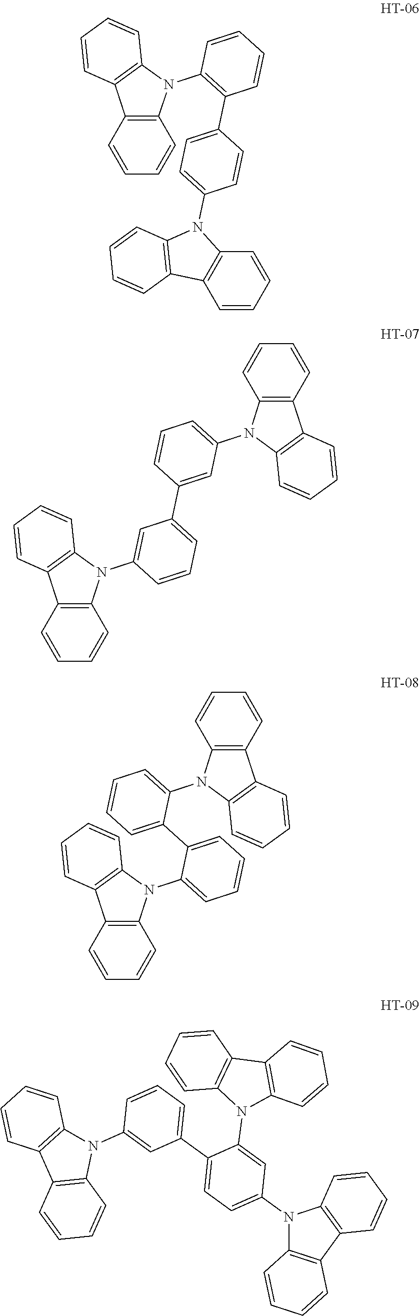

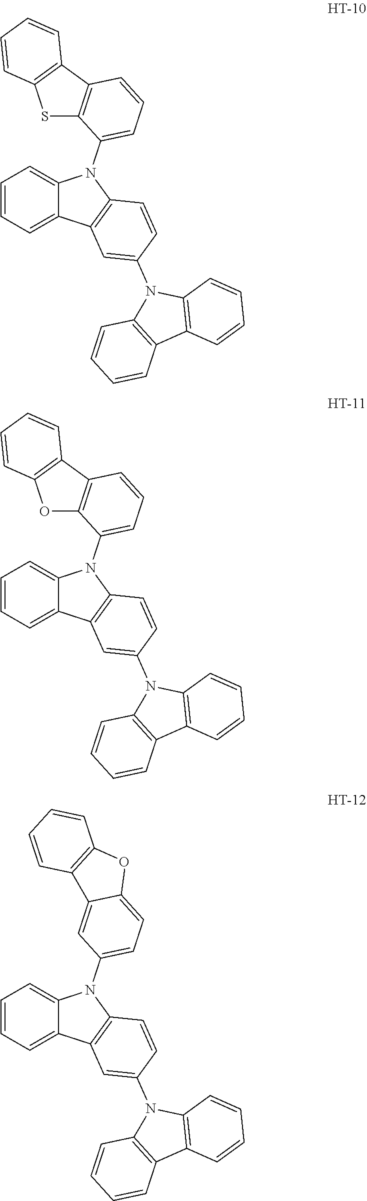 [SMILES: c1ccc2c(c1)sc1c(-n3c4ccccc4c4cc(-n5c6ccccc6c6ccccc65)ccc43)cccc12 ; c1ccc2c(c1)oc1c(-n3c4ccccc4c4cc(-n5c6ccccc6c6ccccc65)ccc43)cccc12 ; c1ccc2c(c1)oc1ccc(-n3c4ccccc4c4cc(-n5c6ccccc6c6ccccc65)ccc43)cc12]

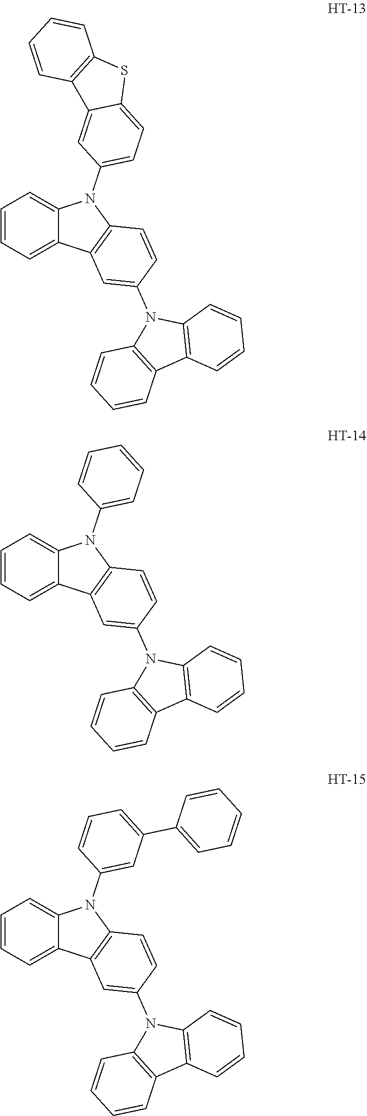

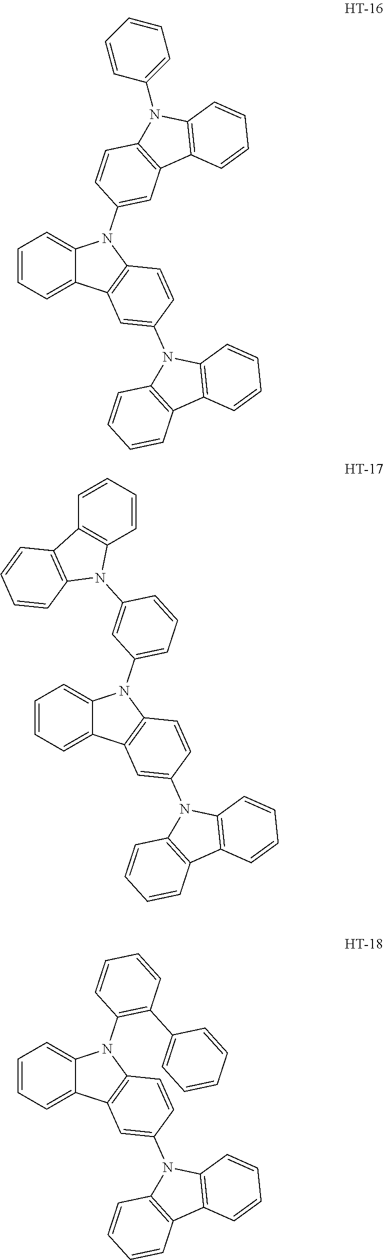

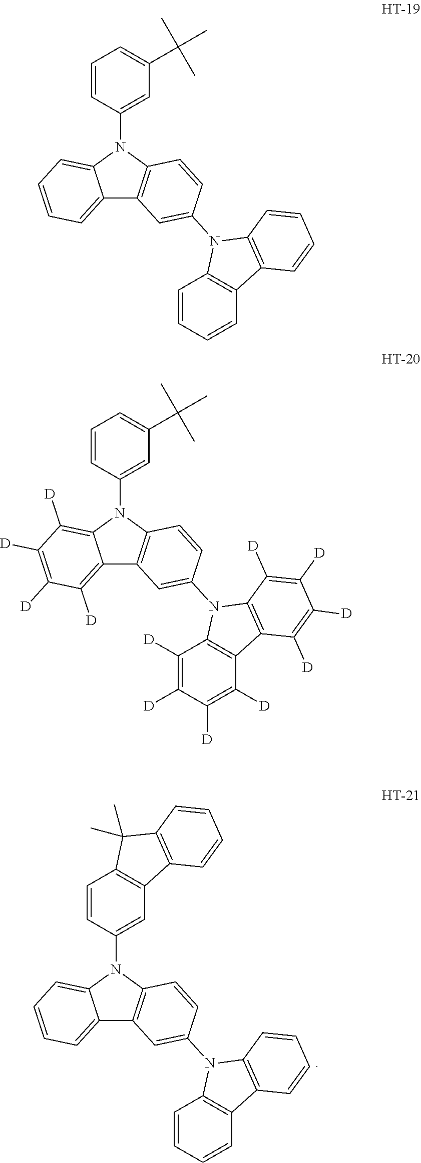 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; CC1(C)c2ccccc2-c2cc(-n3c4ccccc4c4cc(-n5c6ccccc6c6ccccc65)ccc43)ccc21]

In the compounds represented in Compound Group 2, D is a deuterium atom.

In an embodiment, the third compound represented by Formula 3 may be any compound represented in Compound Group 3. The emission layer EML may include at least one of the compounds represented in Compound Group 3 as an electron transport host material.

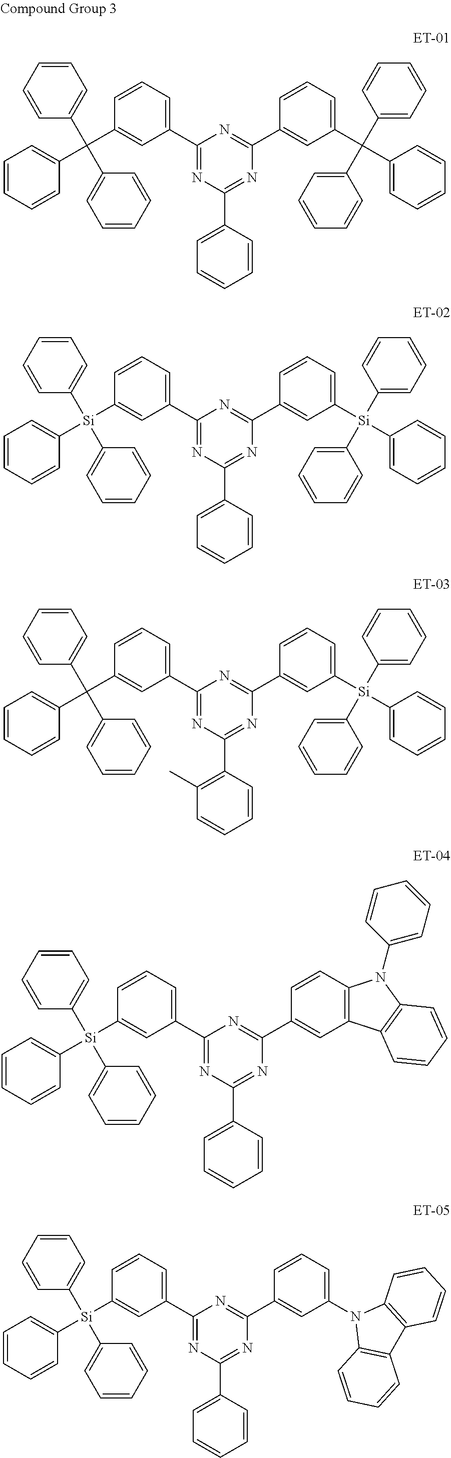

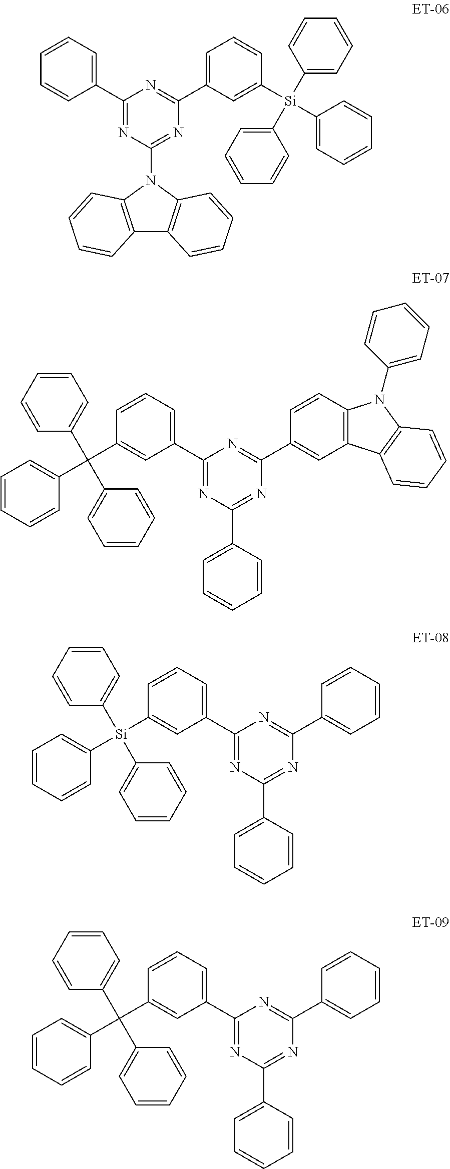 [SMILES: c1ccc(-c2nc(-c3cccc([Si](c4ccccc4)(c4ccccc4)c4ccccc4)c3)nc(-n3c4ccccc4c4ccccc43)n2)cc1 ; c1ccc(-c2nc(-c3cccc(C(c4ccccc4)(c4ccccc4)c4ccccc4)c3)nc(-c3ccc4c(c3)c3ccccc3n4-c3ccccc3)n2)cc1 ; c1ccc(-c2nc(-c3ccccc3)nc(-c3cccc([Si](c4ccccc4)(c4ccccc4)c4ccccc4)c3)n2)cc1 ; c1ccc(-c2nc(-c3ccccc3)nc(-c3cccc(C(c4ccccc4)(c4ccccc4)c4ccccc4)c3)n2)cc1]

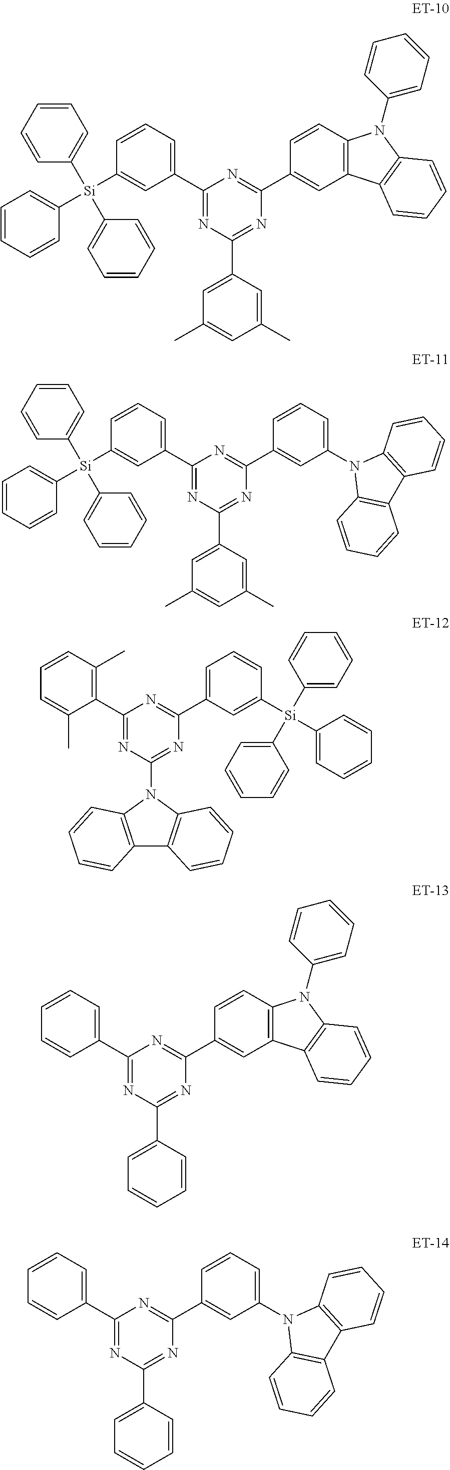

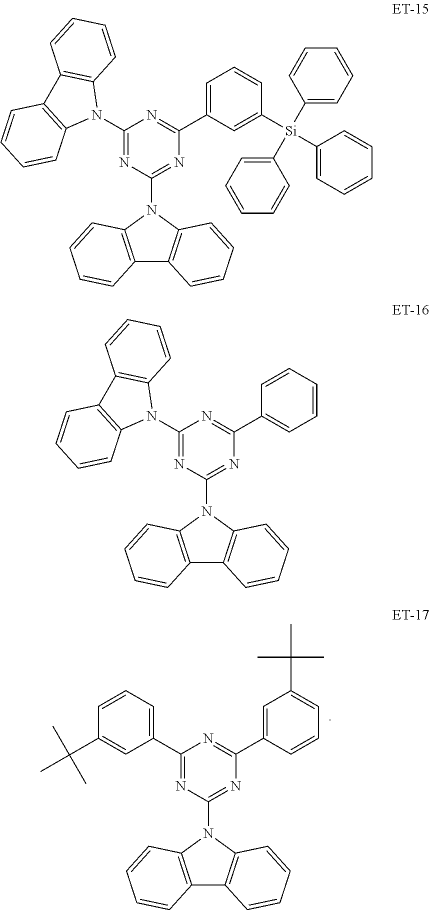

In an embodiment, the fourth compound represented by Formula 4 may include any compound represented in Compound Group 4. The emission layer EML may include at least one of the compounds represented in Compound Group 4 as a sensitizer material.

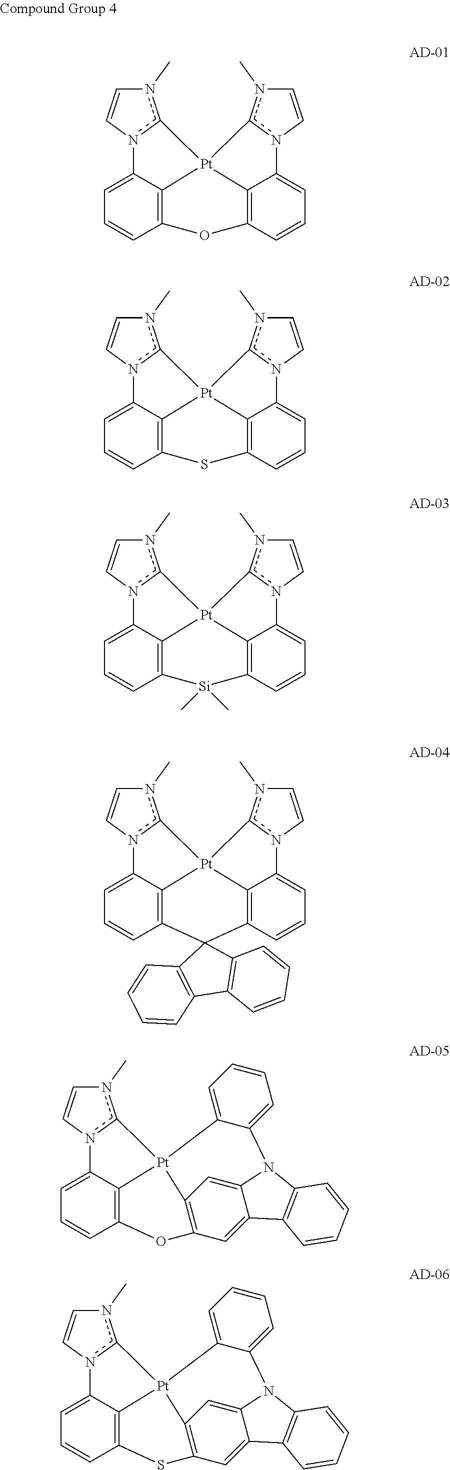

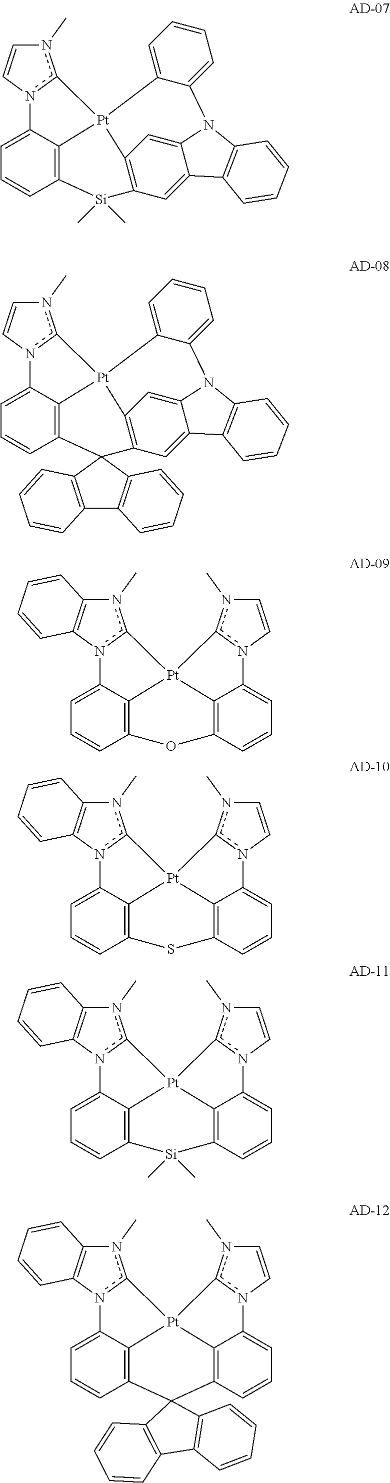

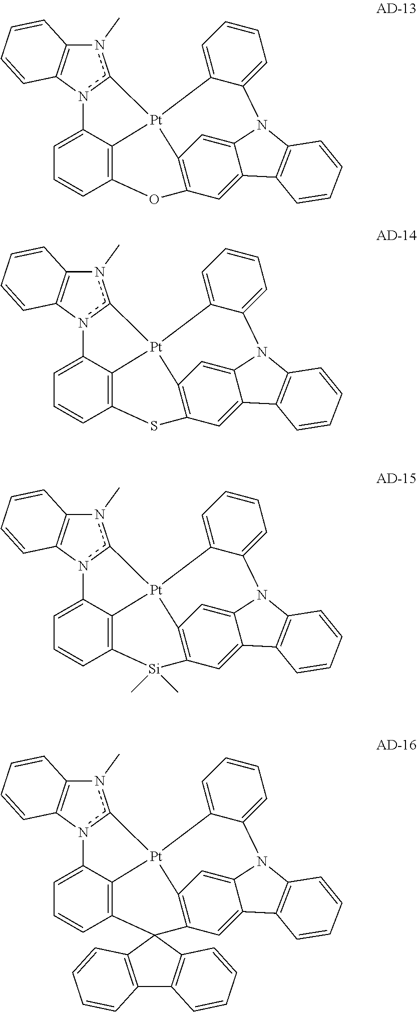

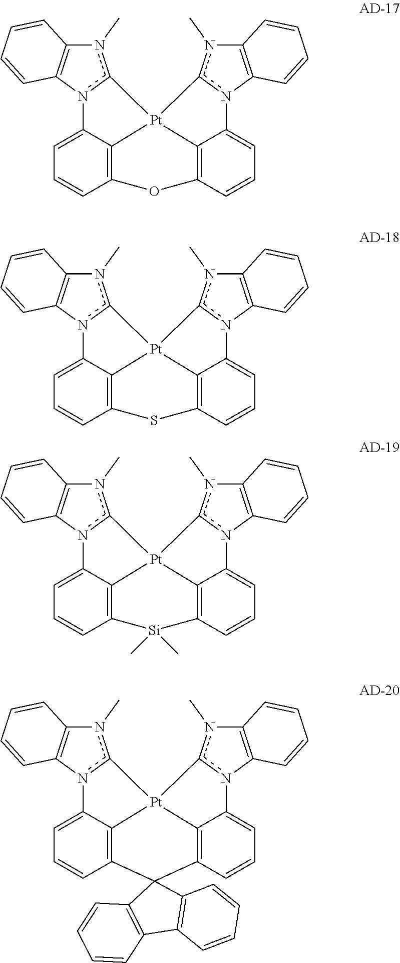

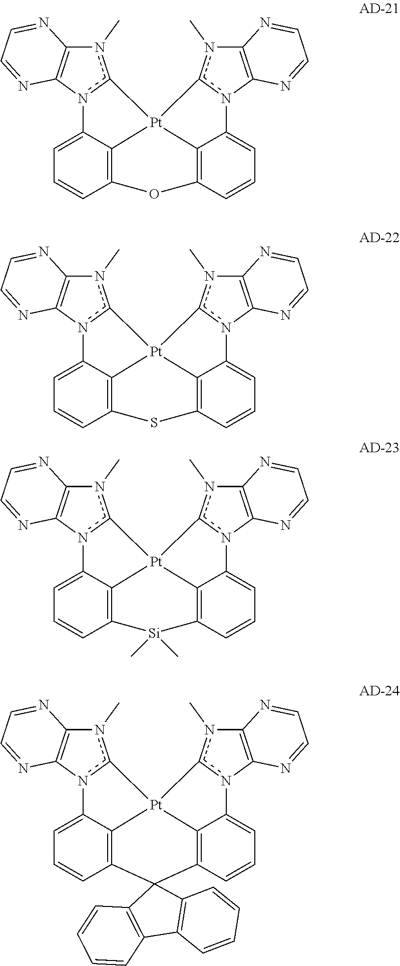

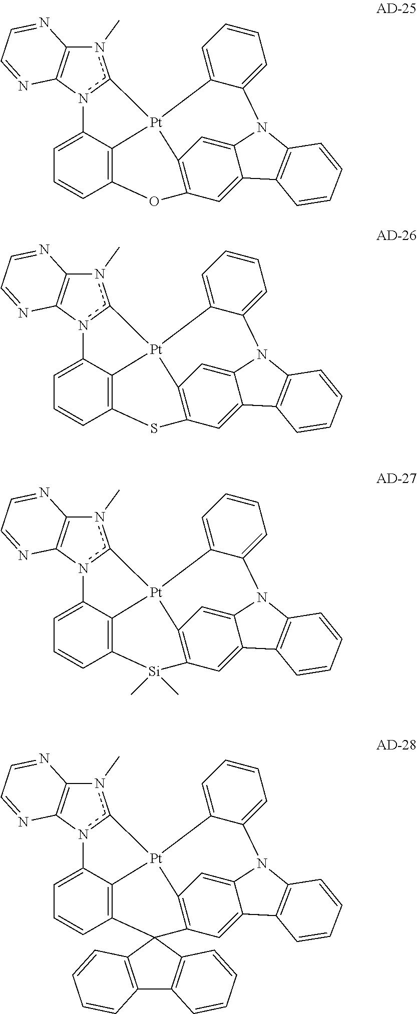

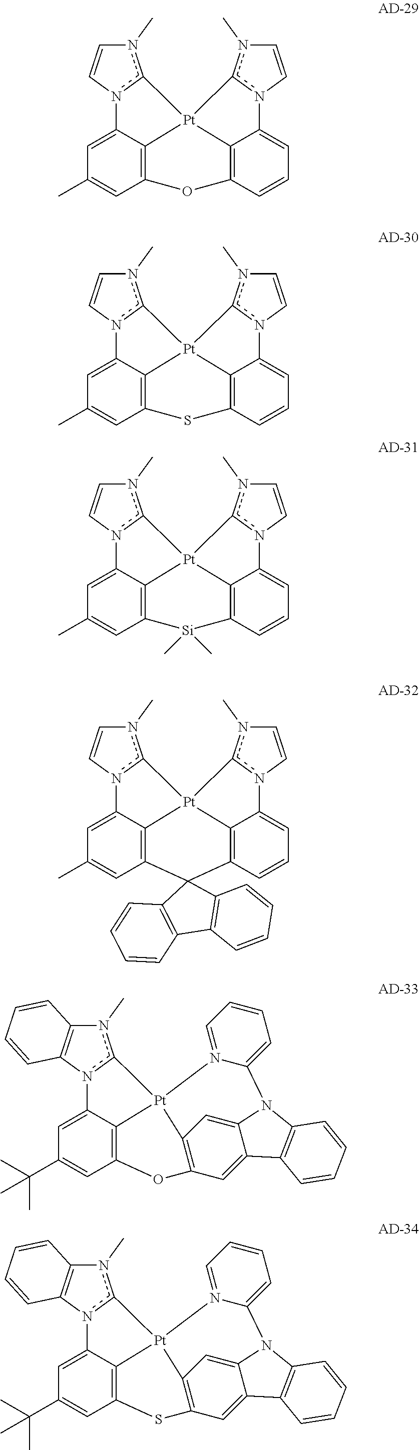

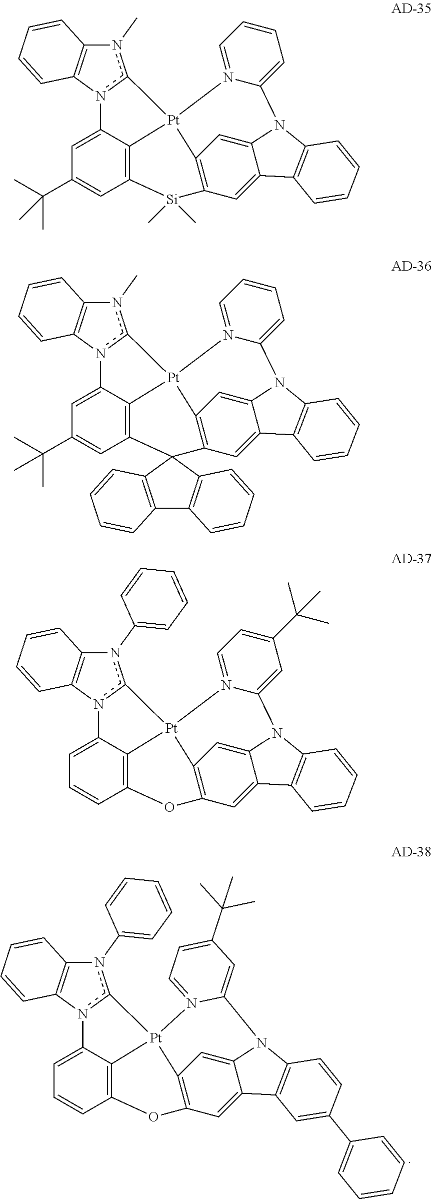

In some embodiments, though not shown in the drawings, the light emitting element ED of an embodiment may include multiple emission layers. The multiple emission layers may be provided by stacking over one another in a set or predetermined order, for example, the light emitting element ED including the multiple emission layers may be to emit white light. The light emitting element including the multiple emission layers may be a light emitting element with a tandem structure. When the light emitting element ED includes multiple emission layers, at least one emission layer EML may include all of the first compound, the second compound, the third compound and the fourth compound as described above.

In the light emitting element ED of an embodiment, the emission layer EML may further include one or more anthracene derivatives, pyrene derivatives, fluoranthene derivatives, chrysene derivatives, dihydrobenzanthracene derivatives, and/or triphenylene derivatives. For example, the emission layer EML may include one or more anthracene derivatives and/or pyrene derivatives.

In the light emitting elements ED of embodiments, shown in FIG. 3 to FIG. 6, the emission layer EML may further include suitable hosts and dopants in addition to the above-described host and dopant, and the emission layer EML may include a compound represented by Formula E-1. The compound represented by Formula E-1 may be utilized as a fluorescence host material.

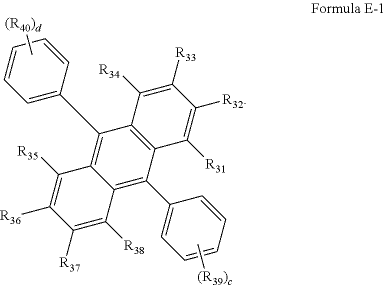

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In some embodiments, R₃₁ to R₄₀ may be combined with an adjacent group to form a saturated hydrocarbon ring, an unsaturated hydrocarbon ring, a saturated heterocycle, or an unsaturated heterocycle.

In Formula E-1, “c” and “d” may each independently be an integer of 0 to 5.

The compound represented by Formula E-1 may be any one of Compound E1 to Compound E19.

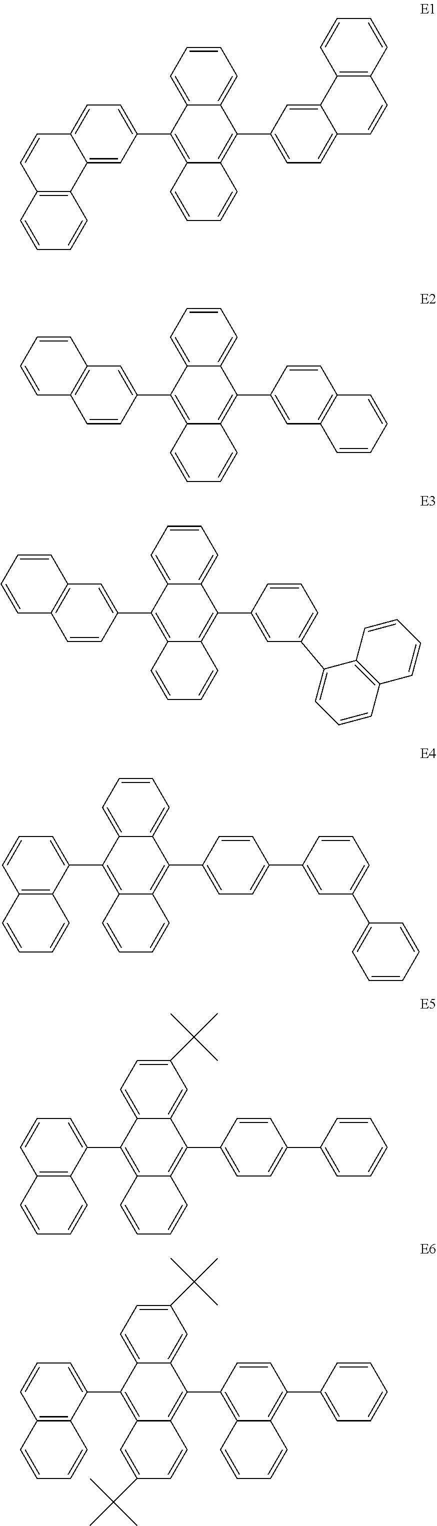

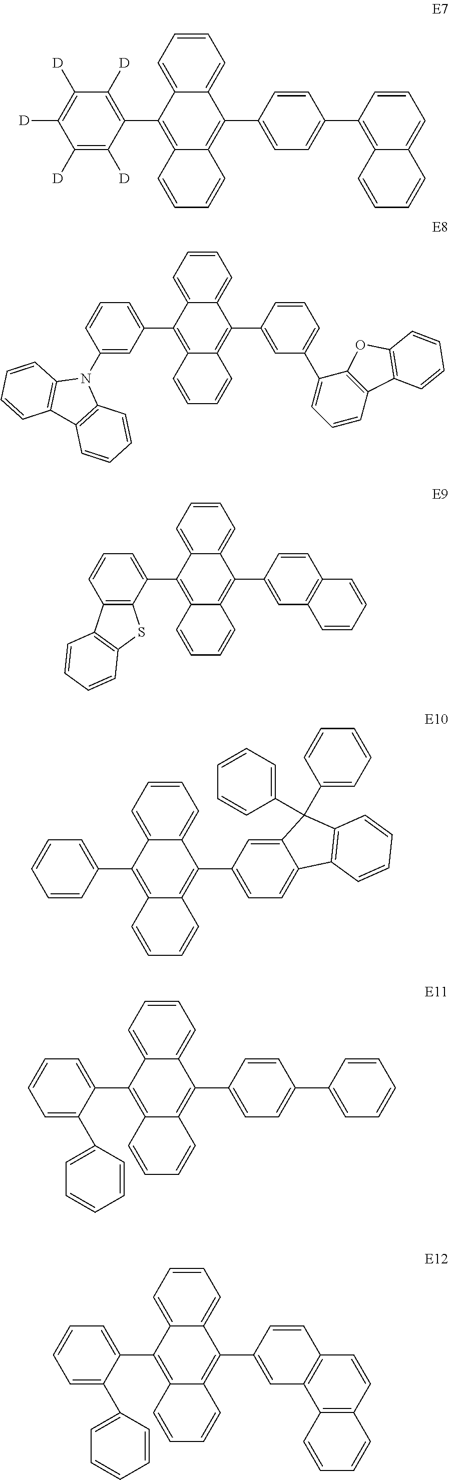

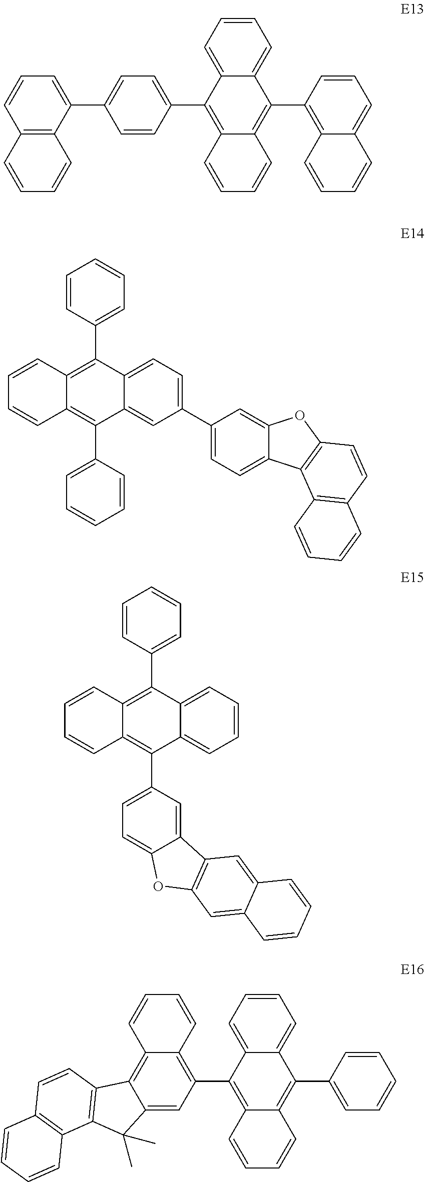

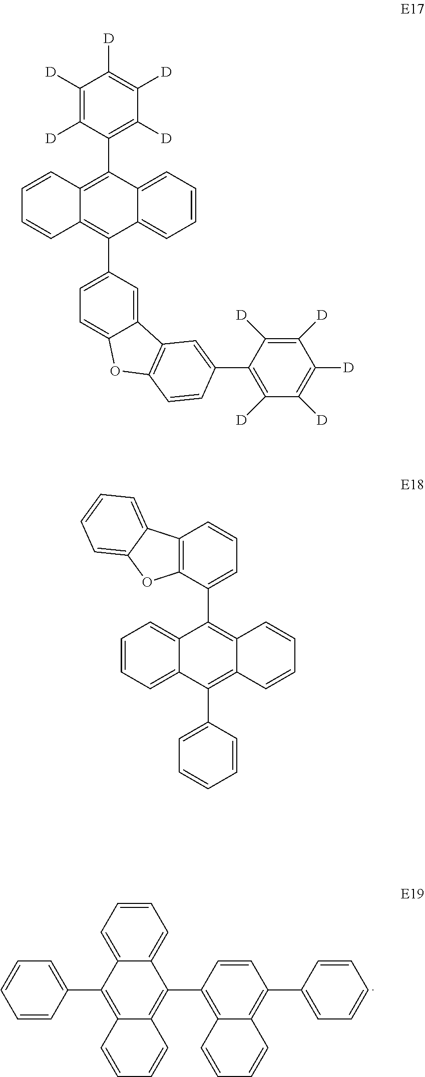

In an embodiment, the emission layer EML may include a compound represented by Formula E-2a or Formula E-2b. The compound represented by Formula E-2a or Formula E-2b may be utilized as a phosphorescence host material.

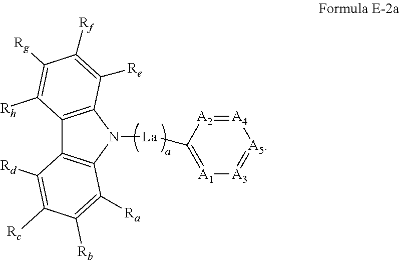

In Formula E-2a, “a” may be an integer of 0 to 10, and La may be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” is an integer of 2 or more, multiple La may each independently be a substituted or unsubstituted arylene group of 6 to 30 ring-forming carbon atoms, or a substituted or unsubstituted heteroarylene group of 2 to 30 ring-forming carbon atoms.

In some embodiments, in Formula E-2a, A₁ to A₅ may each independently be N or CRi. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. Rₐ to Rᵢ may be combined with an adjacent group to form a hydrocarbon ring or a heterocycle containing N, O, S, and/or the like as ring-forming atoms.

In some embodiments, in Formula E-2a, two or three selected from A₁ to A₅ may be N, and any remainder thereof may be CRI.

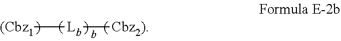

In Formula E-2b, Cbz1 and Cbz2 may each independently be an unsubstituted carbazole group, or a carbazole group substituted with an aryl group of 6 to 30 ring-forming carbon atoms. L_{b} may be a direct linkage, a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and when “b” is an integer of 2 or more, multiple L_{b} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be any one of Compound E-2-1 to Compound E-2-24 in Compound Group E-2. However, Compound E-2-1 to Compound E-2-24 are only examples, and the compound represented by Formula E-2a or Formula E-2b is not limited to Compound E-2-1 to Compound E-2-24.

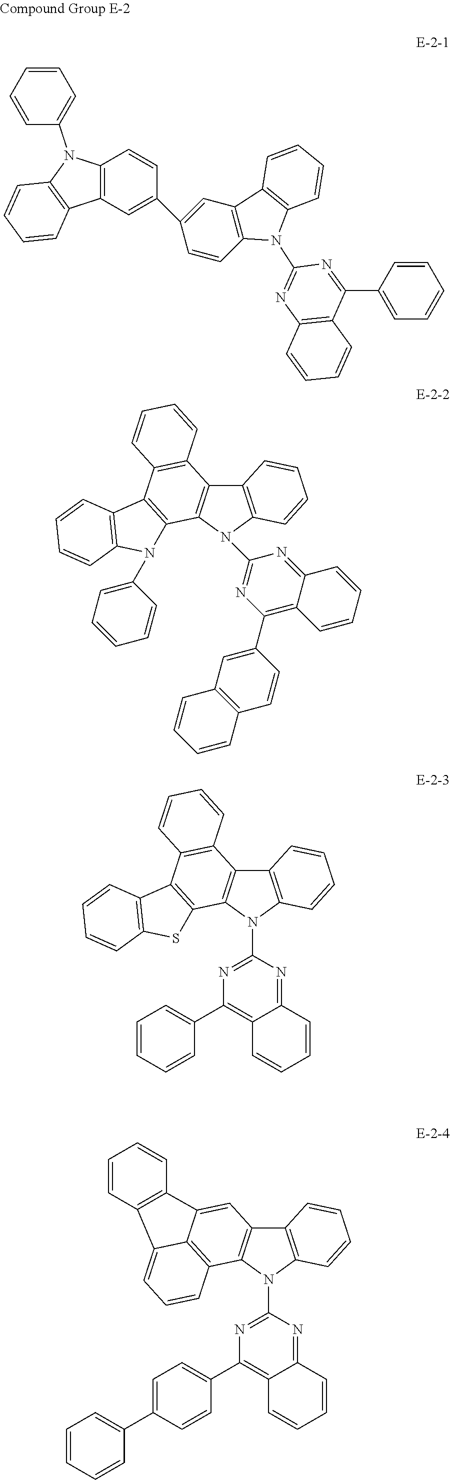

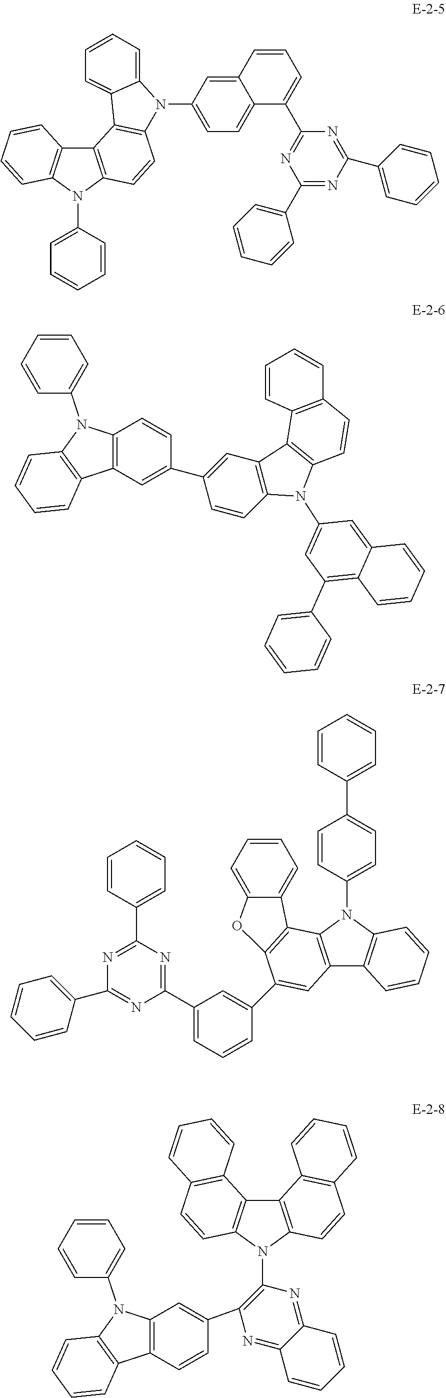

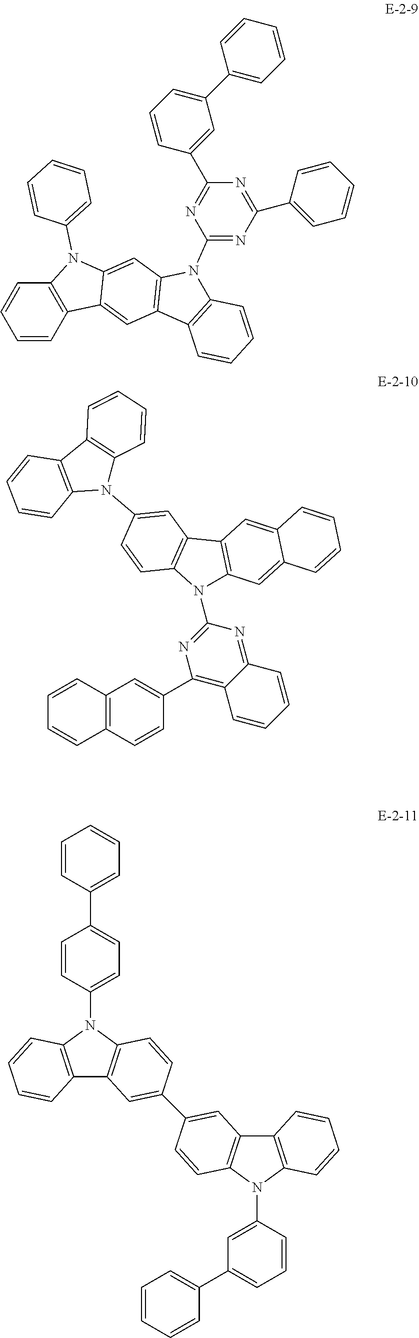 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

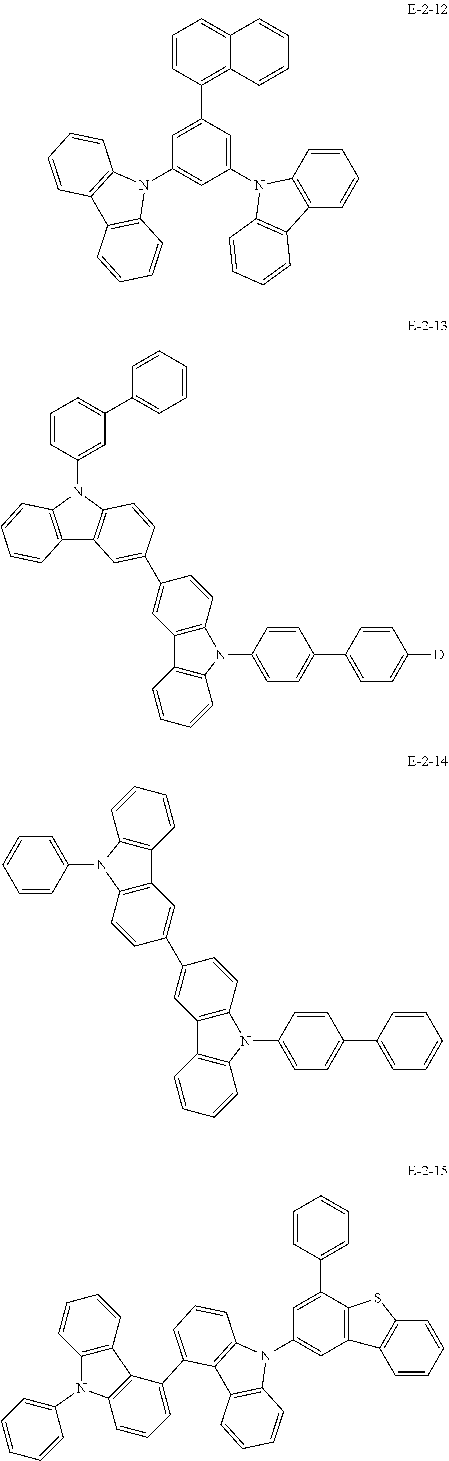 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

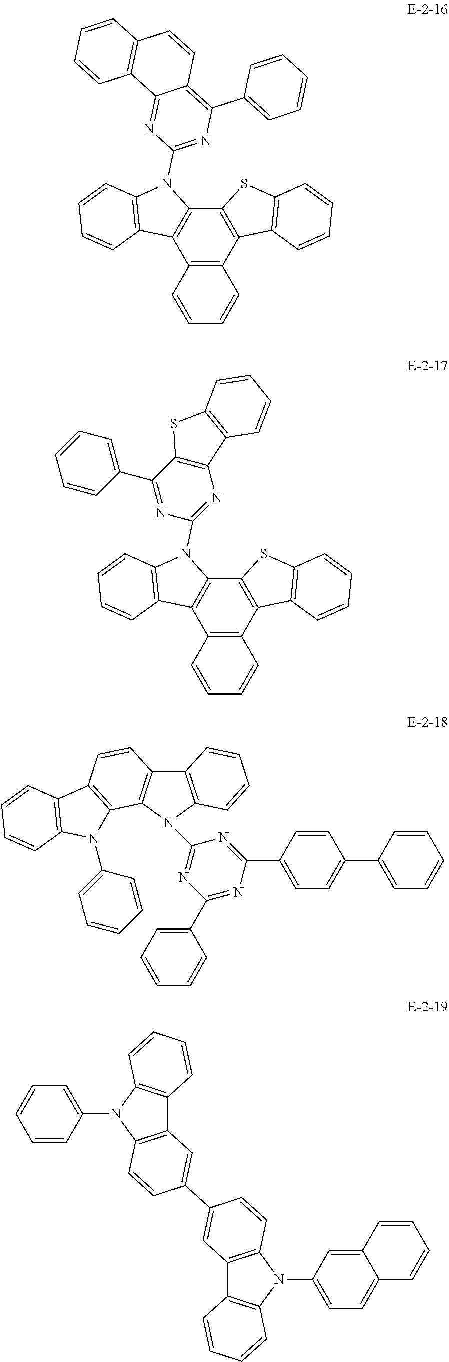

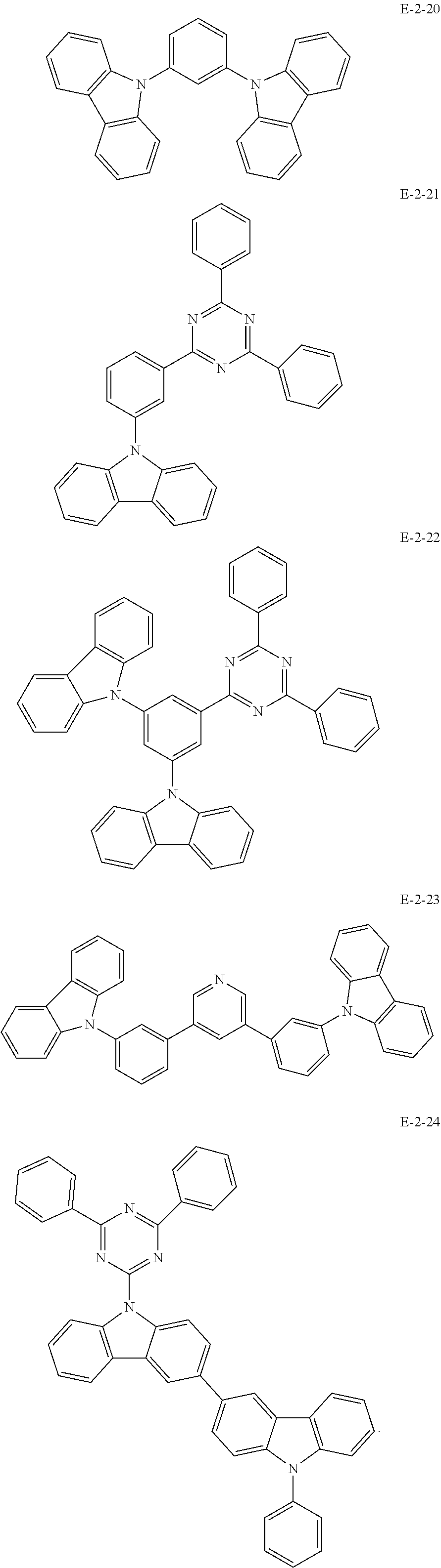

The emission layer EML may further include a suitable material in the art as a host material. For example, the emission layer EML may include as a host material, at least one of bis (4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 3,3′-di(9H-carbazol-9-yl)-1,1′-biphenyl (mCBP), 4,4′-bis(N-carbazolyl)-1,1′-biphenyl (CBP), 1,3-bis(carbazol-9-yl)benzene (mOP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, an embodiment of the present disclosure is not limited thereto. For example, tris(8-hydroxyquinolino)aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), and/or the like may be utilized as the host material.

The emission layer EML may include a compound represented by Formula M-a. The compound represented by Formula M-a may be utilized as a phosphorescence dopant material. In an embodiment, the compound represented by Formula M-a may be utilized as an auxiliary dopant material.

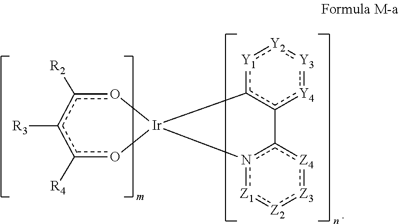

In Formula M-a, Y1 to Y4, and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. In Formula M-a, “m” may be 0 or 1, and “n” may be 2 or 3. In Formula M-a, when “m” is 0, “n” is 3, and when “m” is 1, “n” is 2.

The compound represented by Formula M-a may be any one of Compounds M-a1 to M-a25. However, Compounds M-a1 to M-a25 are examples, and the compound represented by Formula M-a is not limited to the compounds represented by Compounds M-a1 to M-a25.

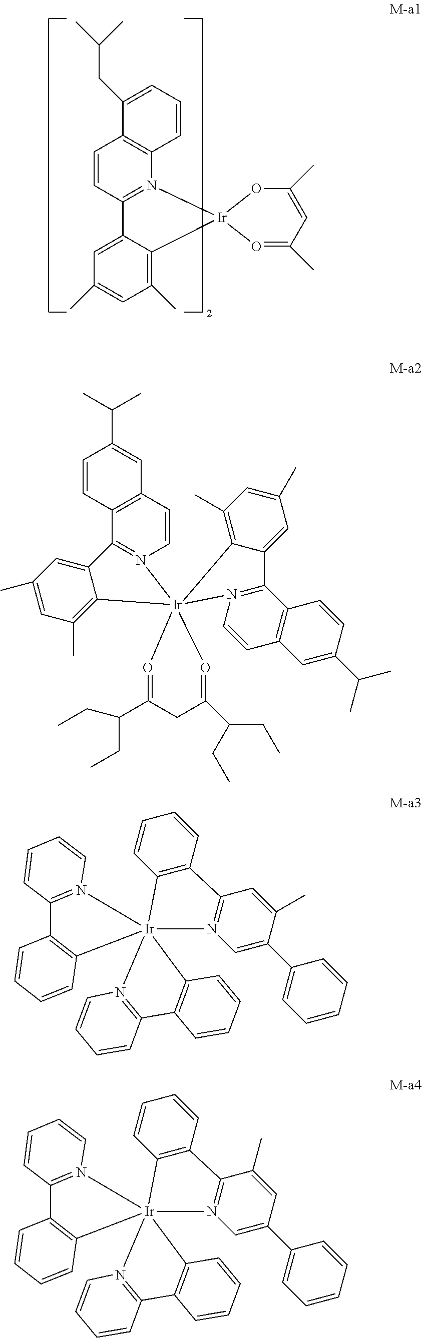

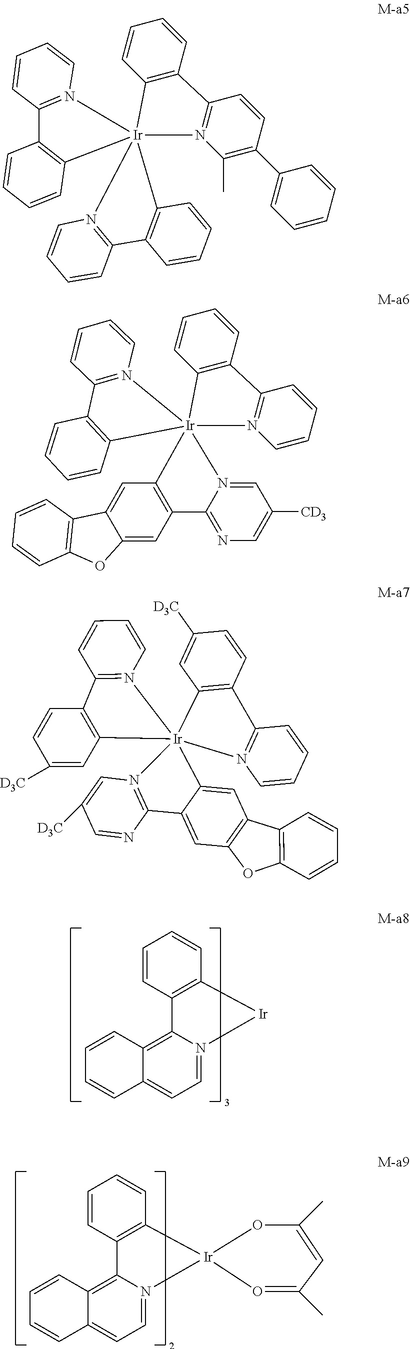

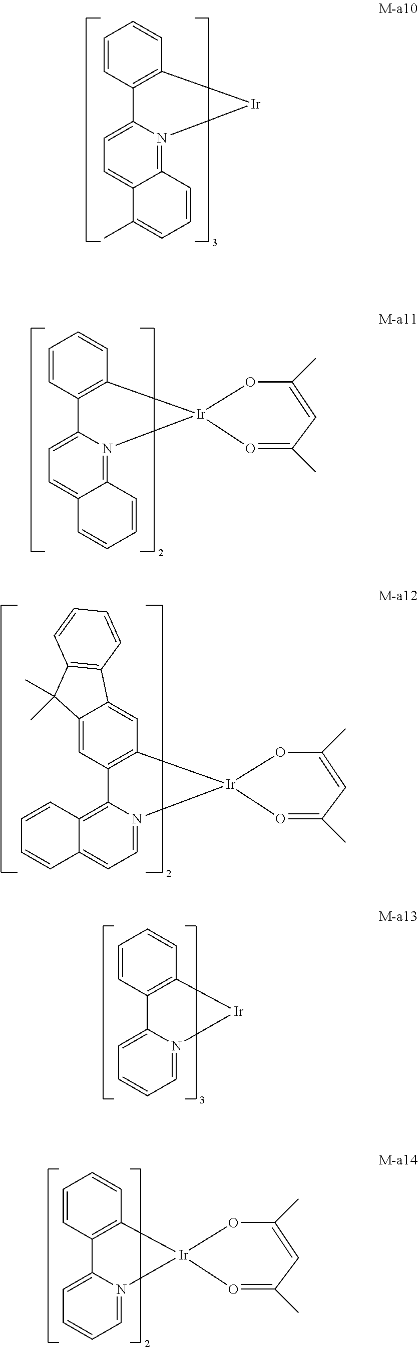

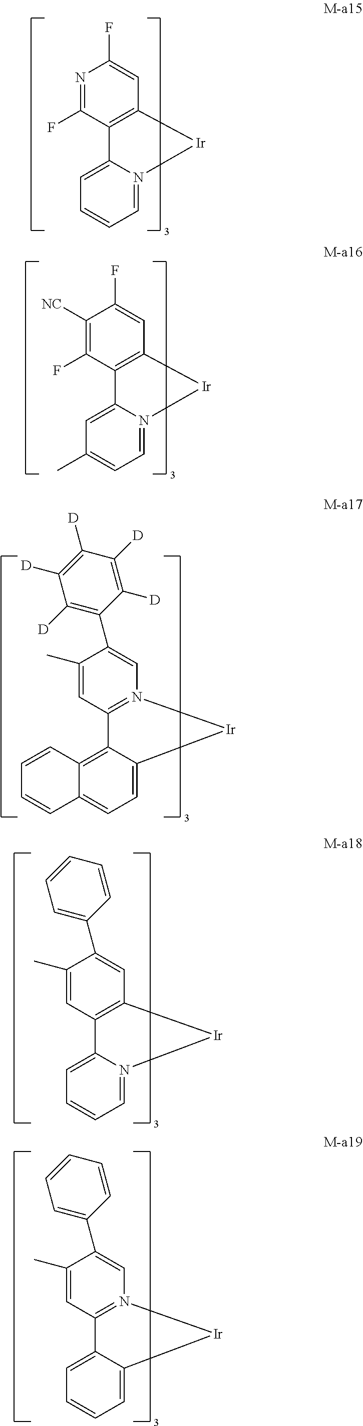

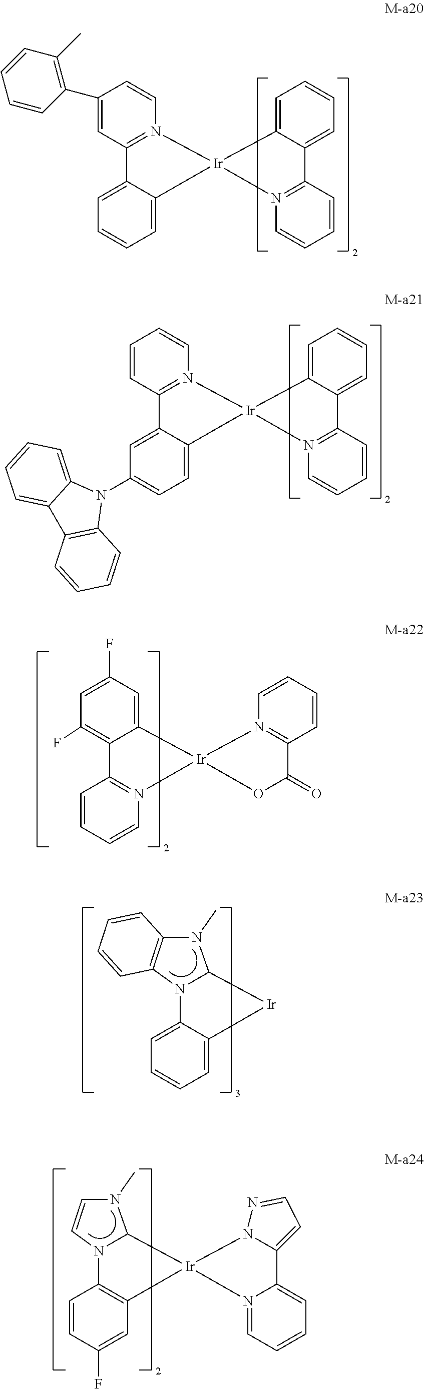

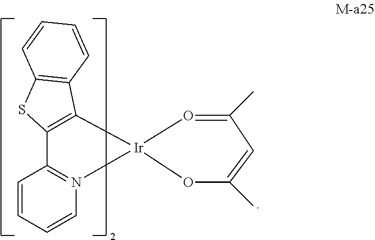

Compound M-a1 and Compound M-a2 may be utilized as red dopant materials, and Compound M-a3 to Compound M-a7 may be utilized as green dopant materials.

The emission layer EML may further include a compound represented by any one selected from among Formula F-a to Formula F-c. The compounds represented by Formula F-a to Formula F-c may be utilized as fluorescence dopant materials.

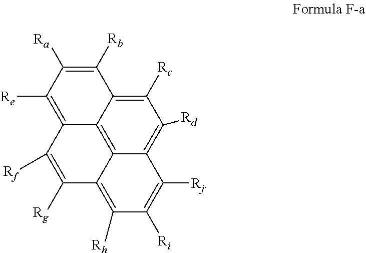

In Formula F-a, two groups selected from Rₐ to Rⱼ may each independently be substituted with

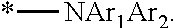

The remainder not substituted with

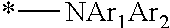

selected from among Rₐ to Rⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In

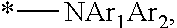

Ar₁ and Ar₂ may each independently be a substituted or unsubstituted aryl group of 6 to 30 ring-forming carbon atoms, or a substituted or unsubstituted heteroaryl group of 2 to 30 ring-forming carbon atoms. For example, Ar₁ and/or Ar₂ may be (e.g., independently be) a heteroaryl group including O or S as a ring-forming atom.

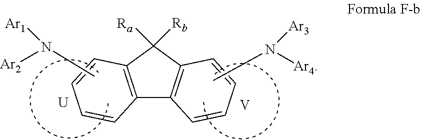

In Formula F-b, Rₐ and Rb may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula F-b, Ar₁ to Ar₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms.

In Formula F-b, the number of rings represented by U and V may each independently be 0 or 1. For example, in Formula F-b, when the number of U or V is 1, one ring indicated by U or V forms a fused ring at the designated part (e.g., a portion indicated by U or V), and when the number of U or V is 0, a ring indicated by U or V does not exist. For example, when the number of U is 0, and the number of V is 1, or when the number of U is 1, and the number of V is 0, a fused ring having the fluorene core of Formula F-b may be a ring compound with four rings. In some embodiments, when the number of U and the number of V are both 0, the fused ring of Formula F-b may be a ring compound with three rings. In some embodiments, when the number of U and the number of V are both 1, a fused ring having the fluorene core of Formula F-b may be a ring compound with five rings.

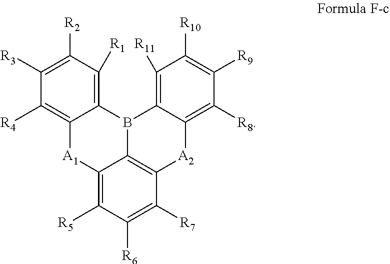

In Formula F-c, A₁ and A₂ may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring.

In Formula F-c, A₁ and A₂ may each independently be combined with the substituents of an adjacent ring to form a fused ring. For example, when A₁ and A₂ may each independently be NRₘ, A₁ may be combined with R₄ or R₅ to form a ring. In some embodiments, A₂ may be combined with R₇ or R₈ to form a ring.

In an embodiment, the emission layer EML may include as a suitable dopant material, one or more styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and the derivatives thereof (for example, 2,5,8,11-tetra-t-butylperylene (TBP)), pyrene and the derivatives thereof (for example, 1,1-dipyrene, 1,4-dipyrenylbenzene, and/or 1,4-bis(N,N-diphenylamino)pyrene), etc.

In an embodiment, when multiple emission layers EML are included, at least one emission layer EML may include a suitable phosphorescence dopant material. For example, the phosphorescence dopant may utilize a metal complex including iridium (Ir), platinum (Pt), osmium (Os), gold (Au), titanium (Ti), zirconium (Zr), hafnium (Hf), europium (Eu), terbium (Tb) or thulium (Tm). For example, bis(4,6-difluorophenylpyridinato-C², N)(picolinate) iridium(III) (Firpic), bis(2,4-difluorophenylpyridinato)-tetrakis(1-pyrazolyl)borate iridium(III) (Fir6), and/or platinum octaethyl porphyrin (PtOEP) may be utilized as the phosphorescence dopant. However, an embodiment of the present disclosure is not limited thereto.

In some embodiments, at least one emission layer EML may include a quantum dot material. The core of the quantum dot may be (may be at least one) selected from a II-VI group compound, a III—VI group compound, a 1-III-VI group compound, a III—V group compound, a III—II—V group compound, a IV—VI group compound, a IV group element, a IV group compound, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The III-VI group compound may include a binary compound such as In₂S₃, and/or In₂Se₃, a ternary compound such as InGaS₃, and/or InGaSe₃, or any combination thereof.

The I-III-VI group compound may be selected from a ternary compound selected from the group consisting of AgInS, AgInS₂, CulnS, CuInS₂, AgGaS₂, CuGaS₂, CuGaO₂, AgGaO₂, AgAIO₂ and mixtures thereof, and a quaternary compound such as AgInGaS₂, and/or CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and mixtures thereof. In some embodiments, the III-V group compound may further include a II group metal. For example, InZnP, etc. may be selected as a III—II—V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

In this case, the binary compound, the ternary compound and/or the quaternary compound may be present at a substantially uniform concentration in a particle or may be present at a partially different concentration distribution state in the same particle. In some embodiments, the quantum dot may have a core/shell structure in which one quantum dot is around (e.g., wraps or encapsulates) another quantum dot. The interface between the core and the shell may have a concentration gradient in which the concentration of an element present in the shell is decreased toward the center of the core.

In some embodiments, the quantum dot may have the above-described core-shell structure including a core including a nanocrystal and a shell around (e.g., wrapping) the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer.

Examples of the shell of the quantum dot may include a metal or non-metal oxide, a semiconductor compound, or any combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄ and/or NiO, or a ternary compound such as MgAl₂O₄, CoFe₂O₄, NiFe₂O₄ and/or CoMn₂O₄, but an embodiment of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but an embodiment of the present disclosure is not limited thereto.

The quantum dot may have a full width of half maximum (FWHM) of emission wavelength spectrum of about 45 nm or less, about 40 nm or less, or, about 30 nm or less. Within these ranges, color purity or color reproducibility may be improved. In some embodiments, light emitted via such quantum dot is emitted in all directions, and light view angle properties may be improved (e.g., a wider viewing angle may be obtained).

In some embodiments, the shape of the quantum dot may be any generally utilized shapes in the art, without specific limitation. For example, the quantum dot may have the shape of spherical, pyramidal, multi-arm, or cubic nanoparticle, nanotube, nanowire, nanofiber, nanoplate particle, etc.

The quantum dot may control the color of light emitted according to the particle size, and accordingly, the quantum dot may have one or more suitable emission colors such as blue, red and/or green.

In the light emitting elements ED of embodiments, as shown in FIG. 3 to FIG. 6, an electron transport region ETR is provided on the emission layer EML. The electron transport region ETR may include at least one of a hole blocking layer HBL, an electron transport layer ETL or an electron injection layer EIL. However, an embodiment of the present disclosure is not limited thereto.

The electron transport region ETR may have a single layer formed utilizing a single material, a single layer formed utilizing multiple different materials, or a multilayer structure having multiple layers formed utilizing multiple different materials.

For example, the electron transport region ETR may have a single layer structure of an electron injection layer EIL or an electron transport layer ETL, or a single layer structure formed utilizing an electron injection material and an electron transport material. Further, the electron transport region ETR may have a single layer structure formed utilizing multiple different materials, or a structure in which electron transport layer ETL/electron injection layer EIL, hole blocking layer HBL/electron transport layer ETL/electron injection layer EIL, or electron transport layer ETL/buffer layer/electron injection layer EIL, are stacked from the emission layer EML in the respective stated order, but the present disclosure is not limited thereto. The thickness of the electron transport region ETR may be, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula EE-1.

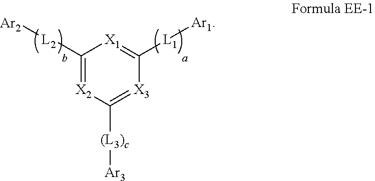

In Formula EE-1, at least one selected from among X₁ to X₃ may be N, and the remainder thereof may be CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula EE-1, “a” to “c” may each independently be an integer of 0 to 10. In Formula EE-1, “L₁” to “L₃” may each independently be a direct linkage, a substituted or unsubstituted arylene group of 6 to 30 ring-forming carbon atoms, or a substituted or unsubstituted heteroarylene group of 2 to 30 ring-forming carbon atoms. In some embodiments, when “a” to “c” are each an integer of 2 or more, “L₁” to “L₃” may each independently be a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, an embodiment of the present disclosure is not limited thereto, and the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), diphenyl(4-(triphenylsilyl)phenyl)phosphine oxide) (TSPO1), and/or one or more mixtures thereof, but the present disclosure is not limited thereto.

The electron transport region ETR may include at least one selected from among Compounds ET1 to ET36.

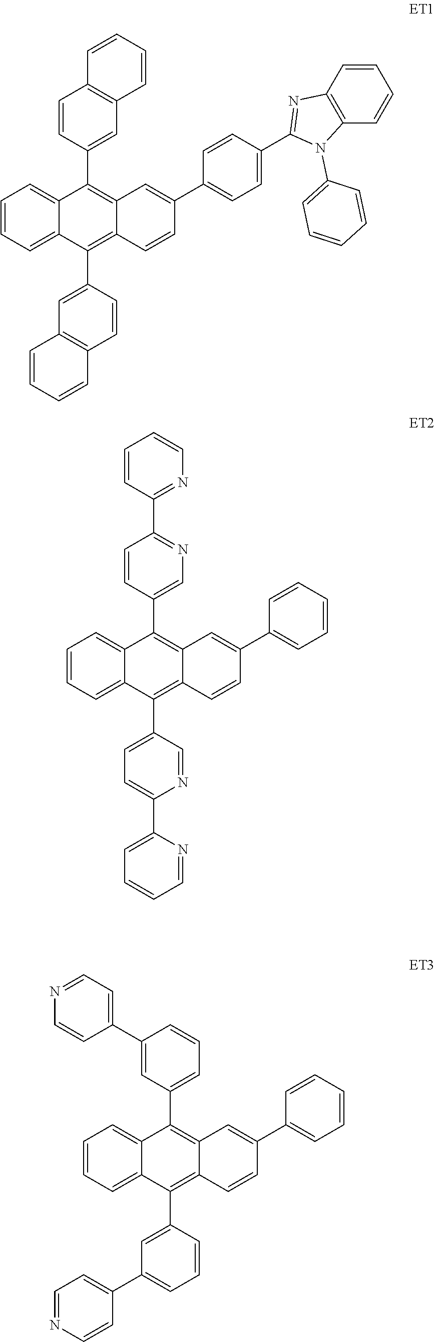 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

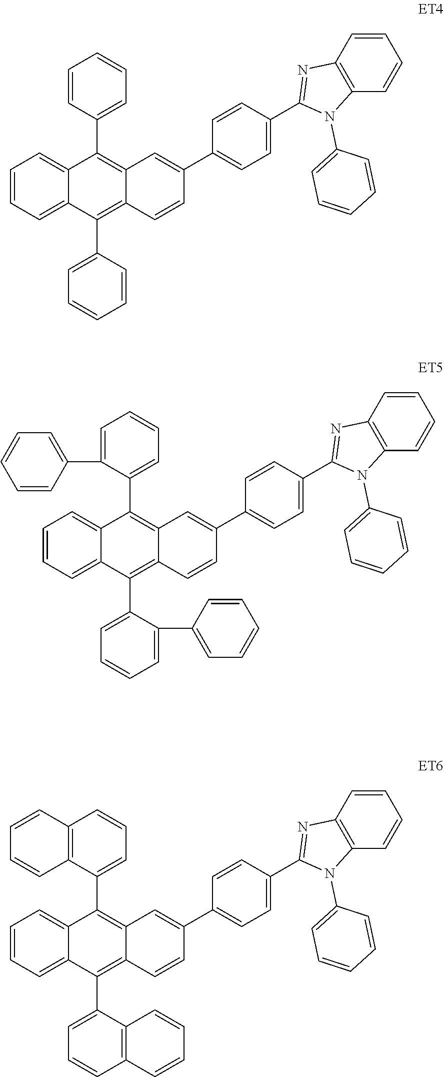 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

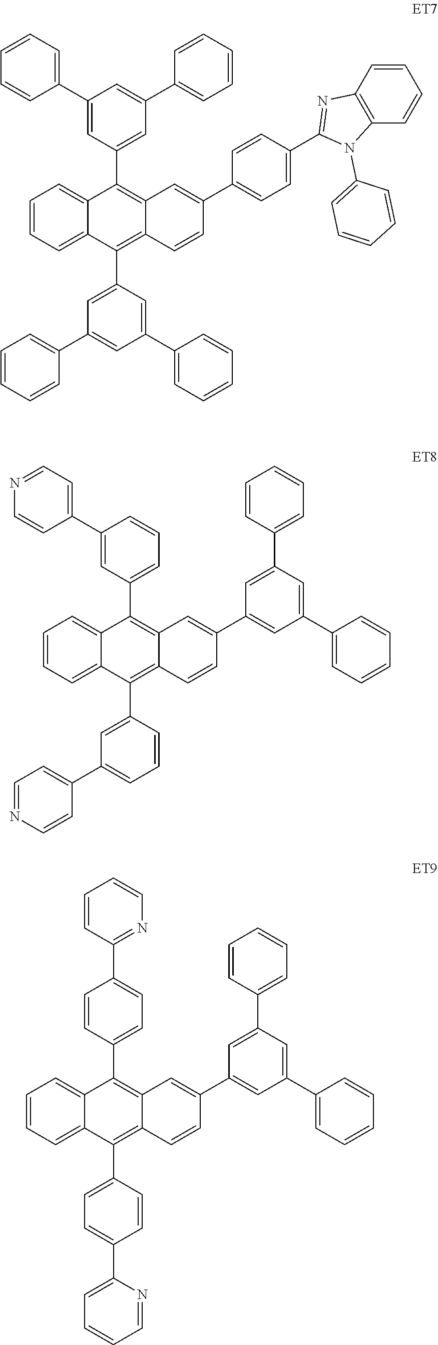 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccncc6)c5)c5ccccc5c(-c5cccc(-c6ccncc6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

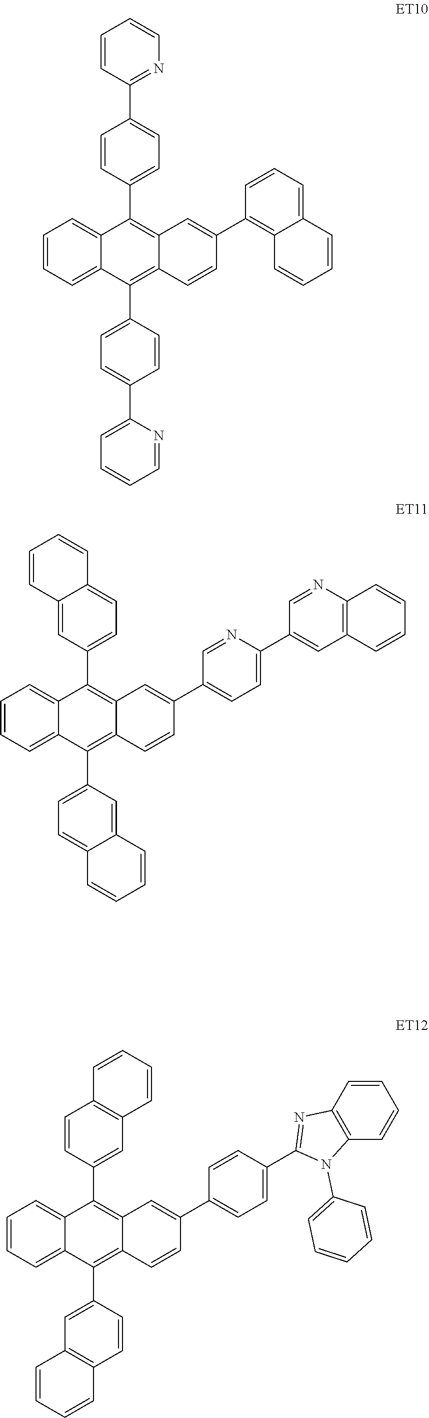 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

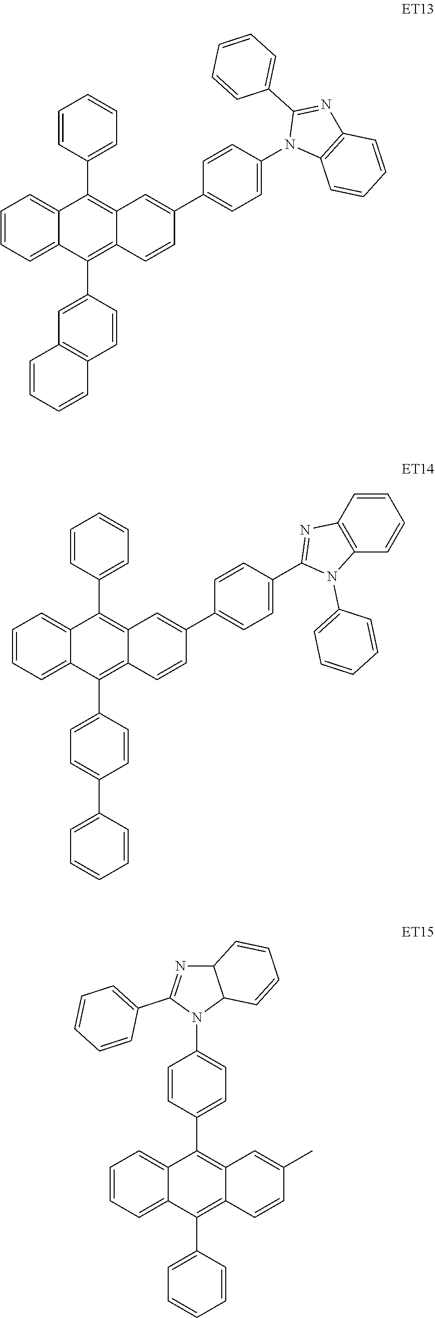 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccccc3)c3ccccc3c(-c3ccc(N4C(c5ccccc5)=NC5C=CC=CC54)cc3)c2c1]

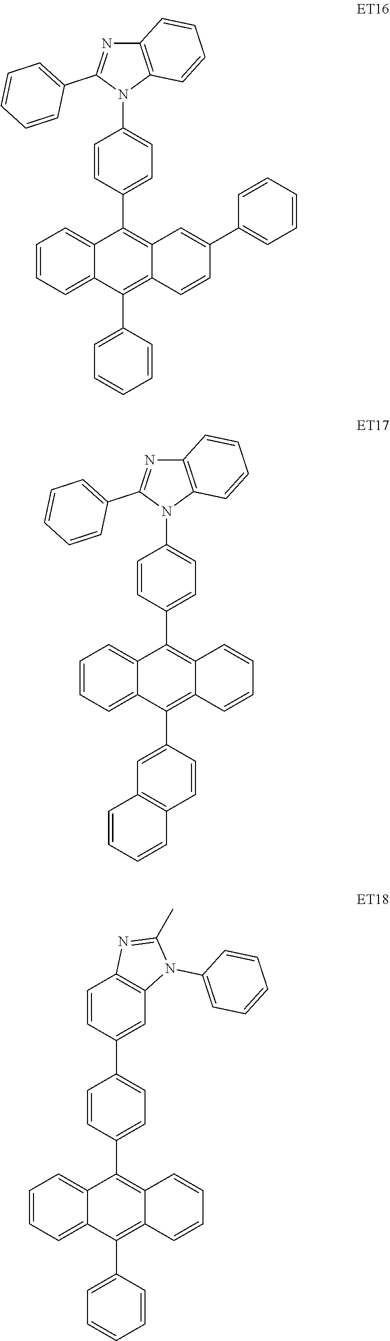 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

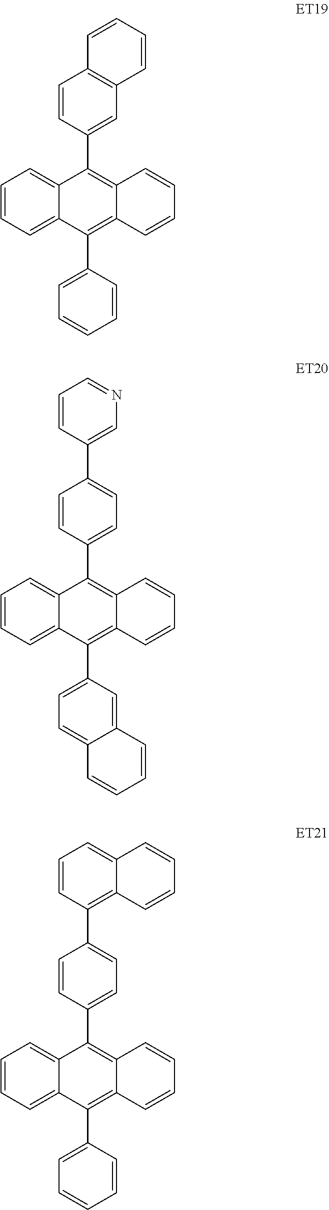

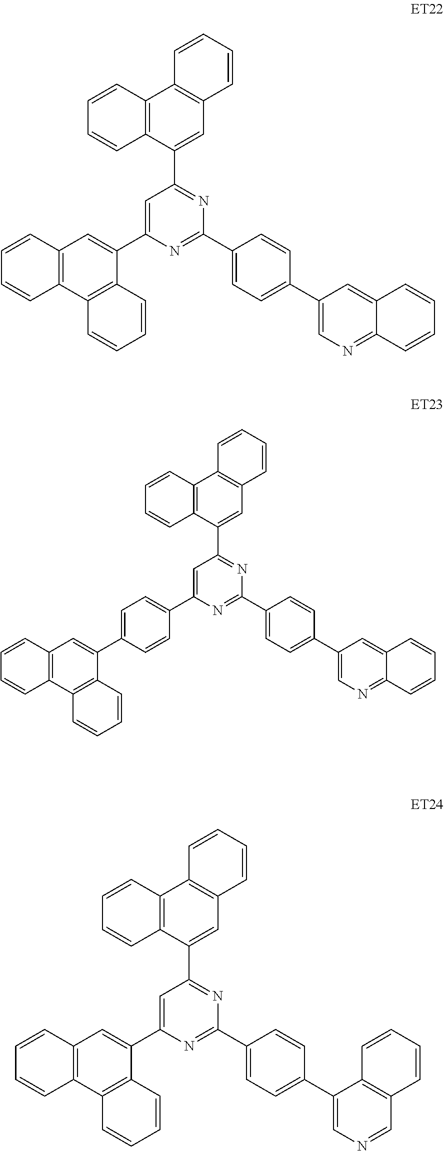 [SMILES: c1ccc2ncc(-c3ccc(-c4nc(-c5cc6ccccc6c6ccccc56)cc(-c5cc6ccccc6c6ccccc56)n4)cc3)cc2c1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)cncc2c1]

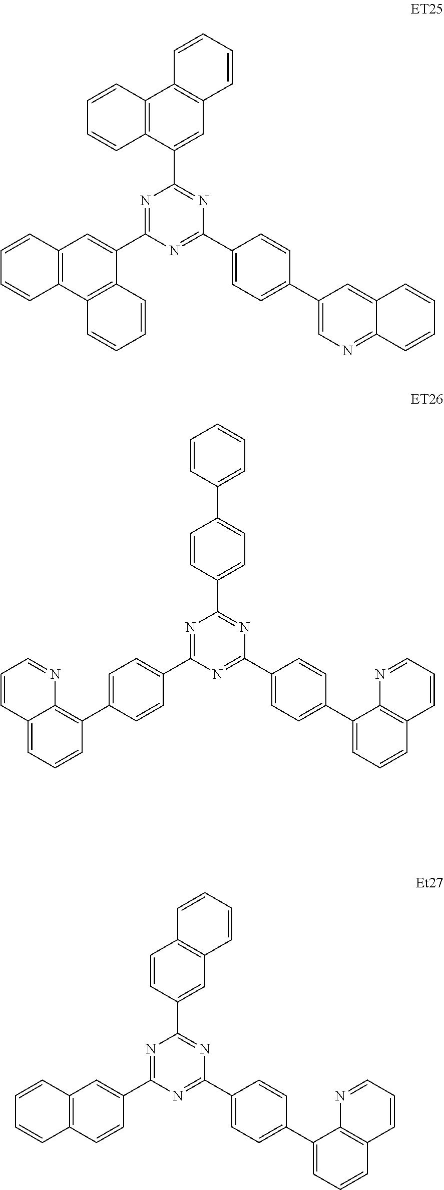 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

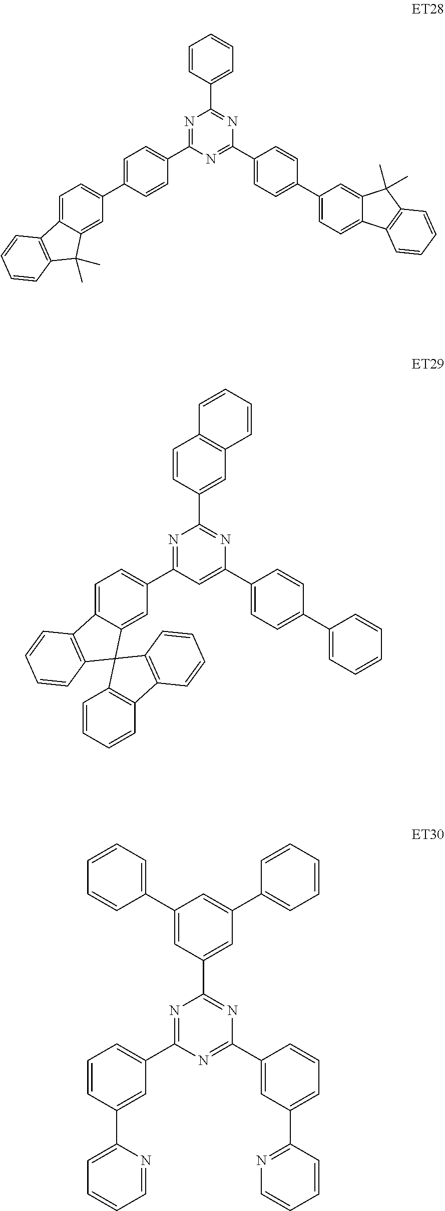 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

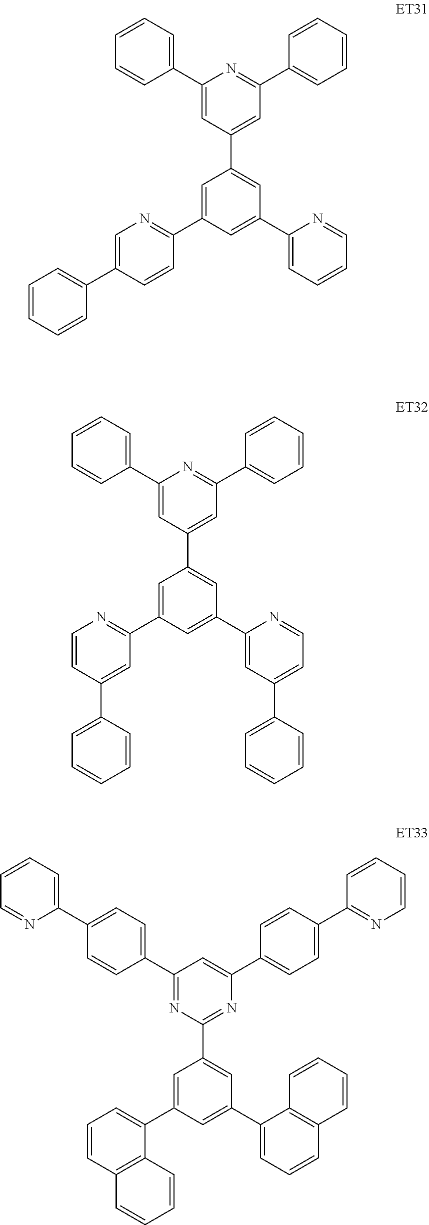 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

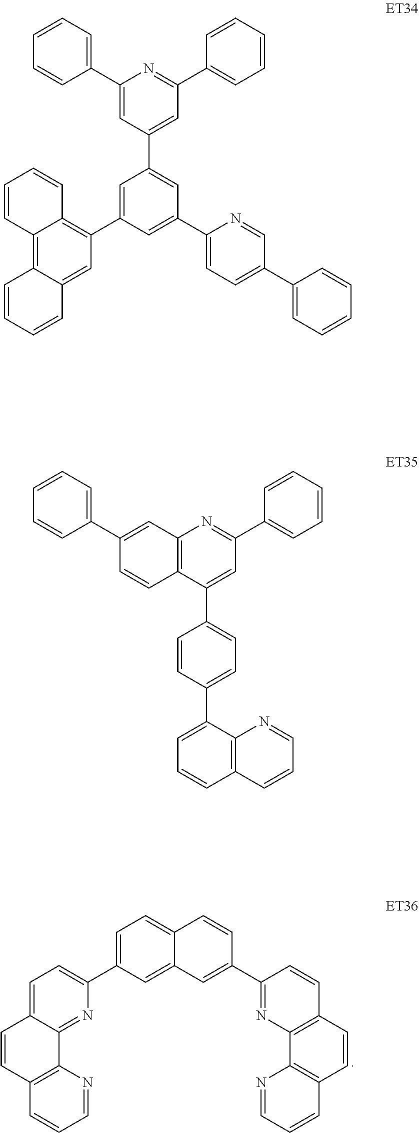 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccccc4)nc3c2)cc1 ; c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, Rbl, Cul and/or KI, a lanthanide metal such as Yb, and/or a co-deposited material of the metal halide and the lanthanide metal. For example, the electron transport region ETR may include KI:Yb, Rbl:Yb, LiF:Yb, etc., as the co-deposited material. In some embodiments, the electron transport region ETR may utilize a metal oxide such as Li₂O and/or BaO, and/or 8-hydroxy-lithium quinolate (Liq). However, an embodiment of the present disclosure is not limited thereto. The electron transport region ETR also may be formed utilizing a mixture material of an electron transport material and an insulating organo metal (e.g., organometallic) salt. The organo metal salt may be a material having an energy band gap of about 4 eV or more. For example, the organo metal salt may include, for example, one or more metal acetates, metal benzoates, metal acetoacetates, metal acetylacetonates, and/or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, an embodiment of the present disclosure is not limited thereto.

The electron transport region ETR may include the above-described compounds of the electron transport region ETR in at least one selected from among an electron injection layer EIL, an electron transport layer ETL, and a hole blocking layer HBL.

When the electron transport region ETR includes the electron transport layer ETL, the thickness of the electron transport layer ETL may be from about 100 Å to about 1,000 Å, for example, from about 150 Å to about 500 Å. When the thickness of the electron transport layer ETL satisfies the above-described ranges, satisfactory electron transport properties may be obtained without substantial increase of a driving voltage. When the electron transport region ETR includes the electron injection layer EIL, the thickness of the electron injection layer EIL may be from about 1 Å to about 100 Å, or from about 3 Å to about 90 Å. When the thickness of the electron injection layer EIL satisfies the above described range, satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but an embodiment of the present disclosure is not limited thereto. For example, when the first electrode EL1 is an anode, the second electrode EL2 may be a cathode, and when the first electrode EL1 is a cathode, the second electrode EL2 may be an anode. The second electrode EL2 may include Ag, Mg, Cu, Al, Pt, Pd, Au, Ni, Nd, Ir, Cr, Li, Ca, LiF, Mo, Ti, W, In, Sn, Zn, compounds of two or more selected therefrom, mixtures of two or more selected therefrom, and/or oxides thereof.

The second electrode EL2 may be a transmissive electrode, a transflective electrode or a reflective electrode. When the second electrode EL2 is the transmissive electrode, the second electrode EL2 may include a transparent metal oxide, for example, ITO, IZO, ZnO, ITZO, etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, one or more compounds thereof, or one or more mixtures thereof (for example, AgMg, AgYb, or MgYb). In some embodiments, the second electrode EL2 may have a multilayered structure including a reflective layer or a transflective layer formed utilizing the above-described materials and a transparent conductive layer formed utilizing ITO, IZO, ZnO, ITZO, etc. For example, the second electrode EL2 may include the aforementioned metal material(s), combination(s) of two or more metal material(s) selected from the aforementioned metal material(s), or oxide(s) of the aforementioned metal materials.

In some embodiments, the second electrode EL2 may be connected with an auxiliary electrode. When the second electrode EL2 is connected with the auxiliary electrode, the resistance of the second electrode EL2 may decrease.

In some embodiments, on the second electrode EL2 in the light emitting element ED of an embodiment, a capping layer CPL may be further disposed. The capping layer CPL may include a multilayer or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include α-NPD, NPB, TPD, m-MTDATA, Alq3, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., and/or may include an epoxy resin, and/or acrylate such as methacrylate. In some embodiments, a capping layer CPL may include at least one selected from among Compounds P1 to P5, but an embodiment of the present disclosure is not limited thereto.

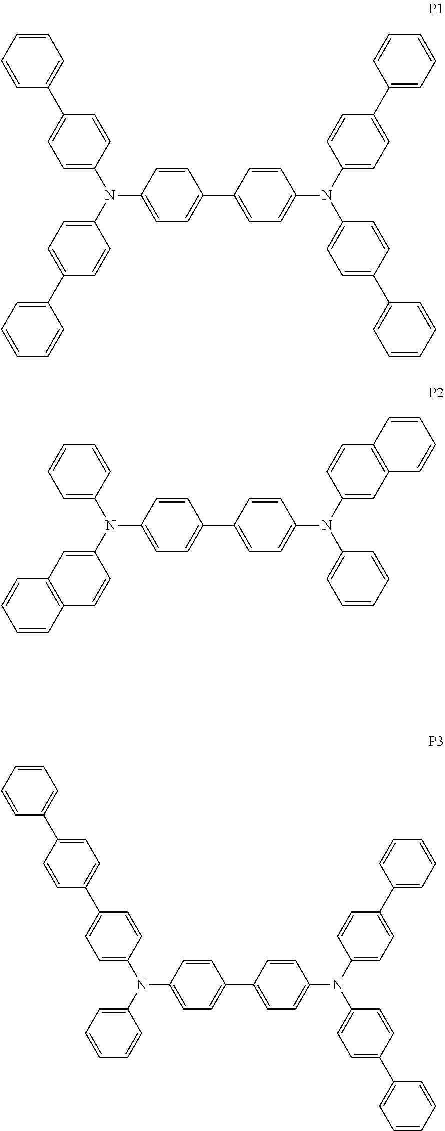 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

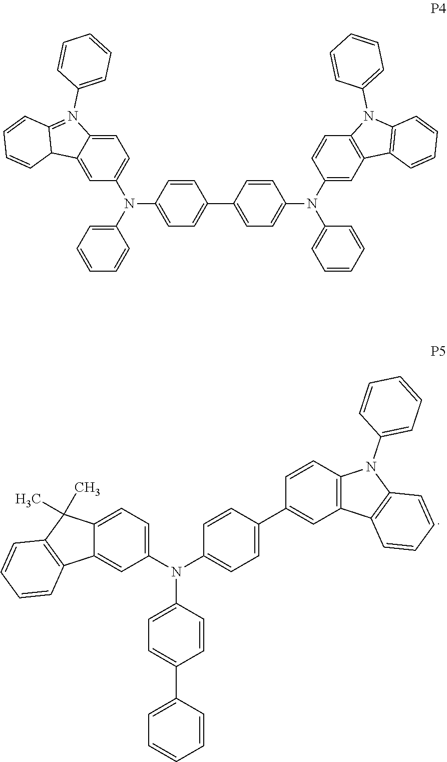

In some embodiments, the refractive index of the capping layer CPL may be about 1.6 or more. For example, the refractive index of the capping layer CPL with respect to light in a wavelength range of about 550 nm to about 660 nm may be about 1.6 or more.

FIG. 7 to FIG. 10 are cross-sectional views on display apparatuses according to embodiments. In the explanation on the display apparatuses of embodiments, referring to FIG. 7 to FIG. 10, the overlapping parts with the explanation on FIG. 1 to FIG. 6 will not be explained again, and the different features will be mainly explained.

Referring to FIG. 7, a display apparatus DD-a according to an embodiment may include a display panel DP including a display device layer DP-ED, a light controlling layer CCL disposed on the display panel DP, and a color filter layer CFL.

In an embodiment shown in FIG. 7, the display panel DP includes a base layer BS, a circuit layer DP-CL provided on the base layer BS and a display device layer DP-ED, and the display device layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the same structures of the light emitting elements of FIG. 3 to FIG. 6 may be applied to the structure of the light emitting element ED shown in FIG. 7.

The emission layer EML of the light emitting element ED included in the display apparatus DD-a according to an embodiment, may include the above-described polycyclic compound of an embodiment.

Referring to FIG. 7, the emission layer EML may be disposed in an opening part OH defined in a pixel definition layer PDL. For example, the emission layer EML divided by the pixel definition layer PDL and correspondingly provided to each of luminous areas PXA-R, PXA-G and PXA-B may be to emit light in substantially the same wavelength region. In the display apparatus DD-a of an embodiment, the emission layer EML may be to emit blue light. Alternatively, different from the embodiment shown in FIG. 7, in an embodiment, the emission layer EML may be provided as a common layer for all luminous areas PXA-R, PXA-G and PXA-B.

The light controlling layer CCL may be disposed on the display panel DP. The light controlling layer CCL may include a light converter. The light converter may be a quantum dot or a phosphor. The light converter may transform the wavelength of light provided and then emit. For example, the light controlling layer CCL may be a layer including a quantum dot or a layer including a phosphor.

The light controlling layer CCL may include multiple light controlling parts CCP1, CCP2 and CCP3. The light controlling parts CCP1, CCP2 and CCP3 may be separated from one another.

Referring to FIG. 7, a partition pattern BMP may be disposed between the separated light controlling parts CCP1, CCP2 and CCP3, but an embodiment of the present disclosure is not limited thereto. In FIG. 7, the partition pattern BMP is shown to not overlap with the light controlling parts CCP1, CCP2 and CCP3, but in some embodiments, at least a portion of the edge of the light controlling parts CCP1, CCP2 and CCP3 may overlap with the partition pattern BMP.

The light controlling layer CCL may include a first light controlling part CCP1 including a first quantum dot QD1 converting a first color light provided from the light emitting element ED into a second color light, a second light controlling part CCP2 including a second quantum dot QD2 converting the first color light into a third color light, and a third light controlling part CCP3 transmitting the first color light.

In an embodiment, the first light controlling part CCP1 may provide red light which is the second color light, and the second light controlling part CCP2 may provide green light which is the third color light. The third color controlling part CCP3 may be to transmit and provide blue light which is the first color light provided from the light emitting element ED. For example, the first quantum dot QD1 may be a red quantum dot, and the second quantum dot QD2 may be a green quantum dot. The quantum dots QD1 and QD2 may be the same as those described above.

In some embodiments, the light controlling layer CCL may further include a scatterer SP. The first light controlling part CCP1 may include the first quantum dot QD1 and the scatterer SP, the second light controlling part CCP2 may include the second quantum dot QD2 and the scatterer SP, and the third light controlling part CCP3 may not include (e.g., may exclude) any quantum dot but may include the scatterer SP.

The scatterer SP may be an inorganic particle. For example, the scatterer SP may include at least one selected from among TiO₂, ZnO, Al₂O₃, SiO₂, and hollow silica. The scatterer SP may include at least one selected from among TiO₂, ZnO, Al₂O₃, SiO₂, and hollow silica, or may be a mixture of two or more materials selected s from among TiO₂, ZnO, Al₂O₃, SiO₂, and hollow silica.

Each of the first light controlling part CCP1, the second light controlling part CCP2, and the third light controlling part CCP3 may include a corresponding one of the base resins BR1, BR2 and BR3 for dispersing the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3. The base resins BR1, BR2 and BR3 are mediums in which the quantum dots QD1 and QD2 and the scatterer SP are dispersed, and may be composed of one or more suitable resin compositions which may be generally referred to as a binder. For example, the base resins BR1, BR2 and BR3 may each independently be one or more of acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking the penetration of moisture and/or oxygen (hereinafter, will be referred to as “humidity/oxygen”). The barrier layer BFL1 may be disposed on the light controlling parts CCP1, CCP2 and CCP3 to block or reduce the exposure of the light controlling parts CCP1, CCP2 and CCP3 to humidity/oxygen. In some embodiments, the barrier layer BFL1 may cover the light controlling parts CCP1, CCP2 and CCP3. In some embodiments, the barrier layer BFL2 may be provided between the light controlling parts CCP1, CCP2 and CCP3 and a color filter layer CFL (e.g., along the thickness direction).

The barrier layers BFL1 and BFL2 may include at least one inorganic layer. For example, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride and/or a metal thin film for securing light transmittance. In some embodiments, the barrier layers BFL1 and BFL2 may further include an organic layer. The barrier layers BFL1 and BFL2 may be composed of a single layer or multiple layers.

In the display apparatus DD-a of an embodiment, the color filter layer CFL may be disposed on the light controlling layer CCL. For example, the color filter layer CFL may be disposed directly on the light controlling layer CCL. In this case, the barrier layer BFL2 may not be provided.

The color filter layer CFL may include filters CF1, CF2 and CF3. The color filter layer CFL may include a first filter CF1 for transmitting the second color light, a second filter CF2 for transmitting the third color light, and a third filter CF3 for transmitting the first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye. In some embodiments, an embodiment of the present disclosure is not limited thereto, and the third filter CF3 may not include (e.g., may exclude) any pigment or dye. The third filter CF3 may include a polymer photosensitive resin and not include any pigment or dye. The third filter CF3 may be transparent. The third filter CF3 may be formed utilizing a transparent photosensitive resin.

In an embodiment, the first filter CF1 and the second filter CF2 may be yellow filters. The first filter CF1 and the second filter CF2 may be provided in one body without distinction (e.g., without being separated). In some embodiments, the first to third filters CF1, CF2 and CF3 may be disposed corresponding to of red luminous area PXA-R, green luminous area PXA-G, and blue luminous area PXA-B, respectively.

In some embodiments, though not shown, the color filter layer CFL may include a light blocking part. The color filter layer CFL may include the light blocking part disposed so as to overlap with the boundaries of the neighboring filters CF1, CF2 and CF3. The light blocking part may be a black matrix. The light blocking part may be formed by including an organic light blocking material or an inorganic light blocking material including a black pigment and/or black dye. The light blocking part may prevent or reduce light leakage phenomenon and divide (define) the boundaries of corresponding adjacent filters CF1, CF2 and CF3. In some embodiments, in an embodiment, the light blocking part may be formed as a blue filter.

On the color filter layer CFL, a base substrate BL may be disposed. The base substrate BL may be a member providing a base surface on which the color filter layer CFL, the light controlling layer CCL, etc. are disposed. The base substrate BL may be a glass substrate, a metal substrate, a plastic substrate, etc. However, an embodiment of the present disclosure is not limited thereto, and the base substrate BL may be an inorganic layer, an organic layer or a composite material layer. In some embodiments, different from the drawing, the base substrate BL may not be provided.

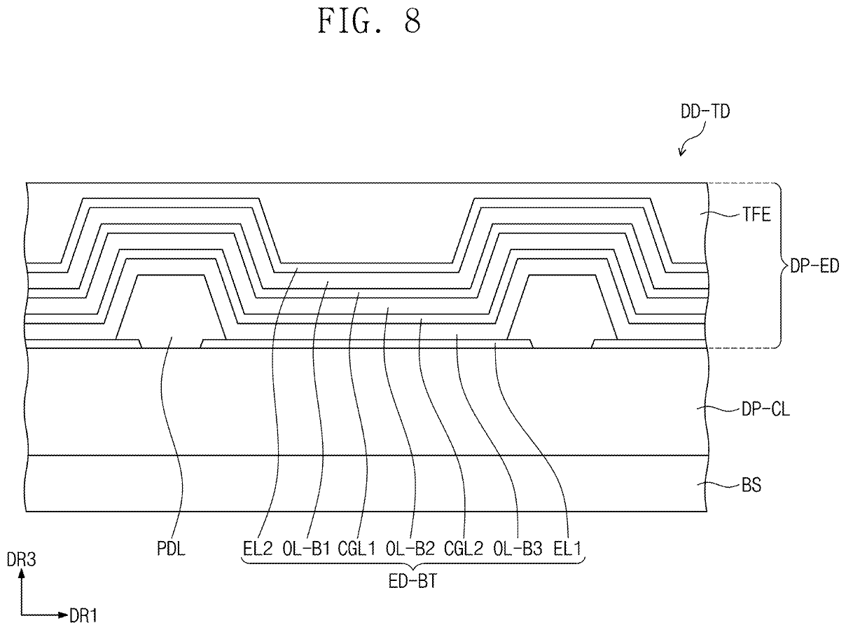

FIG. 8 is a cross-sectional view showing a portion of the display apparatus according to an embodiment. In FIG. 8, the cross-sectional view of a portion corresponding to the display panel DP in FIG. 7 is shown. In a display apparatus DD-TD of an embodiment, the light emitting element ED-BT may include multiple light emitting structures OL-B1, OL-B2 and OL-B3. The light emitting element ED-BT may include oppositely disposed first electrode EL1 and second electrode EL2, and the multiple light emitting structures OL-B1, OL-B2 and OL-B3 stacked in order in a thickness direction between the first electrode EL1 and the second electrode EL2. Each of the light emitting structures OL-B1, OL-B2 and OL-B3 may include an emission layer EML (FIG. 7), and a hole transport region HTR and an electron transport region ETR, disposed with the emission layer EML (FIG. 7) therebetween.

For example, the light emitting element ED-BT included in the display apparatus DD-TD of an embodiment may be a light emitting element of a tandem structure including multiple emission layers.

In an embodiment shown in FIG. 8, light emitted from the light emitting structures OL-B1, OL-B2 and OL-B3 may all be blue light. However, an embodiment of the present disclosure is not limited thereto, and the wavelength regions of light emitted from the light emitting structures OL-B1, OL-B2 and OL-B3 may be different from each other. For example, the light emitting element ED-BT including the multiple light emitting structures OL-B1, OL-B2 and OL-B3 emitting light in different wavelength regions may be to emit white light.

Between neighboring light emitting structures OL-B1, OL-B2 and OL-B3, charge generating layers CGL1 and CGL2 may be disposed. The charge generating layers CGL1 and CGL2 may include a p-type or kind charge generating layer (e.g., a P-charge generation layer) and/or an n-type or kind charge generating layer (e.g., a N-charge generation layer).

In at least one of the light emitting structures OL-B1, OL-B2 and OL-B3, included in the display apparatus DD-TD of an embodiment, the polycyclic compound of an embodiment may be included. For example, at least one selected from among multiple emission layers included in the light emitting element ED-BT may include the polycyclic compound of an embodiment.

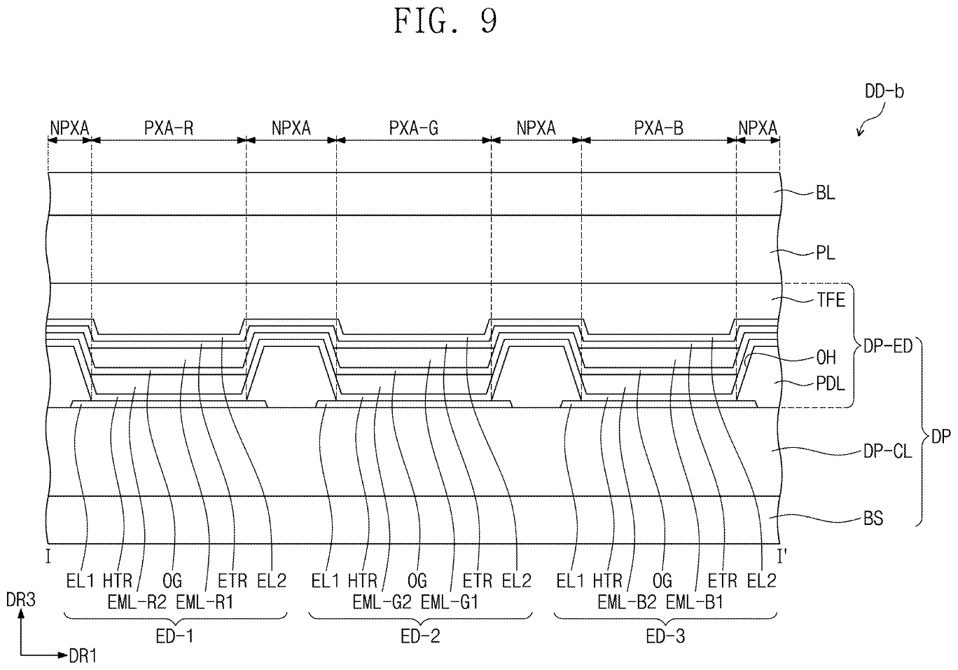

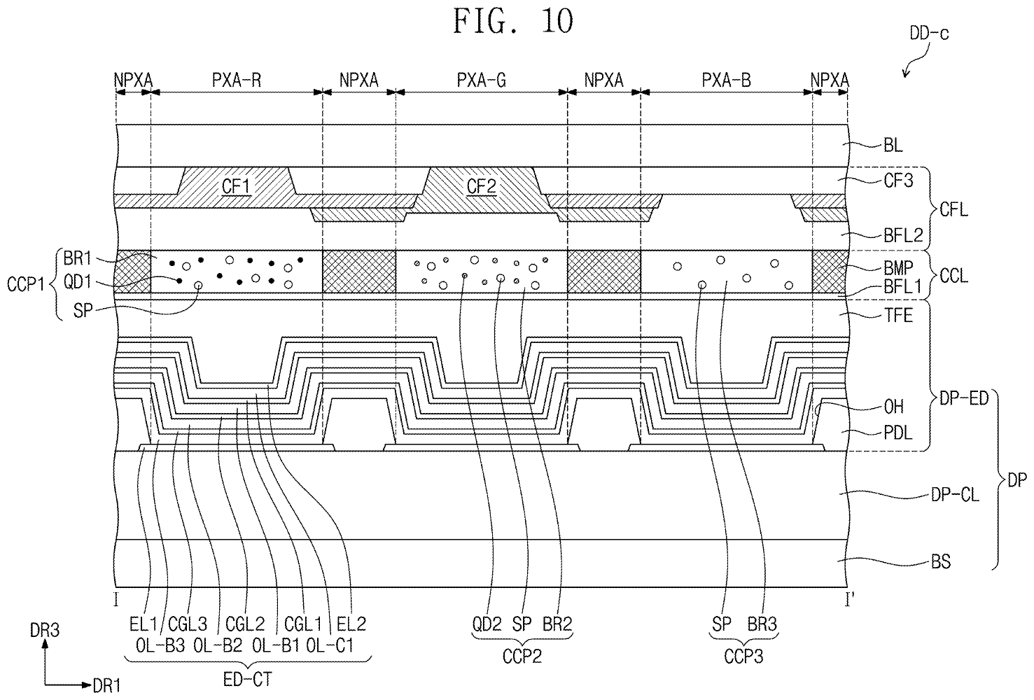

Referring to FIG. 9, a display apparatus DD-b according to an embodiment may include light emitting elements ED-1, ED-2 and ED-3, each formed by stacking two emission layers over each other. Compared to the display apparatus DD of an embodiment, shown in FIG. 2, an embodiment shown in FIG. 9 is different in that the first to third light emitting elements ED-1, ED-2 and ED-3 each include two emission layers stacked in a thickness direction. In the first to third light emitting elements ED-1, ED-2 and ED-3, the two emission layers may be to emit light in substantially the same wavelength region.

The first light emitting element ED-1 may include a first red emission layer EML-R₁ and a second red emission layer EML-R₂. The second light emitting element ED-2 may include a first green emission layer EML-G1 and a second green emission layer EML-G2. In addition, the third light emitting element ED-3 may include a first blue emission layer EML-B1 and a second blue emission layer EML-B2. Between the first red emission layer EML-R₁ and the second red emission layer EML-R₂, between the first green emission layer EML-G1 and the second green emission layer EML-G2, and between the first blue emission layer EML-B1 and the second blue emission layer EML-B2, an emission auxiliary part OG may be disposed.

The emission auxiliary part OG may include a single layer or a multilayer. The emission auxiliary part OG may include a charge generating layer. For example, the emission auxiliary part OG may include an electron transport region, a charge generating layer, and a hole transport region stacked in the stated order. The emission auxiliary part OG may be provided as a common layer in all of the first to third light emitting elements ED-1, ED-2 and ED-3. However, an embodiment of the present disclosure is not limited thereto, and the emission auxiliary part OG may be patterned and provided in an opening part OH defined in the pixel definition layer PDL.

The first red emission layer EML-R₁, the first green emission layer EML-G1 and the first blue emission layer EML-B1 may be disposed between the electron transport region ETR and the emission auxiliary part OG. The second red emission layer EML-R₂, the second green emission layer EML-G2 and the second blue emission layer EML-B2 may be disposed between the emission auxiliary part OG and the hole transport region HTR.

For example, the first light emitting element ED-1 may include a first electrode EL1, a hole transport region HTR, a second red emission layer EML-R₂, an emission auxiliary part OG, a first red emission layer EML-R₁, an electron transport region ETR, and a second electrode EL2, stacked in the stated order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, stacked in the stated order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, stacked in the stated order.

In some embodiments, an optical auxiliary layer PL may be disposed on a display device layer DP-ED. The optical auxiliary layer PL may include a polarization layer. The optical auxiliary layer PL may be disposed on a display panel DP and may control reflected light at the display panel DP by external light. Different from the drawings, the optical auxiliary layer PL may not be provided from the display apparatus according to an embodiment.

At least one emission layer included in the display apparatus DD-b of an embodiment, shown in FIG. 9, may include the polycyclic compound of an embodiment. For example, in an embodiment, at least one selected from among a first blue emission layer EML-B1 and a second blue emission layer EML-B2 may include the polycyclic compound of an embodiment.

Different from FIG. 8 and FIG. 9, a display apparatus DD-c in FIG. 10 is shown to include four light emitting structures OL-B1, OL-B2, OL-B3 and OL-C1. A light emitting element ED-CT may include oppositely disposed first electrode EL1 and second electrode EL2, and first to fourth light emitting structures OL-B1, OL-B2, OL-B3 and OL-C1 stacked in the stated order in a thickness direction between the first electrode EL1 and the second electrode EL2. Between the first to fourth light emitting structures OL-B1, OL-B2, OL-B3 and OL-C1, charge generating layers CGL1, CGL2 and CGL3 may be disposed. From among the four light emitting structures, the first to third light emitting structures OL-B1, OL-B2 and OL-B3 emit blue light, and the fourth light emitting structure OL-C1 may be to emit green light. However, an embodiment of the present disclosure is not limited thereto, and the first to fourth light emitting structures OL-B1, OL-B2, OL-B3 and OL-C1 may be to emit light of different wavelengths.

Charge generating layers CGL1, CGL2 and CGL3 disposed selected from among neighboring light emitting structures OL-B1, OL-B2, OL-B3 and OL-C1 may include a p-type or kind charge generating layer (e.g., a P-charge generation layer) and/or an n-type or kind charge generating layer (e.g., a N-charge generation layer).

In at least one selected from among the light emitting structures OL-B1, OL-B2, OL-B3 and OL-C1, included in the display apparatus DD-c of an embodiment, the polycyclic compound of an embodiment may be included. For example, at least one selected from among the first to third light emitting structures OL-B1, OL-B2, and OL-B3 may include the polycyclic compound of an embodiment.

The light emitting element ED according to an embodiment of the present disclosure may include the polycyclic compound of an embodiment in at least one functional layer disposed between the first electrode EL1 and the second electrode EL2 to show (e.g., realize) improved life (e.g., lifespan) characteristics. For example, the polycyclic compound according to an embodiment may be included in the emission layer EML of the light emitting element ED of an embodiment, and the light emitting element of an embodiment may show long-life characteristics.

The polycyclic compound of an embodiment includes a heavy atom in a fused ring containing a boron atom and a nitrogen atom, and when utilized as a dopant material of thermally activated delayed fluorescence, reverse intersystem crossing may occur easily and high material stability may be achieved. In addition, the polycyclic compound of an embodiment includes an ortho-type or kind terphenyl group connected with the fused ring, and may show steric shielding effects, and when applied to a light emitting element, emission efficiency may be improved.

Hereinafter, the polycyclic compound according to an embodiment and the light emitting element according to an embodiment of the present disclosure will be explained referring to embodiments and comparative embodiments. In addition, the embodiments (examples) below are only illustrations to assist the understanding of the present disclosure, and the scope of the present disclosure is not limited thereto.

### EXAMPLES

### 1. Synthesis of Polycyclic Compound

First, the synthetic method of the polycyclic compound according to an embodiment of the present disclosure will be explained in more detail by referring to the synthetic methods of Compound 2, Compound 36, Compound 50, Compound 87, and Compound 112 to Compound 115. In addition, the synthetic methods of the polycyclic compounds explained hereinafter are only embodiments, and the synthetic method of the polycyclic compound according to an embodiment of the present disclosure is not limited to the embodiments.

Meanwhile, in the synthetic methods, “D” is a deuterium atom.

### 1) Synthesis of Compound 2

Compound 2 according to an embodiment may be synthesized by, for example, the steps (e.g., acts or tasks) of Reaction 1.

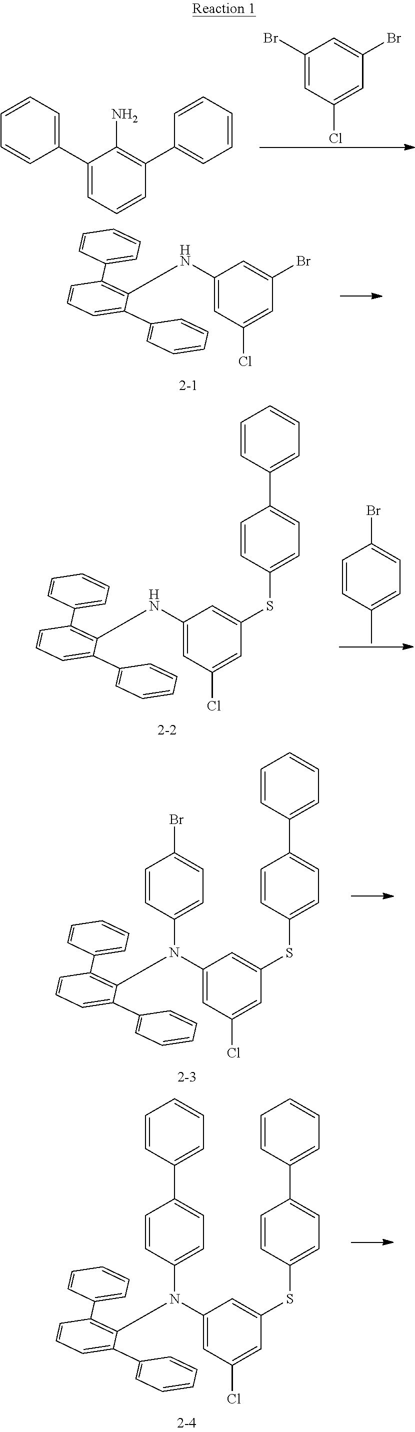

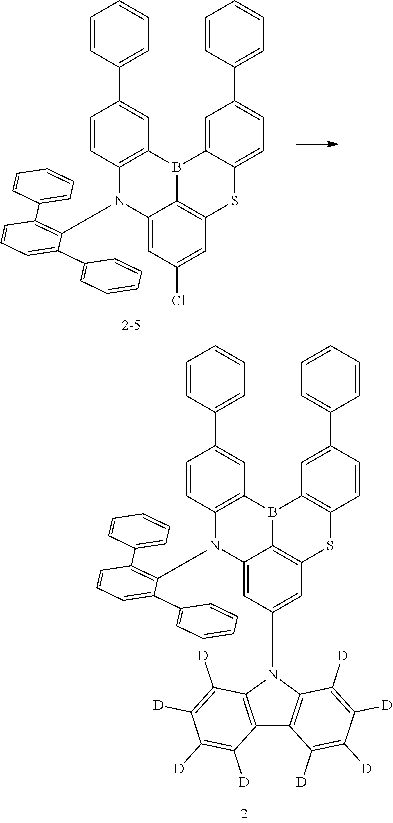 [SMILES: Clc1cc2c3c(c1)N(c1c(-c4ccccc4)cccc1-c1ccccc1)c1ccc(-c4ccccc4)cc1B3c1cc(-c3ccccc3)ccc1S2 ; [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccc(-c4ccccc4)cc1B3c1cc(-c3ccccc3)ccc1S2]

### (1) Synthesis of Intermediate 2-1

Under an argon atmosphere, [1,1′:3′,1″-terphenyl]-2′-amine (1 eq), 1,3-dibromo-5-chlorobenzene (1 eq), Pd₂dba₃ (0.03 eq), tris-tert-butyl phosphine (0.06 eq), and sodium tert-butoxide (1.5 eq) were added and dissolved in o-xylene, and the reaction solution was stirred at about 140 degrees Celsius (° C.) for about 12 hours. After cooling, water (1 L) and ethyl acetate (300 mL) were added, extraction was performed, and organic layers were collected. Then, the resultant was dried over MgSO₄ and filtered. The solvent was removed from the filtrate solution under a reduced pressure, and the solid thus obtained was separated and purified by column chromatography utilizing silica gel by utilizing CH₂Cl₂ and hexane as developing solvents to obtain Intermediate 2-1 (yield: 70%).

### (2) Synthesis of Intermediate 2-2

Under an argon atmosphere, Intermediate 2-1 (1 eq), [1,1′-biphenyl]-4-thiol (1 eq), copper iodide (0.1 eq), 2-picolinic acid (0.2 eq), and K₃PO₄ (3 eq) were dissolved in DMF and stirred under a nitrogen atmosphere at about 160° C. for about 12 hours. After cooling, the resultant was washed with ethyl acetate and water three times, and the organic layer thus obtained was dried over MgSO₄ and dried under a reduced pressure. Through column chromatography, Intermediate 2-2 was obtained (yield: 65%).

### (3) Synthesis of Intermediate 2-3

Under an argon atmosphere, Intermediate 2-2 (1 eq), 4-iodobromoobenzene (10 eq), Pd₂dba₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Intermediate 2-3 (yield: 40%).

### (4) Synthesis of Intermediate 2-4

Under an argon atmosphere, Intermediate 2-3 (1 eq) was added, and phenylboronic acid (1 eq), Pd(PPh₃)₄ (0.05 eq), and potassium carbonate (2 eq) were added and dissolved in toluene and water, and the reaction solution was stirred at about 100° C. for about 12 hours. After cooling, water and ethyl acetate were added, extraction was performed, and organic layers were collected, dried over MgSO₄ and filtered. The solvent was removed from the filtrate solution under a reduced pressure, and the resultant was separated and purified by column chromatography utilizing silica gel to obtain Intermediate 2-4 (yield: 73%).

### (5) Synthesis of Intermediate 2-5

Under an argon atmosphere, Intermediate 2-4 (1 eq) was dissolved in o-dichlorobenzene, BBr₃ (5 eq) was slowly added thereto dropwisely at about 0° C., and the reaction solution was stirred at about 180° C. for about 12 hours. After cooling, triethylamine (5 eq) was added to terminate the reaction, and the resultant was extracted with water and CH₂Cl₂. Organic layers were collected, dried over MgSO₄ and filtered. The solvent was removed from the filtrate solution under a reduced pressure, and the resultant was separated and purified by column chromatography utilizing silica gel to obtain Intermediate 2-5 (yield: 30%).

### (6) Synthesis of Compound 2

Intermediate 2-5, 9H-carbazole-1,2,3,4-d4 (1 eq), Pd₂dba₃ (0.05 eq), tris-tert-butyl phosphine (0.1 eq), and sodium tert-butoxide (1.5 eq) were added and dissolved in o-xylene, and the reaction solution was stirred at about 140° C. for about 12 hours. After cooling, water and ethyl acetate were added, extraction was performed, and organic layers were collected, dried over MgSO₄ and filtered. The solvent was removed from the filtrate solution under a reduced pressure, and the resultant was separated and purified by column chromatography utilizing silica gel to obtain Compound 2 (yield: 79%).

### 2) Synthesis of Compound 36

Compound 36 according to an embodiment may be synthesized by, for example, the steps (e.g., acts or tasks) of Reaction 2.

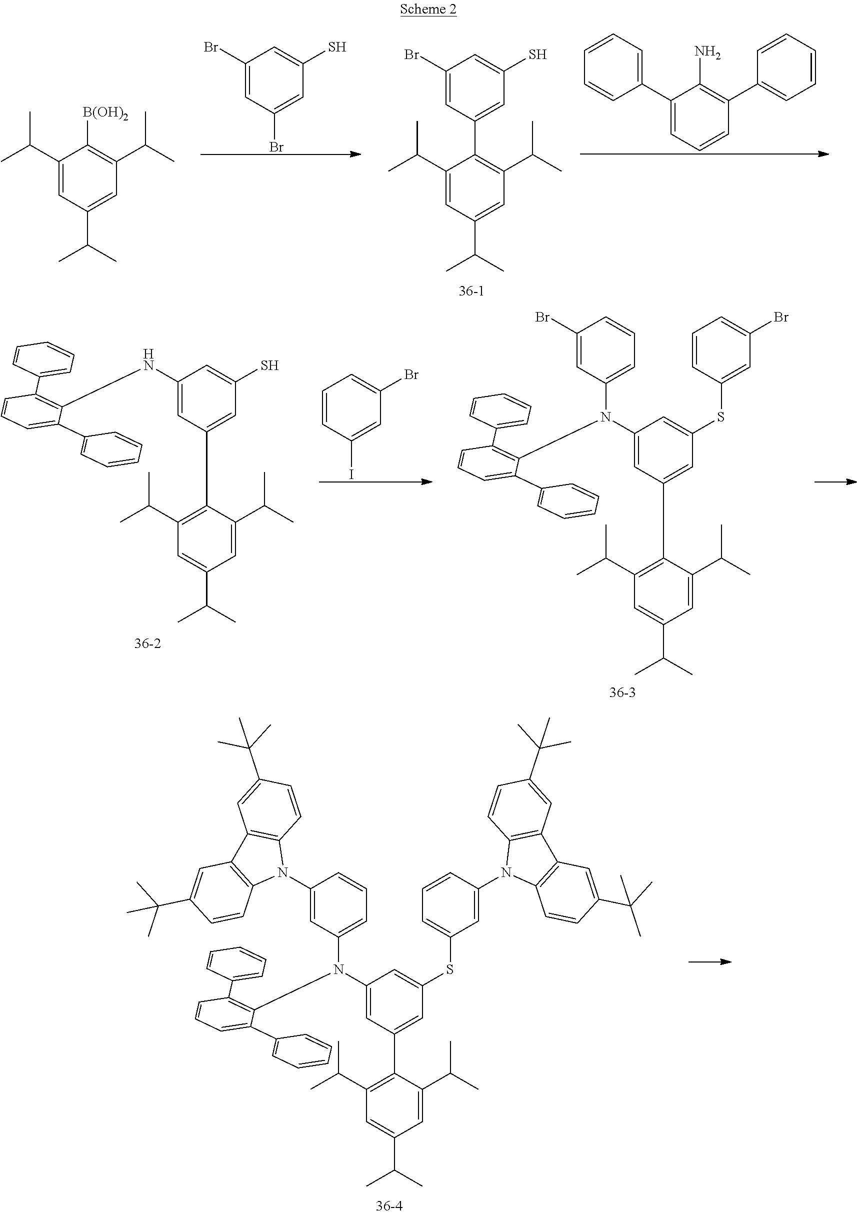

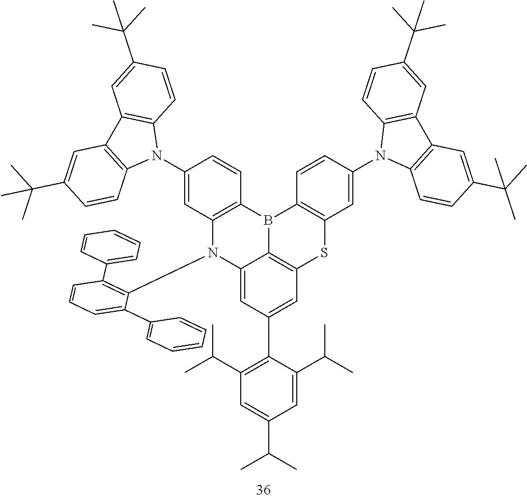 [SMILES: CC(C)c1cc(C(C)C)c(-c2cc3c4c(c2)N(c2c(-c5ccccc5)cccc2-c2ccccc2)c2cc(-n5c6ccc(C(C)(C)C)cc6c6cc(C(C)(C)C)ccc65)ccc2B4c2ccc(-n4c5ccc(C(C)(C)C)cc5c5cc(C(C)(C)C)ccc54)cc2S3)c(C(C)C)c1]

### (1) Synthesis of Intermediate 36-1

Under an argon atmosphere, (2,4,6-triisopropylphenyl)boronic acid (1.2 eq), 3,5-dibromobenzenethiol (1 eq), Pd(PPh₃)₄ (0.05 eq), and potassium carbonate (2 eq) were added and dissolved in toluene and water, and the reaction solution was stirred at about 100° C. for about 12 hours. After cooling, water and ethyl acetate were added, extraction was performed, and organic layers were collected. Then, the resultant was dried over MgSO₄ and filtered. The solvent was removed from the filtrate solution under a reduced pressure, and the resultant was separated and purified by column chromatography utilizing silica gel to obtain Intermediate 36-1 (yield: 69%).

### (2) Synthesis of Intermediate 36-2

Under an argon atmosphere, [1,1′:3′,1″-terphenyl]-2′-amine (1 eq), Intermediate 36-1 (1 eq), Pd₂dba₃ (0.03 eq), tris-tert-butyl phosphine (0.06 eq), and sodium tert-butoxide (1.5 eq) were added and dissolved in o-xylene, and the reaction solution was stirred at about 140° C. for about 12 hours. After cooling, ethyl acetate and water were added, extraction was performed, and organic layers were collected, dried over MgSO₄ and filtered. The solvent was removed from the filtrate solution under a reduced pressure, and the solid thus obtained was separated and purified by column chromatography utilizing silica gel by utilizing CH₂Cl₂ and hexane as developing solvents to obtain Intermediate 36-2 (yield: 65%).

### (3) Synthesis of Intermediate 36-3

Under an argon atmosphere, Intermediate 36-2 (1 eq), 3-iodobromoobenzene (10 eq), Pd₂dba₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Intermediate 36-3 (yield: 51%).

### (4) Synthesis of Intermediate 36-4

Intermediate 36-3,3,6-di-tert-butyl-9H-carbazole (2 eq), Pd₂dba₃ (0.05 eq), tris-tert-butyl phosphine (0.1 eq), and sodium tert-butoxide (1.5 eq) were added and dissolved in o-xylene, and the reaction solution was stirred at about 140° C. for about 12 hours. After cooling, water and ethyl acetate were added, extraction was performed, and organic layers were collected, dried over MgSO₄ and filtered. The solvent was removed from the filtrate solution under a reduced pressure, and the resultant was separated and purified by column chromatography utilizing silica gel to obtain Intermediate 36-4 (yield: 77%).

### (5) Synthesis of Compound 36

Under an argon atmosphere, Intermediate 36-4 (1 eq) was dissolved in o-dichlorobenzene, BBr₃ (5 eq) was slowly added thereto dropwisely at about 0° C., and the reaction solution was stirred at about 180° C. for about 12 hours. After cooling, triethylamine (5 eq) was added to terminate the reaction, and the resultant was extracted with water and CH₂Cl₂. Organic layers were collected, dried over MgSO₄ and filtered. The solvent was removed from the filtrate solution under a reduced pressure, and the resultant was separated and purified by column chromatography utilizing silica gel to obtain Compound 36 (yield: 34%).

### 3) Synthesis of Compound 50

Compound 50 according to an embodiment may be synthesized by, for example, the steps (e.g., acts or tasks) of Reaction 3.

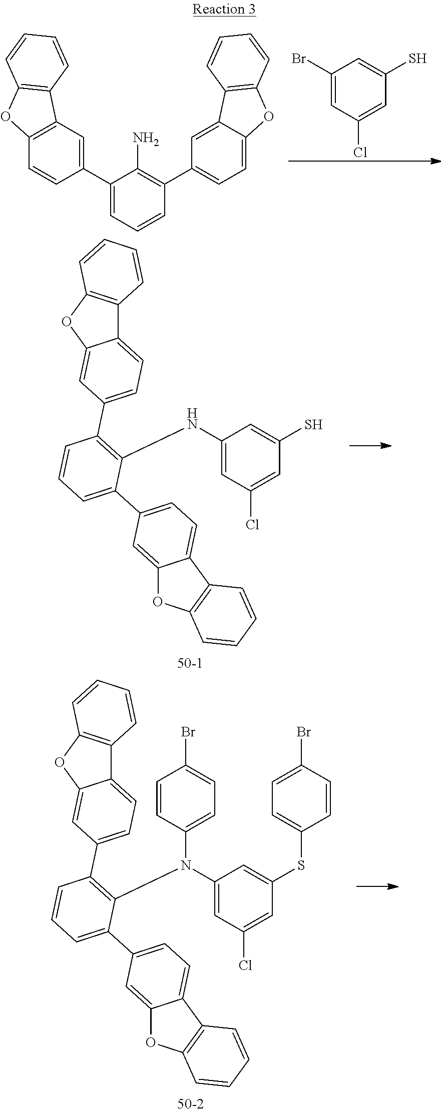

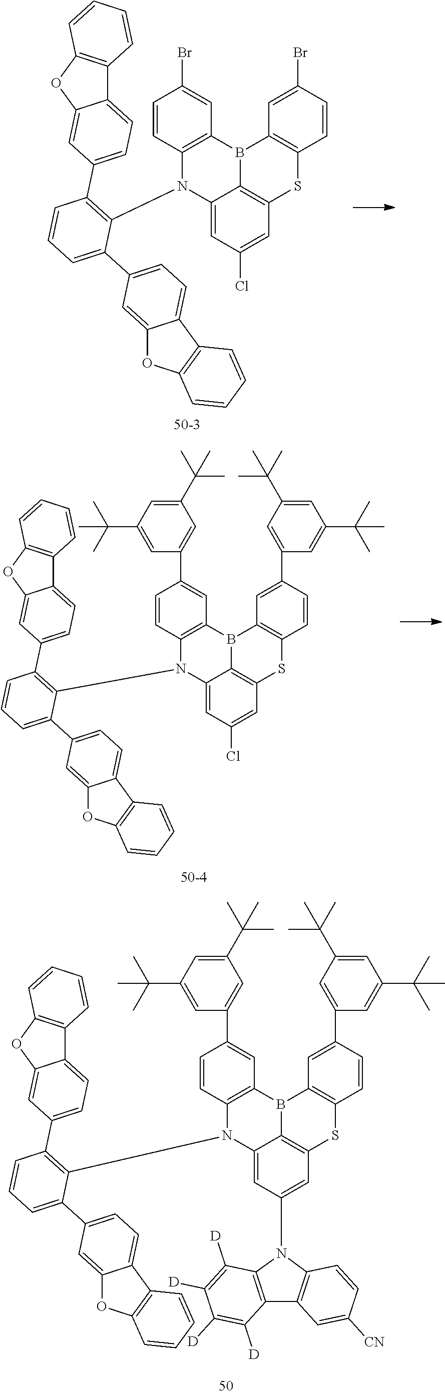 [SMILES: Clc1cc2c3c(c1)N(c1c(-c4ccc5c(c4)oc4ccccc45)cccc1-c1ccc4c(c1)oc1ccccc14)c1ccc(Br)cc1B3c1cc(Br)ccc1S2 ; CC(C)(C)c1cc(-c2ccc3c(c2)B2c4cc(-c5cc(C(C)(C)C)cc(C(C)(C)C)c5)ccc4N(c4c(-c5ccc6c(c5)oc5ccccc56)cccc4-c4ccc5c(c4)oc4ccccc45)c4cc(Cl)cc(c42)S3)cc(C(C)(C)C)c1 ; [2H]c1c([2H])c([2H])c2c(c1[2H])c1cc(C#N)ccc1n2-c1cc2c3c(c1)N(c1c(-c4ccc5c(c4)oc4ccccc45)cccc1-c1ccc4c(c1)oc1ccccc14)c1ccc(-c4cc(C(C)(C)C)cc(C(C)(C)C)c4)cc1B3c1cc(-c3cc(C(C)(C)C)cc(C(C)(C)C)c3)ccc1S2]

### (1) Synthesis of Intermediate 50-1

Under an argon atmosphere, 2,6-bis(dibenzo[b,d]furan-2-yl)aniline (1 eq), 3-bromo-5-chlorobenzenethiol (1 eq), Pd₂dba₃ (0.05 eq), tris-tert-butyl phosphine (0.1 eq), and sodium tert-butoxide (3 eq) were added and dissolved in o-xylene, and the reaction solution was stirred at about 140° C. for about 12 hours. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel by utilizing CH₂Cl₂ and hexane as developing solvents to obtain Intermediate 50-1 (yield: 58%).

### (2) Synthesis of Intermediate 50-2

Under an argon atmosphere, Intermediate 50-1 (1 eq), 4-iodobromobenzene (10 eq), Pd₂dba₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Intermediate 50-2 (yield: 54%).

### (3) Synthesis of Intermediate 50-3

Under an argon atmosphere, Intermediate 50-2 (1 eq) was dissolved in o-dichlorobenzene, BBr₃ (5 eq) was slowly added thereto dropwisely at about 0° C., and the reaction solution was stirred at about 180° C. for about 12 hours. After cooling, triethylamine (5 eq) was added to terminate the reaction, and the resultant was extracted with water and CH₂Cl₂. Organic layers were collected, dried over MgSO₄ and filtered. The solvent was removed from the filtrate solution under a reduced pressure, and the resultant was separated and purified by column chromatography utilizing silica gel to obtain Intermediate 50-3 (yield: 41%).

### (4) Synthesis of Intermediate 50-4

Under an argon atmosphere, Intermediate 50-3, 3,5-di-tert-butylphenyl)boronic acid (2.5 eq), Pd(PPh₃)₄ (0.05 eq), and potassium carbonate (2 eq) were added and dissolved in toluene and water, and the reaction solution was stirred at about 100° C. for about 12 hours. After cooling, water and ethyl acetate were added, extraction was performed, and organic layers were collected, dried over MgSO₄ and filtered. The solvent was removed from the filtrate solution under a reduced pressure, and the resultant was separated and purified by column chromatography utilizing silica gel to obtain Intermediate 50-4 (yield: 72%).

### (5) Synthesis of Compound 50

Under an argon atmosphere, Intermediate 50-4 (1 eq), 9H-carbazole-3-carbonitrile-5,6,7,8-d4-methane (1/1) (1.2 eq), Pd₂dba₃ (0.05 eq), tris-tert-butyl phosphine (0.1 eq), and sodium tert-butoxide (3 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Compound 50 (yield: 75%).

### 4) Synthesis of Compound 87

Compound 87 according to an embodiment may be synthesized by, for example, the steps (e.g., acts or tasks) of Reaction 4.

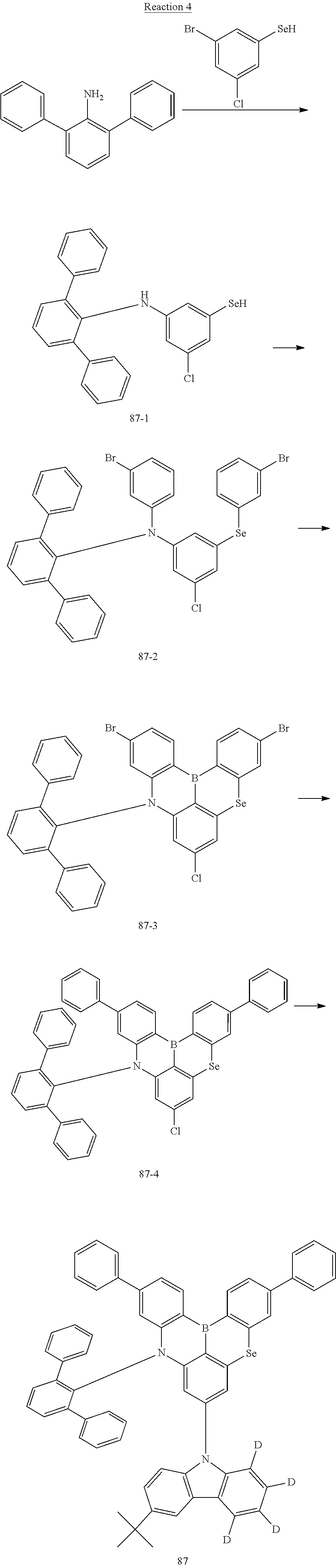

### (1) Synthesis of Intermediate 87-1

Under an argon atmosphere, [1,1′:3′,1″-terphenyl]-2′-amine (1 eq), 3-bromo-5-chlorobenzeneselenolol (1 eq), Pd₂dba₃ (0.05 eq), tris-tert-butyl phosphine (0.1 eq), and sodium tert-butoxide (3 eq) were added and dissolved in o-xylene, and the reaction solution was stirred at about 140° C. for about 12 hours. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel by utilizing CH₂Cl₂ and hexane as developing solvents to obtain Intermediate 87-1 (yield: 66%).

### (2) Synthesis of Intermediate 87-2

Under an argon atmosphere, Intermediate 87-1 (1 eq), 3-iodobromobenzene (10 eq), Pd₂dba₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Intermediate 87-2 (yield: 58%).

### (3) Synthesis of Intermediate 87-3

Under an argon atmosphere, Intermediate 87-2 (1 eq) was dissolved in o-dichlorobenzene, BBr₃ (5 eq) was slowly added thereto dropwisely at about 0° C., and the reaction solution was stirred at about 180° C. for about 12 hours. After cooling, triethylamine (5 eq) was added to terminate the reaction, and the resultant was extracted with water and CH₂Cl₂. Organic layers were collected, dried over MgSO₄ and filtered. The solvent was removed from the filtrate solution under a reduced pressure, and the resultant was separated and purified by column chromatography utilizing silica gel to obtain Intermediate 87-3 (yield: 39%).

### (4) Synthesis of Intermediate 87-4

Under an argon atmosphere, Intermediate 87-3 (1 eq), phenylboronic acid (2.5 eq), Pd(PPh₃)₄ (0.05 eq), and potassium carbonate (2 eq) were added and dissolved in toluene and water, and the reaction solution was stirred at about 100° C. for about 12 hours. After cooling, water and ethyl acetate were added, extraction was performed, and organic layers were collected, dried over MgSO₄ and filtered. The solvent was removed from the filtrate solution under a reduced pressure, and the resultant was separated and purified by column chromatography utilizing silica gel to obtain Intermediate 87-4 (yield: 75%).

### (5) Synthesis of Compound 87

Under an argon atmosphere, Intermediate 87-4 (1 eq), 3-(tert-butyl)-9H-carbazole-5,6,7,8-d4 (1.2 eq), Pd₂dba₃ (0.05 eq), tris-tert-butyl phosphine (0.1 eq), and sodium tert-butoxide (3 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Compound 87 (yield: 79%).

### 5) Synthesis of Compound 112

Compound 112 according to an embodiment may be synthesized by, for example, the steps (e.g., acts or tasks) of Reaction 5.

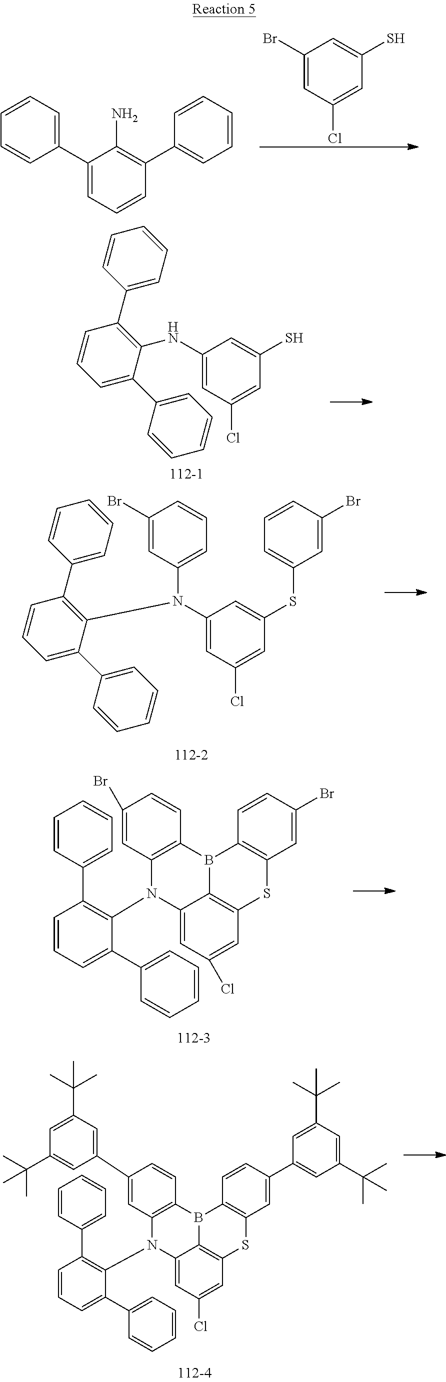

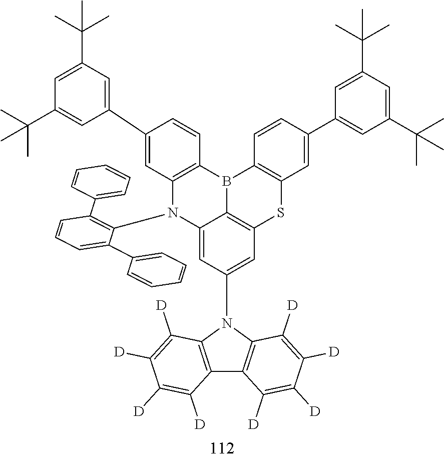 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1cc(-c4cc(C(C)(C)C)cc(C(C)(C)C)c4)ccc1B3c1ccc(-c3cc(C(C)(C)C)cc(C(C)(C)C)c3)cc1S2]

### (1) Synthesis of Intermediate 112-1

Under an argon atmosphere, [1,1′:3′,1″-terphenyl]-2′-amine (1 eq), 3-bromo-5-chlorobenzeneselenolol (1 eq), Pd₂dba₃ (0.05 eq), tris-tert-butyl phosphine (0.1 eq), and sodium tert-butoxide (3 eq) were added and dissolved in o-xylene, and the reaction solution was stirred at about 140° C. for about 12 hours. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel by utilizing CH₂Cl₂ and hexane as developing solvents to obtain Intermediate 112-1 (yield: 60%).

### (2) Synthesis of Intermediate 112-2

Under an argon atmosphere, Intermediate 112-1 (1 eq), 3-iodobromobenzene (10 eq), Pd₂dba₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Intermediate 112-2 (yield: 63%).

### (3) Synthesis of Intermediate 112-3

Under an argon atmosphere, Intermediate 112-2 (1 eq) was dissolved in o-dichlorobenzene, BBr₃ (5 eq) was slowly added thereto dropwisely at about 0° C., and the reaction solution was stirred at about 180° C. for about 12 hours. After cooling, triethylamine (5 eq) was added to terminate the reaction, and the resultant was extracted with water and CH₂Cl₂. Organic layers were collected, dried over MgSO₄ and filtered. The solvent was removed from the filtrate solution under a reduced pressure, and the resultant was separated and purified by column chromatography utilizing silica gel to obtain Intermediate 112-3 (yield: 30%).

### (4) Synthesis of Intermediate 112-4

Under an argon atmosphere, Intermediate 112-3 (1 eq), (3,5-di-tert-butylphenyl)boronic acid (2.5 eq), Pd(PPh₃)₄ (0.05 eq), and potassium carbonate (2 eq) were added and dissolved in toluene and water, and the reaction solution was stirred at about 100° C. for about 12 hours. After cooling, water and ethyl acetate were added, extraction was performed, and organic layers were collected, dried over MgSO₄ and filtered. The solvent was removed from the filtrate solution under a reduced pressure, and the resultant was separated and purified by column chromatography utilizing silica gel to obtain Intermediate 112-4 (yield: 70%).

### (5) Synthesis of Compound 112

Under an argon atmosphere, Intermediate 112-4 (1 eq), 9H-carbazole-1,2,3,4,5,6,7,8-d8 (1.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Compound 112 (yield: 82%).

### 6) Synthesis of Compound 113

Compound 113 according to an embodiment may be synthesized by, for example, the steps (e.g., acts or tasks) of Reaction 6.

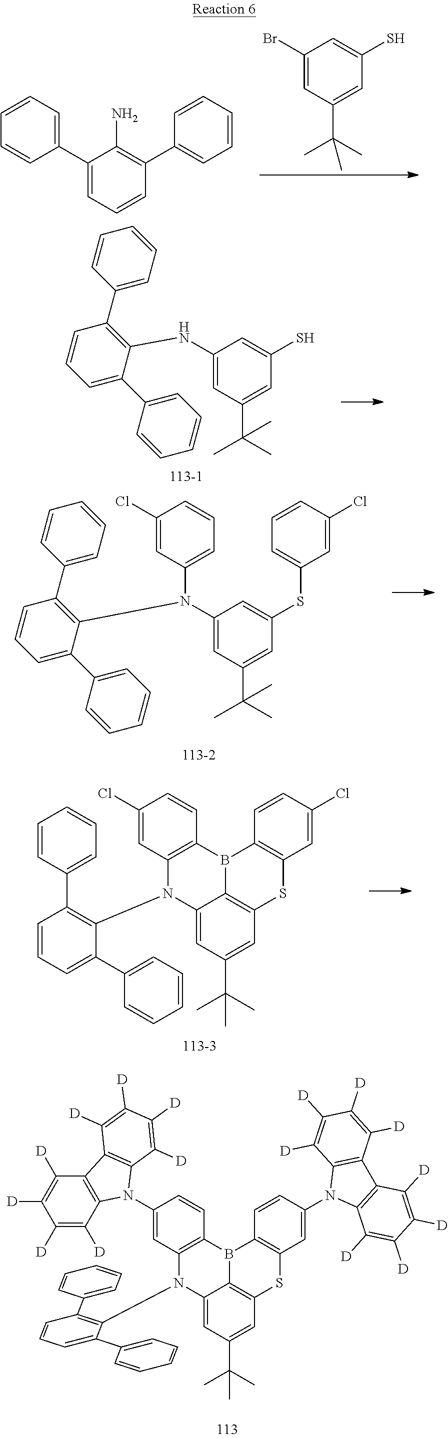

### (1) Synthesis of Intermediate 113-1

Under an argon atmosphere, [1,1′:3′,1″-terphenyl]-2′-amine (1 eq), 3-bromo-5-(tert-butyl)benzenethiol (1 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 12 hours. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel by utilizing CH₂Cl₂ and hexane as developing solvents to obtain Intermediate 113-1 (yield: 72%).

### (2) Synthesis of Intermediate 113-2

Under an argon atmosphere, Intermediate 113-1 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Intermediate 113-2 (yield: 65%).

### (3) Synthesis of Intermediate 113-3

Under an argon atmosphere, Intermediate 113-2 (1 eq) was dissolved in o-dichlorobenzene, BBr₃ (5 eq) was slowly added thereto dropwisely at about 0° C., and the reaction solution was stirred at about 180° C. for about 24 hours. After cooling, triethylamine (5 eq) was added to terminate the reaction, and the resultant was extracted with water and CH₂Cl₂. Organic layers were collected, dried over MgSO₄ and filtered. The solvent was removed from the filtrate solution under a reduced pressure, and the resultant was separated and purified by column chromatography utilizing silica gel to obtain Intermediate 113-3 (yield: 35%).

### (4) Synthesis of Compound 113

Under an argon atmosphere, Intermediate 113-3 (1 eq), 9H-carbazole-1,2,3,4,5,6,7,8-d8 (2.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 160° C. for about 12 hours. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Compound 113 (yield: 80%).

### 7) Synthesis of Compound 114

Compound 114 according to an embodiment may be synthesized by, for example, the steps (e.g., acts or tasks) of Reaction 7.

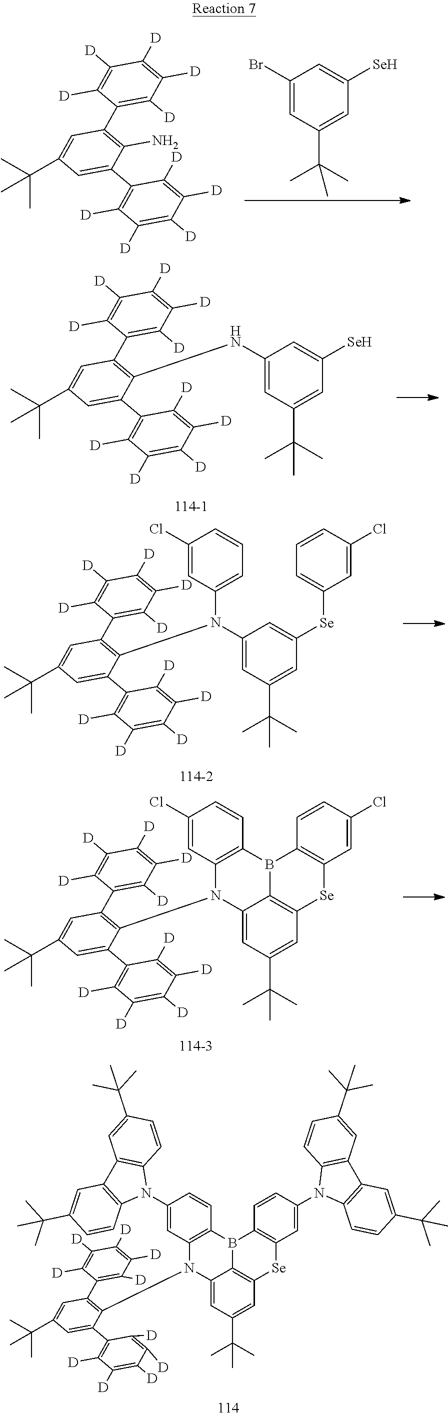

### (1) Synthesis of Intermediate 114-1

Under an argon atmosphere, 5′-(tert-butyl)-[1,1′:3′,1′-terphenyl]-2,2″,3,3″,4,4″,5,5″,6,6″-d10-2′-amine (1 eq), 3-bromo-5-(tert-butyl)benzeneselenol (1 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 12 hours. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel by utilizing CH₂Cl₂ and hexane as developing solvents to obtain Intermediate 114-1 (yield: 68%).

### (2) Synthesis of Intermediate 114-2

Under an argon atmosphere, Intermediate 114-1 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Intermediate 114-2 (yield: 66%).

### (3) Synthesis of Intermediate 114-3

Under an argon atmosphere, Intermediate 114-2 (1 eq) was dissolved in o-dichlorobenzene, BBr₃ (5 eq) was slowly added thereto dropwisely at about 0° C., and the reaction solution was stirred at about 180° C. for about 24 hours. After cooling, triethylamine (5 eq) was added to terminate the reaction, and the resultant was extracted with water and CH₂Cl₂. Organic layers were collected, dried over MgSO₄ and filtered. The solvent was removed from the filtrate solution under a reduced pressure, and the resultant was separated and purified by column chromatography utilizing silica gel to obtain Intermediate 114-3 (yield: 35%).

### (4) Synthesis of Compound 114

Under an argon atmosphere, Intermediate 114-3 (1 eq), 3,6-di-tert-butyl-9H-carbazole (2.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 160° C. for about 12 hours. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Compound 114 (yield: 77%).

### 8) Synthesis of Compound 115

Compound 115 according to an embodiment may be synthesized by, for example, the steps (e.g., acts or tasks) of Reaction 8.

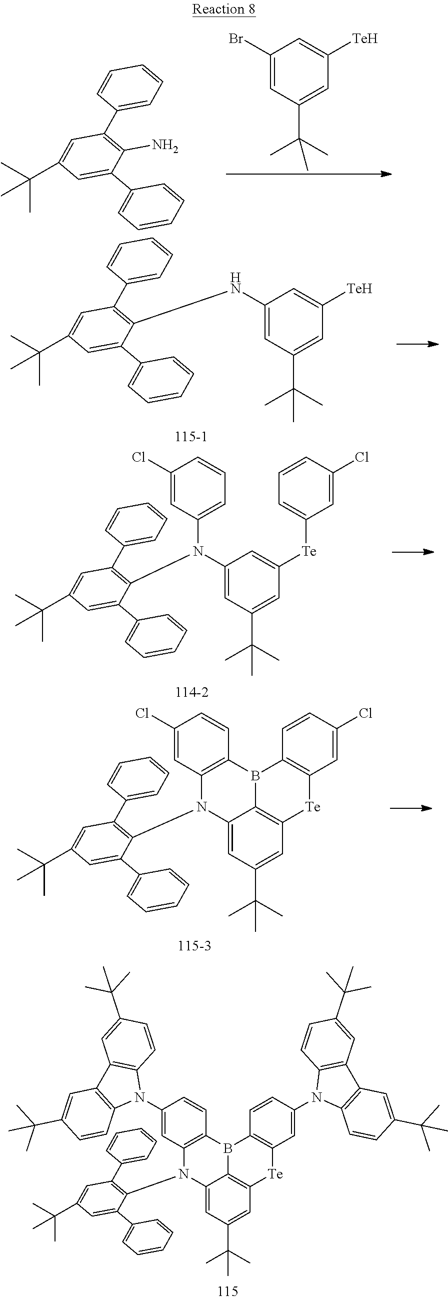

### (1) Synthesis of Intermediate 115-1

Under an argon atmosphere, 5′-(tert-butyl)-[1,1′:3′,1′-terphenyl]-2′-amine (1 eq), 3-bromo-5-(tert-butyl)benzenetellurol (1 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 140° C. for about 12 hours. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel by utilizing CH₂Cl₂ and hexane as developing solvents to obtain Intermediate 115-1 (yield: 74%).

### (2) Synthesis of Intermediate 115-2

Under an argon atmosphere, Intermediate 115-1 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and the reaction solution was stirred at about 160° C. for about 3 days. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Intermediate 115-2 (yield: 61%).

### (3) Synthesis of Intermediate 115-3

Under an argon atmosphere, Intermediate 115-2 (1 eq) was dissolved in o-dichlorobenzene, BBr₃ (5 eq) was slowly added thereto dropwisely at about 0° C., and the reaction solution was stirred at about 180° C. for about 24 hours. After cooling, triethylamine (5 eq) was added to terminate the reaction, and the resultant was extracted with water and CH₂Cl₂. Organic layers were collected, dried over MgSO₄ and filtered. The solvent was removed from the filtrate solution under a reduced pressure, and the resultant was separated and purified by column chromatography utilizing silica gel to obtain Intermediate 115-3 (yield: 31%).

### (4) Synthesis of Compound 115

Under an argon atmosphere, Intermediate 115-3 (1 eq), 3,6-di-tert-butyl-9H-carbazole (2.2 eq), Pd₂(dba)₃ (0.05 eq), tris-tert-butyl phosphine (0.1 eq), and sodium tert-butoxide (3 eq) were added and dissolved in o-xylene, and the reaction solution was stirred at about 160° C. for about 12 hours. After cooling, water and ethyl acetate were added, extraction was performed, and organic layers were collected, dried over MgSO₄ and filtered. The solvent was removed from the filtrate solution under a reduced pressure, and the solid thus obtained was separated and purified by column chromatography utilizing silica gel to obtain Compound 115 (yield: 78%).

The H NMR (δ) and FAB-MS of Compound 2, Compound 36, Compound 50, Compound 87, and Compound 112 to Compound 115, synthesized by the above-described synthetic methods, were measured, and the production of the Example Compounds were confirmed. In Table 1, the H NMR (δ) and FAB-MS of the Example Compounds measured are shown.

TABLE 1

| | | MS/FAB | |
|---|---|---|---|
| Compound | H NMR (δ) | Calc | Found |
| 2 | 1H-NMR (400 MHz, CDCl3): d = 9.05 (s, 2H), 8.28 | 838.34 | 838.34 |
| | (d, 2H), 7.75 (m, 4H), 7.62-7.43(m, 10H), 7.42-7.22 | | |
| | (m, 8H), 7.12-7.07 (m, 4H), 6.89 (s, 1H). | | |
| 36 | 1H-NMR (400 MHz, CDCl3): d = 9.10 (d, 2H), 8.32 | 1270.71 | 1270.69 |
| | (s, 2H), 7.95 (d, 2H), 7.86 (m, 3H), 7.63-7.40(m, | | |
| | 16H), 7.35-7.20 (m, 11H), 7.03 (s, 1H), 6.90 (s, | | |
| | 1H), 1.34 (ss, 36H), 1.20 (ss, 18H). | | |
| 50 | 1H-NMR (400 MHz, CDCl3): d = 9.02 (ss, 2H), 8.20 | 1264.59 | 1264.58 |
| | (d, 2H), 7.73 (m, 4H), 7.69-7.54 (m, 13H), 7.47- | | |
| | 7.25 (m, 11H), 6.97 (s, 1H), 6.88 (s, 1H), 1.32 (ss, 36H). | | |
| 87 | 1H-NMR (400 MHz, CDCl3): d = 9.11 (d, 2H), 8.95 | 938.32 | 938.30 |
| | (s, 1H), 8.20 (d, 2H), 7.86 (m, 3H), 7.75-7.62 (m, | | |
| | 6H), 7.52-7.33 (m, 12H), 7.30-7.11 (m, 6H) 7.07 | | |
| | (s, 1H), 6.91 (s, 1H), 1.41 (s, 9H). | | |
| 112 | 1H-NMR (400 MHz, CDCl3): d = 9.05 (dd, 2H), | 1062.59 | 1062.58 |
| | 8.23 (d, 2H), 7.76 (m, 4H), 7.61-7.53 (m, 5H), 7.48- | | |
| | 7.34 (m, 7H), 7.30-7.11 (m, 5H) 7.05 (s, 1H), | | |
| | 6.99 (s, 1H), 1.32 (s, 36H). | | |
| 113 | 1H-NMR (400 MHz, CDCl3): d = 8.99 (dd, 2H), | 915.45 | 915.43 |
| | 8.20 (d, 2H), 7.75 (m, 2H), 7.51-7.34 (m, 6H), 7.30- | | |
| | 7.18 (m, 7H), 7.01 (s, 1H), 6.96 (s, 1H), 1.32 (s, 9H). | | |
| 114 | 1H-NMR (400 MHz, CDCl3): d = 9.03 (dd, 2H), | 1237.67 | 1237.66 |
| | 8.85(s, 2H), 8.83 (s, 2H), 7.68-7.53 (m, 4H), 7.46- | | |
| | 7.30 (m, 7H), 7.27-7.22 (m, 3H) 7.02 (s, 1H), 6.99 | | |
| | (s, 1H), 1.42 (s, 36H), 1.39 (s, 9H), 1.35 (s, 9H). | | |
| 115 | 1H-NMR (400 MHz, CDCl3): d = 9.01 (dd, 2H), | 1277.60 | 1277.59 |
| | 8.82(s, 2H), 8.79 (s, 2H), 7.87 (dd, 2H), 7.66-7.57 | | |
| | (m, 5H), 7.49-7.24 (m, 9H), 7.20-7.14 (m, 9H), | | |
| | 7.02 (s, 1H), 6.98 (s, 1H), 1.40 (s, 36H), 1.39 (s, | | |
| | 9H), 1.37 (s, 9H). | | |

### 2. Manufacture and Evaluation of Light Emitting Element

Light emitting elements of Examples 1 to 8 and Comparative Examples 1 to 4 were manufactured utilizing Compounds 2, 36, 50, 87 and 112 to 115, and Comparative Compounds C1 to C4 respectively as dopant materials of emission layers.

### Example Compounds

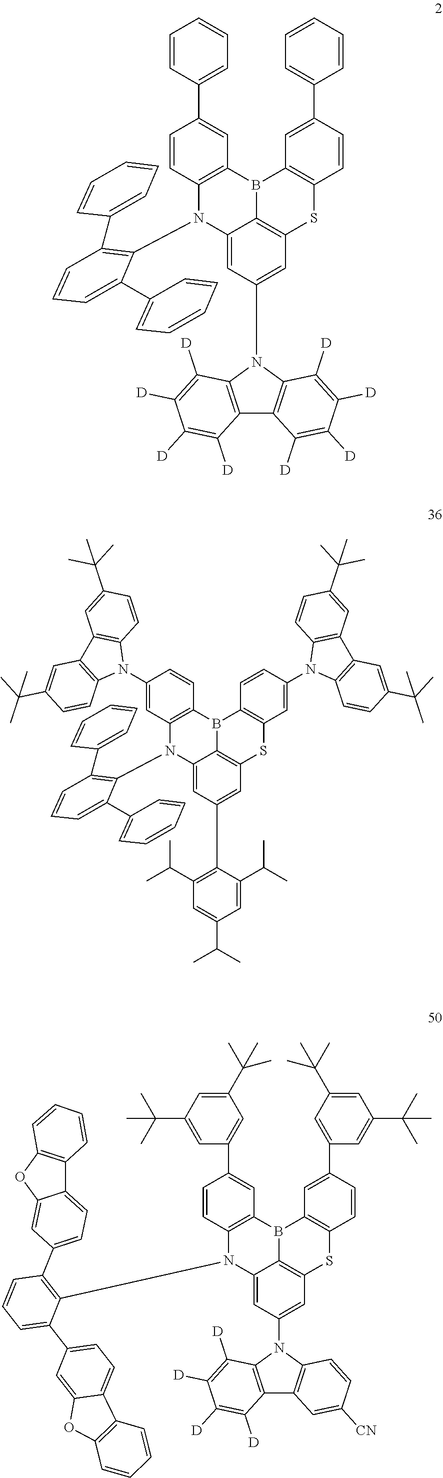

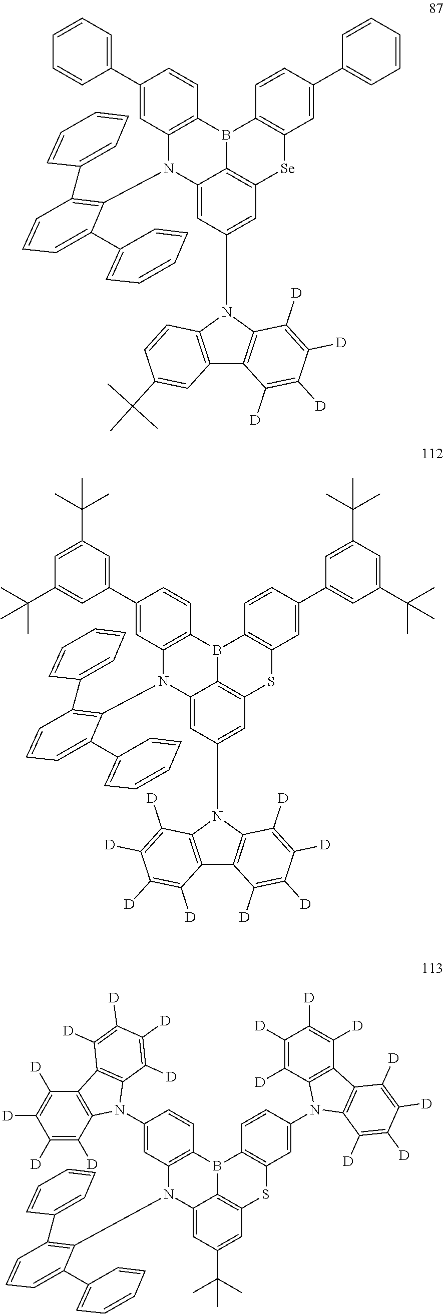

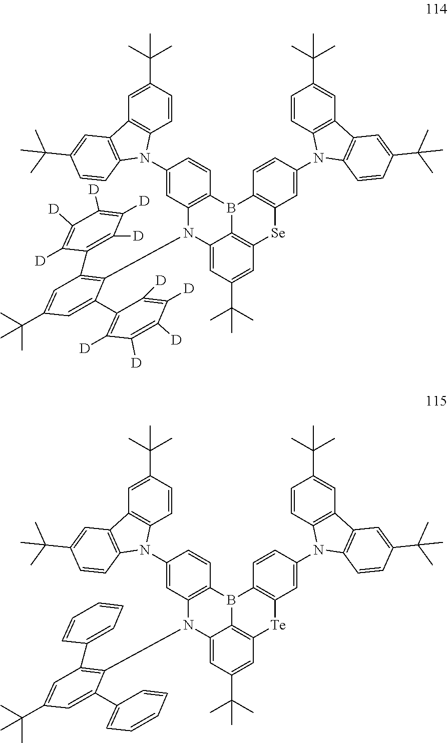

### Comparative Compounds

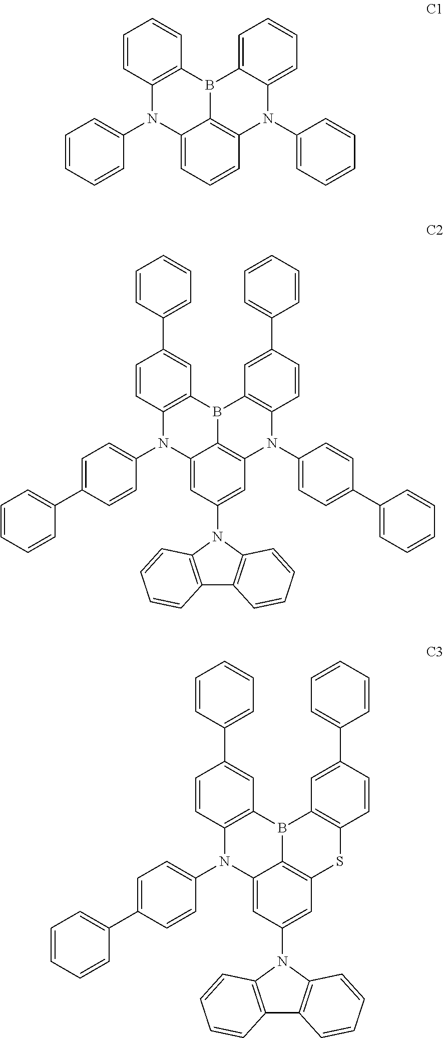 [SMILES: c1ccc(N2c3ccccc3B3c4ccccc4N(c4ccccc4)c4cccc2c43)cc1 ; c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1 ; c1ccc(-c2ccc(N3c4ccc(-c5ccccc5)cc4B4c5cc(-c6ccccc6)ccc5Sc5cc(-n6c7ccccc7c7ccccc76)cc3c54)cc2)cc1]

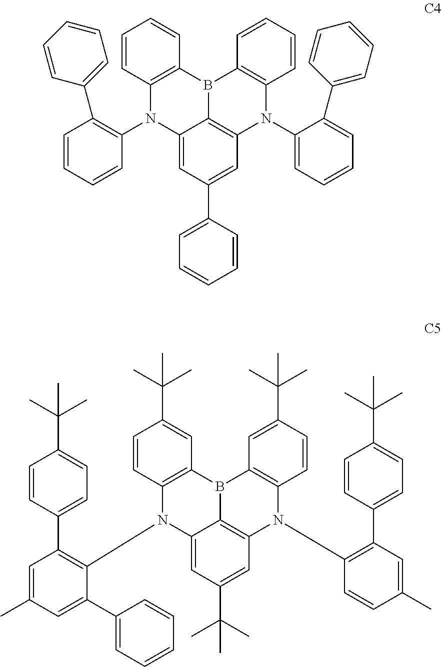

### Manufacture of Light Emitting Element

A glass substrate on which ITO with a thickness of about 150 Å was patterned was cleaned with ultrasonic waves utilizing isopropyl alcohol and pure water for about 5 minutes each. After ultrasonic wave cleaning, UV was irradiated for about 30 minutes and ozone treatment was performed.

Then, a hole injection layer of a thickness of about 300 Å was formed utilizing NPD, and on the hole injection layer, HT6 was deposited to form a hole transport layer of a thickness of about 200 Å. On the hole transport layer, a hole transport compound CzSi was deposited to form an emission auxiliary layer of a thickness of about 100 Å.

Then, a respective one of the Example Compound or Comparative Compound and mCBP were co-deposited to form an emission layer of a thickness of about 200 Å. The Example Compound or Comparative Compound and mCBP were co-deposited in a weight ratio of about 1:99. During the manufacture of a light emitting element, the Example Compound or Comparative Compound was utilized as a dopant material.

After that, on the emission layer, TSPO1 was deposited to form an electron transport layer of a thickness of about 200 Å, and on the electron transport layer, a buffer electron transport compound of TPBI was deposited to form a buffer layer of a thickness of about 300 Å.

On the buffer layer, LiF, an alkali metal halide, was deposited to form an electron injection layer of a thickness of about 10 Å, and Al was deposited to form a LiF/Al electrode (second electrode) of a thickness of about 3000 Å. On the electrode, P4 was deposited to form a capping layer of a thickness of about 700 Å to complete the manufacturing of a light emitting element.

The hole transport region, emission layer, electron transport region and the second electrode were formed utilizing a vacuum deposition apparatus.

The compounds utilized for the manufacture of the light emitting elements of the Examples and Comparative Examples are shown below. The materials were utilized for the manufacture of the elements after purchasing commercial products and performing sublimation purification.

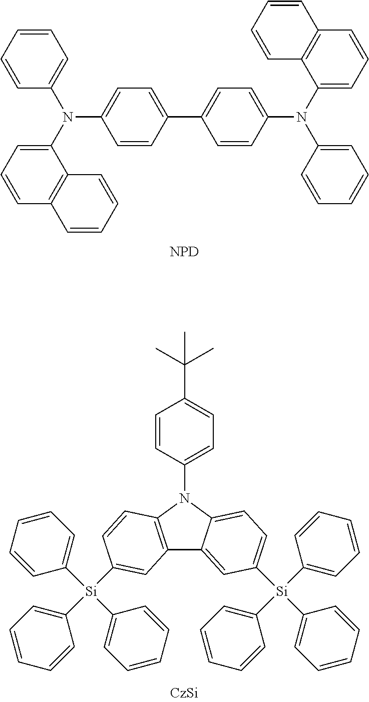

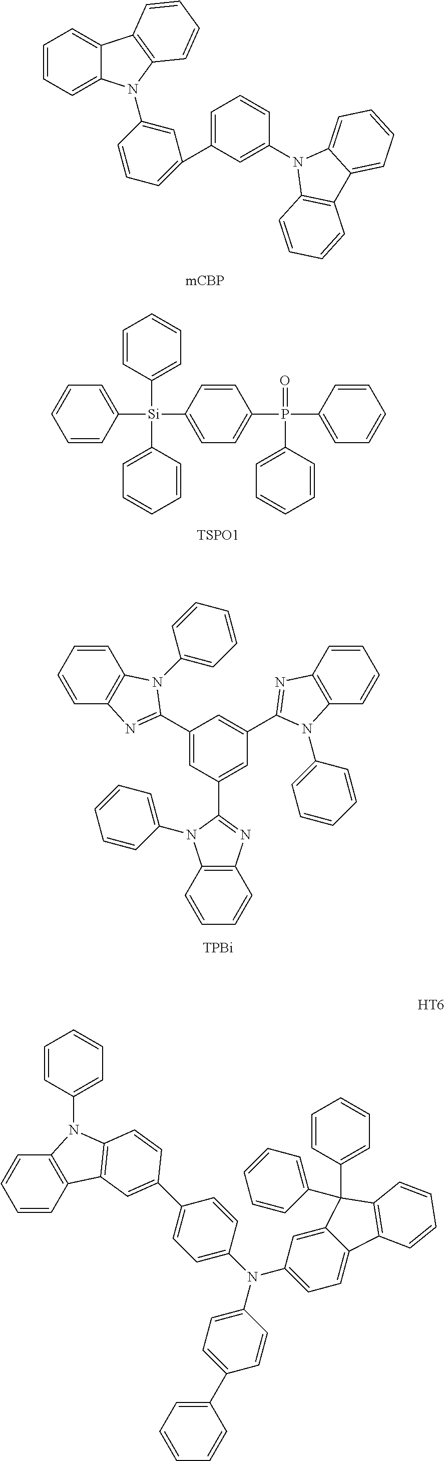

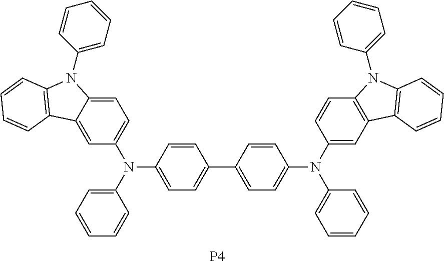 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; "P4"]

### Evaluation of Physical Properties of the Example Compounds and Comparative Compounds

The physical properties of the Example Compounds, i.e., Compound 2, Compound 36, Compound 50, Compound 87, Compound 112, Compound 113, Compound 114, and Compound 115, and the Comparative Compounds C1 to C4 were evaluated and shown in Table 2 and Table 3.

In Table 2 and Table 3, the lowest unoccupied molecular orbital (LUMO) energy level, the highest occupied molecular orbital (HOMO) energy level, the lowest excitation singlet energy level (Si), the lowest excitation triplet energy level (Ti), a difference (S1-T1, hereinafter, ΔE_{ST}) between the lowest excitation singlet energy level (S1) and the lowest excitation triplet energy level (T1), k_{RISC} (RISC transition rate), (RISC transition time), emission efficiency (PLY, Photoluminescence Quantum Yield), λ_{Abs} (maximum absorption wavelength), λₑₘᵢ (maximum emission wavelength), A_{film} (maximum emission wavelength), Stokes-shift (difference between λ_{Abs} and λₑₘᵢ), and the full width at quarter maximum (FWQM) of each of the Example Compounds and Comparative Compounds were measured. λₑₘᵢ is the maximum emission wavelength of the Example Compound or Comparative Compound in a solution state, and λfilm is the maximum emission wavelength of the Example Compound or Comparative Compound in a film state (e.g., solid state) formed in an element.

TABLE 2

| | | HOMO | LUMO | S1 | T1 | ΔE_{ST} | K_{RISC} | t |
|---|---|---|---|---|---|---|---|---|
| Division | Dopant | (eV) | (eV) | (eV) | (eV) | (eV) | (S⁻¹) | (ms) |
| Example 1 | Compound 2 | −5.29 | −2.38 | 2.71 | 2.54 | 0.17 | 1.1 × 10⁻⁸ | 14 |
| Example 2 | Compound | −5.36 | −2.17 | 2.70 | 2.56 | 0.14 | 6.7 × 10⁻⁷ | 32 |
| | 36 | | | | | | | |
| Example 3 | Compound | −5.43 | −2.23 | 2.71 | 2.57 | 0.14 | 2.4 × 10⁻⁸ | 12 |
| | 50 | | | | | | | |
| Example 4 | Compound | −5.37 | −2.35 | 2.71 | 2.59 | 0.12 | 1.3 × 10⁻¹² | 6 |
| | 87 | | | | | | | |
| Example 5 | Compound | −5.35 | −2.38 | 2.72 | 2.58 | 0.14 | 3.3 × 10⁻⁸ | 11 |
| | 112 | | | | | | | |
| Example 6 | Compound | −5.36 | −2.42 | 2.68 | 2.56 | 0.12 | 8.1 × 10⁻⁷ | 28 |
| | 113 | | | | | | | |
| Example 7 | Compound | −5.26 | −2.34 | 2.70 | 2.54 | 0.16 | 2.7 × 10⁻¹² | 9 |
| | 114 | | | | | | | |
| Example 8 | Compound | −5.33 | −2.46 | 2.70 | 2.55 | 0.15 | 0.3 × 10⁻¹⁴ | 1 |
| | 115 | | | | | | | |
| Comparative | Comparative | −5.12 | −2.33 | 2.72 | 2.51 | 0.21 | 2.2 × 10⁻⁴ | 133 |
| Example | Compound | | | | | | | |
| 1 | C1 | | | | | | | |
| Comparative | Comparative | −5.29 | −2.38 | 2.71 | 2.54 | 0.17 | 1.4 × 10⁻⁵ | 38 |
| Example | Compound | | | | | | | |
| 2 | C2 | | | | | | | |
| Comparative | Comparative | −5.29 | −2.38 | 2.71 | 2.54 | 0.17 | 1.1 × 10⁻⁶ | 30 |
| Example | Compound | | | | | | | |
| 3 | C3 | | | | | | | |
| Comparative | Comparative | −5.12 | −2.43 | 2.70 | 2.52 | 0.18 | 5.2 × 10⁻⁴ | 101 |
| Example | Compound | | | | | | | |
| 4 | C4 | | | | | | | |
| Comparative | Comparative | −5.18 | −2.39 | 2.72 | 2.55 | 0.18 | 3.8 × 10⁻⁴ | 110 |
| Example | Compound | | | | | | | |
| 5 | C5 | | | | | | | |

TABLE 3

| | | PLQY | λ_{Abs} | λₑₘᵢ | λ_{film} | Stokes- | FWQM |
|---|---|---|---|---|---|---|---|
| Division | Dopant | (%) | (nm) | (nm) | (nm) | shift | (nm) |
| Example 1 | Compound 2 | 93 | 447 | 457 | 458 | 10 | 36 |
| Example 2 | Compound 36 | 95 | 446 | 459 | 460 | 13 | 36 |
| Example 3 | Compound 50 | 91 | 445 | 455 | 457 | 10 | 36 |
| Example 4 | Compound 87 | 99 | 444 | 456 | 458 | 12 | 35 |
| Example 5 | Compound | 96 | 444 | 455 | 457 | 11 | 35 |
| | 112 | | | | | | |
| Example 6 | Compound | 94 | 448 | 458 | 460 | 10 | 34 |
| | 113 | | | | | | |
| Example 7 | Compound | 97 | 448 | 457 | 459 | 9 | 35 |
| | 114 | | | | | | |
| Example 8 | Compound | 93 | 445 | 457 | 459 | 12 | 34 |
| | 115 | | | | | | |
| Comparative | Comparative | 91 | 444 | 456 | 465 | 12 | 39 |
| Example | Compound C1 | | | | | | |
| 1 | | | | | | | |
| Comparative | Comparative | 86 | 446 | 458 | 462 | 12 | 33 |
| Example | Compound C2 | | | | | | |
| 2 | | | | | | | |
| Comparative | Comparative | 85 | 445 | 458 | 461 | 13 | 35 |
| Example | Compound C3 | | | | | | |
| 3 | | | | | | | |
| Comparative | Comparative | 86 | 447 | 460 | 464 | 13 | 37 |
| Example | Compound C4 | | | | | | |
| 4 | | | | | | | |
| Comparative | Comparative | 87 | 442 | 454 | 459 | 12 | 37 |
| Example | Compound C5 | | | | | | |
| 5 | | | | | | | |

Referring to Table 2 and Table 3 above, it was confirmed that the compounds of Example 1 to Example 8 and Comparative Example 1 to Comparative Example 5 each have ΔE_{ST} values of about 0.2 eV or less and may be utilized as TADF dopant materials. The compounds of Example 1 to Example 8 and Comparative Example 1 to Comparative Example 5 have similar λ_{Abs} and λₑₘᵢ values. However, when comparing λ_{film} values, it could be confirmed that the elements including the compounds of Example 1 to Example 8 have the maximum emission wavelength values closer to about 460 nm when compared to the elements including the compounds of Comparative Example 1 to Comparative Example 5. That is, the light emitting elements of the Examples each emit light with more pure blue color when compared to the light emitting elements of the Comparative Examples.

In addition, it could be confirmed that the Example Compounds included in Example 1 to Example 8 each have smaller k_{RISC} and t, higher emission efficiency (PLQY) and smaller full width at quarter maximum when compared to the compounds included in Comparative Example 1 to Comparative Example 5. In the case of Stokes-shift, it could be confirmed that the average value of the Stokes-shift of the Examples Compounds included in Example 1 to Example 8 is smaller than the average value of the Stokes-shift of the compounds included in Comparative Example 1 to Comparative Example 5.

Accordingly, the light emitting elements of Example 1 to Example 8 could show (e.g., are capable of delivering) higher emission efficiency, improved element life, and higher color purity when compared to the light emitting elements of Comparative Example 1 to Comparative Example 5.

### Evaluation of Properties of Light Emitting Elements

The evaluation of the properties of the light emitting elements manufactured was conducted utilizing a measurement apparatus of brightness orientation properties.

In order to evaluate the properties of the light emitting elements according to the Examples and Comparative Examples, driving voltages, emission efficiency, emission wavelengths, life ratios, color coordinates (CIE) and quantum efficiency (Q.E.) were measured and shown in Table 4.

Table 4 shows the evaluation results of light emitting elements that include a hole transport host, an electron transport host, and a dopant in an emission layer.

In Table 4, a driving voltage (V) and emission efficiency (cd/A) were measured at a current density of 10 mA/cm² for the light emitting elements manufactured. The life ratio was obtained by first measuring the time it took for the luminance to decrease from an initial value to 50% of the initial value when continuously driving at a current density of 10 mA/cm², and then calculating a relative value based on the life ratio of Comparative Example 1 as 1.

In Table 4, HT6 was utilized as the hole transport host, and E-2-20 was utilized as the electron transport host.

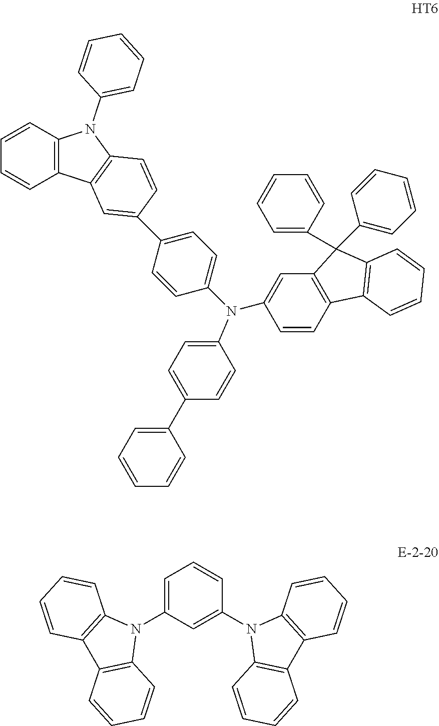 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1cc(-n2c3ccccc3c3ccccc32)cc(-n2c3ccccc3c3ccccc32)c1]

TABLE 4

| | | Driving | Emission | Emission | Life | | |
|---|---|---|---|---|---|---|---|
| | | voltage | efficiency | wavelength | ratio | | Q.E |
| Division | Dopant | (V) | (cd/A) | (nm) | (T95) | CIE (x, y) | (%) |
| Example 1 | Compound | 4.4 | 7.9 | 459 | 2.6 | 0.140, | 10.1 |
| | 2 | | | | | 0.103 | |
| Example 2 | Compound | 4.5 | 8.2 | 462 | 2.8 | 0.138, | 10.3 |
| | 36 | | | | | 0.108 | |
| Example 3 | Compound | 4.5 | 7.9 | 460 | 2.4 | 0.141, | 10.0 |
| | 50 | | | | | 0.116 | |
| Example 4 | Compound | 4.4 | 8.1 | 458 | 2.6 | 0.141, | 10.2 |
| | 87 | | | | | 0.113 | |
| Example 5 | Compound | 4.4 | 8.2 | 457 | 2.7 | 0.142, | 10.2 |
| | 112 | | | | | 0.110 | |
| Example 6 | Compound | 4.3 | 8.4 | 459 | 3.2 | 0.141, | 10.4 |
| | 113 | | | | | 0.111 | |
| Example 7 | Compound | 4.4 | 8.3 | 458 | 3.2 | 0.141, | 10.3 |
| | 114 | | | | | 0.112 | |
| Example 8 | Compound | 4.4 | 8.3 | 458 | 3.0 | 0.141, | 10.3 |
| | 115 | | | | | 0.113 | |
| Comparative | Compound | 5.5 | 2.4 | 462 | 1.0 | 0.133, | 3.0 |
| Example | C1 | | | | | 0.135 | |
| 1 | | | | | | | |
| Comparative | Compound | 4.9 | 7.3 | 461 | 1.4 | 0.134, | 7.2 |
| Example | C2 | | | | | 0.098 | |
| 2 | | | | | | | |
| Comparative | Compound | 4.9 | 7.3 | 461 | 1.5 | 0.134, | 7.3 |
| Example | C3 | | | | | 0.100 | |
| 3 | | | | | | | |
| Comparative | Compound | 4.8 | 6.8 | 461 | 1.2 | 0.133, | 5.9 |
| Example | C4 | | | | | 0.099 | |
| 4 | | | | | | | |
| Comparative | Compound | 4.9 | 5.6 | 459 | 1.1 | 0.141, | 5.5 |
| Example | C5 | | | | | 0.113 | |
| 5 | | | | | | | |

Referring to Table 4, the light emitting elements of Example 1 to Example 8 each showed lower driving voltages, higher emission efficiency, improved element life and higher quantum efficiency when compared to the light emitting elements of Comparative Example 1 to Comparative Example 5.

In order to evaluate the properties of the light emitting elements according to the Examples and Comparative Examples, driving voltages, emission efficiency, emission wavelengths, half widths, life ratios, color coordinates (CIE) and quantum efficiency (Q.E.) were measured and shown in Table 5.

Table 5 shows the evaluation results of light emitting elements that include a hole transport host, an electron transport host, a dopant, and a sensitizer in an emission layer.

In Table 5, a driving voltage (V) and emission efficiency (cd/A) were measured at a current density of 10 mA/cm² for the light emitting elements manufactured. The life ratio was obtained by first measuring the time it took for the luminance to reduce from an initial value to 50% of the initial value when continuously driving at a current density of 10 mA/cm², and then calculating a relative value based on the life ratio of Comparative Example 1 as 1.

In Table 5, HT6 was utilized as the hole transport host, E-2-20 was utilized as the electron transport host, and AD-37 was utilized as the sensitizer.

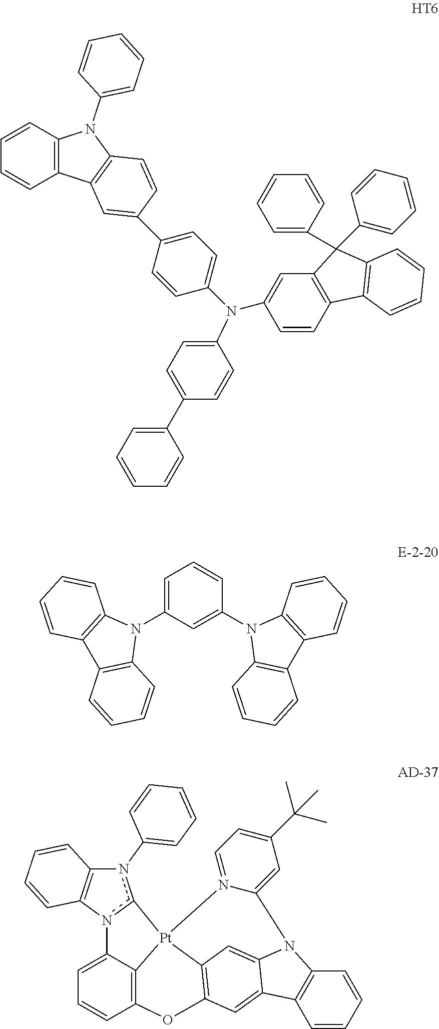

TABLE 5

| | | Driving | Emission | Emission | Half | Life | | |
|---|---|---|---|---|---|---|---|---|
| | | voltage | efficiency | wavelength | width | ratio | CIE | Q.E |
| Division | Dopant | (V) | (cd/A) | (nm) | (nm) | (T95) | (x, y) | (%) |
| Example 1 | Compound | 4.4 | 22.3 | 458 | 46 | 14.7 | 0.138, | 24.7 |
| | 2 | | | | | | 0.156 | |
| Example 2 | Compound | 4.3 | 23.8 | 460 | 48 | 15.0 | 0.136, | 24.9 |
| | 36 | | | | | | 0.146 | |
| Example 3 | Compound | 4.4 | 21.7 | 457 | 47 | 14.6 | 0.135, | 25.7 |
| | 50 | | | | | | 0.145 | |
| Example 4 | Compound | 4.5 | 25.8 | 458 | 46 | 13.4 | 0.138, | 29.3 |
| | 87 | | | | | | 0.156 | |
| Example 5 | Compound | 4.4 | 21.9 | 457 | 47 | 15.7 | 0.135, | 23.7 |
| | 112 | | | | | | 0.145 | |
| Example 6 | Compound | 4.4 | 22.6 | 460 | 46 | 12.1 | 0.136, | 26.1 |
| | 113 | | | | | | 0.146 | |
| Example 7 | Compound | 4.5 | 26.3 | 459 | 46 | 10.9 | 0.135, | 27.8 |
| | 114 | | | | | | 0.145 | |
| Example 8 | Compound | 4.4 | 28.9 | 459 | 47 | 8.7 | 0.135, | 32.1 |
| | 115 | | | | | | 0.145 | |
| Comparative | Compound | 4.9 | 13.3 | 465 | 48 | 1.0 | 0.137, | 13.4 |
| Example 1 | C1 | | | | | | 0.158 | |
| Comparative | Compound | 4.8 | 15.0 | 462 | 50 | 2.4 | 0.133, | 16.3 |
| Example 2 | C2 | | | | | | 0.142 | |
| Comparative | Compound | 4.8 | 16.3 | 462 | 48 | 2.7 | 0.134, | 17.3 |
| Example 3 | C3 | | | | | | 0.145 | |
| Comparative | Compound | 4.9 | 15.2 | 464 | 48 | 2.0 | 0.133, | 16.4 |
| Example 4 | C4 | | | | | | 0.144 | |
| Comparative | Compound | 4.9 | 15.0 | 459 | 47 | 1.4 | 0.135, | 16.3 |
| Example 5 | C5 | | | | | | 0.144 | |

Referring to Table 5, the light emitting elements of Example 1 to Example 8 each showed lower driving voltage, higher emission efficiency, improved element life and higher quantum efficiency when compared to the light emitting elements of Comparative Example 1 to Comparative Example 5. In addition, light emitted from the light emitting elements of Example 1 to Example 8 each has a half width in a range of about 46 nm to about 48 nm, and light emitted from the light emitting elements of Comparative Example 1 to Comparative Example 5 each has a half width in a range of about 48 nm to about 50 nm. Accordingly, it could be confirmed that the light emitting elements of Example 1 to Example 8 showed higher color purity properties when compared to the light emitting elements of Comparative Example 1 to Comparative Example 5.

Referring to Table 4 and Table 5 together, Comparative Compounds C1, C2, C4 and C5 did not include a heavy atom in a fused ring, and the transition properties of a molecule were deteriorated when compared to the elements of the Examples, and for example, reverse intersystem crossing was not active, and element life was reduced. In addition, in the cases of Comparative Compounds C1, C2 and C4, a phenyl group or a biphenyl group instead of an ortho-type or kind terphenyl group was connected to a nitrogen atom in a fused ring, and intermolecular interaction might become active, and emission efficiency might be deteriorated when compared to the Examples.

Comparative Compound C3 included a heavy atom in a fused ring, but a biphenyl group instead of an ortho-type or kind terphenyl group was connected with the fused ring, and the p-orbital of the boron atom of Comparative Compound C3 could not be protected but was connected with an external nucleophile to induce element deterioration. In addition, in Comparative Compound C3, a biphenyl group instead of an ortho-type or kind terphenyl group was connected with the fused ring, and intermolecular interaction (intermolecular aggregation excimer formation, exciplex formation, and/or the like) which might be the factor reducing emission efficiency, might become relatively active, and emission efficiency of an element was deteriorated.

The polycyclic compound of the present disclosure includes a fused ring skeleton containing a boron atom, a nitrogen atom and a heavy atom as ring-forming atoms, and an ortho-type or kind terphenyl group connected with the nitrogen atom of the fused ring skeleton, and reverse intersystem crossing in a molecule may become easy, material stability may be improved, and intermolecular interaction may be reduced.

For example, the polycyclic compound of the present disclosure includes a heavy atom, and the transition properties in a molecule may be improved, for example, the transition rate of excitons from a triplet to a single may increase, and the time of reverse intersystem crossing (RISC) may be reduced, thereby reducing the concentration of triplet excitons having an unstable state. Accordingly, energy transfer efficiency may be improved, and emission efficiency may be further improved. The light emitting element of an embodiment includes the polycyclic compound of an embodiment as the light emitting dopant of a thermally activated delayed fluorescence (TADF) emitting element, and high element efficiency particularly in a blue light wavelength region may be achieved.

The ortho-type or kind terphenyl group included in the polycyclic compound protects the p-orbital of a boron atom, and may prevent or reduce the deformation of the trigonal bond structure of the boron atom, which may be a cause of element deterioration. Accordingly, the polycyclic compound of the present disclosure may achieve the improvement of element life. In addition, the ortho-type or kind terphenyl group increases intermolecular distance, and the polycyclic compound of the present disclosure may relatively reduce intermolecular interaction such as intermolecular aggregation, excimer formation, and/or exciplex formation, which may cause reduced emission efficiency.

A light emitting element including the polycyclic compound of the present disclosure as the dopant of an emission layer may show markedly improved lifetime and increased emission efficiency.

The light emitting element of an embodiment includes the polycyclic compound of an embodiment and may show high efficiency and long-life characteristics.

The polycyclic compound of an embodiment includes a polycyclic group having large steric effects and may contribute to the improvement of the life (e.g., lifespan) and the increase of the emission efficiency of a light emitting element.

As used herein, the term “and/or” includes any and all combinations of one or more of the associated listed items. Throughout the disclosure, the expression “at least one of a, b or c”, “at least one selected from a, b, and c”, “at least one selected from the group consisting of a, b, and c”, “at least one selected from among a, b, and c”, etc., indicates only a, only b, only c, both (e.g., simultaneously) a and b, both (e.g., simultaneously) a and c, both (e.g., simultaneously) b and c, all of a, b, and c, or variations thereof.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed, and equivalents thereof.

What is claimed is:

1. A light emitting element, comprising:
a first electrode;
a second electrode facing the first electrode; and
at least one functional layer between the first electrode and the second electrode,
wherein the at least one functional layer comprises:
a first compound represented by Formula 1; and
at least one compound selected from among a second compound represented by Formula 2, a third compound represented by Formula 3, and a fourth compound represented by Formula 4: 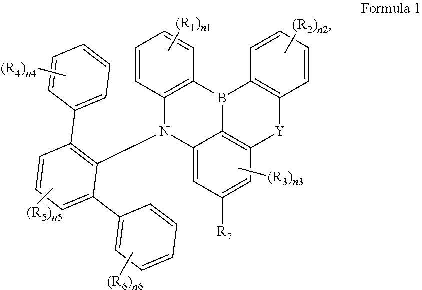
in Formula 1,
Y is S, Se, or Te,
R₁ to R₇ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
n1 and n2 are each independently an integer of 0 to 4,
n3 is an integer of 0 to 2,
n4 is an integer of 0 to 5,
n5 is an integer of 0 to 3, and
n6 is an integer of 0 to 5, 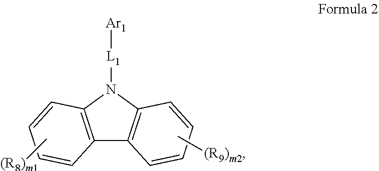
in Formula 2,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Ar₁ is a substituted or unsubstituted aryl group of 6 to 30 ring-forming carbon atoms, or a substituted or unsubstituted heteroaryl group of 2 to 30 ring-forming carbon atoms,
R₈ and R₉ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and
m1 and m2 are each independently an integer of 0 to 4, 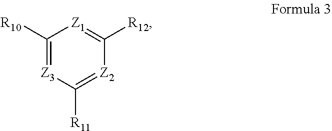
in Formula 3,
Z₁, Z₂ and Z₃ are each independently N or CR₁₃, and at least one thereof is N, and
R₁₀ to R₁₃ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, 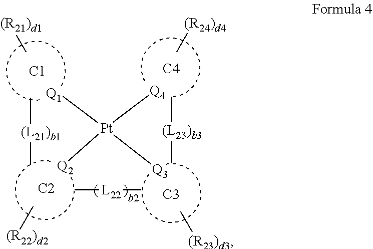
in Formula 4,
Q₁ to Q₄ are each independently C or N,
C1 to C4 are each independently a substituted or unsubstituted hydrocarbon ring of 5 to 30 ring-forming carbon atoms, or a substituted or unsubstituted heterocycle of 2 to 30 ring-forming carbon atoms,
L₂₁ to L₂₃ are each independently a direct linkage, 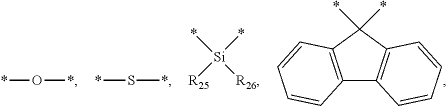
a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b1 to b3 are each independently 0 or 1,
R₂₁ to R₂₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and
d1 to d4 are each independently an integer of 0 to 4.

2. The light emitting element of claim 1, wherein the at least one functional layer comprises an emission layer, a hole transport region between the first electrode and the emission layer, and an electron transport region between the emission layer and the second electrode, and
the emission layer comprises:
the first compound; and
at least one compound selected from among the second compound, the third compound, and the fourth compound.

3. The light emitting element of claim 2, wherein the emission layer is to emit delayed fluorescence.

4. The light emitting element of claim 2, wherein the emission layer is to emit light having a central wavelength of about 430 nm to about 490 nm.

5. The light emitting element of claim 1, wherein the at least one functional layer comprises the first compound, the second compound, and the third compound.

6. The light emitting element of claim 1, wherein the at least one functional layer comprises the first compound, the second compound, the third compound, and the fourth compound.

7. The light emitting element of claim 1, wherein the first compound represented by Formula 1 is represented by any one selected from among Formula 1-1a to Formula 1-1h: 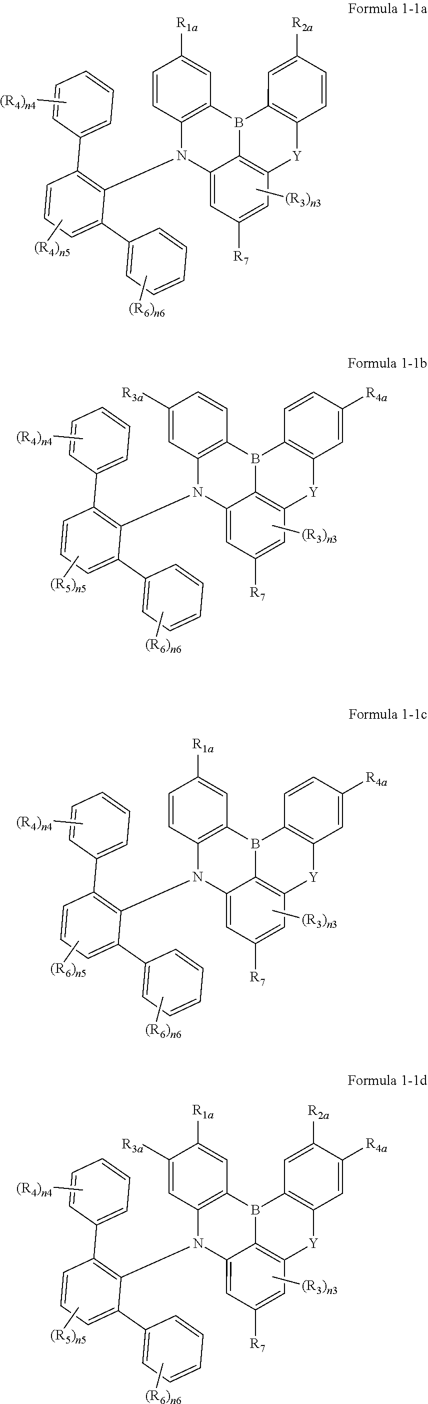 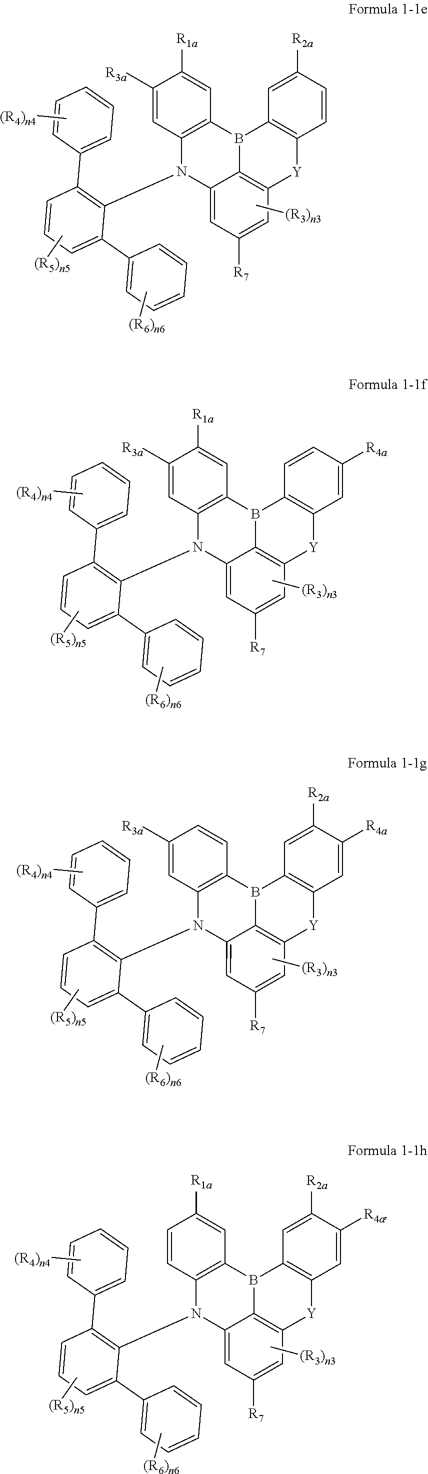
in Formula 1-1a to Formula 1-1h,
R₁ₐ to R₄ₐ are each independently a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and
R₃ to R₇, Y, and n3 to n6 are the same as respectively defined in Formula 1.

8. The light emitting element of claim 7, wherein R₁ₐ to R₄ₐ are each independently a substituted or unsubstituted t-butyl group, a substituted or unsubstituted phenyl group, a substituted or unsubstituted biphenyl group, a substituted or unsubstituted naphthyl group, a substituted or unsubstituted terphenyl group, a substituted or unsubstituted pyridine group, or a substituted or unsubstituted carbazole group, and/or combined with an adjacent group to form a ring.

9. The light emitting element of claim 1, wherein R₁ and R₂ are each independently a hydrogen atom, a substituted or unsubstituted t-butyl group, a substituted or unsubstituted phenyl group, a substituted or unsubstituted biphenyl group, a substituted or unsubstituted naphthyl group, a substituted or unsubstituted terphenyl group, a substituted or unsubstituted pyridine group, or a substituted or unsubstituted carbazole group, and/or combined with an adjacent group to form a ring.

10. The light emitting element of claim 1, wherein R₃ is a hydrogen atom.

11. The light emitting element of claim 1, wherein R₄ and R₆ are each independently a hydrogen atom, a deuterium atom, a halogen atom, a cyano group, a substituted or unsubstituted silyl group, a substituted or unsubstituted alkoxy group, a substituted or unsubstituted methyl group, a substituted or unsubstituted t-butyl group, a substituted or unsubstituted cyclohexyl group, a substituted or unsubstituted phenyl group, or a substituted or unsubstituted carbazole group, and/or combined with an adjacent group to form a ring.

12. The light emitting element of claim 1, wherein R₅ is a hydrogen atom or a substituted or unsubstituted t-butyl group.

13. The light emitting element of claim 1, wherein R₇ is a hydrogen atom, a substituted or unsubstituted methyl group, a substituted or unsubstituted t-butyl group, a substituted or unsubstituted cyclohexyl group, a substituted or unsubstituted silyl group, a substituted or unsubstituted amine group, a substituted or unsubstituted phenyl group, a substituted or unsubstituted pyridine group, a substituted or unsubstituted carbazole group, a substituted or unsubstituted dibenzofuran group, or a substituted or unsubstituted dibenzothiophene group.

14. The light emitting element of claim 1, wherein R₇ is a substituent of substituents represented in Substituent Group S1: 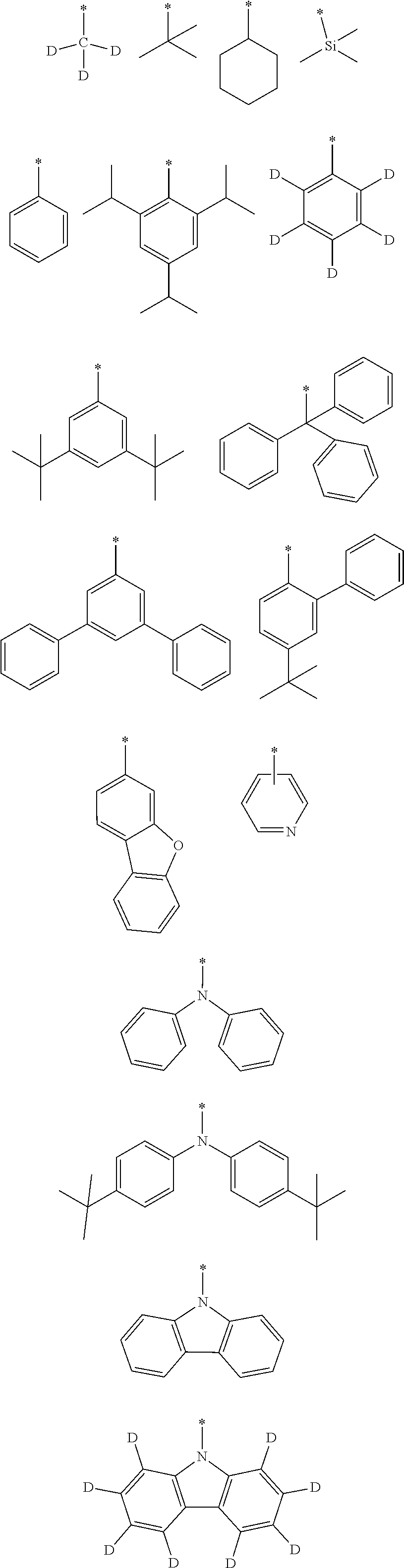 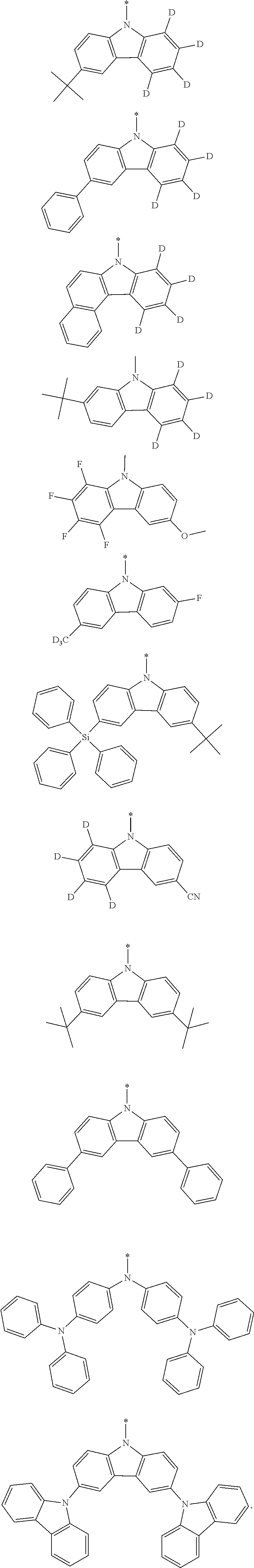
in Substituent Group S₁, D is a deuterium atom, and
“ [symbol] ” indicates a position where R₇ is connected with Formula 1.

15. The light emitting element of claim 1, wherein the first compound is any one of compounds in Compound Group 1: 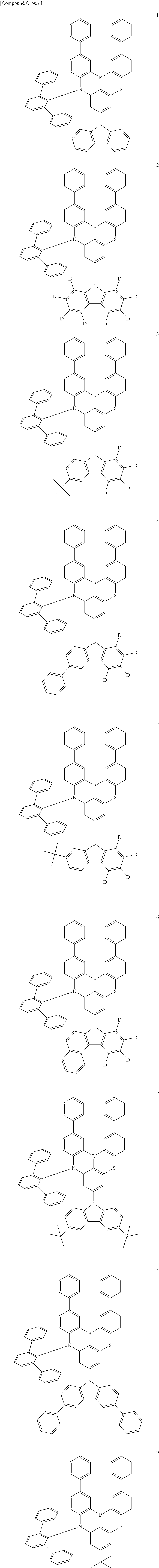 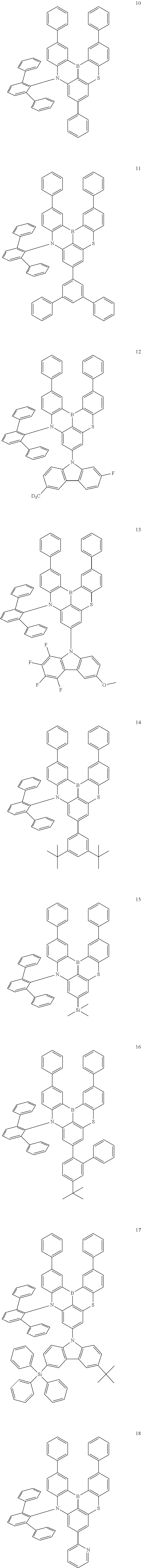 [chemical structure] 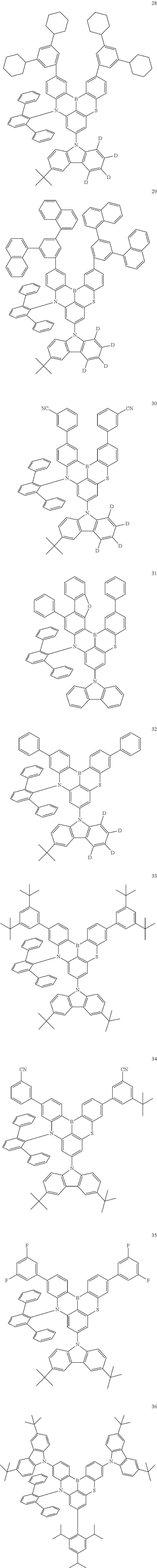 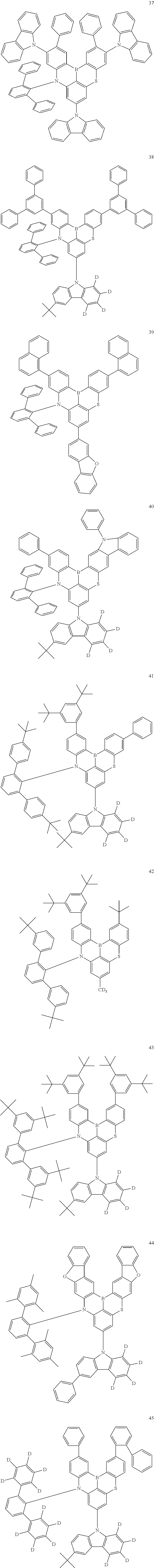 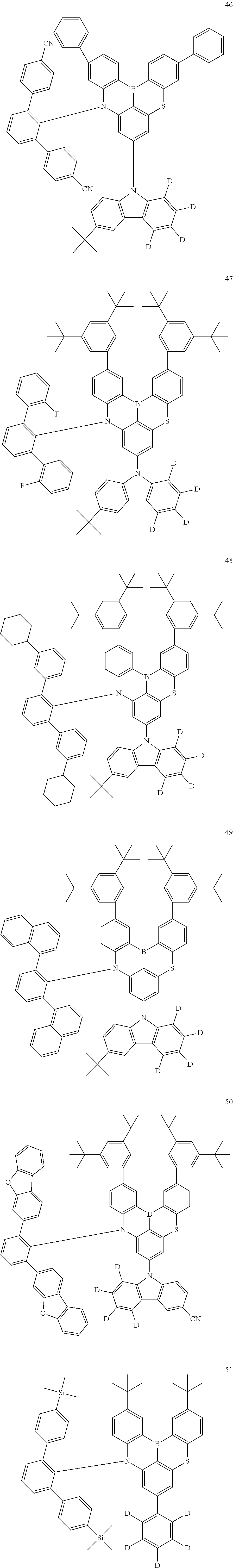 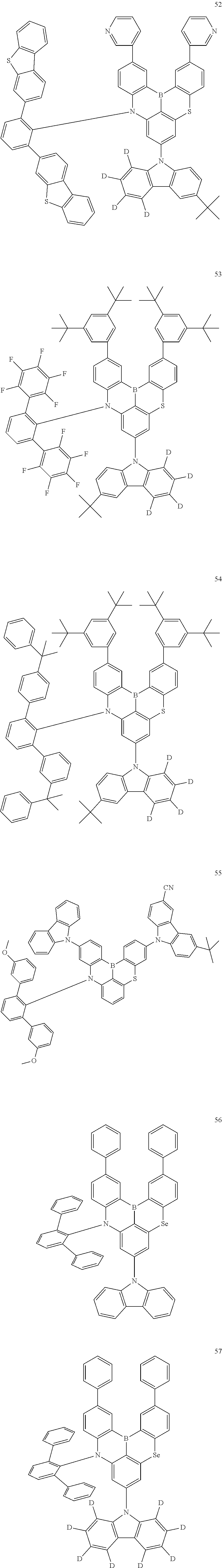 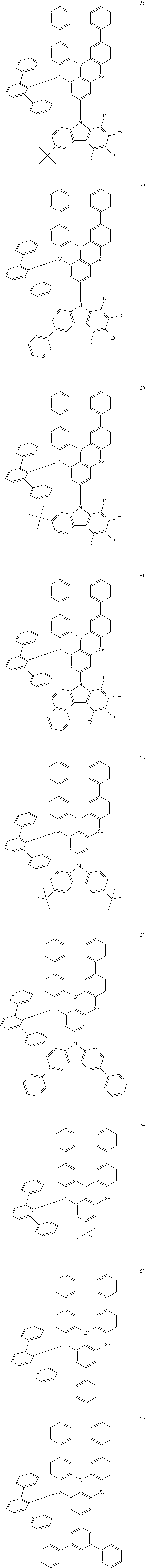 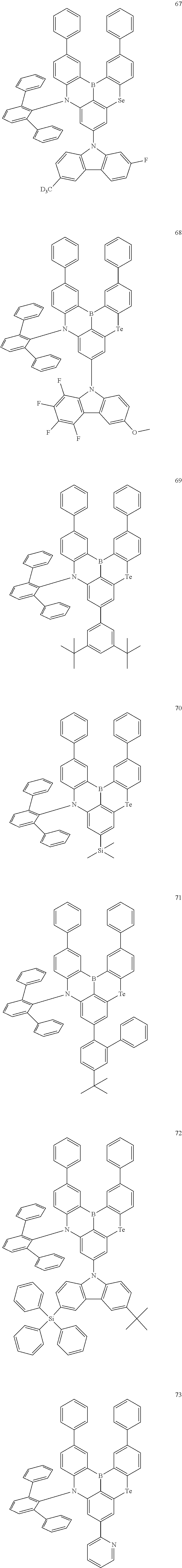 [chemical structure] 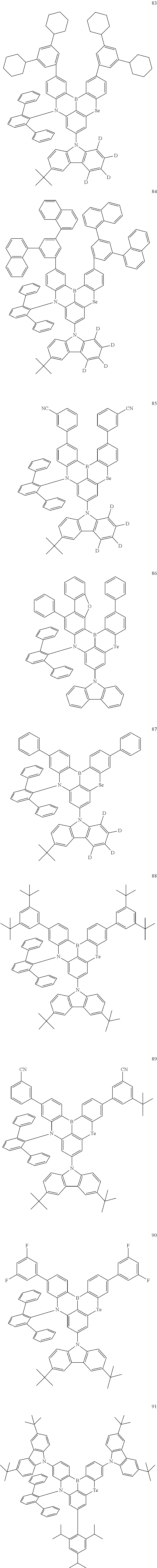 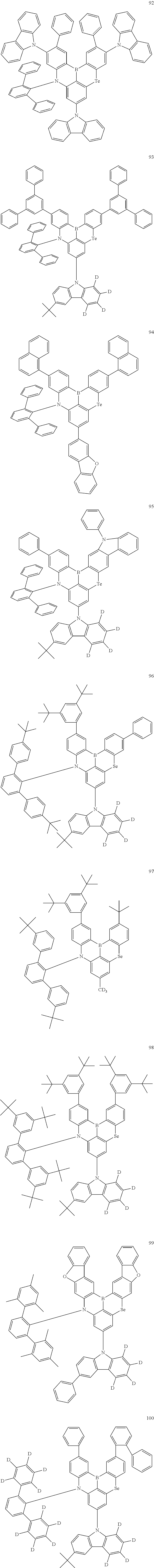 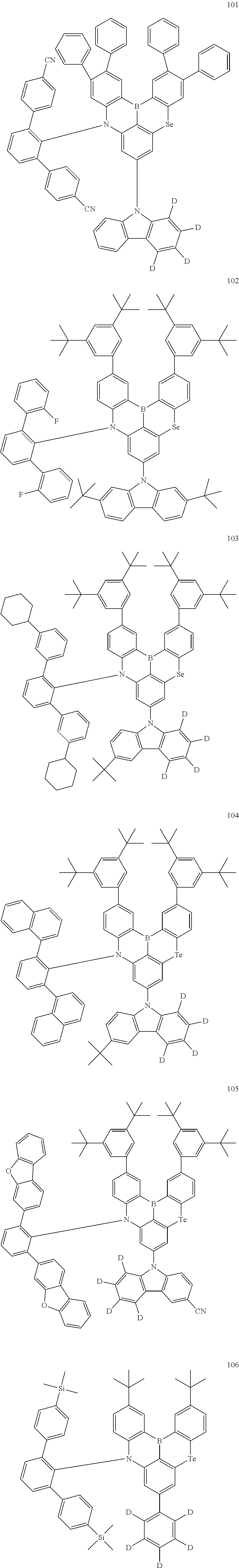 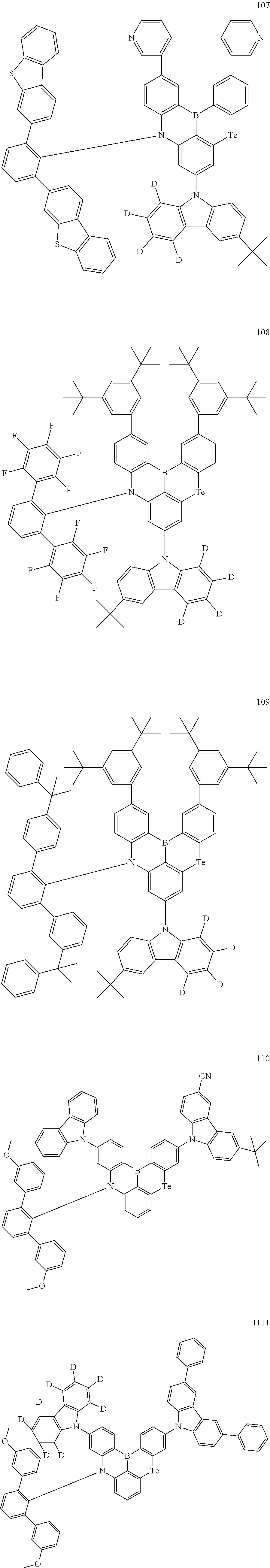 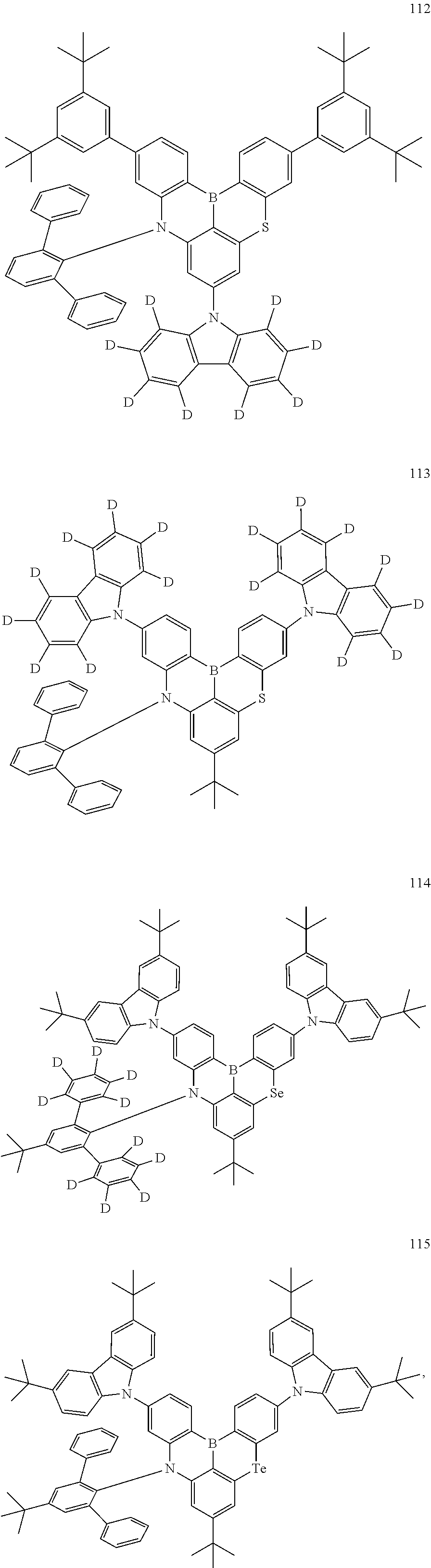
in Compound Group 1, D is a deuterium atom.

16. A light emitting element, comprising:
a first electrode;
a second electrode on the first electrode; and
an emission layer between the first electrode and the second electrode, and comprising a polycyclic compound represented by Formula 1: 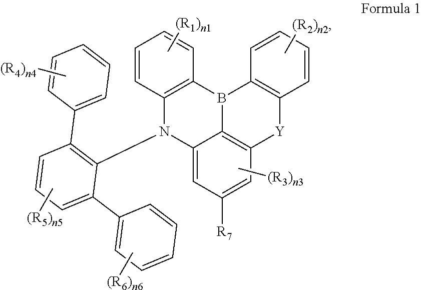
in Formula 1,
Y is S, Se, or Te,
R₁ to R₇ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
n1 and n2 are each independently an integer of 0 to 4,
n3 is an integer of 0 to 2,
n4 is an integer of 0 to 5,
n5 is an integer of 0 to 3, and
n6 is an integer of 0 to 5.

17. The light emitting element of claim 16, wherein the polycyclic compound represented by Formula 1 is represented by any one selected from among Formula 1-1a to Formula 1-1h: 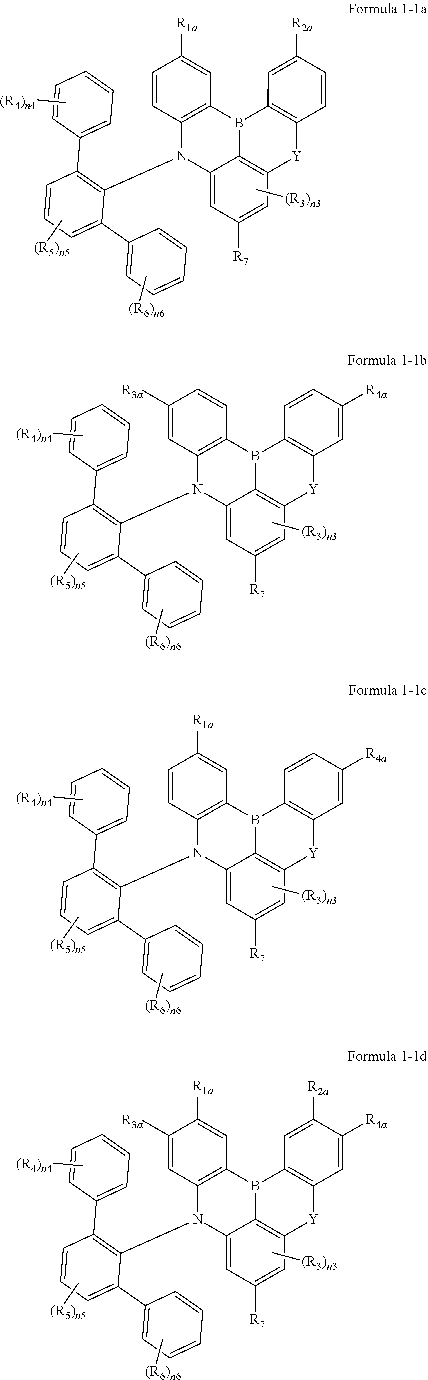 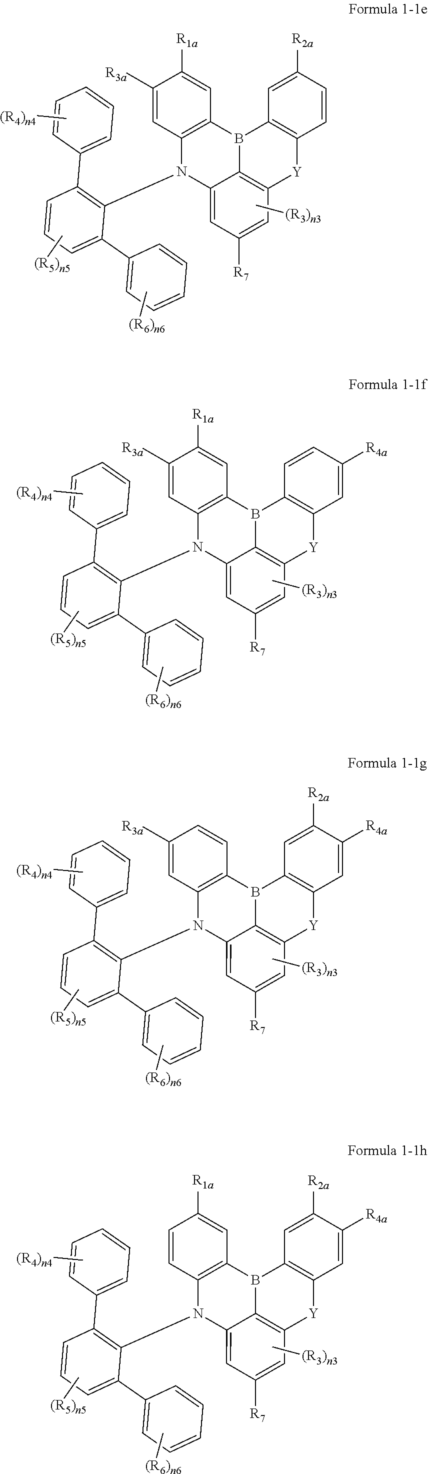
in Formula 1-1a to Formula 1-1h,
R₁ₐ to R₄ₐ are each independently a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and
R₃ to R₇, Y, and n3 to n6 are the same as respectively defined in Formula 1.

18. A polycyclic compound represented by Formula 1: 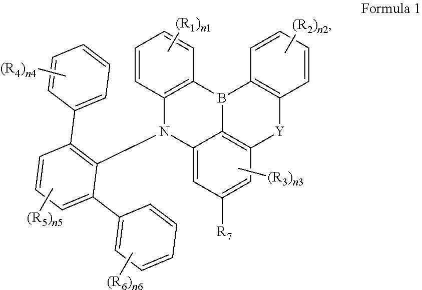
in Formula 1,
Y is S, Se, or Te,
R₁ to R₇ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
n1 and n2 are each independently an integer of 0 to 4,
n3 is an integer of 0 to 2,
n4 is an integer of 0 to 5,
n5 is an integer of 0 to 3, and
n6 is an integer of 0 to 5.

19. The polycyclic compound of claim 18, wherein the polycyclic compound represented by Formula 1 is represented by any one selected from among Formula 1-1a to Formula 1-1h: 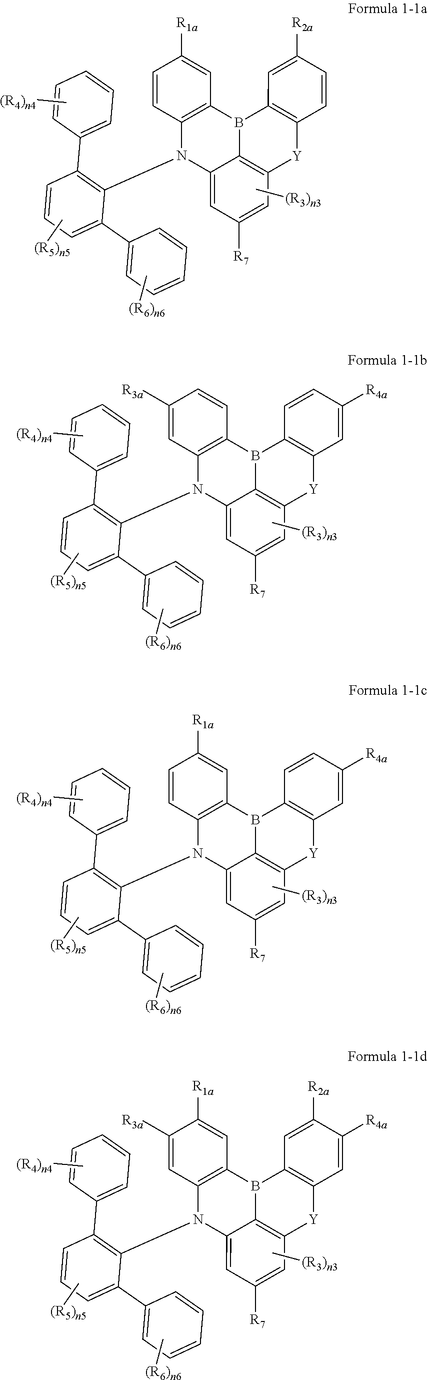 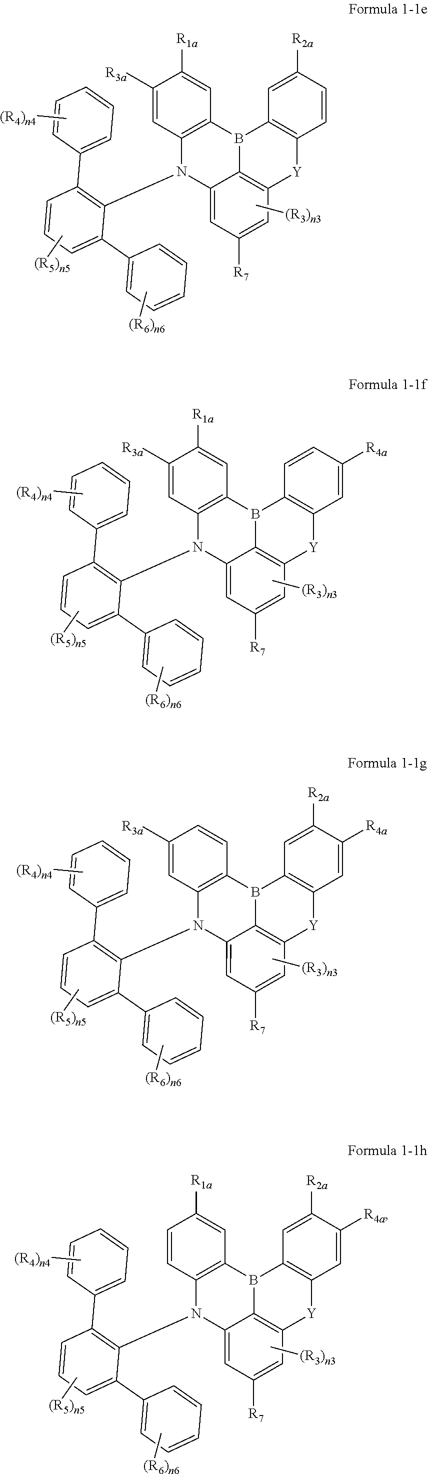
in Formula 1-1a to Formula 1-1h,
R₁ₐ to R₄ₐ are each independently a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, and
R₃ to R₇, Y, and n3 to n6 are the same as respectively defined in Formula 1.

20. The polycyclic compound of claim 18, wherein the polycyclic compound is any one of compounds in Compound Group 1: 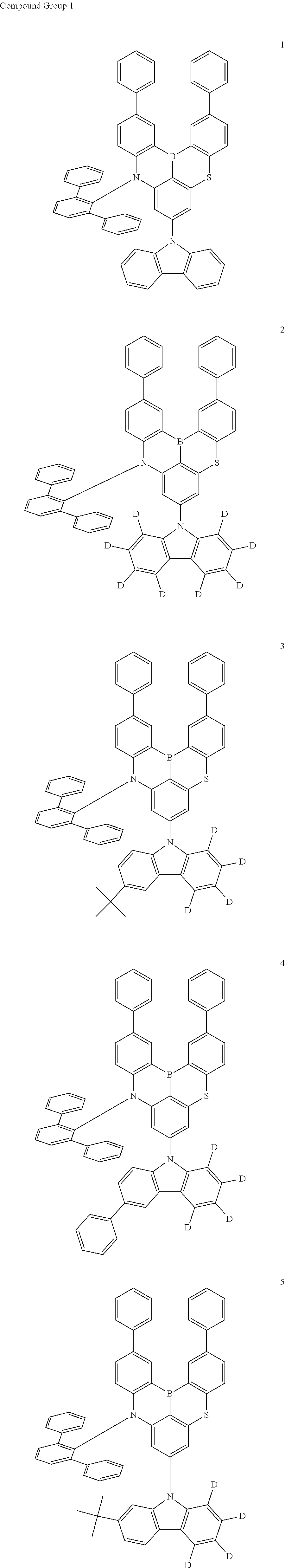 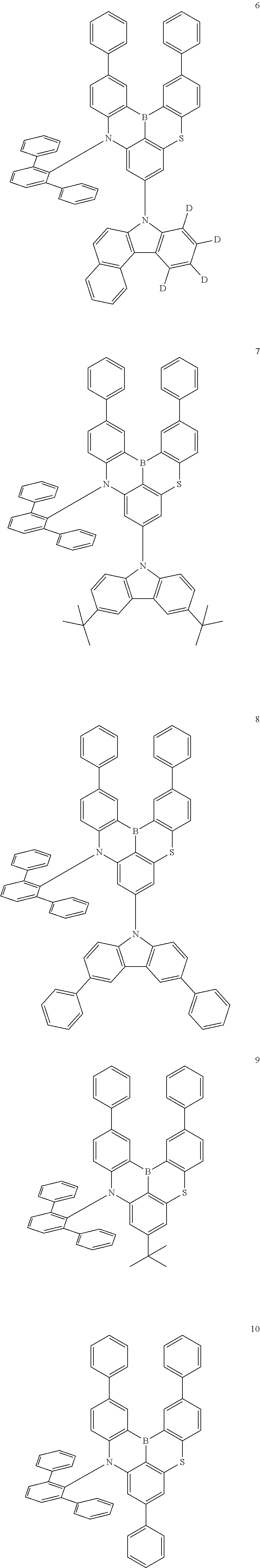 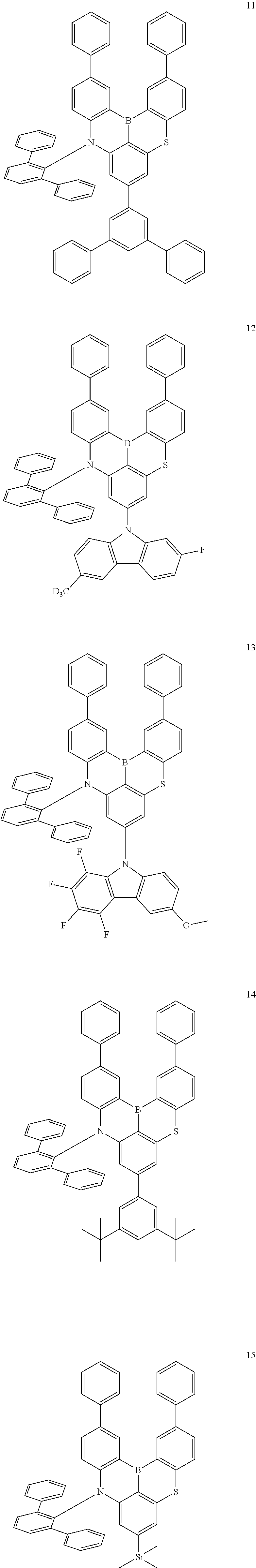 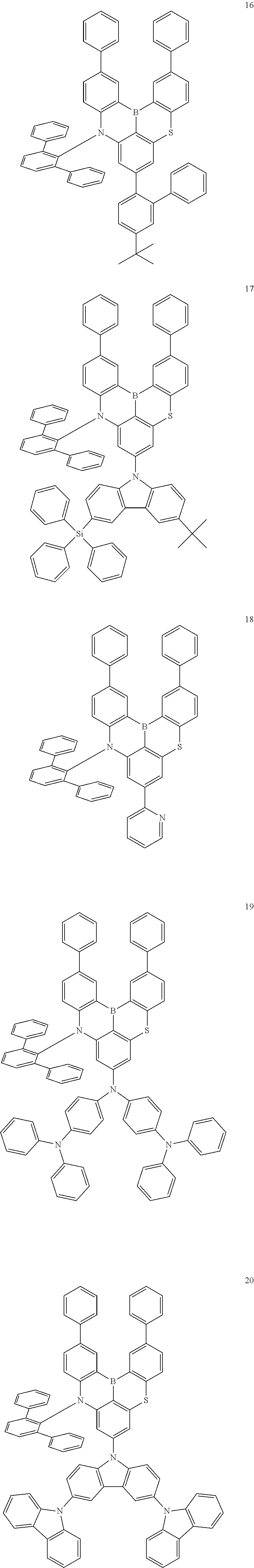 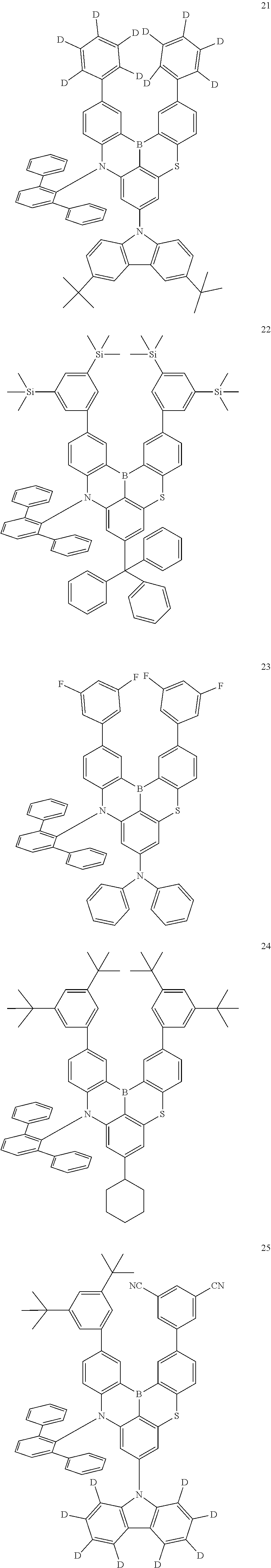 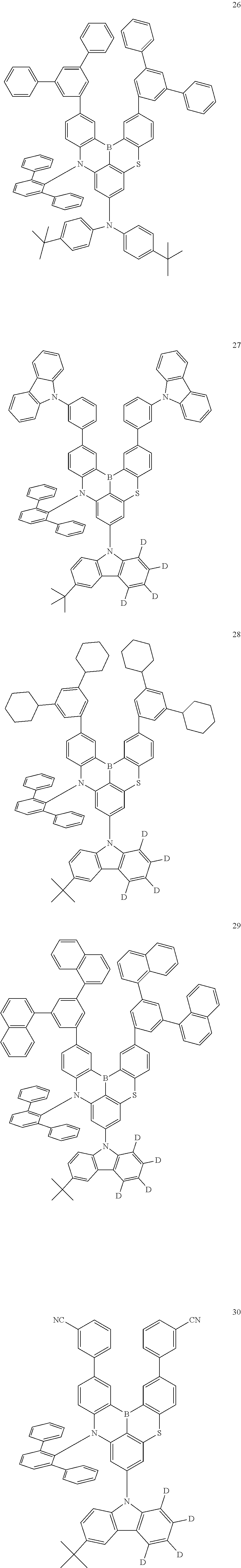 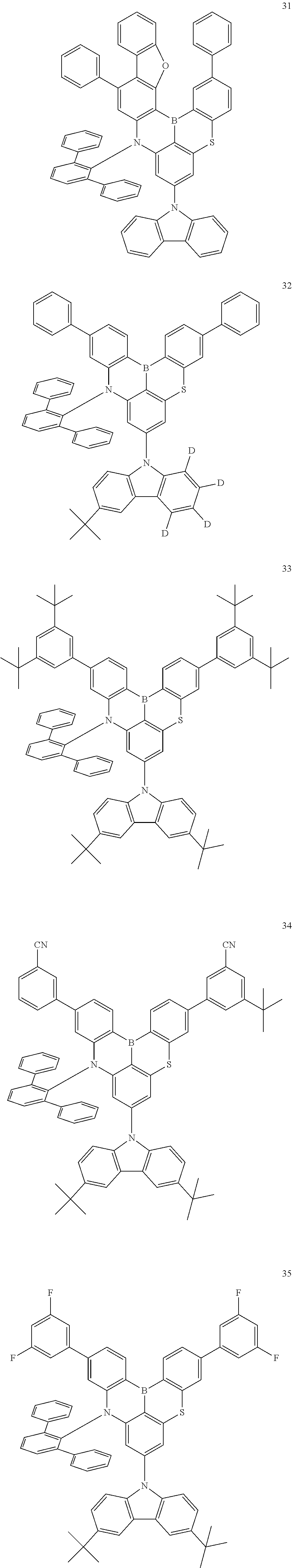 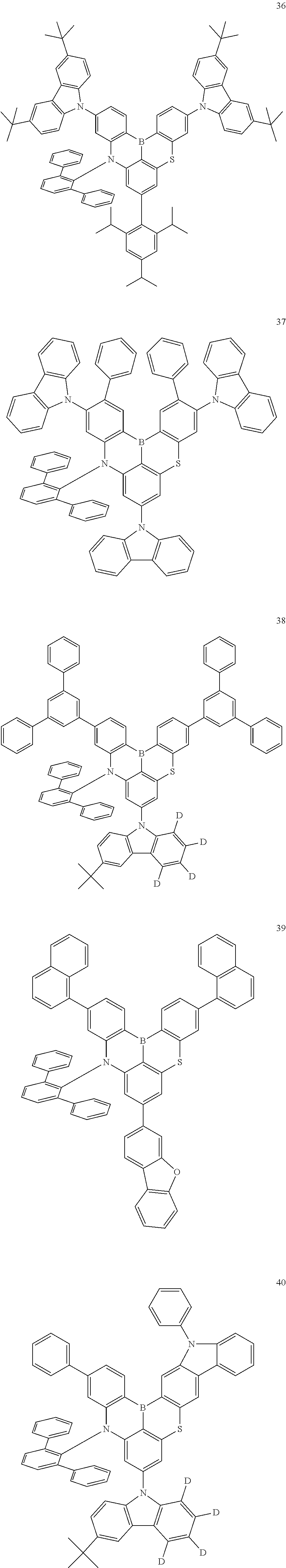 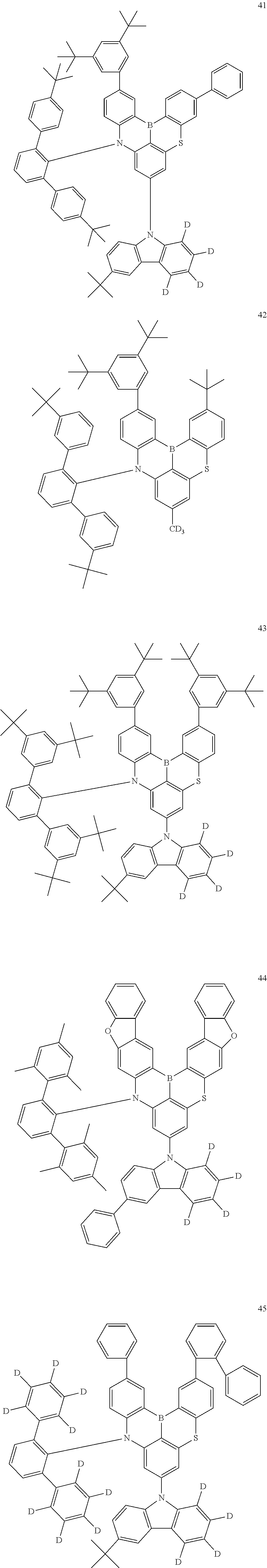 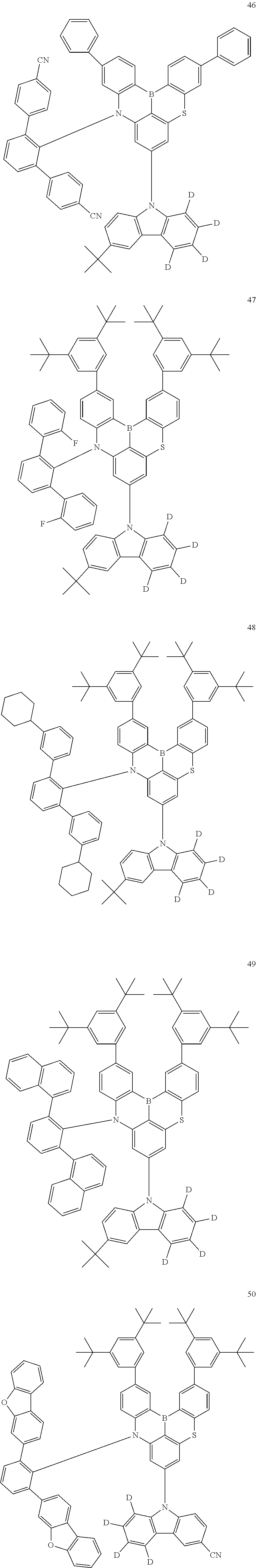 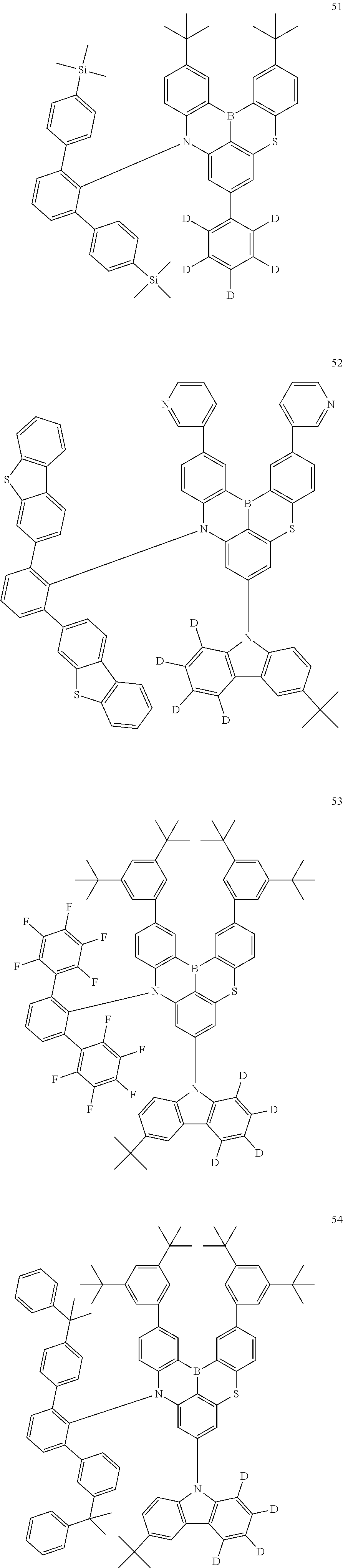 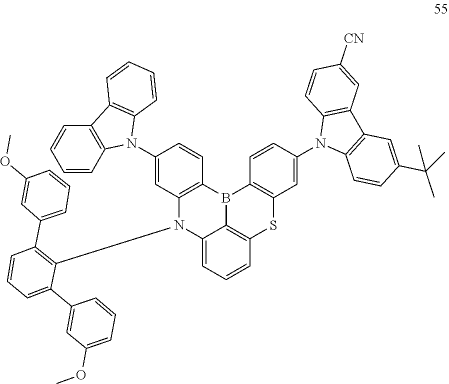 [SMILES: COc1cccc(-c2cccc(-c3cccc(OC)c3)c2N2c3cc(-n4c5ccccc5c5ccccc54)ccc3B3c4ccc(-n5c6ccc(C#N)cc6c6cc(C(C)(C)C)ccc65)cc4Sc4cccc2c43)c1] 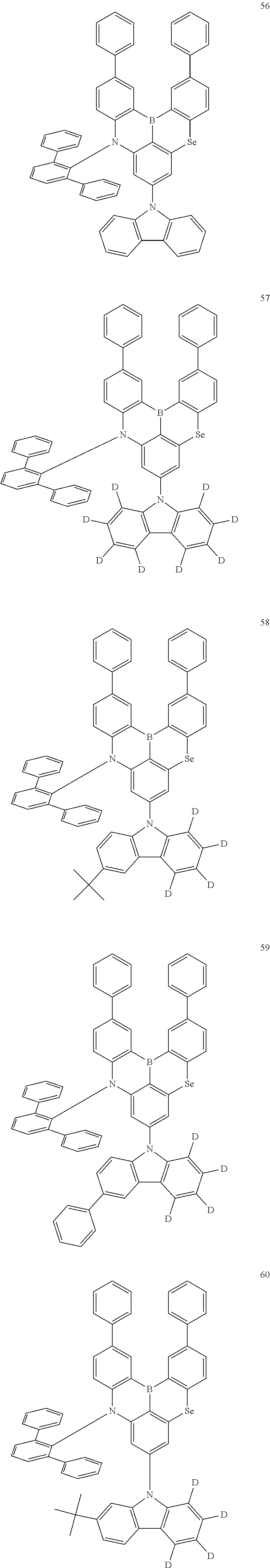 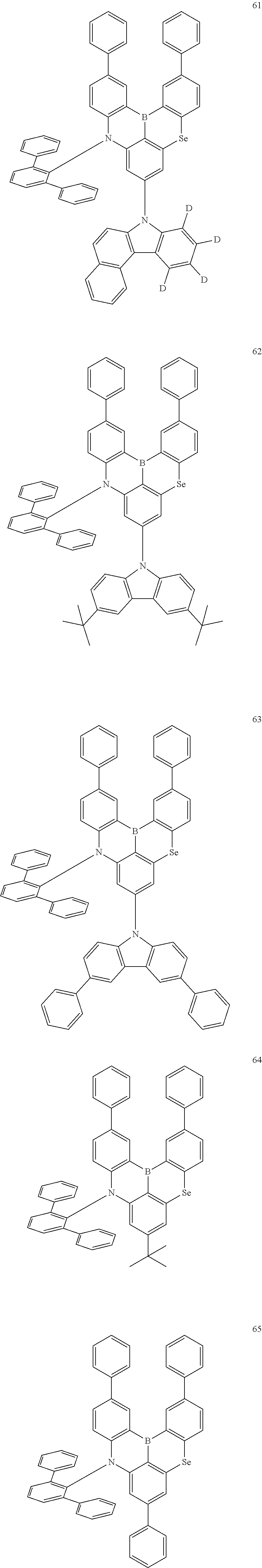 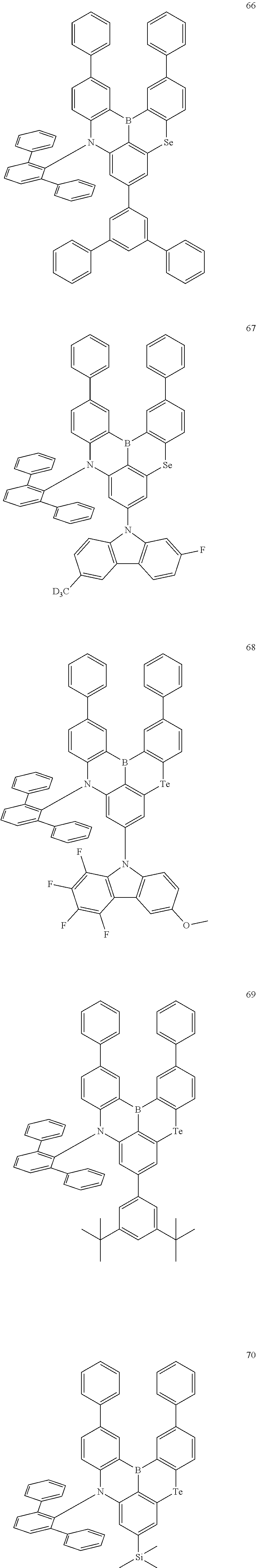 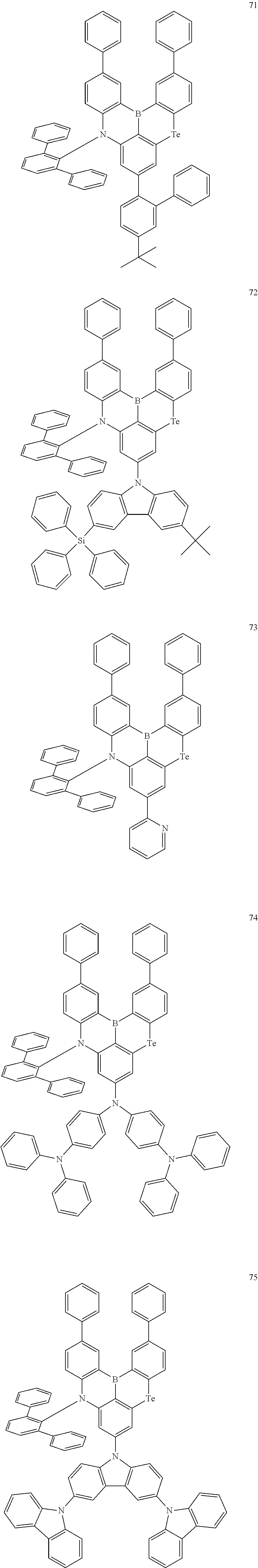 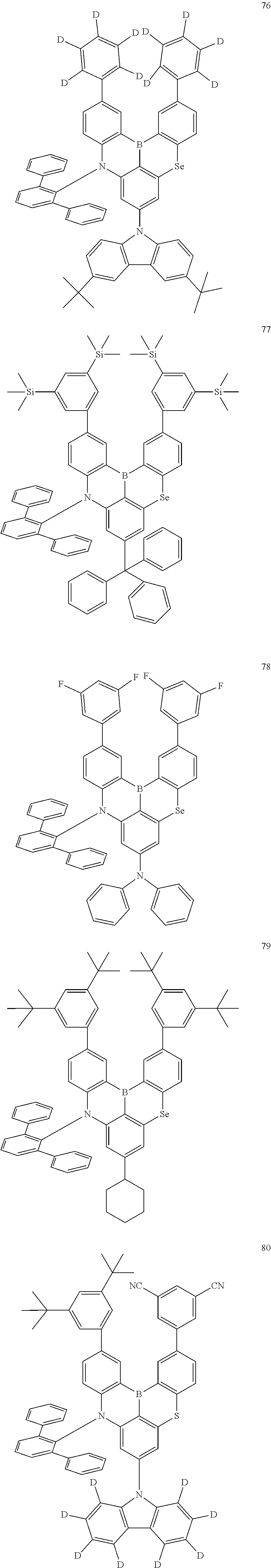 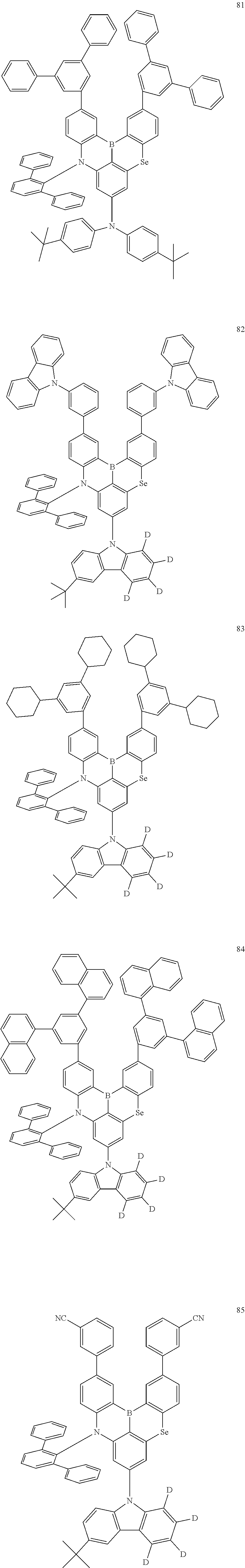 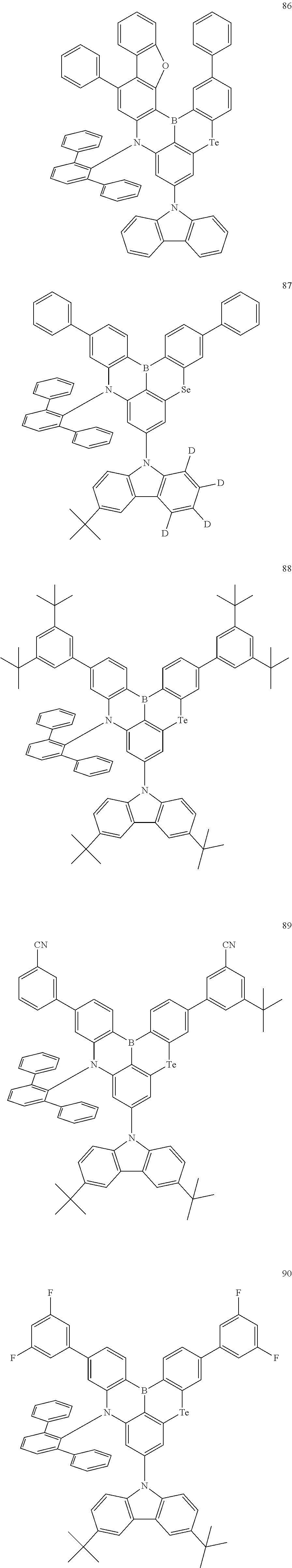 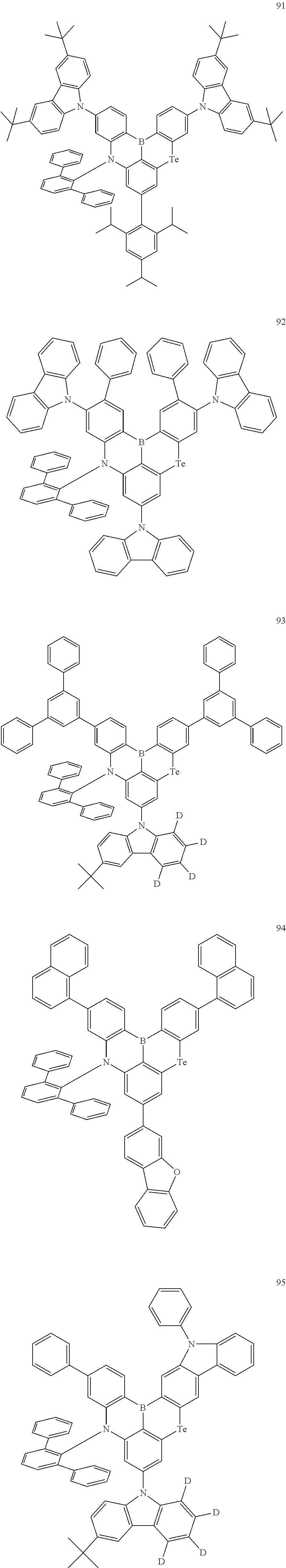 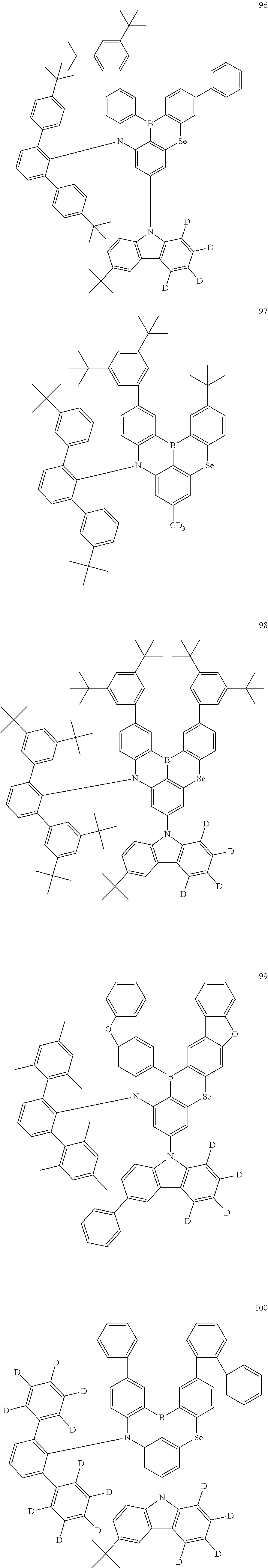 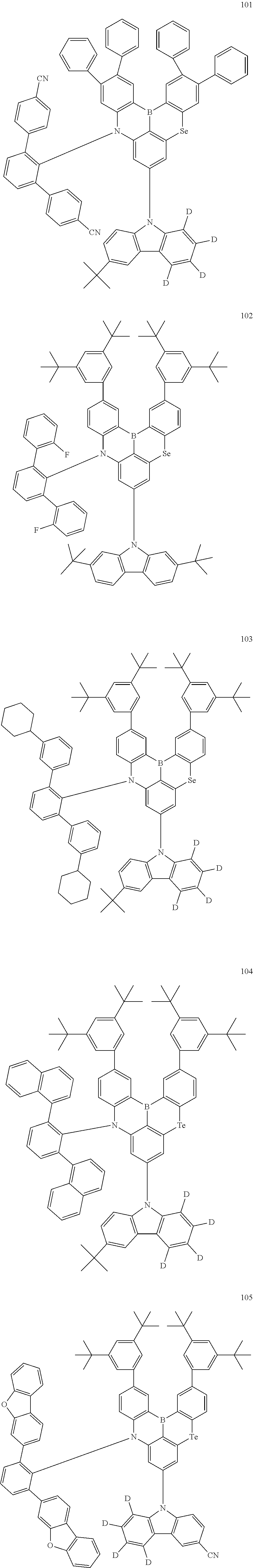 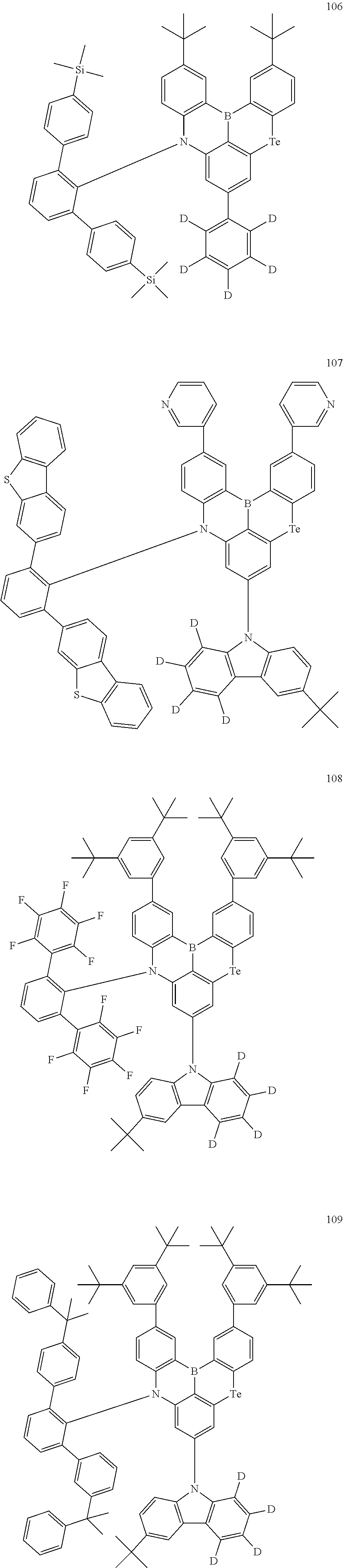 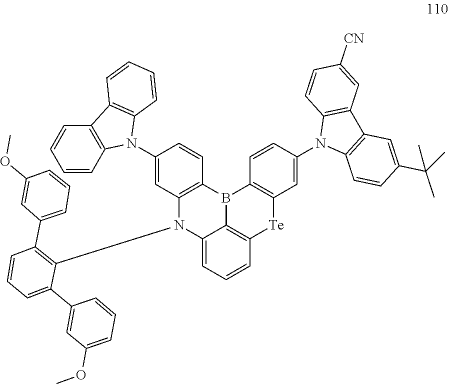 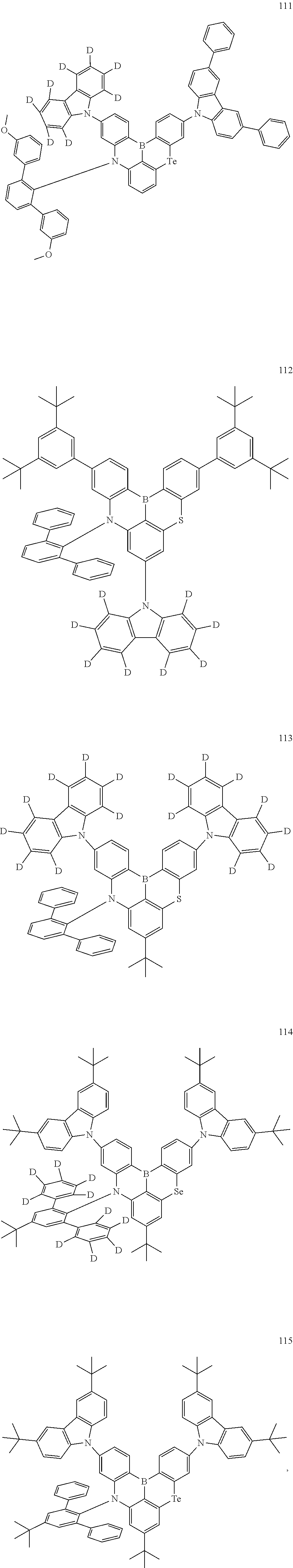
in Compound Group 1, D is a deuterium atom.
